(19) United States
(12) Patent Application Publication
(10) Pub. No.: US 2024/0043453 A1
(43) Pub. Date: Feb. 8, 2024

(54) HETEROCYCLIC COMPOUND AND AN ORGANIC ELECTROLUMINESCENCE DEVICE COMPRISING THE HETEROCYCLIC COMPOUND

(71) Applicant: IDEMITSU KOSAN CO.,LTD., Chiyoda-ku (JP)

(72) Inventors: Thomas SCHAEFER, Liestal (CH); Peter MURER, Oberwil (CH); Yuichi NISHIMAE, Basel (CH)

(73) Assignee: IDEMITSU KOSAN CO.,LTD., Chiyoda-ku (JP)

(21) Appl. No.: 18/251,978

(22) PCT Filed: Nov. 19, 2021
(86) PCT No.: PCT/IB2021/060748

§ 371 Date: May 5, 2023

(30) Foreign Application Priority Data
Nov. 20, 2020 (EP) 20208956.1

(51) Int. Cl. C07F 5/02; H10K 85/60; H10K 50/12; C09K 11/06

(52) U.S. Cl. CPC C07F 5/02; H10K 85/658; H10K 50/12; H10K 85/615; C09K 11/06

(57) ABSTRACT

Specific heterocyclic compounds, a material, preferably an emitter material, for an organic electroluminescence device containing the specific heterocyclic compounds, an electronic equipment containing the organic electroluminescence device, a light emitting layer containing at least one host and at least one dopant, where the dopant contains at least one of the heterocyclic compounds, and the use of the heterocyclic compounds in an organic electroluminescence device.

The present invention relates to specific heterocyclic compounds, a material, preferably an emitter material, for an organic electroluminescence device comprising said specific heterocyclic compounds, an organic electroluminescence device comprising said specific heterocyclic compounds, an electronic equipment comprising said organic electroluminescence device, a light emitting layer comprising at least one host and at least one dopant, wherein the dopant comprises at least one of said specific heterocyclic compounds, and the use of said heterocyclic compounds in an organic electroluminescence device.

When a voltage is applied to an organic electroluminescence device (hereinafter may be referred to as an organic EL device), holes are injected to an emitting layer from an anode and electrons are injected to an emitting layer from a cathode. In the emitting layer, injected holes and electrons are re-combined and excitons are formed.

An organic EL device comprises an emitting layer between the anode and the cathode. Further, there may be a case where it has a stacked layer structure comprising an organic layer such as a hole-injecting layer, a hole-transporting layer, an electron-injecting layer, an electron-transporting layer, etc.

US 2019/0067577 A1 relates to boron containing heterocyclic compounds for organic electronic devices, such as organic light emitting devices having a structure according to the following Formula I

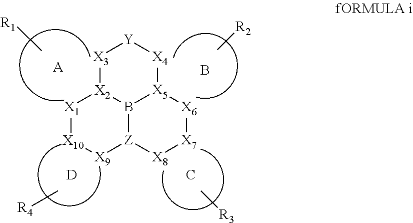

wherein
rings A, B, C, and D are each independently 5- or 6-membered aryl or heteroaryl rings; R₁, R₂, R₃ and R₄ each independently represent no substitution or up to the maximum available substitutions;
Y is NR, O, PR, S or Se; and
Z is N or P.

An example for a compound of formula I is the following compound

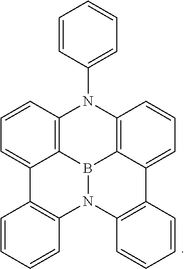 [SMILES: c1ccc(N2c3cccc4c3B3c5c(cccc52)-c2ccccc2N3c2ccccc2-4)cc1]

WO2020/135953 A1 relates to organic light-emitting molecules of the following formula and their use in organic light-emitting diodes (OLEDs) and in other optoelectronic devices.

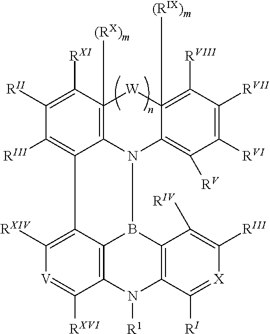

CN 111 471 061 A relates to an organic electroluminescent material containing boron and nitrogen and the application thereof in organic electroluminescent devices. The organic electroluminescent material contains boron and nitrogen and has the structure shown in the general formula (I).

However, the specific structure and substitution pattern of polycyclic compounds has a significant impact on the performance of the polycyclic compounds in organic electronic devices.

Notwithstanding the developments described above, there remains a need for organic electroluminescence devices comprising new materials, especially dopant (=emitter) materials, to provide improved performance of electroluminescence devices. In addition, said materials should be easily available in good yields.

Accordingly, it is an object of the present invention, with respect to the aforementioned related art, to provide materials suitable for organic electroluminescence devices, which ensure good performance of the organic electroluminescence devices, especially good EQEs and/or a long lifetime. More particularly, it should be possible to provide dopant (=emitter) materials, especially blue light emitting dopant materials having a narrow spectrum (smaller FWHM), i.e. good color purity when used as dopant in organic electroluminescence devices.

Said object is according to one aspect of the present invention solved by a heterocyclic compound represented by formula (I):

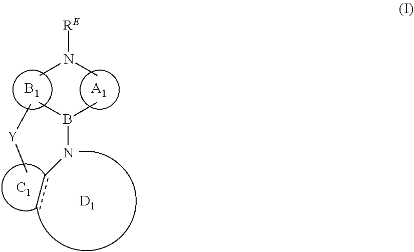

wherein
ring A₁, ring B₁ and ring C₁ each independently represents a substituted or unsubstituted aromatic group having 6 to 60 ring carbon atoms, preferably from 6 to 30, more preferably from 6 to 18 ring carbon atoms, or a substituted or unsubstituted heteroaromatic group having 5 to 60, preferably 5 to 30, more preferably 5 to 18 ring atoms;
ring D₁ represents a substituted or unsubstituted, preferably substituted, monocyclic ring having to 7 ring atoms, which may be fused with at least one unsubstituted or substituted non-aromatic group having 5 to 60 ring atoms; preferably, ring D₁ represents a substituted or unsubstituted, preferably a substituted, heteroaromatic monocyclic ring having 5 to 7 ring atoms, which may be fused with at least one unsubstituted or substituted non-aromatic group having 5 to 60 ring atoms or a substituted or unsubstituted non-heteroaromatic monocyclic ring having 5 to 7 ring atoms, which may be fused with at least one unsubstituted or substituted non-aromatic group having 5 to 60 ring atoms;
ring C₁ and ring D₁ are fused together by a shared single or double bond;
ring A₁ and ring D₁ may additionally be connected via a direct bond, O, S, NR²³, SiR²⁴R²⁵ or CR²⁷R²⁸, preferably via a direct bond;
R^{E} represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an iminyl group R²³—C═N, an alkynyl group having from 2 to 20 carbon atoms which is unsubstituted or substituted;
or
R^{E} or a substituent on R^{E} may be bonded to the ring A₁ and/or to the ring B₁ or to a substituent on the ring A₁ and or the ring B₁ to form a ring structure which is unsubstituted or substituted,
Y represents a direct bond, O, S, NR²³, SiR²⁴R²⁵ or CR²⁷R²⁸, preferably a direct bond;
in the case that Y is a direct bond, ring B₁ and C₁ may additionally be connected via O, S, NR²³, SiR²⁴R²⁵ or CR²⁷R²⁸;
R²³, R²⁴, R²⁵, R²⁷ and R²⁸ each independently represents an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted;
and/or
R²³, R²⁴, R²⁵, R²⁷ and R²⁸ may be bonded to the ring B₁ and/or to the ring C₁ to form a ring structure which is unsubstituted or substituted;
and/or
two residues R²⁴ and R²⁵ and/or two residues R²⁷ and R²⁸ together form a ring structure which is unsubstituted or substituted.

Wherein the term “substituted or unsubstituted” referred to above or hereinafter includes an aryl group having from 6 to 60, preferably from 6 to 30, more preferably from 6 to 18 ring carbon atoms which is in turn unsubstituted or substituted, a heteroaryl group having from 5 to 60, prefer-ably 5 to 30, more preferably 5 to 18 ring atoms which is in turn unsubstituted or substituted, an alkyl group having 1 to 20, preferably 1 to 8 carbon atoms, a cycloalkyl group having 3 to 20, preferably 3 to 10 carbon atoms, a group OR²⁰, an alkylhalide group having 1 to 20, preferably 1 to 8 carbon atoms, a group N(R²²)₂, a halogen atom (fluorine, chlorine, bromine, iodine), a cy-ano group, a carboxyalkyl group having 1 to 20 carbon atoms, preferably 1 to 8 carbon atoms, a carboxamidalkyl group having 1 to 20 carbon atoms, preferably 1 to 8 carbon atoms, a silyl group SiR²⁴R²⁵R²⁶, B(R²¹)₂, a group SR²⁰, a carboxyaryl group having 6 to 18 ring carbon atoms in the aryl residue and a carboxamidaryl group having 6 to 18 ring carbon atoms in the aryl residue;
or
two adjacent substituents together form a ring structure which is in turn unsubstituted or substituted:
R²⁰, R²¹ and R²² each independently represents an aryl group having from 6 to 60, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted and which is linked via a carbon atom to N, O, S or B; an alkyl group having from 1 to 20 carbon atoms which is unsubstituted or substituted; or a cycloalkyl group having from 3 to 20 ring carbon atoms which is unsubstituted or substituted;
and/or
two residues R²² and/or two residues R²¹ together form a ring structure which is unsubstituted or substituted;
or
R²⁰, R²¹, and/or R²² together with an adjacent substituent form a ring structure which is unsubstituted or substituted;
R²⁶ represents an aryl group having from 6 to 60, preferably from 6 to 30, more preferably from 6 to 18 ring carbon atoms which is unsubstituted or substituted; a heteroaryl group having from to 60, preferably 5 to 30, more preferably 5 to 18 ring atoms which is unsubstituted or substituted and which is linked via a carbon atom to N or Si; an alkyl group having from 1 to 20 carbon atoms which is unsubstituted or substituted; or a cycloalkyl group having from 3 to 20 ring carbon atoms which is unsubstituted or substituted; and
R²⁴, R²⁵ are defined above.

The term “preferably substituted” in the definition of D₁ preferably includes at least one substituent as defined as R²⁹ mentioned below, wherein R²⁹ is not hydrogen.

The compounds of formula (I) can be in principal used in any layer of an EL device. Preferably, the compound of formula (I) is a dopant (=emitter) in organic EL elements, especially in the light-emitting layer, more preferably a fluorescent dopant. Particularly, the compounds of formula (I) are used as fluorescent dopants in organic EL devices, especially in the light-emitting layer.

The term organic EL device (organic electroluminescence device) is used interchangeably with the term organic light-emitting diode (OLED) in the present application.

It has been found that the specific compounds of formula (I) show a narrow emission characteristic, preferably a narrow fluorescence, more preferably a narrow blue fluorescence. Such a narrow emission characteristic is suitable to prevent energy losses by outcoupling. The compounds of formula (I) according to the present invention preferably have a Full width at half maximum (FWHM) of lower than 30 nm, more preferably lower than 25 nm.

It has further been found that organic EL devices comprising the compounds of the present invention are generally characterized by high external quantum efficiencies (EQE) and long life-times, especially when the specific compounds of formula (I) are used as dopants (light emitting material), especially fluorescent dopants in organic electroluminescence devices. Further, the inventors developed a preparation process which makes compounds are easily available in good yields.

Examples of the optional substituent(s) indicated by “substituted or unsubstituted” and “may be substituted” referred to above or hereinafter include an aryl group having from 6 to 60, preferably from 6 to 30, more preferably from 6 to 18 ring carbon atoms which is in turn unsubstituted or substituted, a heteroaryl group having from 5 to 60, preferably 5 to 30, more preferably 5 to 18 ring atoms which is in turn unsubstituted or substituted, an alkyl group having 1 to 20, prefer-ably 1 to 8 carbon atoms, a cycloalkyl group having 3 to 20, preferably 3 to 10 carbon atoms, a group OR²⁰, an alkylhalide group having 1 to 20, preferably 1 to 8 carbon atoms, a group N(R²²)₂, a halogen atom (fluorine, chlorine, bromine, iodine), a cyano group, a carboxyalkyl group having 1 to 20 carbon atoms, preferably 1 to 8 carbon atoms, a carboxamidalkyl group having 1 to 20 carbon atoms, preferably 1 to 8 carbon atoms, a silyl group SiR²⁴R²⁵R²⁶, B(R²¹)₂, a group SR²⁰, a carboxyaryl group having 6 to 18 ring carbon atoms in the aryl residue and a carboxamidaryl group having 6 to 18 ring carbon atoms in the aryl residue; or
two adjacent substituents together form a ring structure which is in turn unsubstituted or substituted;
R²⁰, R²¹ and R²² each independently represents an aryl group having from 6 to 60, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted and which is linked via a carbon atom to N, O, S or B; an alkyl group having from 1 to 20 carbon atoms which is unsubstituted or substituted; or a cycloalkyl group having from 3 to 20 ring carbon atoms which is unsubstituted or substituted; and/or
two residues R²² and/or two residues R²¹ together form a ring structure which is unsubstituted or substituted;
or
R²⁰, R²¹, and/or R²² together with an adjacent substituent form a ring structure which is unsubstituted or substituted;
R²⁶ represents an aryl group having from 6 to 60, preferably from 6 to 30, more preferably from 6 to 18 ring carbon atoms which is unsubstituted or substituted; a heteroaryl group having from to 60, preferably 5 to 30, more preferably 5 to 18 ring atoms which is unsubstituted or substituted and which is linked via a carbon atom to N or Si; an alkyl group having from 1 to 20 carbon atoms which is unsubstituted or substituted; or a cycloalkyl group having from 3 to 20 ring carbon atoms which is unsubstituted or substituted; and
R²⁴, R²⁵ are defined above.

The terms hydrogen, halogen, an alkyl group having from 1 to 20 carbon atoms which is unsubstituted or substituted, an alkylhalide group having from 1 to 20 carbon atoms which is unsubstituted or substituted, a cycloalkyl group having from 3 to 20 ring carbon atoms which is unsubstituted or substituted, a substituted or unsubstituted aromatic group having 6 to 60, preferably from 6 to 30, more preferably from 6 to 18 ring carbon atoms; a substituted or unsubstituted heteroaromatic group having 5 to 60, preferably 5 to 30, more preferably 5 to 18 ring atoms, a carboxyalkyl group having 1 to 20 carbon atoms, preferably 1 to 8 carbon atoms, a carboxamidalkyl group having 1 to 20 carbon atoms, preferably 1 to 8 carbon atoms, a carboxyaryl group having 6 to 18 ring carbon atoms in the aryl residue, a carboxamidaryl group having 6 to 18 ring carbon atoms in the aryl residue, N(R²²)₂, OR²⁰, SR²⁰, SR²⁰, SiR²⁴R²⁵R²⁶ and B(R²¹)₂, are known in the art and generally have the following meaning, if said groups are not further specified in specific embodiments mentioned below:

In the invention, hydrogen includes isomers differing in the number of neutrons, i.e. protium, deuterium and tritium.

The substituted or unsubstituted aromatic group (also called aryl group) having 6 to 60, preferably from 6 to 30, more preferably from 6 to 18 ring carbon atoms most preferably having from 6 to 13 ring carbon atoms, may be a non-condensed aromatic group or a condensed aromatic group. Specific examples thereof include phenyl group, naphthyl group, phenanthryl group, bi-phenyl group, terphenyl group, fluoranthenyl group, triphenylenyl group, phenanthrenyl group, fluorenyl group, indenyl group, anthracenyl, chrysenyl, spirofluorenyl group, benzo[c]phenanthrenyl group, with phenyl group, naphthyl group, biphenyl group, terphenyl group, phenanthryl group, triphenylenyl group, fluorenyl group, indenyl group and fluoranthenyl group being preferred, phenyl group, 1-naphthyl group, 2-naphthyl group, biphenyl-2-yl group, biphenyl-3-yl group, biphenyl-4-yl group, phenanthrene-9-yl group, phenanthrene-3-yl group, phenanthrene-2-yl group, triphenylene-2-yl group, fluorene-2-yl group, especially a 9,9-di-C₁₋₂₀alkylfluorene-2-yl group, like a 9,9-dimethylfluorene-2-yl group, a 9,9-di-C₆₋₁₈arylfluorene-2-yl group, like a 9,9-diphenylfluorene-2-yl group, or a 9,9-di-C₆₋₁₈heteroarylfluorene-2-yl group, 1,1-dimethylindenyl group, fluoranthene-3-yl group, fluoranthene-2-yl group and fluoranthene-8-yl group being more preferred, and phenyl group being most preferred.

In the case of the rings A₁, B₁ and C₁, preferred substituted or unsubstituted aromatic groups having 6 to 60, preferably from 6 to 30, more preferably from 6 to 18 ring carbon atoms are mentioned below.

The substituted or unsubstituted heteroaromatic group (also called heteroaryl group) having 5 to 60, preferably 5 to 30, more preferably 5 to 18 ring atoms, most preferably having from 5 to 13 ring atoms, may be a non-condensed heteroaromatic group or a condensed heteroaromatic group. Specific examples thereof include the residues of pyrrole ring, isoindole ring, benzofuran ring, isobenzofuran ring, benzothiophene, dibenzothiophene ring, isoquinoline ring, quinoxaline ring, quinazoline, phenanthridine ring, phenanthroline ring, pyridine ring, pyrazine ring, pyrimidine ring, pyridazine ring, indole ring, quinoline ring, acridine ring, carbazole ring, furan ring, thi-ophene ring, benzoxazole ring, benzothiazole ring, benzimidazole ring, dibenzofuran ring, triazine ring, oxazole ring, oxadiazole ring, thiazole ring, thiadiazole ring, triazole ring, imidazole ring, indolidine ring, imidazopyridine ring, 4-imidazo[1,2-a]benzimidazoyl, 5-benzimidazo[1,2-a]benzimidazoyl, and benzimidazolo[2,1-b][1,3]benzothiazolyl, with the residues of benzofuran ring, indole ring, benzothiophene ring, dibenzofuran ring, carbazole ring, and dibenzothiophene ring being preferred, and the residues of benzofuran ring, 1-phenylindol ring, benzothiophene ring, dibenzofuran-1-yl group, dibenzofuran-3-yl group, dibenzofuran-2-yl group, dibenzofuran-4-yl group, 9-phenylcarbazole-3-yl group, 9-phenylcarbazole-2-yl group, 9-phenylcarbazole-4-yl group, dibenzothiophene-2-yl group, and dibenzothiophene-4-yl, dibenzothiophene-1-yl group, and dibenzothiophene-3-yl group being more preferred.

In the case of the rings A₁, B₁ and C₁, preferred substituted or unsubstituted heteroaromatic groups having 5 to 60, preferably 5 to 30, more preferably 5 to 18 ring atoms are mentioned below.

Examples of the alkyl group having from 1 to 20 carbon atoms which is unsubstituted or substituted include methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, 1-methylpentyl group, with methyl group, ethyl group, n-propyl group, isopropyl group, n-butyl group, s-butyl group, isobutyl group, t-butyl group being preferred. Preferred are alkyl groups having 1 to 8 carbon atoms, more preferably 1 to 4 carbon atoms. Suitable examples for alkyl groups having 1 to 8 carbon atoms respectively 1 to 4 carbon atoms are mentioned before.

Examples of the alkylhalide group having from 1 to 20 carbon atoms which is unsubstituted or substituted include those disclosed as alkyl groups wherein the hydrogen atoms thereof are partly or entirely substituted by halogen atoms. Preferred alkylhalide groups are fluoroalkyl groups having 1 to 20 carbon atoms including the alkyl groups mentioned above wherein the hydrogen atoms thereof are partly or entirely substituted by fluorine atoms, for example CF₃.

Examples of the cycloalkyl group having from 3 to 20 ring carbon atoms which is unsubstituted or substituted include cyclopropyl group, cyclobutyl group, cyclopentyl group, cyclohexyl group, cyclooctyl group, and adamantyl group, with cyclopentyl group, and cyclohexyl group being preferred. Preferred are cycloalkyl groups having 3 to 10 carbon atoms. Suitable examples for cyclo-alkyl groups having 3 to 10 carbon atoms are mentioned before.

Examples of halogen atoms include fluorine, chlorine, bromine, and iodine, with fluorine being preferred.

The group OR²⁰ is preferably a C₁₋₂₀alkoxy group or a C₆₋₁₈aryloxy group. Examples of an alkoxy group having 1 to 20 carbon atoms, preferably 1 to 8 carbon atoms, include those having an alkyl portion selected from the alkyl groups mentioned above. Examples of an aryloxy group having 6 to 18 ring carbon atoms include those having an aryl portion selected from the aryl groups mentioned above, for example —OPh.

The group SR²⁰ is preferably a C₁₋₂₀alkylthio group or a C₆₋₁₈arylthio group. Examples of an alkylthio group having 1 to 20 carbon atoms, preferably 1 to 8 carbon atoms, include those having an alkyl portion selected from the alkyl groups mentioned above. Examples of an arylthio group having 6 to 18 ring carbon atoms include those having an aryl portion selected from the aryl groups mentioned above, for example —SPh.

The group N(R²²)₂ is preferably an C₁₋₂₀alkyl and/or C₆₋₁₈aryl and/or heteroaryl (having 5 to 18 ring atoms) substituted amino group. Examples of an alkylamino group (alkyl substituted amino group) having 1 to 20 ring carbon atoms include those having an alkyl portion selected from the alkyl groups mentioned above. Examples of an arylamino group (aryl substituted amino group) having 6 to 18 ring carbon atoms include those having an aryl portion selected from the aryl groups mentioned above, for example —NPh₂. Examples of a heteroarylamino group (heteroaryl substituted amino group), preferably a heteroarylamino group having 5 to 18 ring atoms include those having an aryl portion selected from the heteroaryl groups mentioned above.

The group B(R²¹)₂ is preferably an C₁₋₂₀alkyl and/or C₆₋₁₈aryl and/or heteroaryl (having 5 to 18 ring atoms) substituted boron group. Examples of an alkylboron group (alkyl substituted boron group) having 1 to 20 ring carbon atoms include those having an alkyl portion selected from the alkyl groups mentioned above. Examples of an arylboron group (aryl substituted boron group) having 6 to 18 ring carbon atoms include those having an aryl portion selected from the aryl groups mentioned above. Examples of a heteroarylboron group (heteroaryl substituted boron group), preferably a heteroarylboron group having 5 to 18 ring atoms include those having an aryl portion selected from the heteroaryl groups mentioned above.

The group SiR²⁴R²⁵R²⁶ is preferably a C₁₋₂₀alkyl and/or C₆₋₁₈aryl substituted silyl group. Preferred examples of C₁₋₂₀alkyl and/or C₆₋₁₈aryl substituted silyl groups include alkylsilyl groups having 1 to 8 carbon atoms in each alkyl residue, preferably 1 to 4 carbon atoms, including trimethylsilyl group, triethylsilyl group, tributylsilyl group, dimethylethylsilyl group, t-butyldimethylsilyl group, propyldimethylsilyl group, dimethylisopropylsilyl group, dimethylpropylsilyl group, dimethylbutyl-silyl group, dimethyltertiarybutylsilyl group, diethylisopropylsilyl group, and arylsilyl groups having 6 to 18 ring carbon atoms in each aryl residue, preferably triphenylsilyl group, and alkyl/arylsilyl groups, preferably phenyldimethylsilyl group, diphenylmethylsilyl group, and diphenyltertiarybutylsilyl group, with diphenyltertiarybutylsilyl group and t-butyldimethylsilyl group being preferred.

Examples of a carboxyalkyl group having 1 to 20 carbon atoms, preferably 1 to 8 carbon atoms, those having an alkyl portion selected from the alkyl groups mentioned above.

Examples of a fluoroalkyl group having 1 to 20 carbon atoms include the alkyl groups mentioned above wherein the hydrogen atoms thereof are partly or entirely substituted by fluorine atoms.

Examples of a carboxamidalkyl group (alkyl substituted amide group) having 1 to 20 carbon atoms, preferably 1 to 8 carbon atoms include those having an alkyl portion selected from the alkyl groups mentioned above.

Examples of a carboxamidaryl group (aryl substituted amide group) having 6 to 18 carbon atoms, preferably 6 to 13 carbon atoms, include those having an aryl portion selected from the aryl groups mentioned above.

The optional substituents preferably each independently represents an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; CN; N(R²²)₂; SiR²⁴R²⁵R²⁶, SR²⁰ or OR²⁰; or
two adjacent substituents together form a ring structure which is in turn unsubstituted or substituted;
R²⁰ and R²² each independently represents an aryl group having from 6 to 18 ring carbon atoms which is unsubstituted or substituted; a heteroaryl group having from 5 to 18 ring atoms which is unsubstituted or substituted and which is linked via a carbon atom to N or O or S; an alkyl group having from 1 to 20 carbon atoms which is unsubstituted or substituted; or a cycloalkyl group having from 3 to 20 ring carbon atoms which is unsubstituted or substituted; or
R²⁰ and/or R²² together with an adjacent substituent form a ring structure which is in turn unsubstituted or substituted;
R²⁴, R²⁵ and R²⁶ represents an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted.

More preferably, the optional substituents each independently represents an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; CN; or N(R²²)₂;
or
two adjacent substituents together form a ring structure which is in turn unsubstituted or substituted:
R²² represents an aryl group having from 6 to 18 ring carbon atoms which is unsubstituted or substituted; or an alkyl group having from 1 to 20 carbon atoms which is unsubstituted or substituted;
or
R²² together with an adjacent substituent forms a ring structure which is in turn unsubstituted or substituted.

Most preferably, the optional substituents each independently represents an alkyl group having 1 to 4 carbon atoms which is unsubstituted or substituted; a cycloalkyl group having from 3 to ring carbon atoms which is unsubstituted or substituted; an aryl group having 6 to 13 ring carbon atoms which is unsubstituted or substituted; a heteroaryl group having from 5 to 13 ring atoms which is unsubstituted or substituted; CN; or N(R²²)₂;
or
two adjacent substituents together form a ring structure which is in turn unsubstituted or substituted;
R²² represents an aryl group having from 6 to 18 ring carbon atoms which is unsubstituted or substituted; or an alkyl group having from 1 to 20 carbon atoms which is unsubstituted or substituted.

The optional substituents mentioned above may be further substituted by one or more of the optional substituents mentioned above.

The number of the optional substituents depends on the group which is substituted by said substituent(s). The maximum number of possible substituents is defined by the number of hydrogen atoms present. Preferred are 1, 2, 3, 5, 6, 7, 8 or 9 optional substituents per group which is substituted, more preferred are 1, 2, 3, 5, 5, 6 or 7 optional substituents, most preferred are 1, 2, 3, 4 or 5 optional substituents, further most preferred are 1, 2, 3, 4 or 5 optional substituents, even further most preferred are 1, 2, 3 or 4 optional substituents and even more further most preferred are 1 or 2 optional substituents per group which is substituted. In a further preferred embodiment, some or all of the groups mentioned above are unsubstituted.

In a further preferred embodiment, the total number of substituents in the compound of formula (I) is 0, 1, 2, 3, 4, 5, 6, 7 or 8, preferably 0, 1, 2, 3, 4, 5, or 6, i.e. the remaining residues are hydrogen.

The “carbon number of a to b” in the expression of “substituted or unsubstituted X group having a to b carbon atoms” is the carbon number of the unsubstituted X group and does not include the carbon atom(s) of an optional substituent.

The term “unsubstituted” referred to by “unsubstituted or substituted” means that a hydrogen atom is not substituted by one the groups mentioned above.

An index of 0 in the definition in any formula mentioned above and below means that a hydro-gen atom is present at the position defined by said index.

### The Compounds of Formula (I)

In the heterocyclic compounds represented by formula (I)

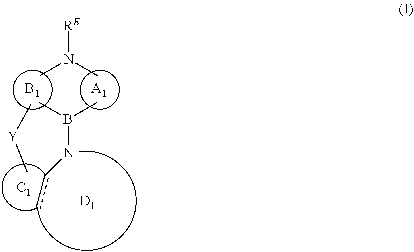

the residues have the following meanings:
ring A₁, ring B₁ and ring C₁ each independently represents a substituted or unsubstituted aromatic group having 6 to 60, preferably from 6 to 30, more preferably from 6 to 18 ring carbon atoms, or a substituted or unsubstituted heteroaromatic group having 5 to 60, preferably 5 to 30, more preferably 5 to 18 ring atoms;
ring D₁ represents a substituted or unsubstituted, preferably substituted, monocyclic ring having to 7 ring atoms, which may be fused with at least one unsubstituted or substituted non-aromatic group having 5 to 60 ring atoms; preferably, ring D₁ represents a substituted or unsubstituted, preferably substituted, heteroaromatic monocyclic ring having 5 to 7 ring atoms, which may be fused with at least one unsubstituted or substituted non-aromatic group having 5 to 60 ring atoms or a substituted or unsubstituted non-heteroaromatic monocyclic ring having 5 to 7 ring atoms, which may be fused with at least one unsubstituted or substituted non-aromatic group having 5 to 60 ring atoms;
ring C₁ and ring D₁ are fused together by a shared single or double bond;
ring A₁ and ring D₁ may additionally be connected via a direct bond, O, S, NR²³, SiR²⁴R²⁵ or CR²⁷R²⁸;
R^{E} represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an iminyl group R²³—C═N, an alkynyl group having from 2 to 20 carbon atoms which is unsubstituted or substituted; or
R^{E} or a substituent on R^{E} may be bonded to the ring A₁ and/or to the ring B₁ or to a substituent on the ring A₁ and or the ring B₁ to form a ring structure which is unsubstituted or substituted,
Y represents a direct bond, O, S, NR²³, SiR²⁴R²⁵ or CR²⁷R²⁸, preferably a direct bond;
in the case that Y is a direct bond, ring B₁ and C₁ may additionally be connected via O, S, NR²³, SiR²⁴R²⁵ or CR²⁷R²⁸;
R²³, R²⁴, R²⁵, R²⁷ and R²⁸ each independently represents an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted;
and/or
R²³, R²⁴, R²⁵, R²⁷ and R²⁸ may be bonded to the ring B₁ and/or to the ring C₁ to form a ring structure which is unsubstituted or substituted;
and/or
two residues R²⁴ and R²⁵ and/or two residues R²⁷ and R²⁸ together form a ring structure which is unsubstituted or substituted.

Preferably, rings A₁ and B₁ each independently represents a substituted or unsubstituted aromatic group having 6 to 60, preferably from 6 to 30, more preferably from 6 to 18 ring carbon atoms, or a substituted or unsubstituted heteroaromatic group having 5 to 60, preferably 5 to 30, more preferably 5 to 18 ring atoms of the following formulae:

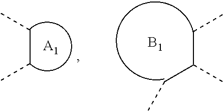

wherein the dotted lines are bonding sites.

More preferred rings A₁ and B₁ are:
Non-condensed aromatic groups or condensed aromatic groups. Specific examples thereof are based on phenyl, naphthyl, phenanthrene, biphenyl, terphenyl, fluoranthene, triphenylene, fluorene, indene, anthracene, chrysene, spirofluorene, benzo[c]phenanthrene, with phenyl, naphthyl, biphenyl, terphenyl, phenanthrene, triphenylene, fluorene, indene and fluoranthene being preferred, and phenyl and naphthyl being most preferred;
or
Non-condensed heteroaromatic groups or condensed heteroaromatic groups. Specific examples thereof are based on pyrrole, isoindole, benzofuran, isobenzofuran, benzothiophene, dibenzothiophene, isoquinoline, quinoxaline, quinazoline, phenanthridine, phenanthroline, pyri-dine, pyrazine, pyrimidine, pyridazine, indole, quinoline, acridine, carbazole, furan, thiophene, benzoxazole, benzothiazole, benzimidazole, dibenzofuran, triazine, oxazole, oxadiazole, thiazole, thiadiazole, triazole, imidazole, indolidine, imidazopyridine, 4-imidazo[1,2-a]benzimidazol, 5-benzimidazo[1,2-a]benzimidazol, and benzimidazolo[2,1-b][1,3]benzothiazol, with indole, especially 1-phenylindole, benzothiophene, dibenzofuran, carbazole, dibenzothiophene, benzofuran, and benzothiophene being preferred.

Most preferably, ring A₁ is represented by the following formulae:

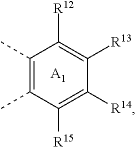

wherein the dotted lines are bonding sites and the residues R¹², R¹³, R¹⁴ and R¹⁵ are defined below;
and ring B₁ is represented by the following formula:

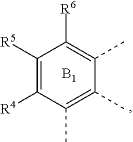

wherein the dotted lines are bonding sites and the residues R⁴, R⁵ and R⁶ are defined below.

Preferably, ring C₁ represents a substituted or unsubstituted aromatic group having 6 to 60, preferably from 6 to 30, more preferably from 6 to 18 ring carbon atoms, or a substituted or un-substituted heteroaromatic group having 5 to 60, preferably 5 to 30, more preferably 5 to 18 ring atoms of the following formula:

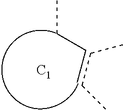

wherein the dotted lines are bonding sites, and the dotted line in the ring structure is an optional double bond, and
wherein ring C₁ and ring D₁ are fused together by a shared single or double bond.

A more preferred ring C₁ is an aromatic group based on phenyl;
or
a heteroaromatic group based on pyrrole, pyridine, pyrazine, pyrimidine, pyridazine, furan, thiophene, triazine, oxazole, oxadiazole, thiazole, thiadiazole or triazole;
with phenyl being preferred,
wherein ring C₁ and ring D₁ are fused together by a shared single or double bond.

Most preferably, ring C₁ is represented by the following formula:

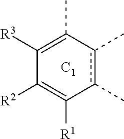

wherein the dotted lines are bonding sites, the dotted line in the ring structure is an optional double bond, and the residues R¹, R² and R³ are defined below; and wherein ring C₁ and ring D₁ are fused together by a shared single or double bond.

Ring D₁ represents a substituted or unsubstituted, preferably substituted, monocyclic ring having 5 to 7 ring atoms, preferably 5 ring atoms, which may be fused—in addition to ring C₁—with at least one unsubstituted or substituted non-aromatic group having 5 to 60 ring atoms, preferably 5 to 30, more preferably 5 to 18 ring atoms.

In one preferred embodiment, ring D₁ represents a substituted or unsubstituted, preferably substituted, monocyclic ring having 5 to 7 ring atoms, which is fused with at least one unsubstituted or substituted non-aromatic group having 5 to 60 ring atoms.

In the case that ring D₁ represents a substituted or unsubstituted, preferably substituted, mono-cyclic ring having 5 to 7 ring atoms, which is fused with at least one unsubstituted or substituted non-aromatic group having 5 to 60 ring atoms, the ring D₁ is preferably defined as follows:

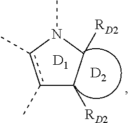

more preferably

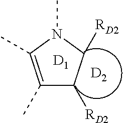

wherein
the dotted lines are bonding sites and the dotted line in the ring structure is an optional double bond,
ring D₂ represents a substituted or unsubstituted aliphatic ring or a non-heteroaromatic monocyclic ring having 5 to 7 ring atoms, which may be fused with at least one unsubstituted or substituted non-aromatic group having 5 to 60 ring atoms, preferably a substituted or unsubstituted aliphatic ring having 5 to 7 ring atoms, more preferably a substituted or unsubstituted aliphatic ring having 6 ring atoms;
R_{D2} each independently represents an aryl group having from 6 to 60 ring carbon atoms which is unsubstituted or substituted; a heteroaryl group having from 5 to 60 ring atoms which is un-substituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an alkynyl group having from 2 to 20 carbon atoms which is unsubstituted or substituted; or two R_{D2} together form a ring structure which is unsubstituted or substituted.

Preferably, R_{D2} is an alkyl group having from 1 to 20 carbon atoms which is unsubstituted or substituted, more preferably an alkyl group having from 1 to 5 carbon atoms, most preferably methyl or ethyl, further most preferably methyl.

Most preferably, in said case mentioned above, the ring D₁ is defined as follows

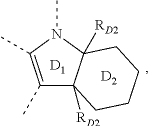

wherein R_{D2} is defined as mentioned above.

Further most preferably, in said case mentioned above, the ring D₁ is defined as follows

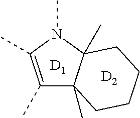

In the case that ring D₁ in formula (I) represents a substituted or unsubstituted, preferably substituted, monocyclic ring having 5 to 7 ring atoms, which is fused with at least one unsubstituted or substituted non-aromatic group having 5 to 60 ring atoms, the compound of formula (I) is preferably defined by the following formula (I-1):

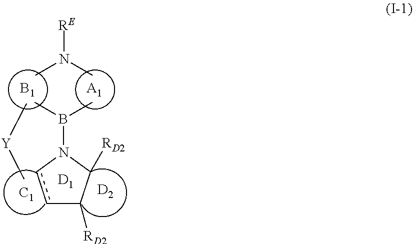

wherein
the dotted line in the ring structure of D₁ is an optional double bond;
ring D₂ represents a substituted or unsubstituted aliphatic ring or a non-heteroaromatic monocyclic ring having 5 to 7 ring atoms, which may be fused with at least one unsubstituted or substituted non-aromatic group having 5 to 60 ring atoms, preferably a substituted or unsubstituted aliphatic ring having 5 to 7 ring atoms, more preferably a substituted or unsubstituted aliphatic ring having 6 ring atoms;
R_{D2} each independently represents an aryl group having from 6 to 60 ring carbon atoms which is unsubstituted or substituted; a heteroaryl group having from 5 to 60 ring atoms which is un-substituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an alkynyl group having from 2 to 20 carbon atoms which is unsubstituted or substituted; or two R_{D2} together form a ring structure which is unsubstituted or substituted.

Preferably, R_{D2} is an alkyl group having from 1 to 20 carbon atoms which is unsubstituted or substituted, more preferably an alkyl group having from 1 to 5 carbon atoms, most preferably methyl or ethyl, further most preferably methyl.

The groups and residues R^{E}, A₁, B₁, C₁ and Y in formula (I-1) are the same as in formula (I) and defined above and below.

Preferably, ring D₁ represents a substituted or unsubstituted, preferably substituted, heteroaromatic monocyclic ring having 5 to 7 ring atoms, preferably 5 ring atoms, which may be fused —in addition to ring C₁— with at least one unsubstituted or substituted non-aromatic group having to 60 ring atoms, preferably 5 to 30, more preferably 5 to 18 ring atoms, or a substituted or un-substituted non-heteroaromatic monocyclic ring having 5 to 7 ring atoms, preferably 5 ring atoms, which may be fused—in addition to ring C₁— with at least one unsubstituted or substituted non-aromatic group having 5 to 60 ring atoms, preferably 5 to 30, more preferably 5 to 18 ring atoms.

More preferably, ring D₁ is represented by the following formula:

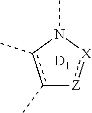

wherein
X and Z each independently represents CR²⁹ or N, and
R²⁹ represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
one residue R²⁹ at the X position and one residue R²⁹ at the Z position together form an unsubstituted or substituted non-aromatic group having 5 to 60 ring atoms, preferably 5 to 30, more preferably 5 to 18 ring atoms; or
R²⁹ at the X position and ring A₁ may be connected via a direct bond, O, S, NR²³, SiR²⁴R²⁵ or CR²⁷R²⁸; and/or
R²⁹ at the Z position may be bonded to the ring C₁ to form a ring structure which is unsubstituted or substituted;
wherein R²⁹ at the X position and R²⁹ at the Z position may be different or the same; and the dotted lines are bonding sites, the dotted line in the ring structure is an optional double bond, wherein preferably at least one of R²⁹ is not hydrogen, more preferably all R²⁹ are not hydrogen.

In the case that all R²⁹ are not hydrogen, R²⁹ represents an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
one residue R²⁹ at the X position and one residue R²⁹ at the Z position together form an unsubstituted or substituted non-aromatic group having 5 to 60 ring atoms, preferably 5 to 30, more preferably 5 to 18 ring atoms; or
R²⁹ at the X position and ring A₁ may be connected via a direct bond, O, S, NR²³, SiR²⁴R²⁵ or CR²⁷R²⁸; and/or
R²⁹ at the Z position may be bonded to the ring C₁ to form a ring structure which is unsubstituted or substituted;
wherein R²⁹ at the X position and R²⁹ at the Z position may be different or the same; and the dotted lines are bonding sites, the dotted line in the ring structure is an optional double bond.

Most preferably, ring D₁ is represented by one of the following formulae:

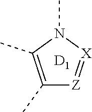

wherein
X and Z each independently represents CR²⁹ or N, and
R²⁹ represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
R²⁹ at the Z position may be bonded to the ring C₁ to form a ring structure which is unsubstituted or substituted;
wherein R²⁹ at the X position and R²⁹ at the Z position may be different or the same; and the dotted lines are bonding sites, the dotted line in the ring structure is an optional double bond,
wherein preferably at least one of R²⁹ is not hydrogen, more preferably all R²⁹ are not hydrogen.

Preferably, R²⁹ represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; CN; N(R²²)₂; OR²⁰; SR²⁰; SiR²⁴R²⁵R²⁶ or halogen;
wherein R²⁹ at the X position and R²⁹ at the Z position may be different or the same,
wherein preferably at least one of R²⁹ is not hydrogen, more preferably all R²⁹ are not hydrogen.

More preferably, R²⁹ represents an aryl group having from 6 to 60 ring carbon atoms which is unsubstituted or substituted, preferably from 6 to 30, more preferably from 6 to 18 ring carbon atoms which is unsubstituted or substituted; or a heteroaryl group having from 5 to 60, preferably 5 to 30, more preferably 5 to 18 ring atoms which is unsubstituted or substituted; wherein R²⁹ at the X position and R²⁹ at the Z position may be different or the same.

Most preferably, R²⁹ represents a phenyl group which is unsubstituted or substituted, wherein R²⁹ at the X position and R²⁹ at the Z position may be different or the same;
preferably R²⁹ represents a group of the following formula (VI):

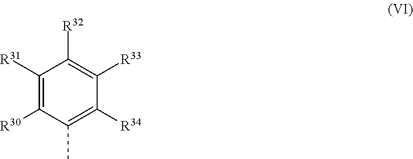

wherein
R³⁰, R³¹, R³², R³³ and R³⁴ each independently represents hydrogen; an aryl group having from 6 to 60 ring carbon atoms which is unsubstituted or substituted, preferably from 6 to 30, more preferably from 6 to 18 ring carbon atoms which is unsubstituted or substituted; or a heteroaryl group having from 5 to 60, preferably 5 to 30, more preferably 5 to 18 ring atoms which is un-substituted or substituted; an alkyl group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰ or halogen;
and/or
two adjacent residues R³⁰, R³¹, R³², R³³ and/or R³⁴ together form a ring structure which is unsubstituted or substituted;
the dotted line is a bonding site; and
wherein R²⁹ at the X position and R²⁹ at the Z position may be different or the same.

Preferably, R³⁰, R³¹, R³², R³³ and R³⁴ each independently represents hydrogen; an aryl group having from 6 to 60 ring carbon atoms which is unsubstituted or substituted, preferably from 6 to 30, more preferably from 6 to 18 ring carbon atoms which is unsubstituted or substituted; or a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; CN; or F.

More preferably, R³⁰, R³¹, R³², R³³ and R³⁴ each independently represents hydrogen; an aryl group having from 6 to 18 ring carbon atoms which is unsubstituted or substituted; or an alkyl group having from 1 to 8 carbon atoms which is unsubstituted or substituted. Most preferably, R³⁰, R³¹, R³², R³³ and R³⁴ each independently represents hydrogen; a phenyl group which is un-substituted or substituted; or an alkyl group having from 1 to 4 carbon atoms, i.e. a methyl group, an ethyl group, a n-propyl group, an isopropyl group, a n-butyl group, a s-butyl group, an isobutyl group or a t-butyl group.

In one most preferred embodiment, one or two residues of R³⁰, R³¹, R³², R³³ and R³⁴ are as de-fined above but different from hydrogen and the remaining residues R³⁰, R³¹, R³², R³³ and R³⁴ are hydrogen. Even further most preferably, at least one of R³⁰ and R³⁴ is as defined above but different from hydrogen and the remaining residues are hydrogen.

X and Z each independently represents CR²⁹ or N; preferably, X represents CR²⁹ and Z represents CR²⁹ or N; more preferably X and Z represent CR²⁹.

Examples for ring structures formed by two adjacent substituents are shown below (the ring structures below may be substituted by one or more of the substituents mentioned above):

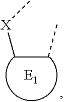

preferably

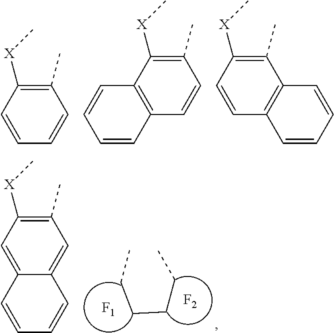

preferably

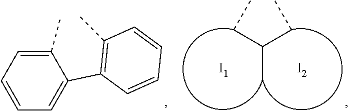

preferably

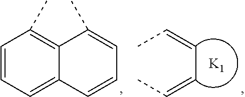

preferably

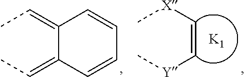

preferably

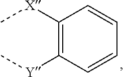

e.g.

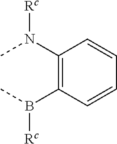

preferably

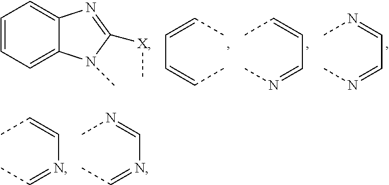

wherein X is O, CR^{a}R^{b}, S or NR^{c},
X″ and Y″ each independently represents O, CR^{a}R^{b}, S, BR^{c} or NR^{c},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀aryl, preferably unsubstituted or substituted phenyl,
E₁, F₁, F₂, G₁, H₁, I₁, I₂, K₁, L₁, M₁ and N₁ each independently represents a substituted or unsubstituted aromatic group having 6 to 60, preferably from 6 to 30, more preferably from 6 to 18 ring carbon atoms, or a substituted or unsubstituted heteroaromatic group having 5 to 60, preferably to 30, more preferably 5 to 18 ring atoms,
and
the dotted lines are bonding sites.

Examples for the case that R^{E} or a substituent on R^{E} may be bonded to the ring A₁ and/or to the ring B₁ or to a substituent on the ring A₁ and or the ring B₁ to form a ring structure which is un-substituted or substituted are:

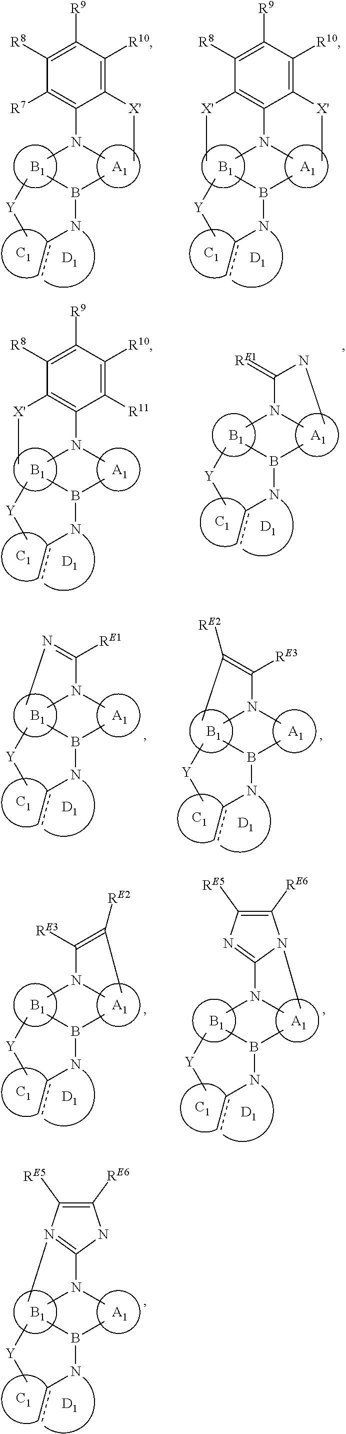

preferably

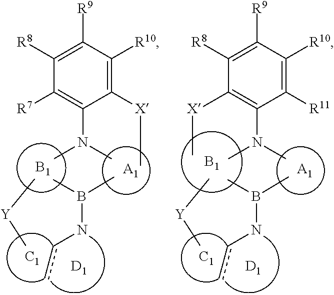

wherein
R^{E1}, R^{E2}, R^{E3}, R^{E5} and R^{E6} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
or
two adjacent residues R^{E2} and R^{E3} or R^{E5} and R^{E6} together form a substituted or unsubstituted ring structure;
X′ represents a direct bond, O, S, NR²³, SiR²⁴R²⁵, CR²⁷R²⁸, or BR²¹,
the rings A₁, B₁, C₁, D₁, R²¹, R²³, R²⁴, R²⁵, R²⁷, R²⁸ and Y are defined above and below, and R⁷, R⁸, R⁹, R¹⁰ and R¹¹ are defined below.

Y represents a direct bond, O, S, NR²³, SiR²⁴R²⁵ or CR²⁷R²⁸, preferably a direct bond;
in the case that Y is a direct bond, ring B₁ and C₁ may additionally be connected via O, S, NR²³, SiR²⁴R²⁵ or CR²⁷R²⁸.

The case that Y is a direct bond and ring B₁ and C₁ additionally are connected via O, S, NR²³, SiR²⁴R²⁵ or CR²⁷R²⁸ is shown below:

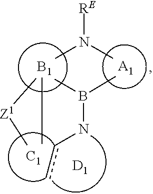

wherein Z¹ is O, S, NR²³, SiR²⁴R²⁵ or CR²⁷R²⁸, and the residues and the indices have been mentioned above.

Preferably, Y is a direct bond.

Preferred heterocyclic compounds according to the present invention are represented formula (II)

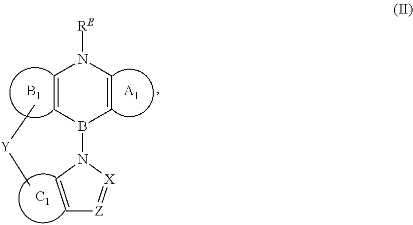

wherein
X and Z each independently represents CR²⁹ or N, and
R²⁹ represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
one residue R²⁹ at the X position and one residue R²⁹ at the Z position together form an unsubstituted or substituted non-aromatic group having 5 to 60 ring atoms, preferably 5 to 30, more preferably 5 to 18 ring atoms; and/or
R²⁹ at the X position and ring A₁ may be connected via a direct bond, O, S, NR²³, SiR²⁴R²⁵ or CR²⁷R²⁸; and/or
R²⁹ at the Z position may be bonded to the ring C₁ to form a ring structure which is unsubstituted or substituted;
wherein R²⁹ at the X position and R²⁹ at the Z position may be different or the same; and
wherein the rings, residues and groups A₁, B₁, C₁, Y and R^{E} are mentioned above, and preferred residues R²⁹ are also mentioned above,
wherein preferably at least one of R²⁹ is not hydrogen, more preferably all R²⁹ are not hydrogen.

In the case that one residue R²⁹ at the X position and one residue R²⁹ at the Z position in the compound of formula (II) together form an unsubstituted or substituted non-aromatic group having 5 to 60 ring atoms, preferably 5 to 30, more preferably 5 to 18 ring atoms, formula (II) is preferably represented by the following formula (II-1)

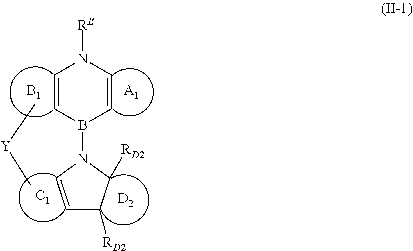

wherein D₂ and R_{D2} are defined above.

The groups and residues R^{E}, A₁, B₁, C₁ and Y in formula (II-1) are the same as in formula (II) and defined above and below.

In a more preferred embodiment, the heterocyclic compounds according to the present invention are represented by formula (III)

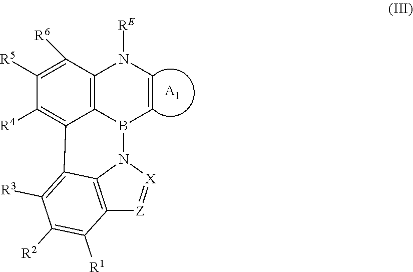

wherein
R¹, R², R³, R⁴, R⁵ and R⁶ each independently represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halo-gen;
or
two adjacent residues R¹, R² and/or R³ and/or two adjacent residues R⁴, R⁵ and/or R⁶ together form a ring structure which is unsubstituted or substituted; and/or
R²⁹ at the Z position and R¹ may together form a ring structure which is unsubstituted or substituted; and/or
R⁶ is bonded to R^{E} or a substituent on R^{E} to form a ring structure which is unsubstituted or substituted;
R²⁰ and R²² each independently represents an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted;
R²¹ represents an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; N(R²²)₂ or OR²⁰;
and/or
two residues R²² and/or two residues R²¹ together form a ring structure which is unsubstituted or substituted;
or
R²⁰, R²¹, and/or R²² together with an adjacent residue R¹, R², R³, R⁴, R⁵ and R⁶ forms a ring structure which is unsubstituted or substituted; and
R²⁴, R²⁵ and R²⁶ each independently represents an aryl group having from 6 to 60 ring carbon atoms which is unsubstituted or substituted; a heteroaryl group having from 5 to 60 ring atoms which is unsubstituted or substituted and which is linked via a carbon atom to N or Si; an alkyl group having from 1 to 20 carbon atoms which is unsubstituted or substituted; or a cycloalkyl group having from 3 to 20 ring carbon atoms which is unsubstituted or substituted and/or
two residues R²⁴ and R²⁵ together form a ring structure which is unsubstituted or substituted; and wherein the further rings, groups and residues shown in formula (III) are described above,
wherein preferably at least one of R²⁹ is not hydrogen, more preferably all R²⁹ are not hydrogen.

In the case that one residue R²⁹ at the X position and one residue R²⁹ at the Z position in the compound of formula (III) together form an unsubstituted or substituted non-aromatic group having 5 to 60 ring atoms, preferably 5 to 30, more preferably 5 to 18 ring atoms, formula (III) is preferably represented by the following formula (III-1)

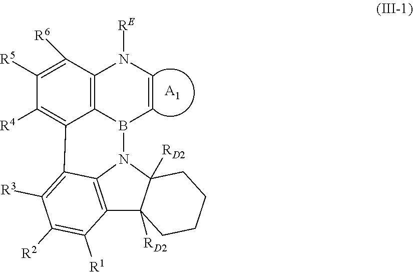

wherein R_{D2} is defined above.

The groups and residues R^{E}, A₁, B₁, C₁ and Y in formula (III-1) are the same as in formula (III) and defined above and below.

In a most preferred embodiment, the heterocyclic compounds according to the present invention are represented by formula (IV)

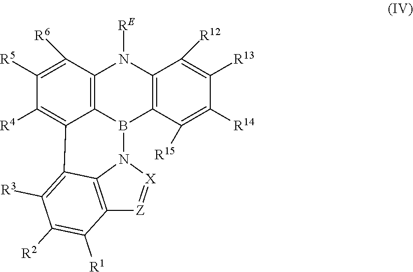

wherein
R¹², R¹³, R¹⁴ and R¹⁵ each independently represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halo-gen;
or
two adjacent residues R¹², R¹³, R¹⁴ and/or R¹⁵ together form a ring structure which is unsubstituted or substituted, and/or
R¹² is bonded to R^{E} or a substituent on R^{E} to form a ring structure which is unsubstituted or substituted and/or
R²⁹ at the X position and R¹⁵ may be connected via a direct bond, O, S, NR²³, SiR²⁴R²⁵ or CR²⁷R²³;
and
wherein the further rings, groups and residues shown in formula (IV) are described above,
wherein preferably at least one of R²⁹ is not hydrogen, more preferably all R²⁹ are not hydrogen.

In the case that one residue R²⁹ at the X position and one residue R²⁹ at the Z position in the compound of formula (IV) together form an unsubstituted or substituted non-aromatic group having 5 to 60 ring atoms, preferably 5 to 30, more preferably 5 to 18 ring atoms, formula (IV) is preferably represented by the following formula (IV-1)

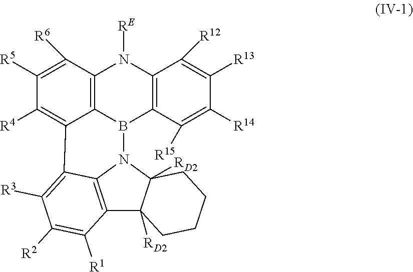

wherein R_{D2} is defined above.

The groups and residues R^{E}, A₁, B₁, C₁ and Y in formula (IV-1) are the same as in formula (IV) and defined above and below.

In one preferred embodiment of the present invention, two adjacent residues R¹², R¹³, R¹⁴ and/or R¹⁵ in the compounds of formula (IV) together form a ring structure which is unsubstituted or substituted. More preferred compounds wherein two adjacent residues R¹², R¹³, R¹⁴ and/or R¹⁵ together form a ring structure which is unsubstituted or substituted are shown in the following:

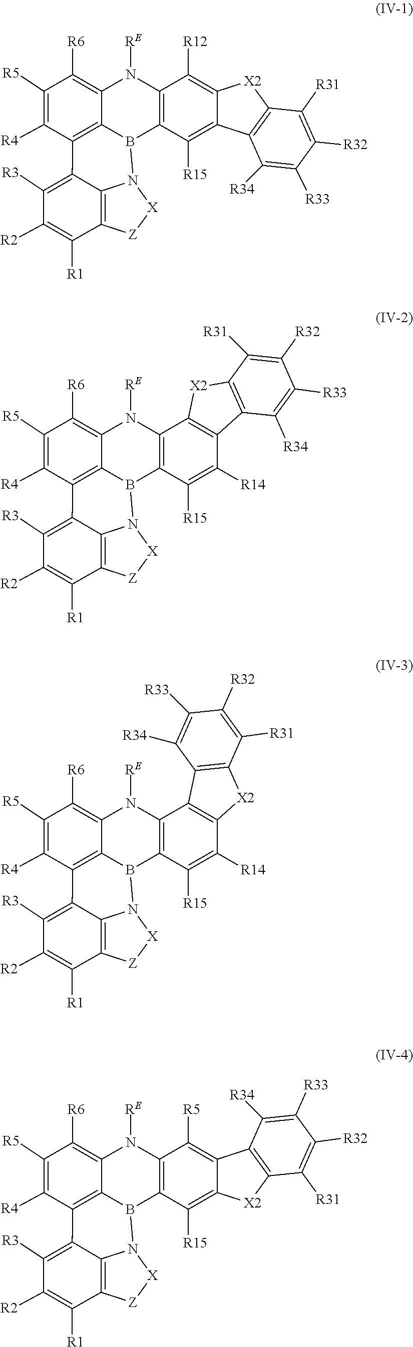

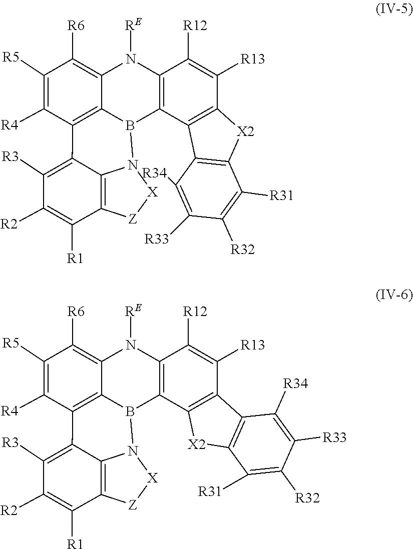

wherein
X₂ represents O, S, NR^{c} or CR^{a}R^{b},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl;
wherein the further rings, groups and residues shown in formulae (IV-1), (IV-2), (IV-3), (IV-4), (IV-5) and (IV-6) are described above,
wherein preferably at least one of R²⁹ is not hydrogen, more preferably all R²⁹ are not hydrogen.

Compounds (IV-1) and (IV-3) are preferred and compound (IV-1) is more preferred.

In one further preferred embodiment of the present invention, two adjacent residues R¹, R² and/or R³ in the compounds of formula (IV) together form a ring structure which is unsubstituted or substituted. More preferred compounds wherein two adjacent residues R¹, R² and/or R³ together form a ring structure which is unsubstituted or substituted are shown in the following:

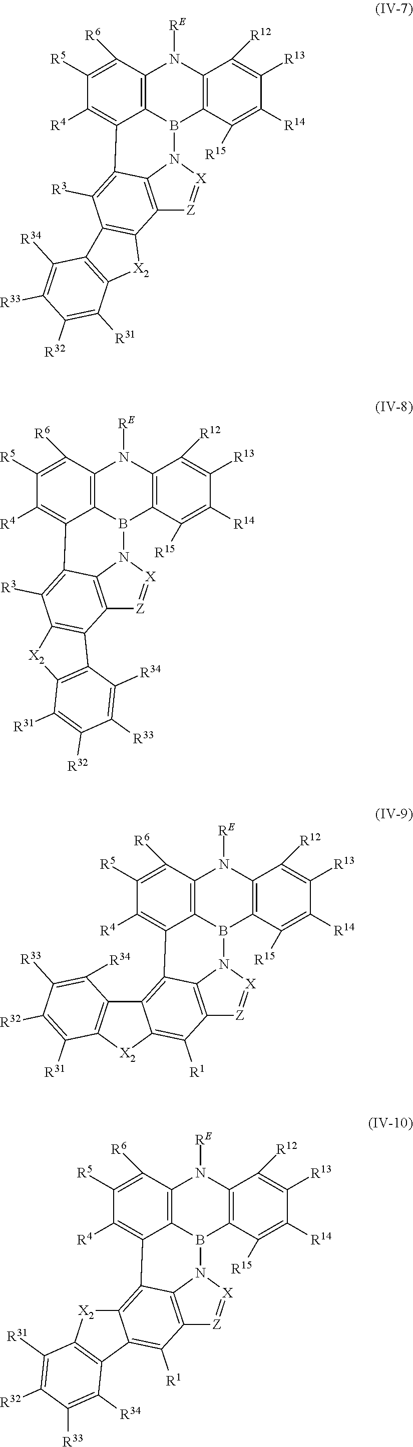

wherein
X₂ represents O, S, NR^{c} or CR^{a}R^{b},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl;
wherein the further rings, groups and residues shown in formulae (IV-7), (IV-8), (IV-9) and (IV-10) are described above,
wherein preferably at least one of R²⁹ is not hydrogen, more preferably all R²⁹ are not hydrogen.

Compounds (IV-7) and (IV-10) are preferred and compound (IV-7) is more preferred.

Preferably, X, Z and R²⁹ in formulae (II), (III) and (IV) mentioned above as well as in the formulae mentioned below are defined as follows:
X and Z each independently represents CR²⁹ or N; preferably, X represents CR²⁹ and Z represents CR²⁹ or N; more preferably X and Z represent CR²⁹; and
R²⁹ represents hydrogen; an aryl group having from 6 to 60 ring carbon atoms which is unsubstituted or substituted, preferably from 6 to 30, more preferably from 6 to 18 ring carbon atoms which is unsubstituted or substituted; a heteroaryl group having from 5 to 60, preferably 5 to 30, more preferably 5 to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
R²⁹ at the Z position may be bonded to the ring C₁ to form a ring structure which is unsubstituted or substituted,
wherein preferably at least one of R²⁹ is not hydrogen, more preferably all R²⁹ are not hydrogen.

Further more preferred definitions of X, Z and R²⁹ in formulae (II), (III) and (IV) mentioned above as well as in the formulae mentioned below are defined above.

R^{E} is preferably a group of the following formula (V):

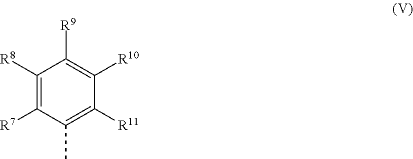

wherein
R⁷, R⁸, R⁹, R¹⁰ and R¹¹ each independently represents hydrogen; an aryl group having from 6 to 60, preferably from 6 to 30, more preferably from 6 to 18 ring carbon atoms which is unsubstituted or substituted; a heteroaryl group having from 5 to 60, preferably 5 to 30, more preferably to 18 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen;
and/or
two adjacent residues R⁷, R⁸, R⁹, R¹⁰ and/or R¹¹ together form a ring structure which is unsubstituted or substituted;
and/or
R⁷ and/or R¹¹ are connected to the ring B₁ and/or to the ring A₁ or to a substituent on the ring A₁ and or the ring B₁ to form a ring structure which is unsubstituted or substituted; preferably,
R⁷ is connected to R⁶ and/or R¹¹ is connected to R¹² to form a ring structure which is unsubstituted or substituted; and
the dotted line is a bonding site.

Further most preferably, the heterocyclic compounds according to the present invention are represented by formula (VII)

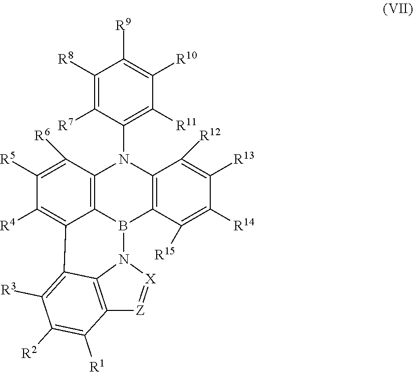

wherein the groups and residues shown in formula (VII) are described above. Preferably, X represents CR²⁹ and Z represents CR²⁹ or N; more preferably X and Z represent CR²⁹,
wherein preferably at least one of R²⁹ is not hydrogen, more preferably all R²⁹ are not hydrogen.

In the case that one residue R²⁹ at the X position and one residue R²⁹ at the Z position in the compound of formula (VII) together form an unsubstituted or substituted non-aromatic group having 5 to 60 ring atoms, preferably 5 to 30, more preferably 5 to 18 ring atoms, formula (VII) is preferably represented by the following formula (VII-1)

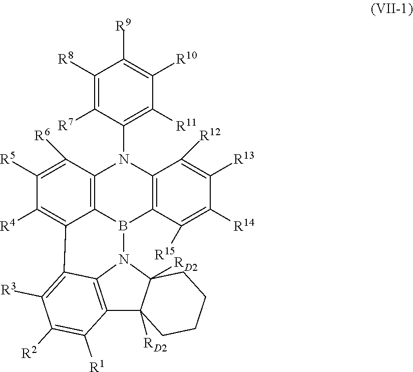

wherein R_{D2} is defined above.

The groups and residues R^{E}, A₁, B₁, C₁ and Y in formula (VII-1) are the same as in formula (VII) and defined above and below.

Examples for ring structures formed by two adjacent residues R¹, R² and/or R³ and/or two adjacent residues R⁴, R⁵ and/or R⁶ and/or two adjacent residues R⁷, R⁸, R⁹, R¹⁰ and/or R¹¹ and/or two adjacent residues R¹², R¹³, R¹⁴ and/or R¹⁵ are shown below (the ring structures below may be substituted by one or more of the substituents mentioned above):

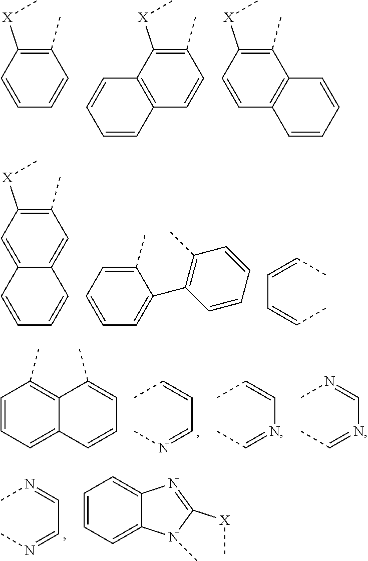

wherein X is O, CR^{a}R^{b}, S or NR^{c},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl.

In one preferred embodiment of the present invention, two adjacent residues R¹², R¹³, R¹⁴ and/or R¹⁵ in the compounds of formula (VII) together form a ring structure which is unsubstituted or substituted. More preferred compounds wherein two adjacent residues R¹², R¹³, R¹⁴ and/or R¹⁵ together form a ring structure which is unsubstituted or substituted are shown in the following:

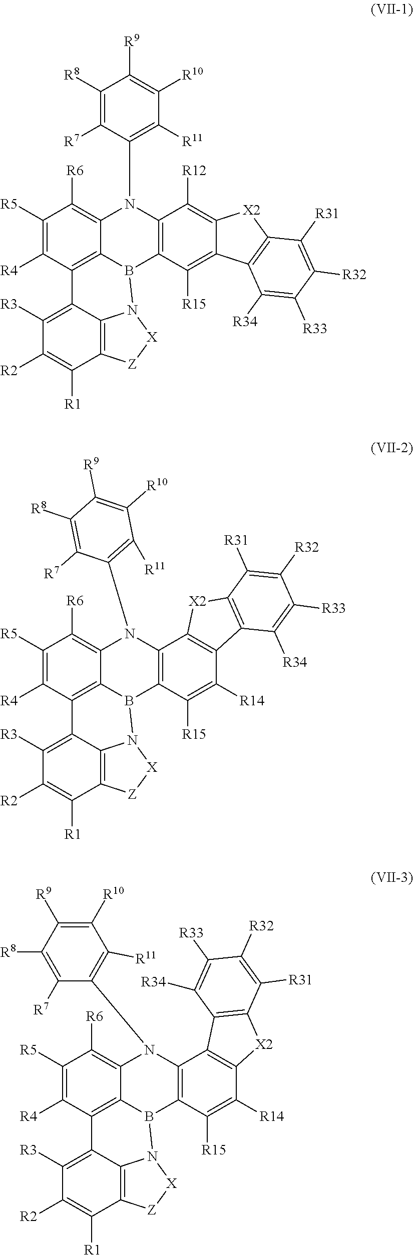

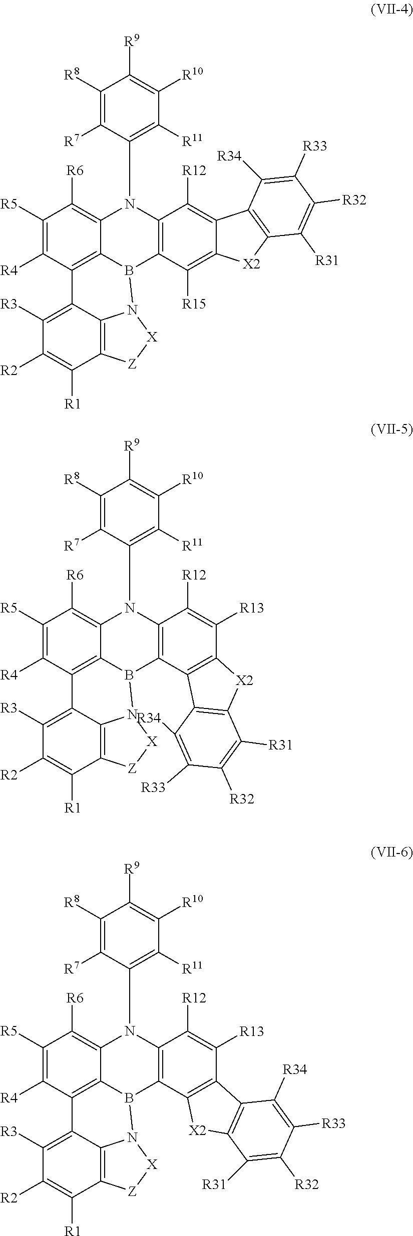

wherein
X₂ represents O, S, NR^{c} or CR^{a}R^{b},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl; wherein the further rings, groups and residues shown in formulae (VII-1), (VII-2), (VII-3), (VII-4), (VII-5) and (VII-6) are described above, wherein preferably at least one of R²⁹ is not hydrogen, more preferably all R²⁹ are not hydrogen.

Compounds (VII-1) and (VII-3) are preferred and compound (VII-1) is more preferred.

In one further preferred embodiment of the present invention, two adjacent residues R¹, R² and/or R³ in the compounds of formula (VII) together form a ring structure which is unsubstituted or substituted. More preferred compounds wherein two adjacent residues R¹, R² and/or R³ together form a ring structure which is unsubstituted or substituted are shown in the following:

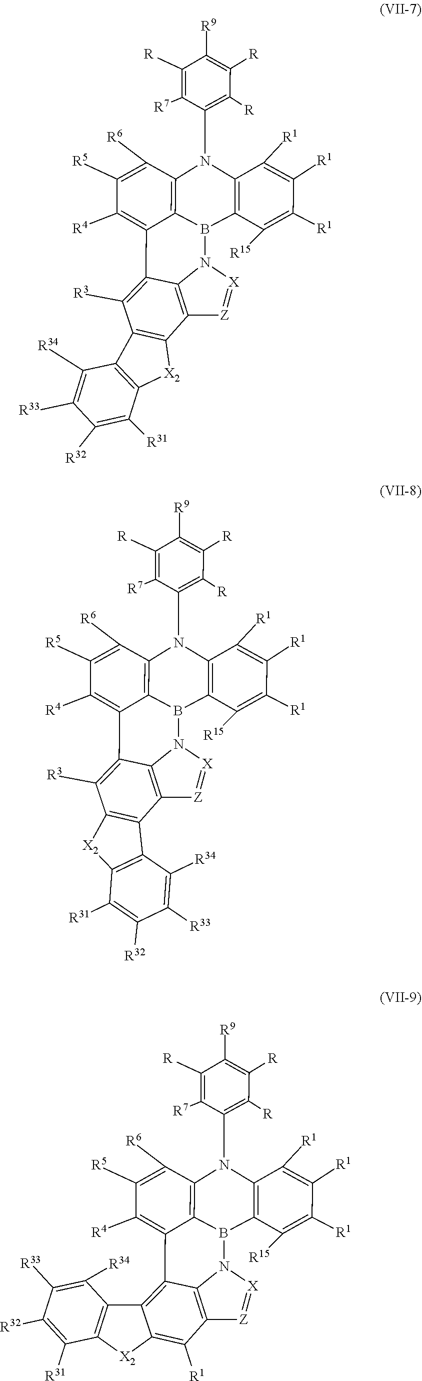

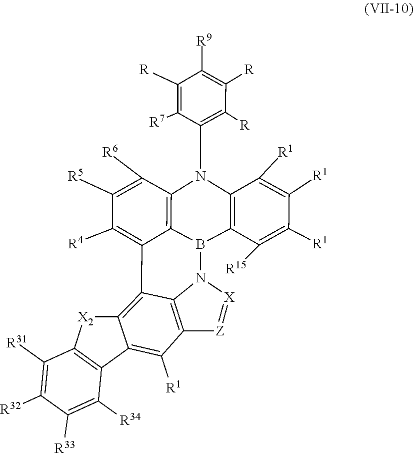

wherein
X₂ represents O, S, NR^{c} or CR^{a}R^{b},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl;
wherein the further rings, groups and residues shown in formulae (VII-1), (VII-2), (VII-3), (VII-4), (VII-5) and (VII-6) are described above,
wherein preferably at least one of R²⁹ is not hydrogen, more preferably all R²⁹ are not hydrogen.

Compounds (IV-7) and (IV-10) are preferred and compound (IV-7) is more preferred.

Examples for the case that R⁶ and R⁷ and/or R¹¹ and R¹² are connected to form a ring structure which is unsubstituted or substituted are:

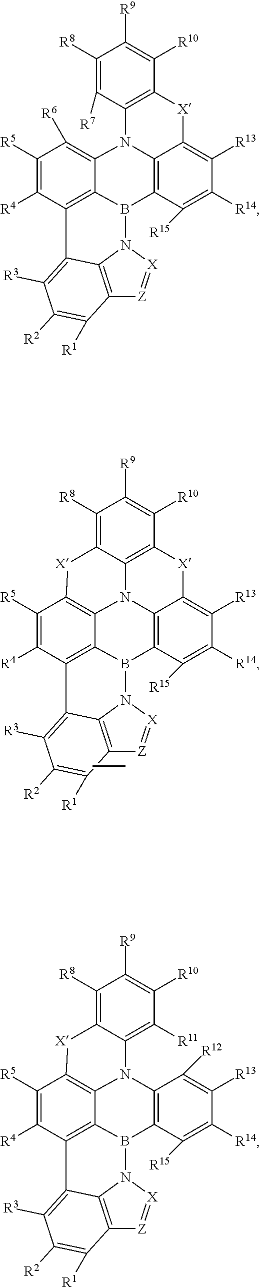

wherein
X′ represents a direct bond, O, S, NR²³, SiR²⁴R²⁵, CR²⁷R²⁸, or BR²¹, and all other residues are defined above and below. Preferably, X represents CR²⁹ and Z represents CR²⁹ or N; more preferably X and Z represent CR²⁹,
wherein preferably at least one of R²⁹ is not hydrogen, more preferably all R²⁹ are not hydrogen.

Preferably, R¹, R², R³, R⁴, R⁵, R⁶, R⁷, R⁸, R⁹, R¹⁰, R¹¹, R¹², R¹³, R¹⁴ and R¹⁵ each independently represents hydrogen, an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; CN; N(R²²)₂; SiR²⁴R²⁵R²⁶, SR²⁰ or OR²⁰;
or
two adjacent residues R¹, R² and/or R³ and/or two adjacent residues R⁴, R⁵ and/or R⁶ and/or
two adjacent residues R⁷, R⁸, R⁹, R¹⁰ and/or R¹¹ and/or two adjacent residues R¹², R¹³, R¹⁴ and/or R¹⁵ together form a ring structure which is unsubstituted or substituted, and/or
R⁶ and R⁷ and/or R¹¹ and R¹² are connected to form a ring structure which is unsubstituted or substituted;
R²⁰ and R²² each independently represents an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted;
or
R²⁰ and/or R²² together with an adjacent residue R¹, R², R³, R⁴, R⁵, R⁶, R⁷, R⁸, R⁹, R¹⁰, R¹¹, R¹²,
R¹³, R¹⁴ or R¹⁵ forms a ring structure which is unsubstituted or substituted; and
R²⁴, R²⁵ and R²⁶ represents an aryl group having from 6 to 18 ring carbon atoms which is unsubstituted or substituted; a heteroaryl group having from 5 to 18 ring atoms which is unsubstituted or; an alkyl group having from 1 to 20 carbon atoms which is unsubstituted or substituted; a cycloalkyl group having from 3 to 20 ring carbon atoms which is unsubstituted or substituted.

More preferably, R¹, R², R³, R⁴, R⁵, R⁶, R⁷, R⁸, R⁹, R¹⁰, R¹¹, R¹², R¹³, R¹⁴ and R¹⁵ each independently represents hydrogen, an aryl group having from 6 to 18 ring carbon atoms which is unsubstituted or substituted; a heteroaryl group having from 5 to 18 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; CN; or N(R²²)₂;
or
two adjacent residues R¹, R² and/or R³ and/or two adjacent residues R⁴, R⁵ and/or R⁶ and/or
two adjacent residues R⁷, R⁸, R⁹, R¹⁰ and/or R¹¹ and/or two adjacent residues R¹², R¹³, R¹⁴ and/or R¹⁵ together form a ring structure which is unsubstituted or substituted, and/or
R⁶ and R⁷ and/or R¹¹ and R¹² to form a ring structure which is unsubstituted or substituted;
R²² represents an aryl group having from 6 to 18 ring carbon atoms which is unsubstituted or substituted; or an alkyl group having from 1 to 20 carbon atoms which is unsubstituted or substituted;
or
R²² together with an adjacent residue R¹, R², R³, R⁴, R⁵, R⁶, R⁷, R⁸, R⁹, R¹⁰, R¹¹, R¹², R¹³, R¹⁴ or
R¹⁵ forms a ring structure which is unsubstituted or substituted.

Most preferably, R¹, R², R³, R⁴, R⁵, R⁶, R⁷, R⁸, R⁹, R¹⁰, R¹¹, R¹², R¹³, R¹⁴ and R¹⁵ each independently represents hydrogen, an alkyl group having 1 to 4 carbon atoms which is unsubstituted or substituted; a cycloalkyl group having from 3 to 10 ring carbon atoms which is unsubstituted or substituted; an aryl group having 6 to 13 ring carbon atoms which is unsubstituted or substituted; a heteroaryl group having from 5 to 13 ring atoms which is unsubstituted or substituted; CN; or N(R²²)₂;
or
two adjacent residues R¹, R² and/or R³ and/or two adjacent residues R⁴, R⁵ and/or R⁶ and/or
two adjacent residues R⁷, R⁸, R⁹, R¹⁰ and/or R¹¹ and/or two adjacent residues R¹², R¹³, R¹⁴ and/or R¹⁵ together form a ring structure which is unsubstituted or substituted, and/or
R⁶ and R⁷ and/or R¹¹ and R¹² to form a ring structure which is unsubstituted or substituted;
R²² represents an aryl group having from 6 to 18 ring carbon atoms which is unsubstituted or substituted; or an alkyl group having from 1 to 20 carbon atoms which is unsubstituted or substituted.

In a further preferred embodiment 0, 1, 2, 3, 4, 5 or 6, preferably 0, 1, 2, 3 or 4 of the residues R¹, R², R³, R⁴, R⁵, R⁶, R⁷, R⁸, R⁹, R¹⁰, R¹¹, R¹², R¹³, R¹⁴ and R¹⁵ are not hydrogen; i.e. the remaining residues are hydrogen. Further preferably, 0, 1, 2, 3, 4, 5 or 6, preferably 0, 1, 2, 3 or 4 of the residues R², R⁵, R⁹, R¹², R¹³, R¹⁴ and R¹⁵ are not hydrogen; i.e. the remaining residues are hydrogen.

In one preferred embodiment of the present invention, two adjacent residues R¹², R¹³, R¹⁴ and/or R¹⁵ together form a ring structure which is unsubstituted or substituted.

In one further preferred embodiment of the present invention, two adjacent residues R¹, R² and/or R³ together form a ring structure which is unsubstituted or substituted.

A preferred example for ring structures formed by two adjacent residues R¹, R² and/or R³ and/or two adjacent residues R¹², R¹³, R¹⁴ and/or R¹⁵ is

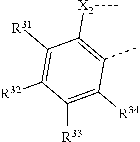

wherein
X₂ represents O, S, NR^{c} or CR^{a}R^{b},
R^{a} and R^{b} each independently represents C₁ to C₈ alkyl or substituted or unsubstituted C₆ to C₁₈ aryl, preferably C₁ to C₄ alkyl or substituted or unsubstituted C₆ to C₁₀ aryl, more preferably methyl or unsubstituted or substituted phenyl,
R^{c} represents C₁ to C₈ alkyl, preferably C₁ to C₄ alkyl, or substituted or unsubstituted C₆ to C₁₀ aryl, preferably unsubstituted or substituted phenyl; and
R³¹, R³², R³³ and R³⁴ are defined above.

In a preferred embodiment the heterocyclic compound according to the present invention is represented by one of the following formulae

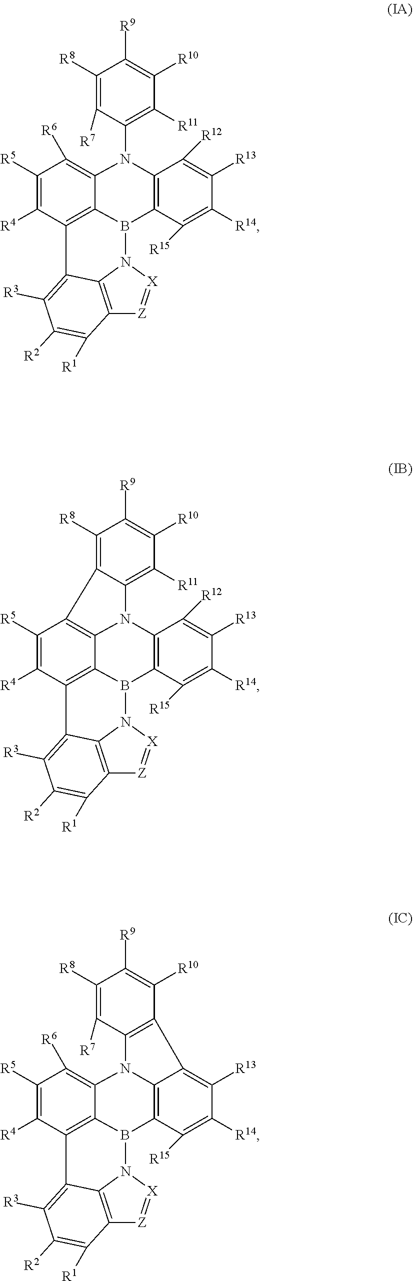

wherein the residues are defined as mentioned above,
wherein
   in formula (IA) and formula (IB)—
two adjacent residues R¹, R² and/or R³ and/or two adjacent residues R⁴, R⁵ and/or R⁶ and/or
two adjacent residues R⁷, R⁸, R⁹, R¹⁰ and/or R¹¹ and/or two adjacent residues R¹², R¹³, R¹⁴
and/or R¹⁵, may form together a ring structure which is unsubstituted or substituted;
   in formula (IC)—
two adjacent residues R¹, R² and/or R³ and/or two adjacent residues R⁴, R⁵ and/or R⁶ and/or
two adjacent residues R⁷, R⁸, R⁹ and/or R¹⁰ and/or two adjacent residues R¹³, R¹⁴ and/or R¹⁵, may form together a ring structure which is unsubstituted or substituted.

Preferably, X represents CR²⁹ and Z represents CR²⁹ or N; more preferably X and Z represent CR²⁹,
wherein preferably at least one of R²⁹ is not hydrogen, more preferably all R²⁹ are not hydrogen.

Heterocyclic compounds of formula (IA) and (IC) are preferred.

Most preferably, the heterocyclic compound according to the present invention is represented by one of the following formulae

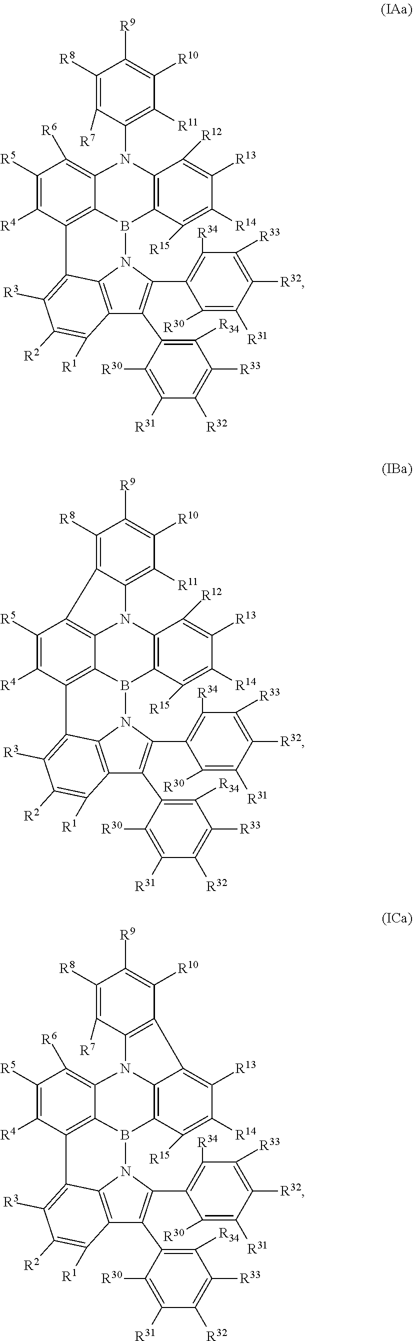

wherein the residues are defined as mentioned above,
wherein PG
   in formula (IAa) and formula (IBa)—
two adjacent residues R¹, R² and/or R³ and/or two adjacent residues R⁴, R⁵ and/or R⁶ and/or two adjacent residues R⁷, R⁸, R¹ and/or R¹¹ and/or two adjacent residues R¹², R¹³, R¹⁴ and/or R¹⁵, may form together a ring structure which is unsubstituted or substituted;
   in formula (ICa)—
two adjacent residues R¹, R² and/or R³ and/or two adjacent residues R⁴, R⁵ and/or R⁶ and/or
two adjacent residues R⁷, R⁸, R⁹ and/or R¹ and/or two adjacent residues R¹³, R¹⁴ and/or R¹⁵, may form together a ring structure which is unsubstituted or substituted.

Heterocyclic compounds of formula (IAa) and (ICa) are preferred.

Below, examples for compounds of formula (I) are given:

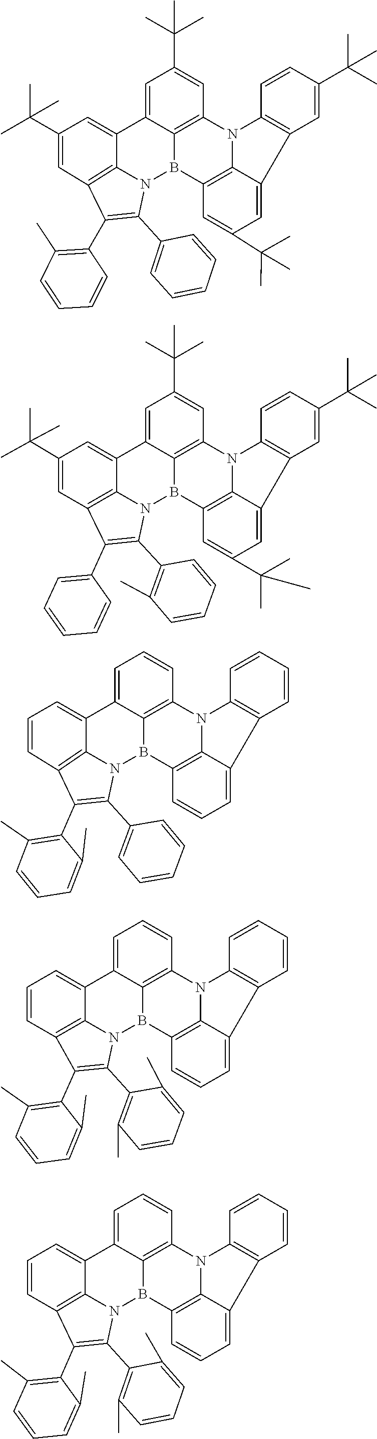

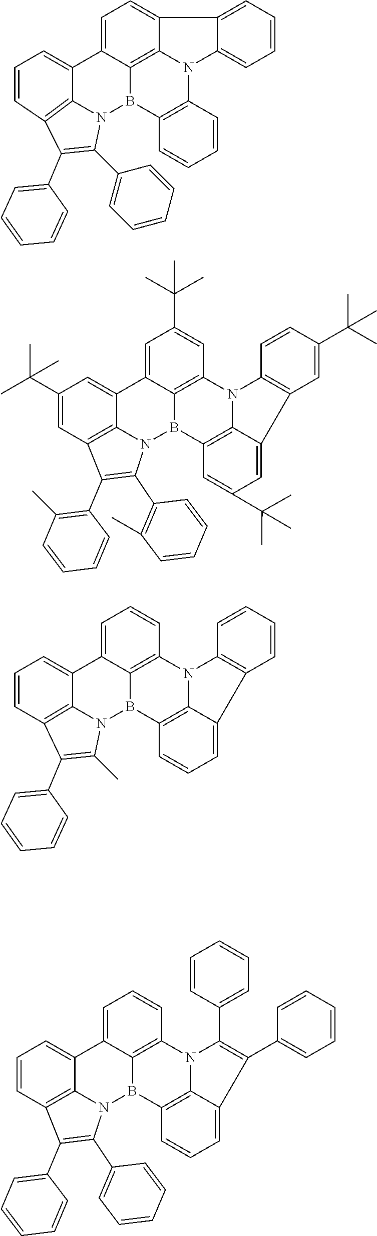

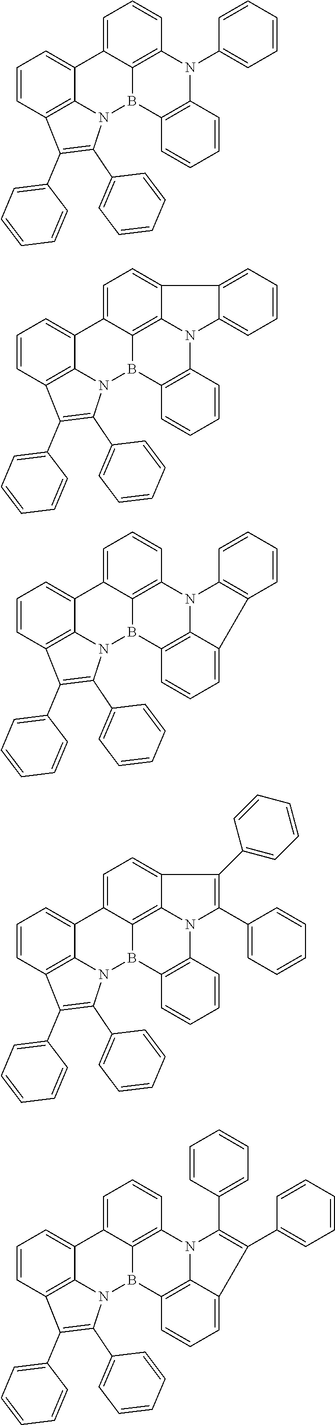

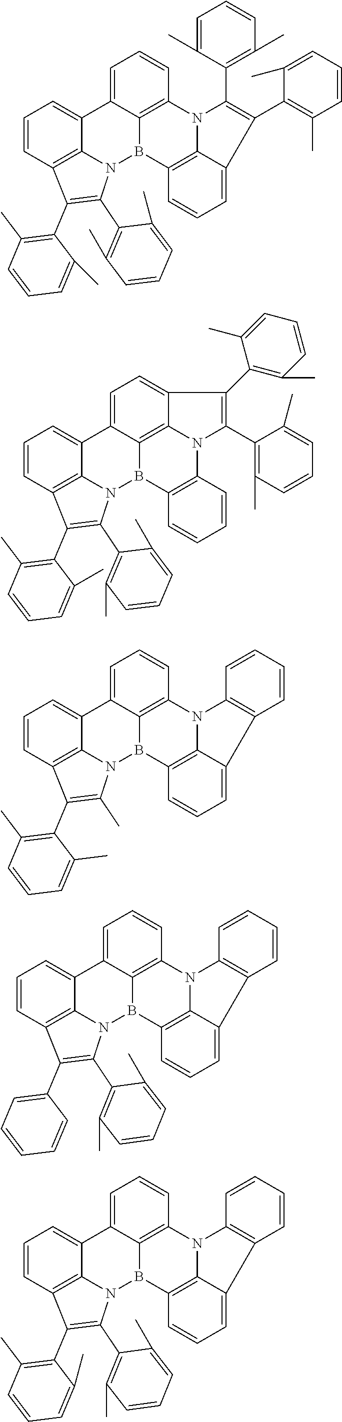

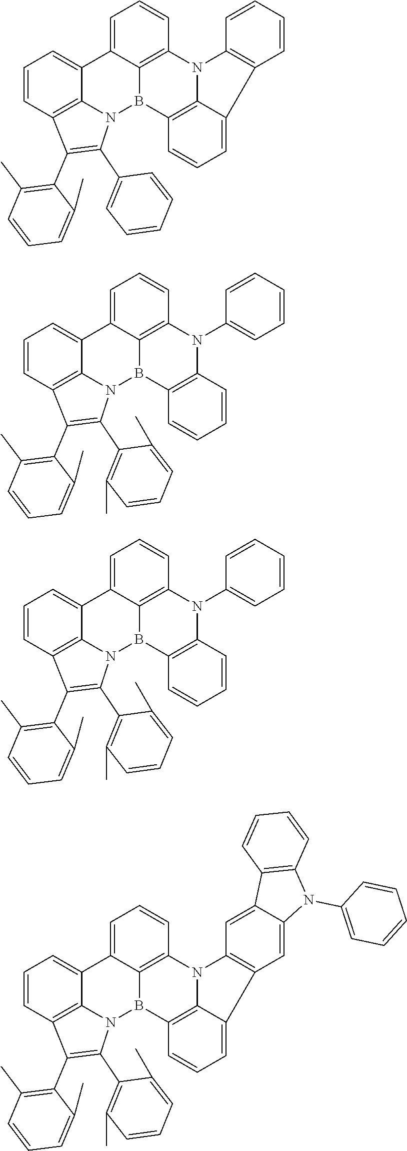

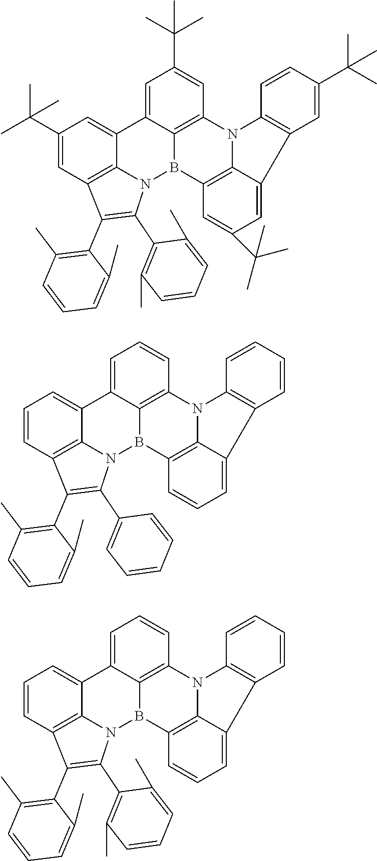

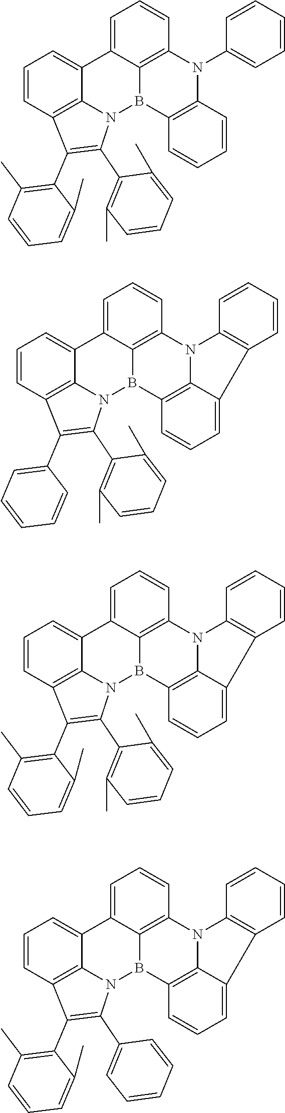 [SMILES: Cc1cccc(C)c1-c1c(-c2c(C)cccc2C)n2c3c(cccc13)-c1cccc3c1B2c1ccccc1N3c1ccccc1 ; Cc1cccc(C)c1-c1c(-c2ccccc2)c2cccc3c2n1B1c2c-3cccc2-n2c3ccccc3c3cccc1c32 ; Cc1cccc(C)c1-c1c(-c2c(C)cccc2C)n2c3c(cccc13)-c1cccc3c1B2c1cccc2c4ccccc4n-3c12 ; Cc1cccc(C)c1-c1c(-c2ccccc2)n2c3c(cccc13)-c1cccc3c1B2c1cccc2c4ccccc4n-3c12]

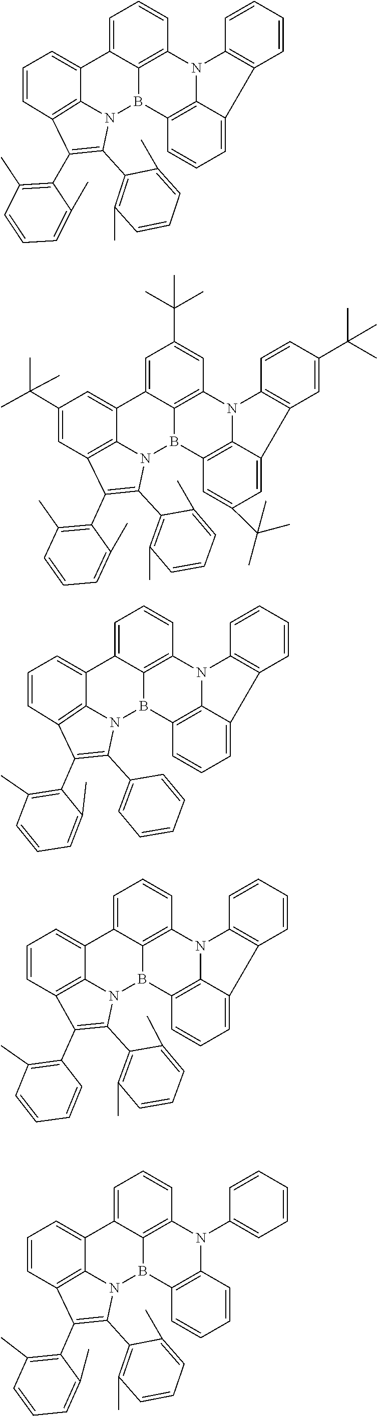

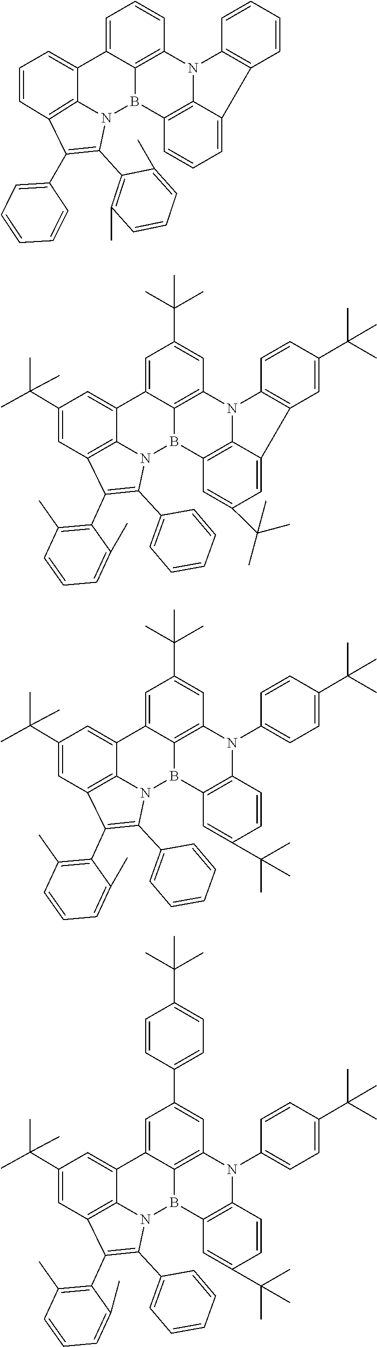

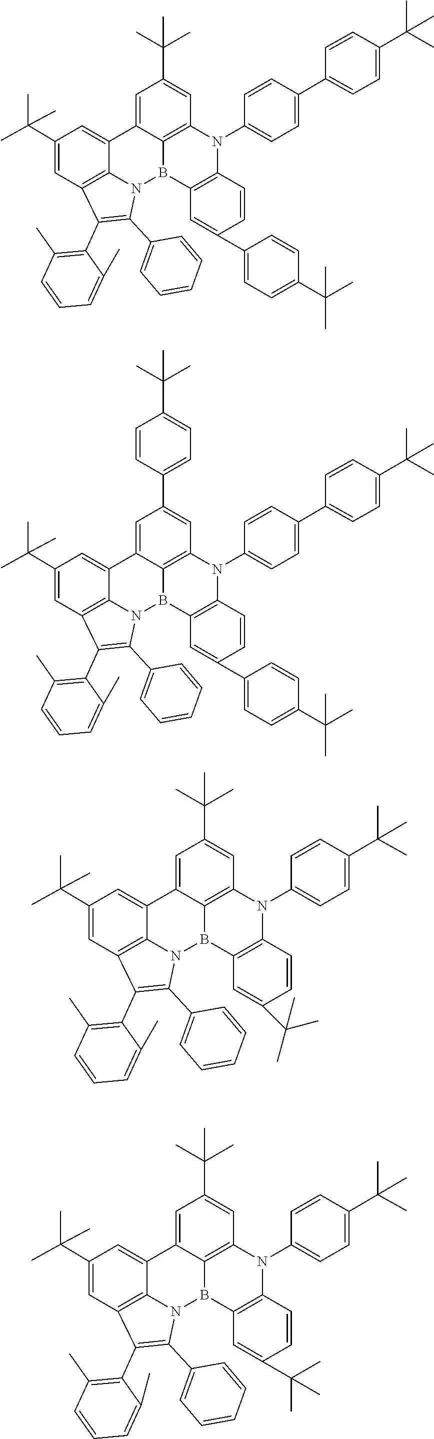

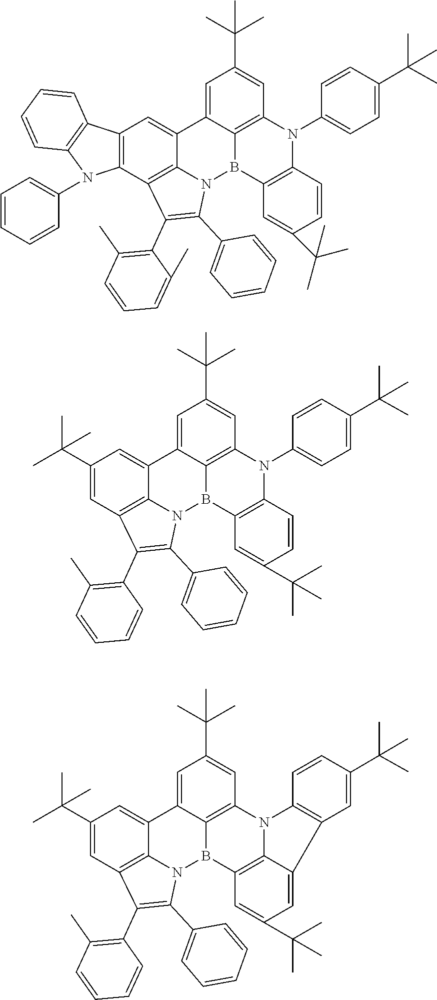

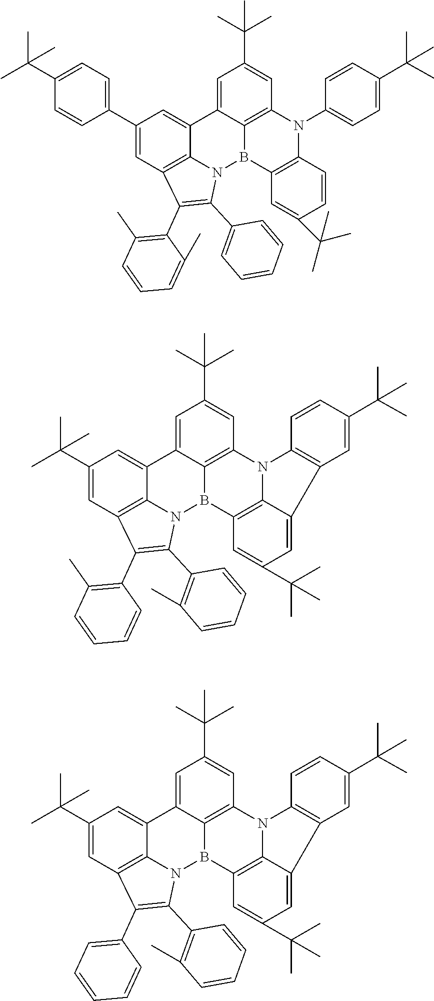

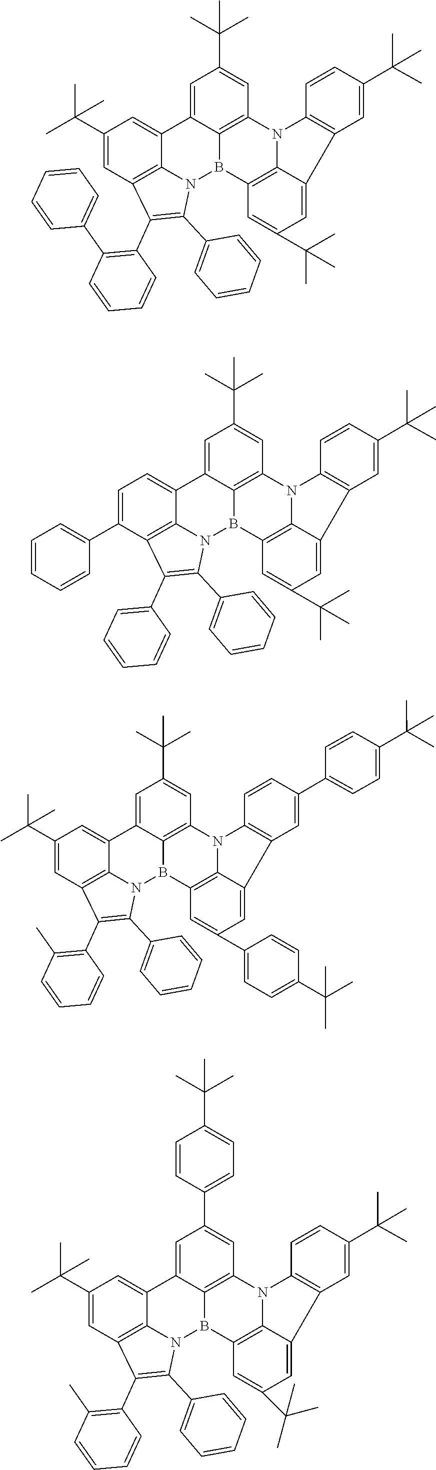

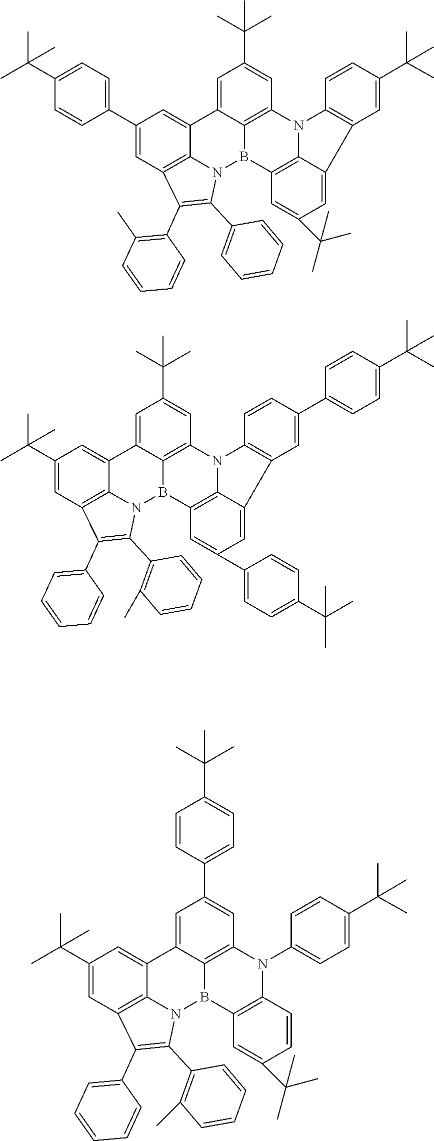

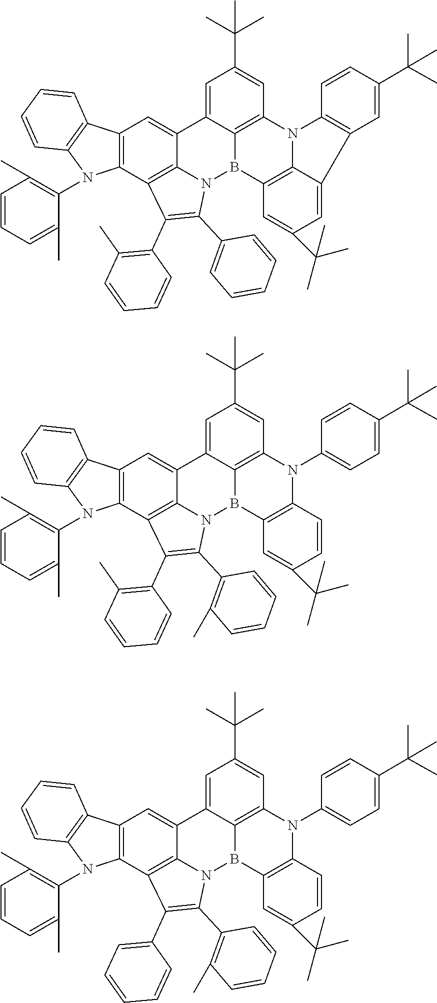

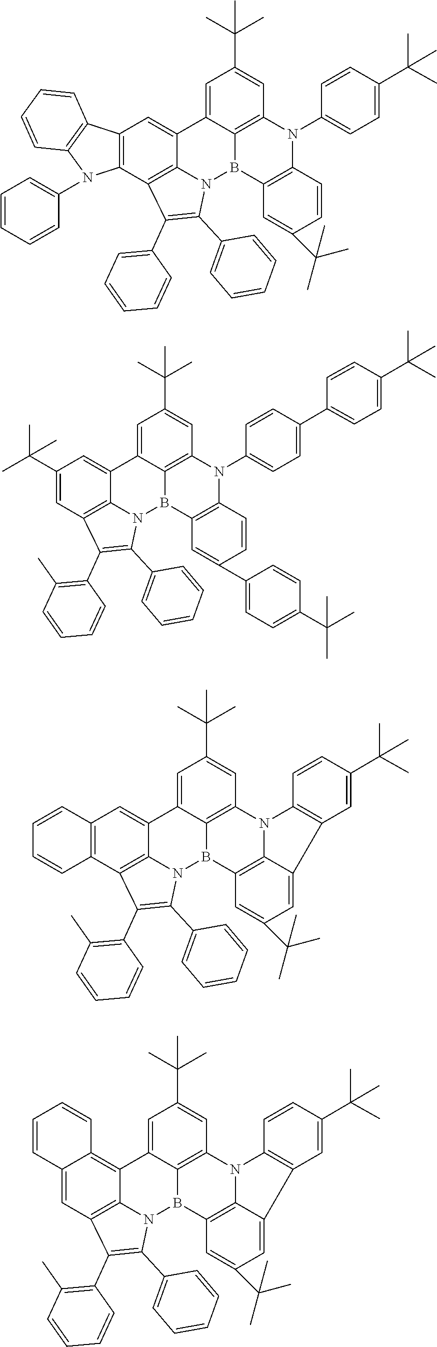

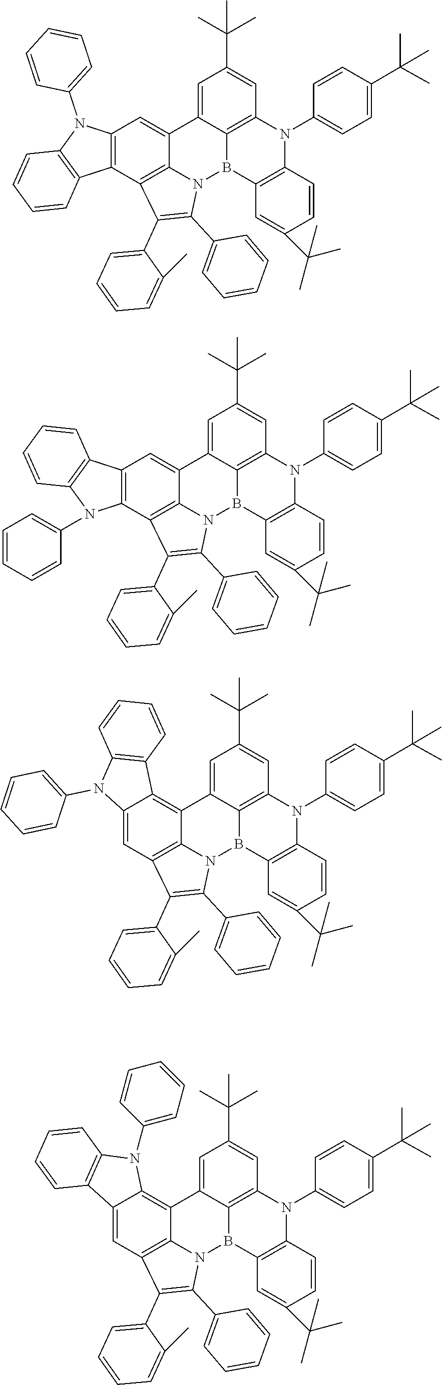

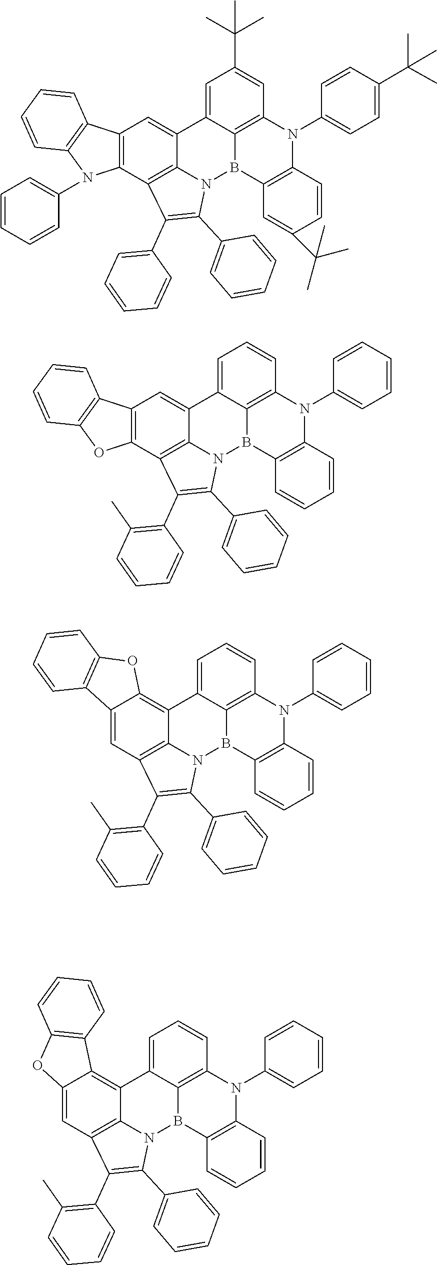

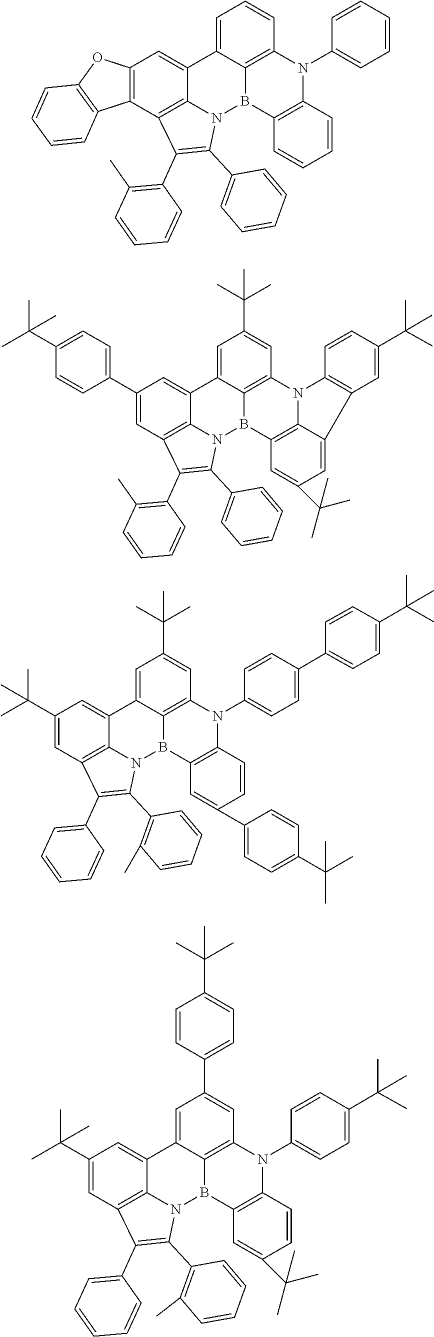

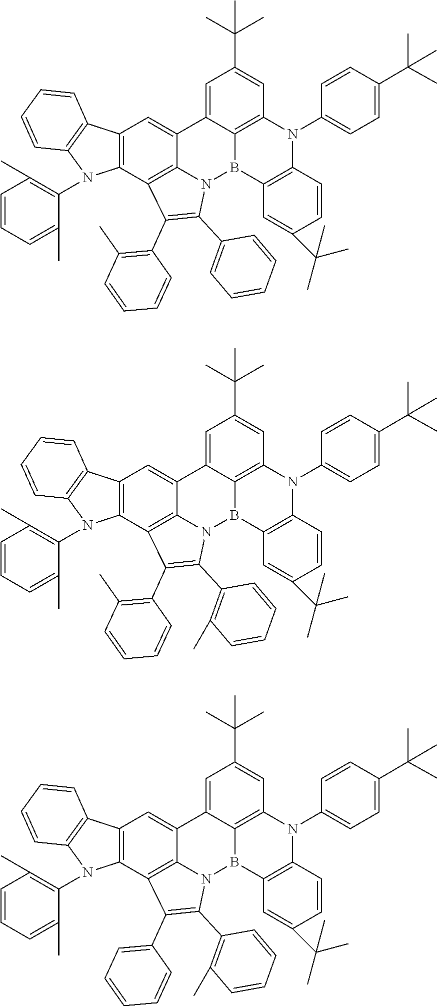 [SMILES: Cc1ccccc1-c1c(-c2ccccc2)n2c3c(cc4c5ccccc5n(-c5c(C)cccc5C)c4c13)-c1cc(C(C)(C)C)cc3c1B2c1cc(C(C)(C)C)ccc1N3c1ccc(C(C)(C)C)cc1 ; Cc1ccccc1-c1c(-c2ccccc2C)n2c3c(cc4c5ccccc5n(-c5c(C)cccc5C)c4c13)-c1cc(C(C)(C)C)cc3c1B2c1cc(C(C)(C)C)ccc1N3c1ccc(C(C)(C)C)cc1 ; Cc1ccccc1-c1c(-c2ccccc2)c2c3c(cc4c5ccccc5n(-c5c(C)cccc5C)c42)-c2cc(C(C)(C)C)cc4c2B(c2cc(C(C)(C)C)ccc2N4c2ccc(C(C)(C)C)cc2)n13]

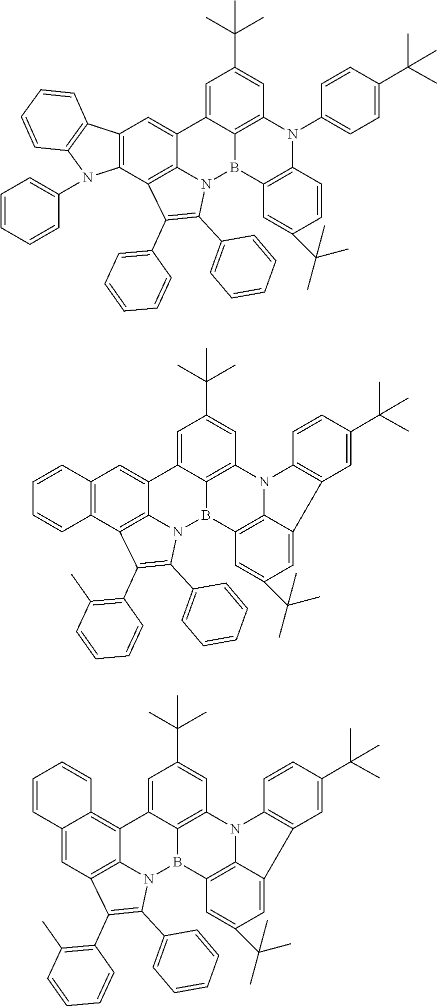 [SMILES: CC(C)(C)c1ccc(N2c3ccc(C(C)(C)C)cc3B3c4c(cc(C(C)(C)C)cc42)-c2cc4c5ccccc5n(-c5ccccc5)c4c4c(-c5ccccc5)c(-c5ccccc5)n3c24)cc1 ; Cc1ccccc1-c1c(-c2ccccc2)n2c3c(cc4ccccc4c13)-c1cc(C(C)(C)C)cc3c1B2c1cc(C(C)(C)C)cc2c4cc(C(C)(C)C)ccc4n-3c12 ; Cc1ccccc1-c1c(-c2ccccc2)n2c3c(c4ccccc4cc13)-c1cc(C(C)(C)C)cc3c1B2c1cc(C(C)(C)C)cc2c4cc(C(C)(C)C)ccc4n-3c12]

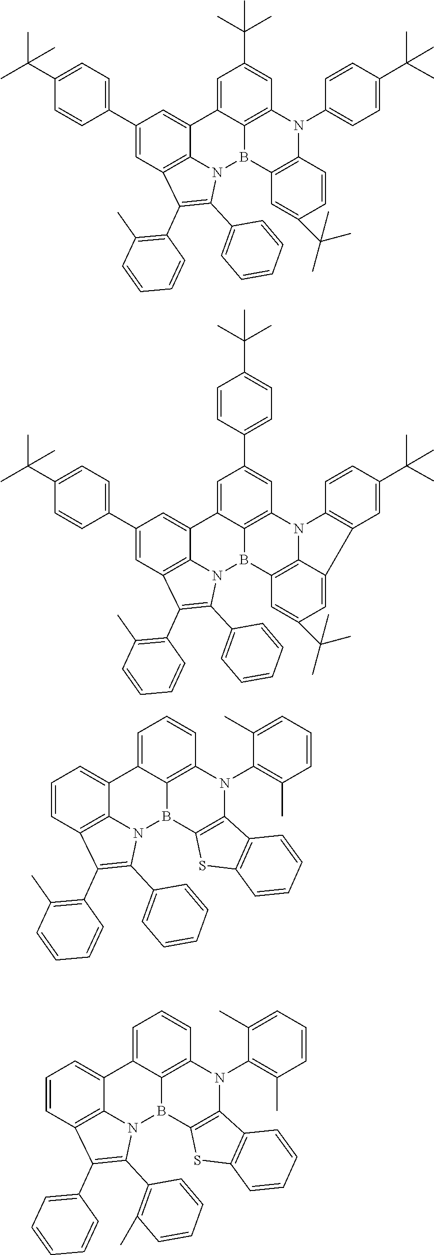

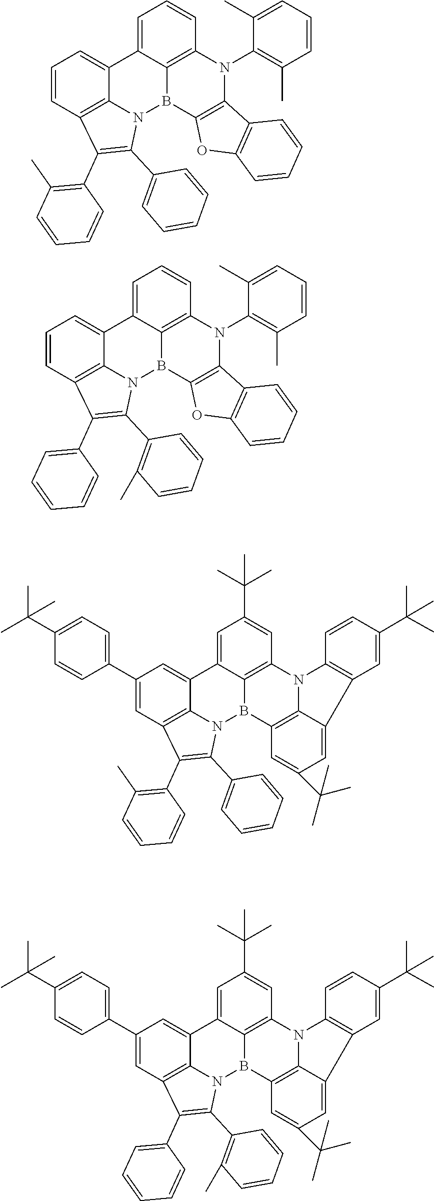

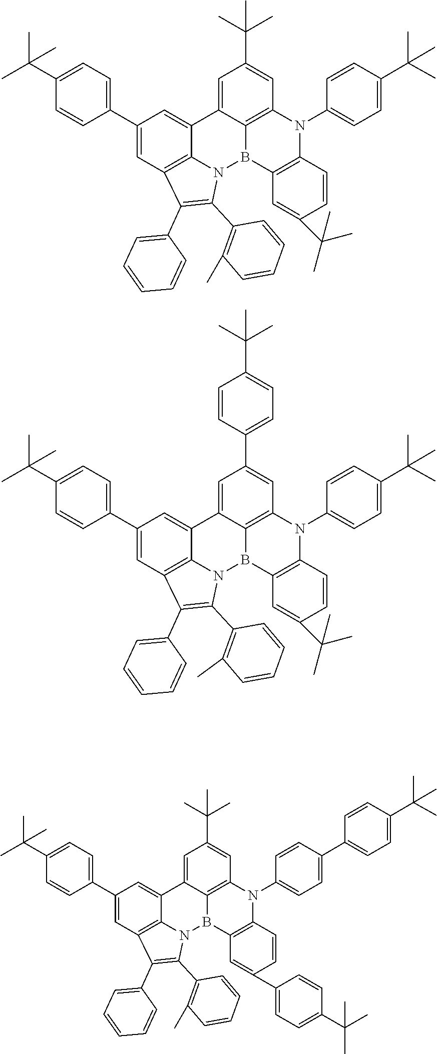

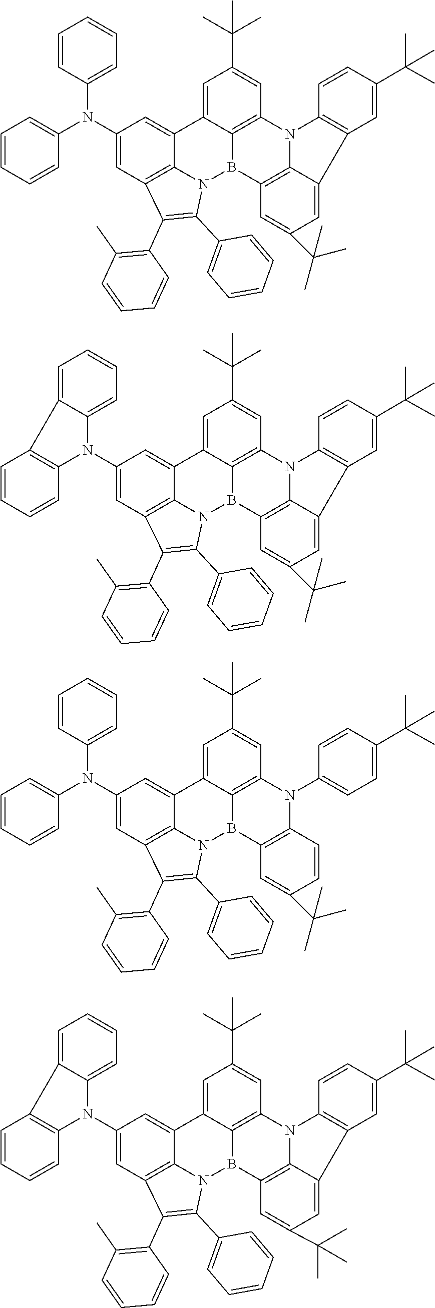

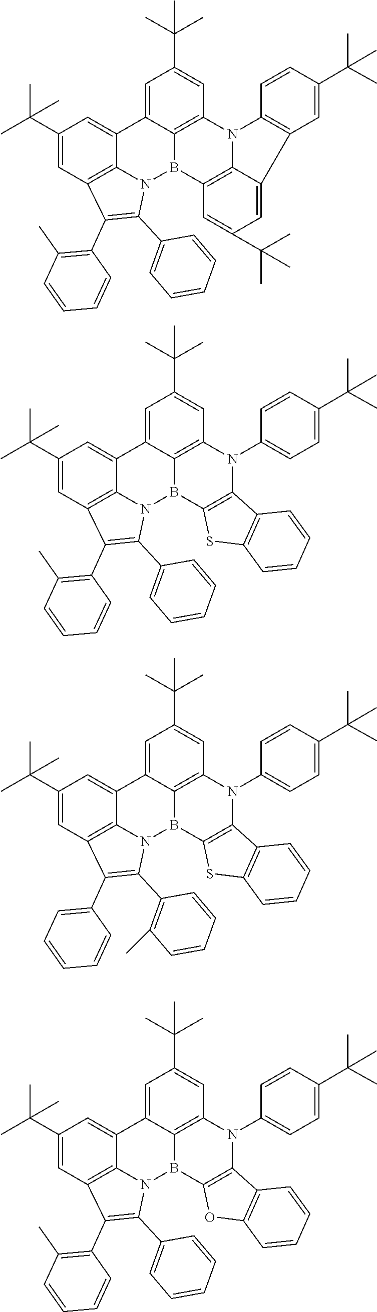

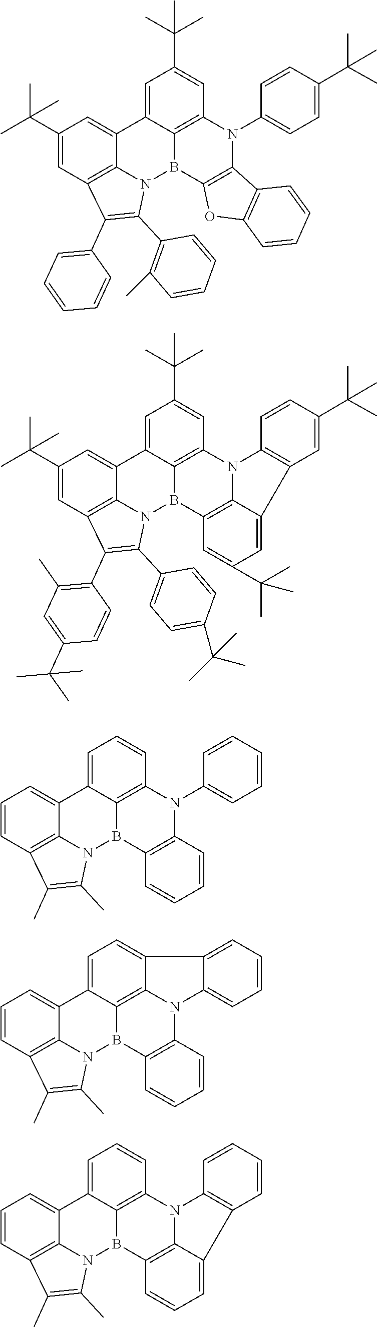

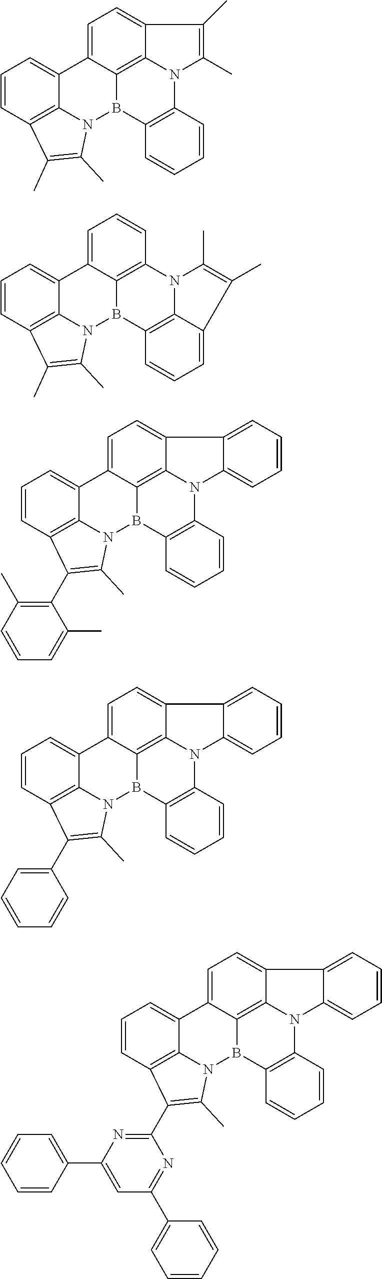

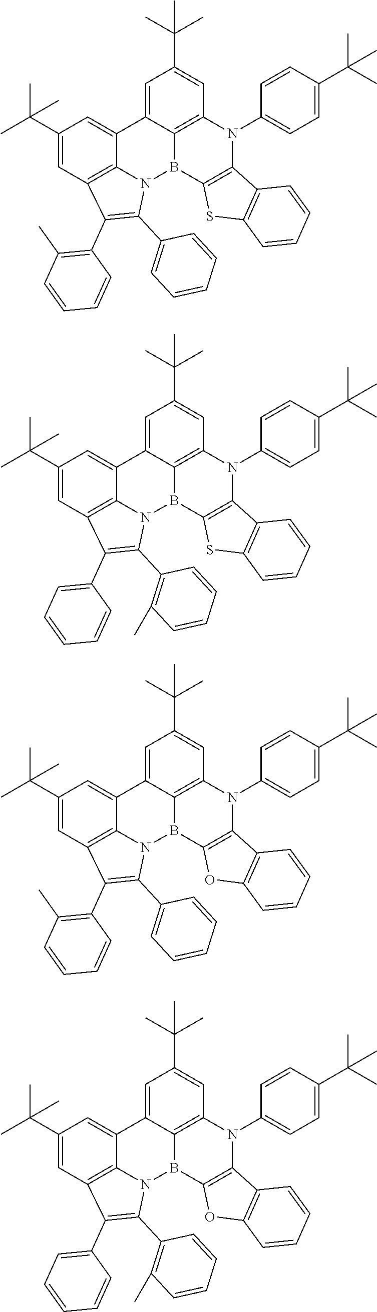

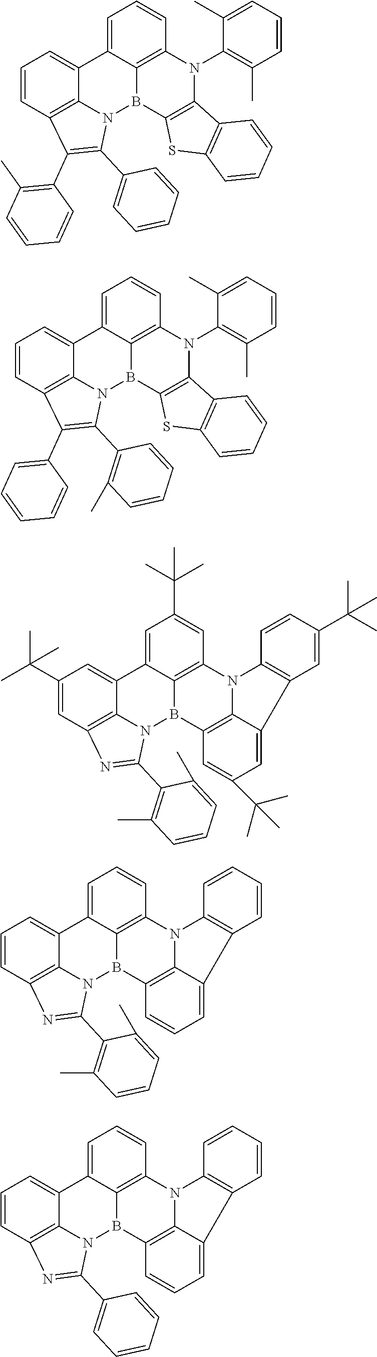

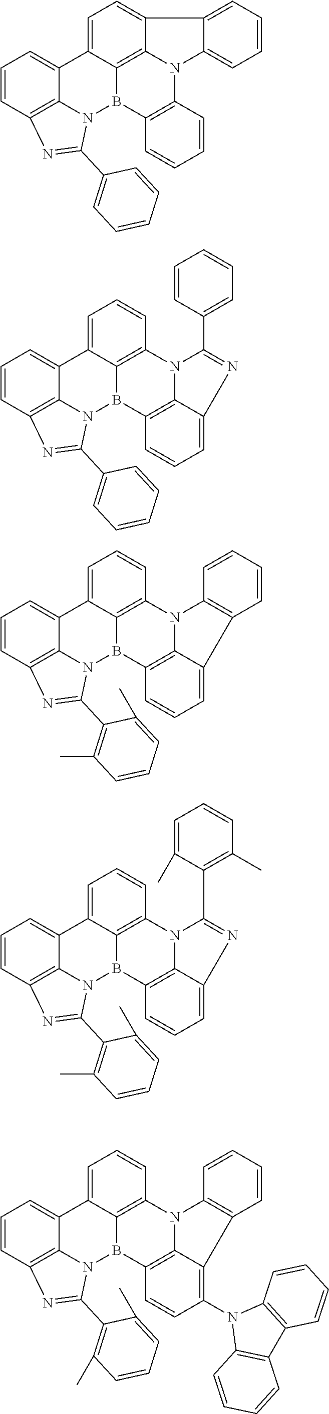

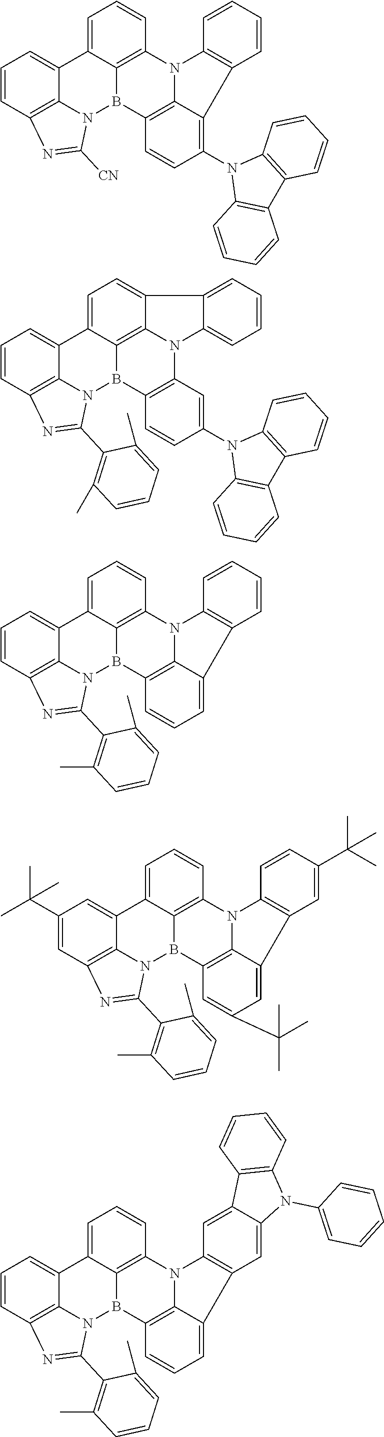

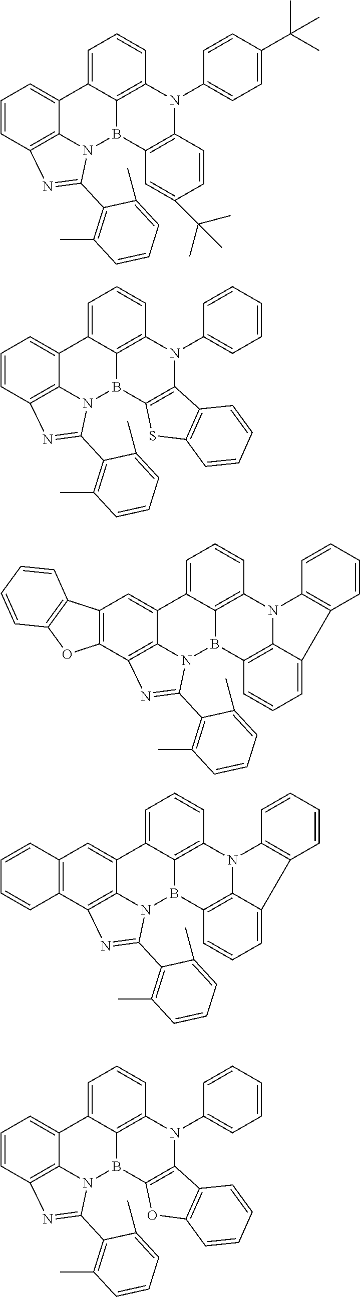

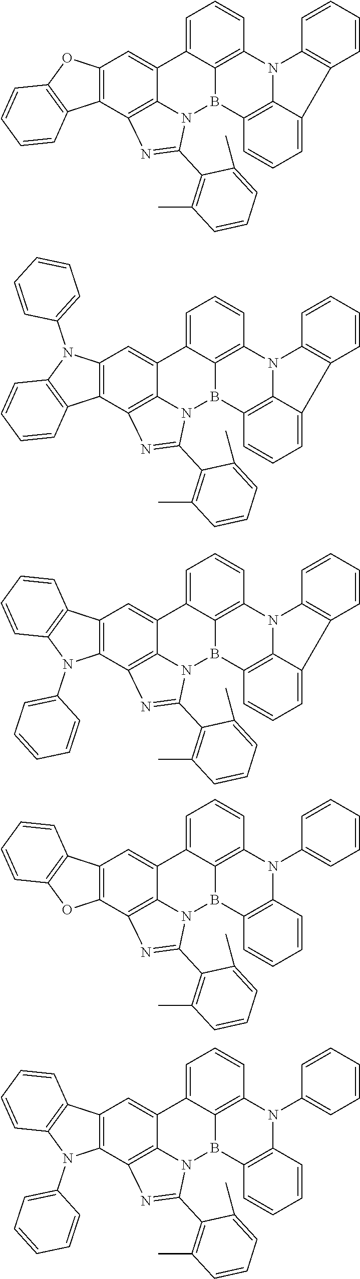

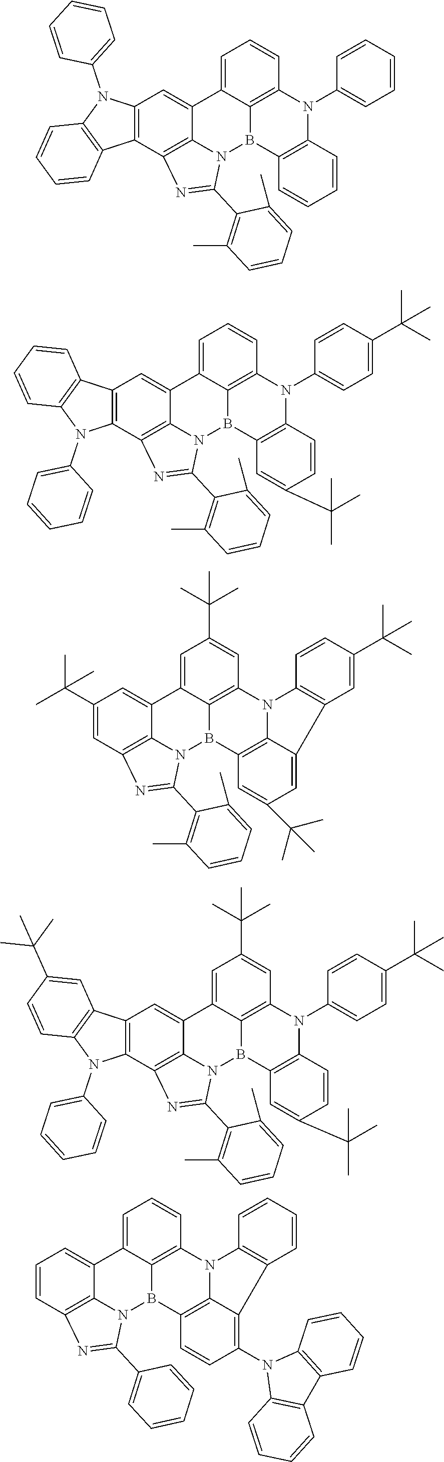

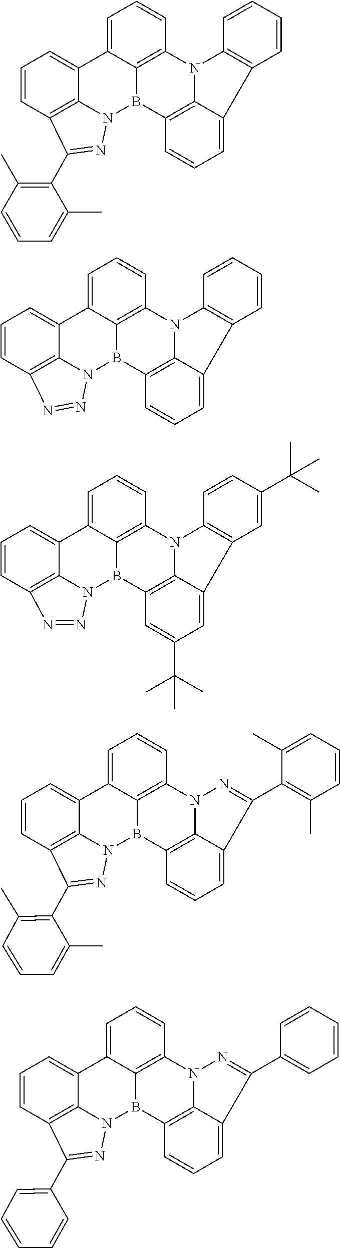

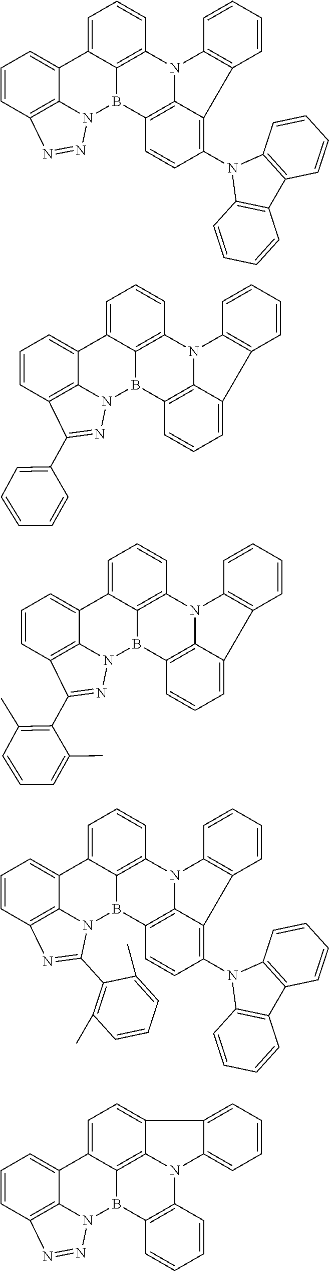

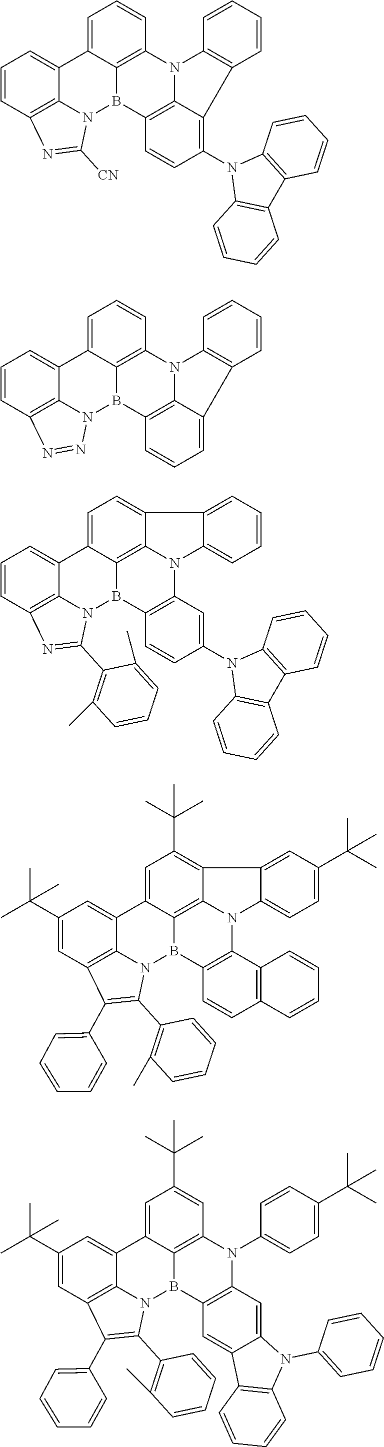

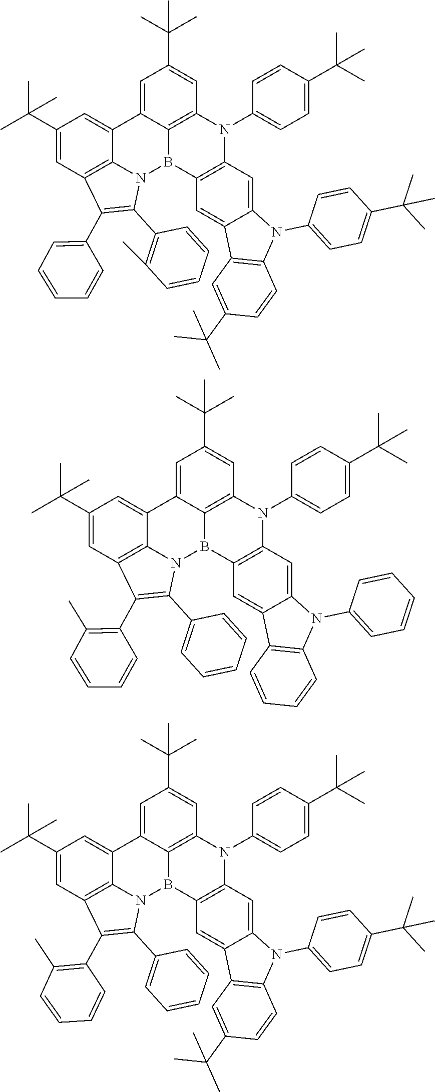

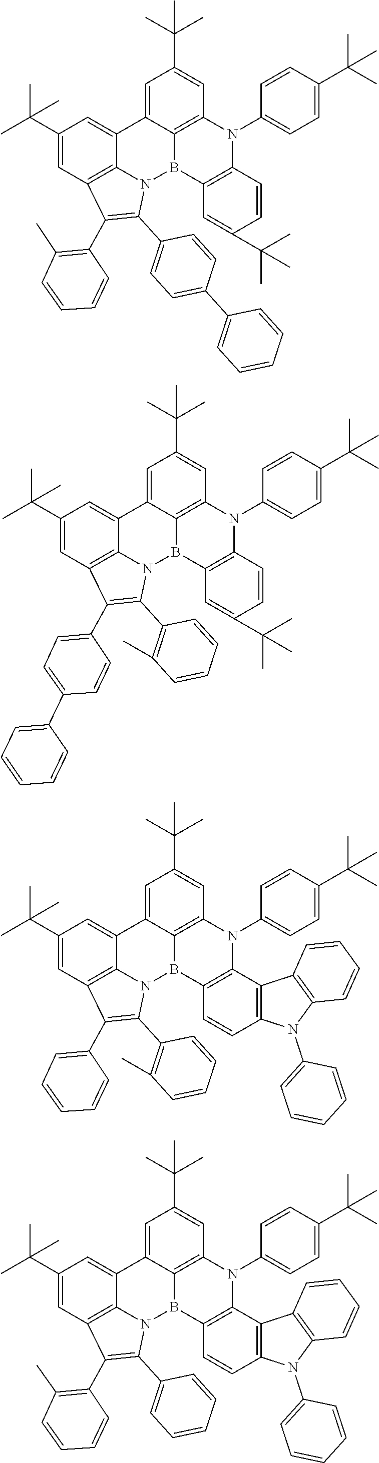

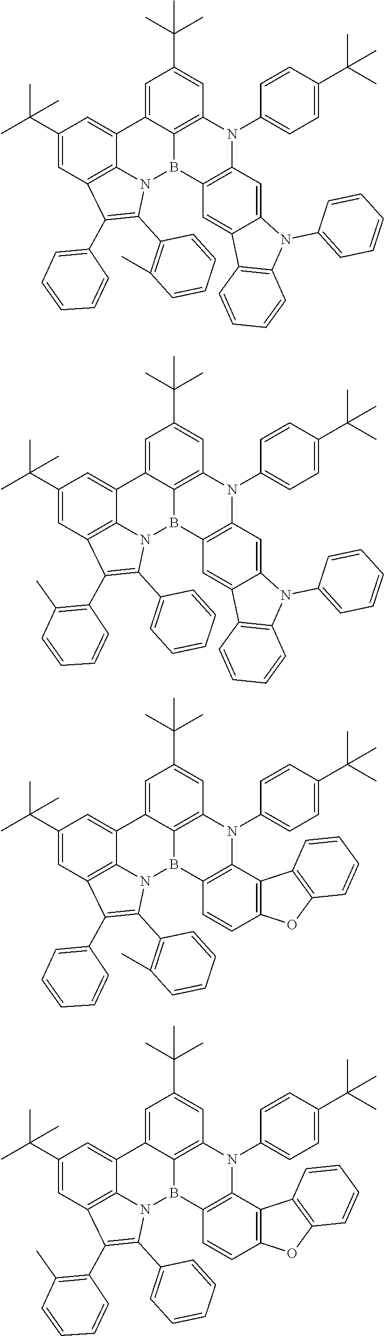

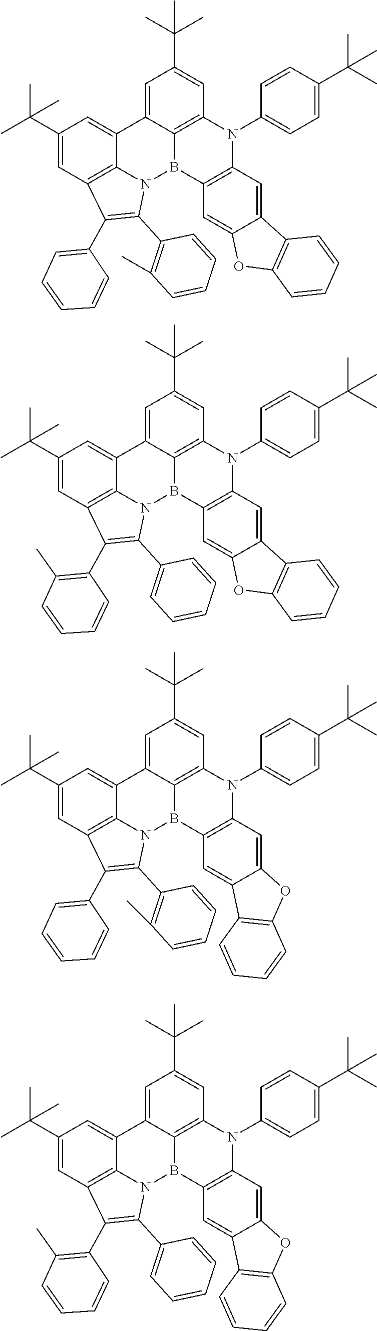

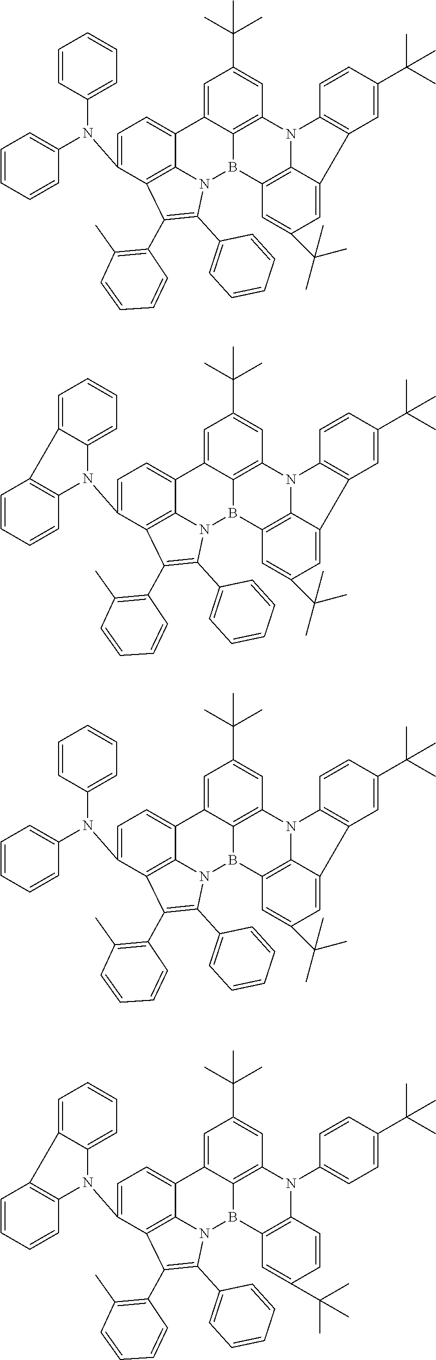 [SMILES: Cc1ccccc1-c1c(-c2ccccc2)n2c3c(ccc(N(c4ccccc4)c4ccccc4)c13)-c1cc(C(C)(C)C)cc3c1B2c1cc(C(C)(C)C)cc2c4cc(C(C)(C)C)ccc4n-3c12 ; Cc1ccccc1-c1c(-c2ccccc2)n2c3c(ccc(-n4c5ccccc5c5ccccc54)c13)-c1cc(C(C)(C)C)cc3c1B2c1cc(C(C)(C)C)cc2c4cc(C(C)(C)C)ccc4n-3c12 ; Cc1ccccc1-c1c(-c2ccccc2)n2c3c(ccc(N(c4ccccc4)c4ccccc4)c13)-c1cc(C(C)(C)C)cc3c1B2c1cc(C(C)(C)C)cc2c4cc(C(C)(C)C)ccc4n-3c12 ; Cc1ccccc1-c1c(-c2ccccc2)n2c3c(ccc(-n4c5ccccc5c5ccccc54)c13)-c1cc(C(C)(C)C)cc3c1B2c1cc(C(C)(C)C)ccc1N3c1ccc(C(C)(C)C)cc1]

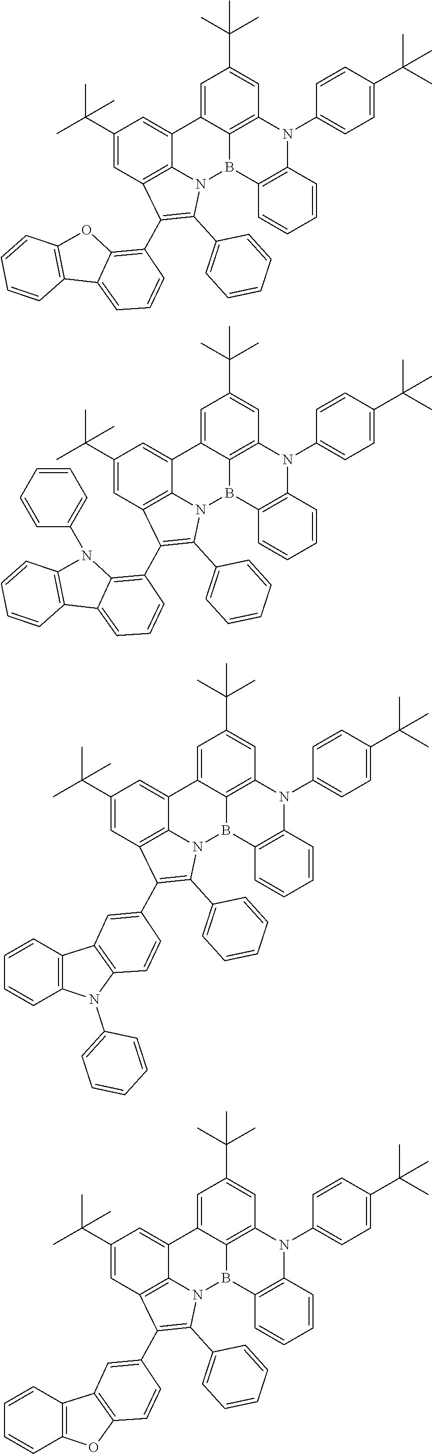

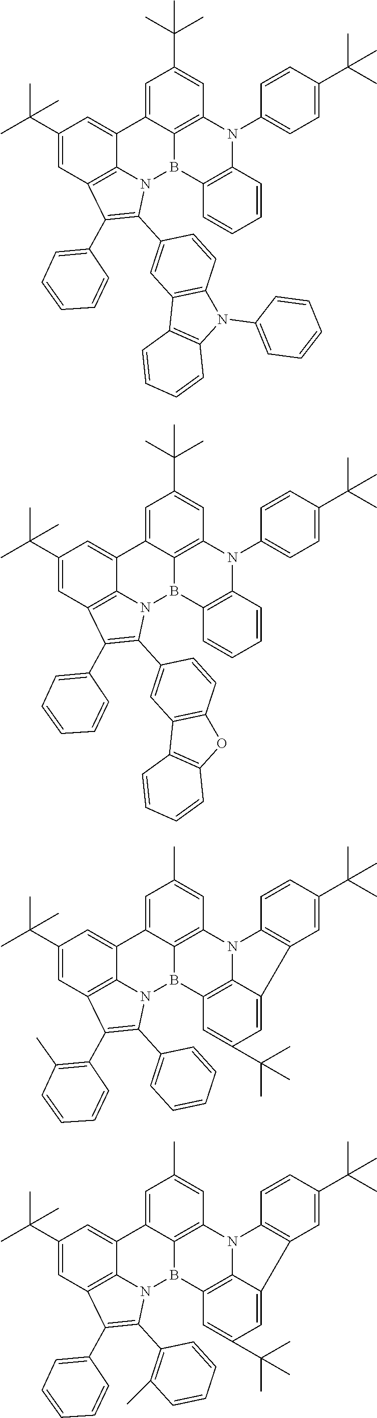

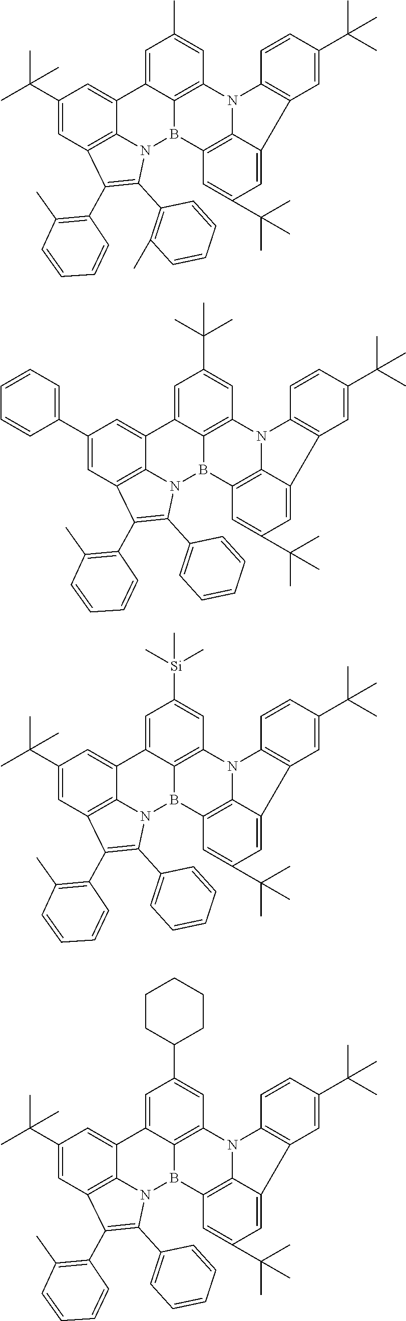

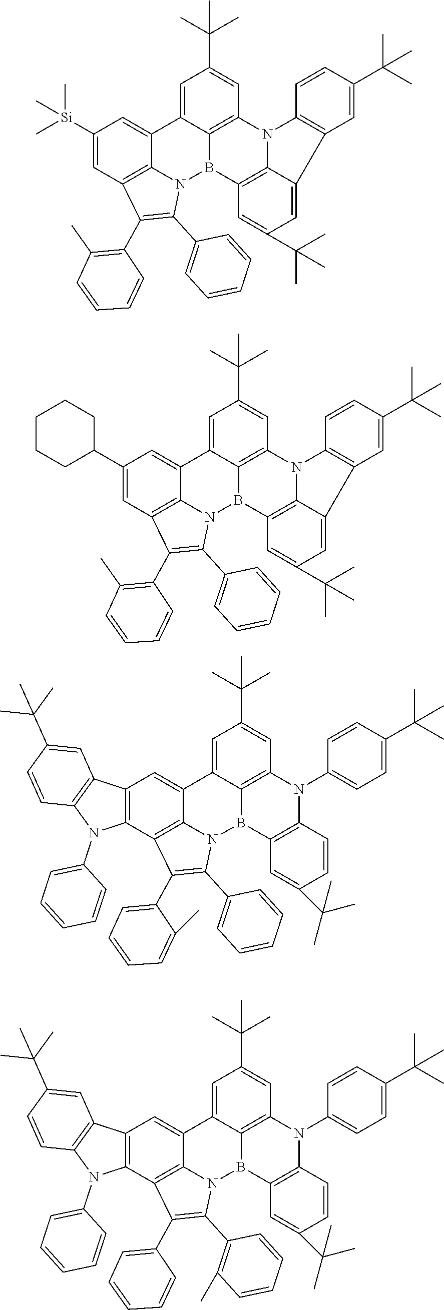

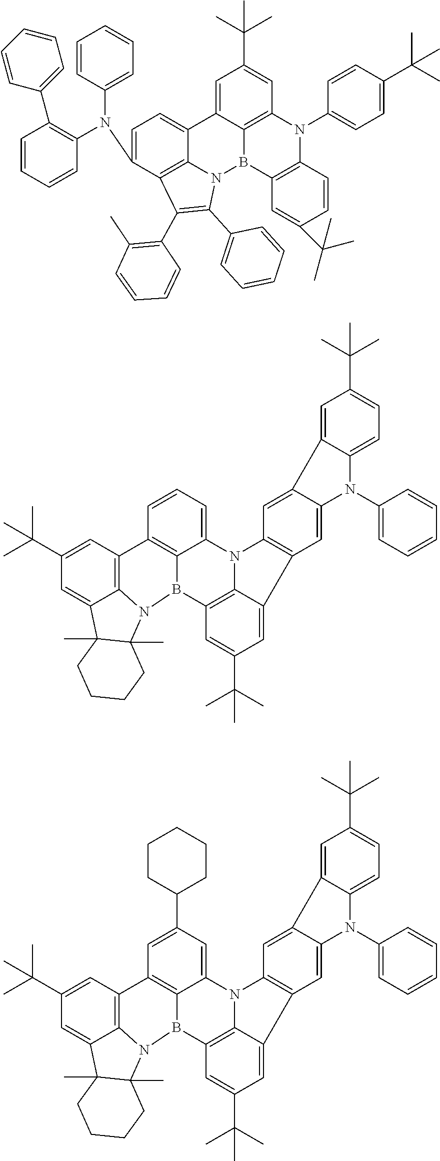

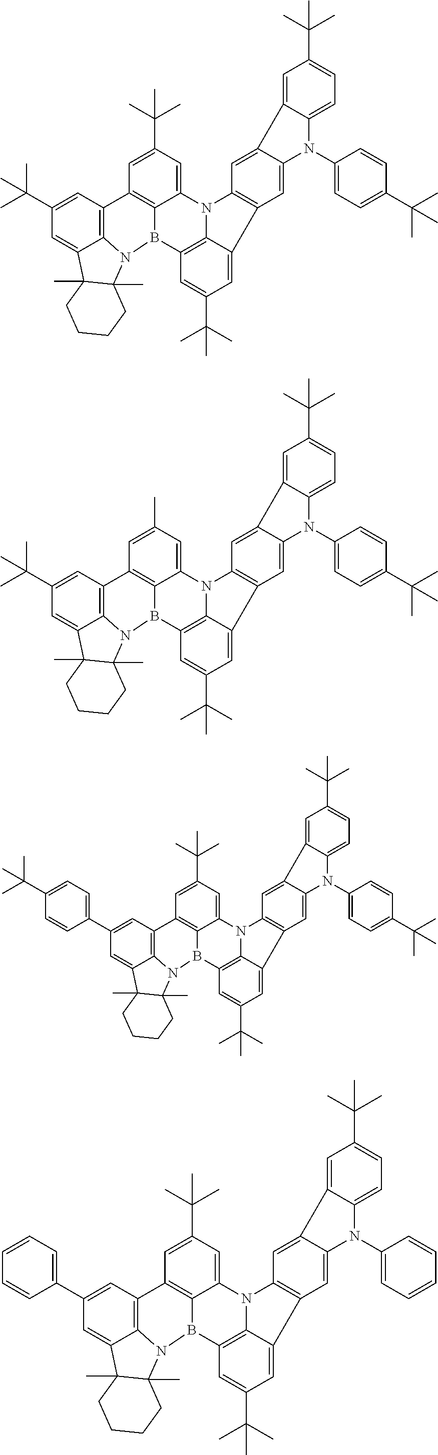

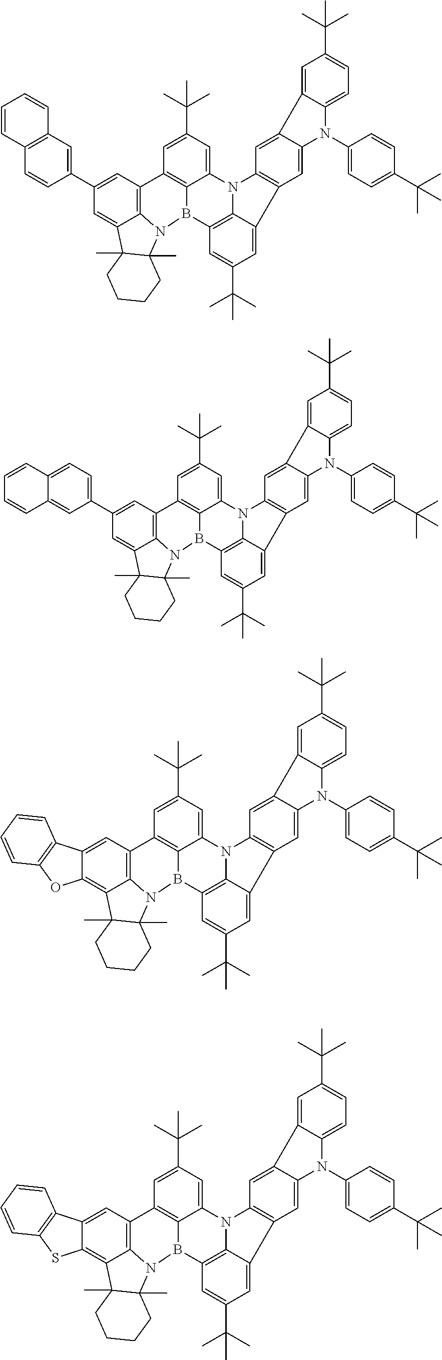

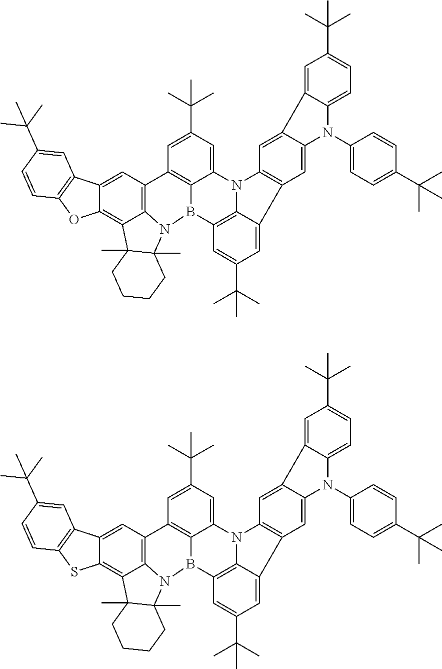

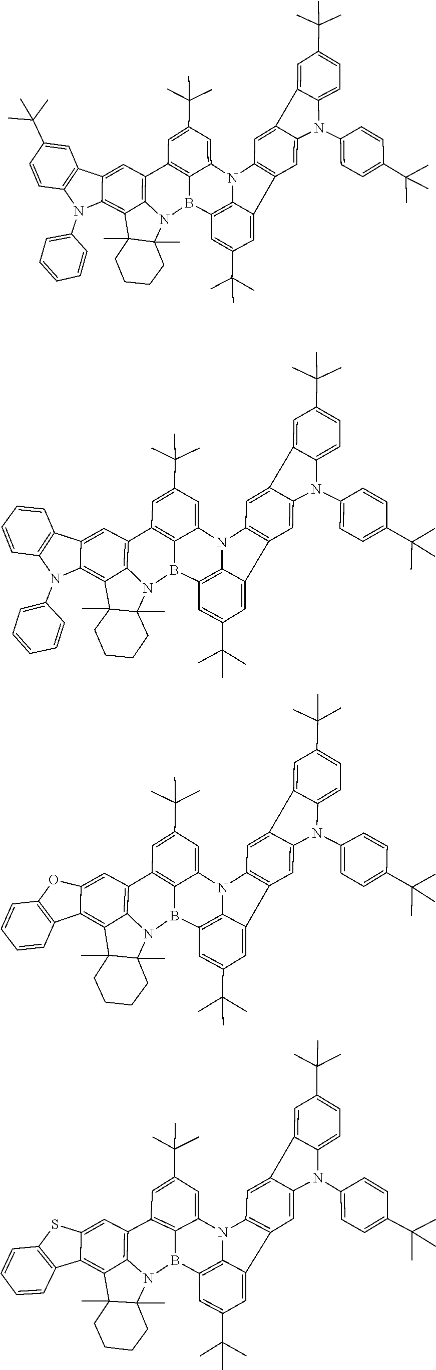

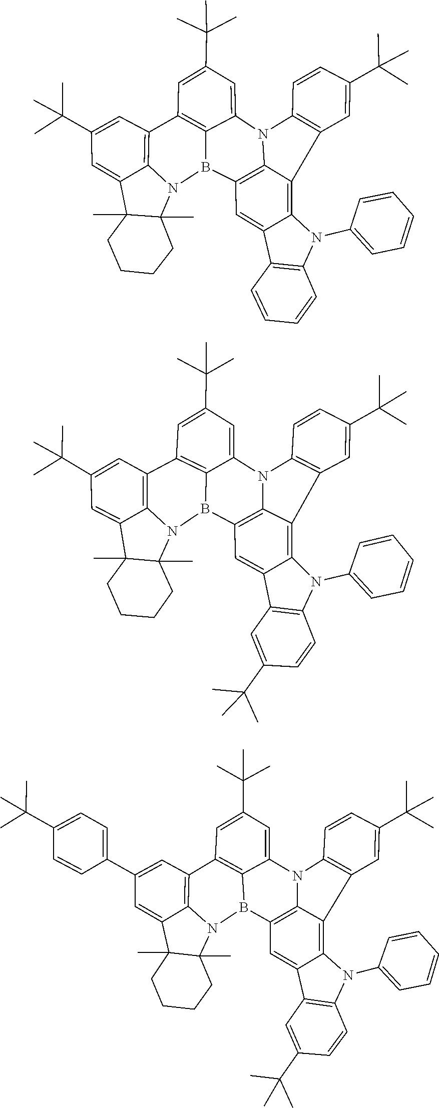

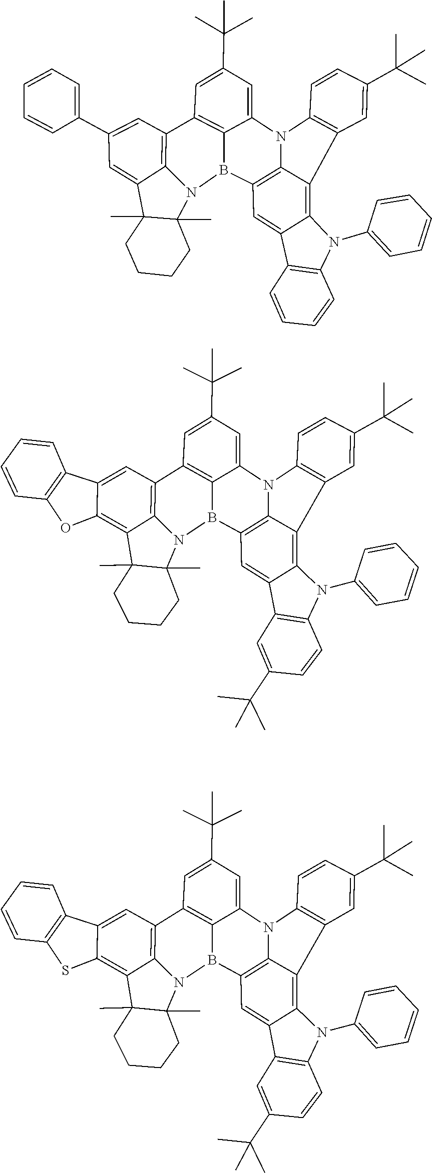 [SMILES: CC(C)(C)c1cc2c3c(c1)-n1c4ccc(C(C)(C)C)cc4c4c1c(cc1c5ccccc5n(-c5ccccc5)c14)B3N1c3c-2cc(-c2ccccc2)cc3C2(C)CCCCC12C ; CC(C)(C)c1cc2c3c(c1)-n1c4ccc(C(C)(C)C)cc4c4c1c(cc1c5cc(C(C)(C)C)ccc5n(-c5ccccc5)c14)B3N1c3c-2cc2c(oc4ccccc42)c3C2(C)CCCCC12C ; CC(C)(C)c1cc2c3c(c1)-n1c4ccc(C(C)(C)C)cc4c4c1c(cc1c5cc(C(C)(C)C)ccc5n(-c5ccccc5)c14)B3N1c3c-2cc2c(sc4ccccc42)c3C2(C)CCCCC12C]

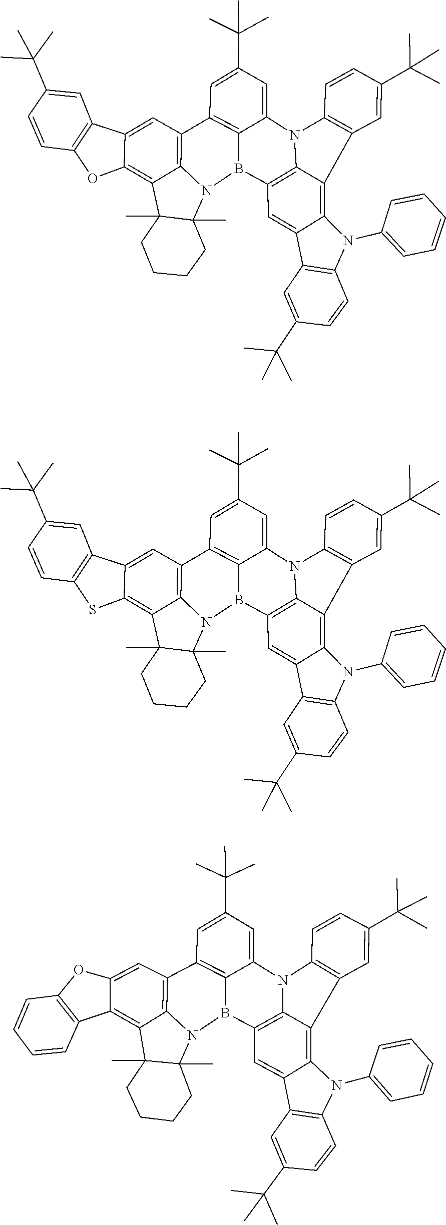 [SMILES: CC(C)(C)c1cc2c3c(c1)-n1c4ccc(C(C)(C)C)cc4c4c1c(cc1c5cc(C(C)(C)C)ccc5n(-c5ccccc5)c14)B3N1c3c-2cc2c(oc4ccc(C(C)(C)C)cc42)c3C2(C)CCCCC12C ; CC(C)(C)c1cc2c3c(c1)-n1c4ccc(C(C)(C)C)cc4c4c1c(cc1c5cc(C(C)(C)C)ccc5n(-c5ccccc5)c14)B3N1c3c-2cc2c(sc4ccc(C(C)(C)C)cc42)c3C2(C)CCCCC12C ; CC(C)(C)c1cc2c3c(c1)-n1c4ccc(C(C)(C)C)cc4c4c1c(cc1c5cc(C(C)(C)C)ccc5n(-c5ccccc5)c14)B3N1c3c-2cc2oc4ccccc4c2c3C2(C)CCCCC12C]

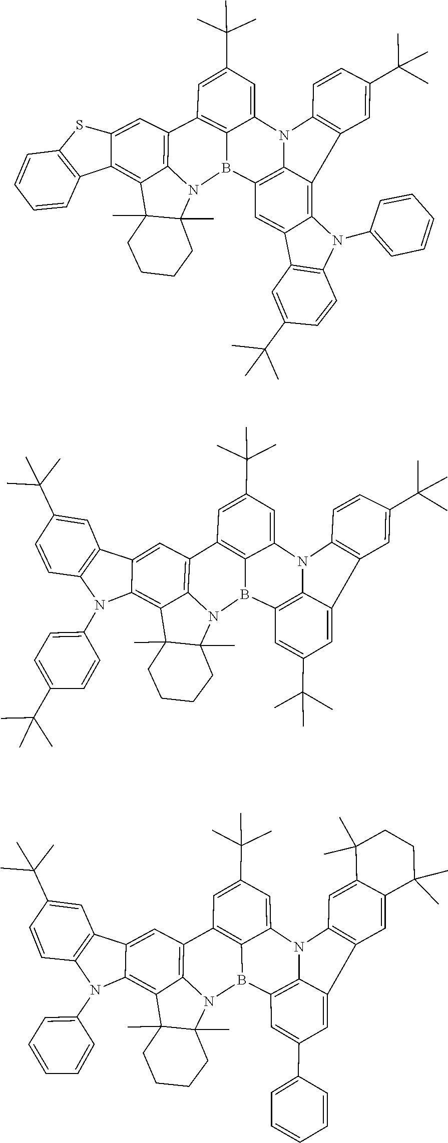

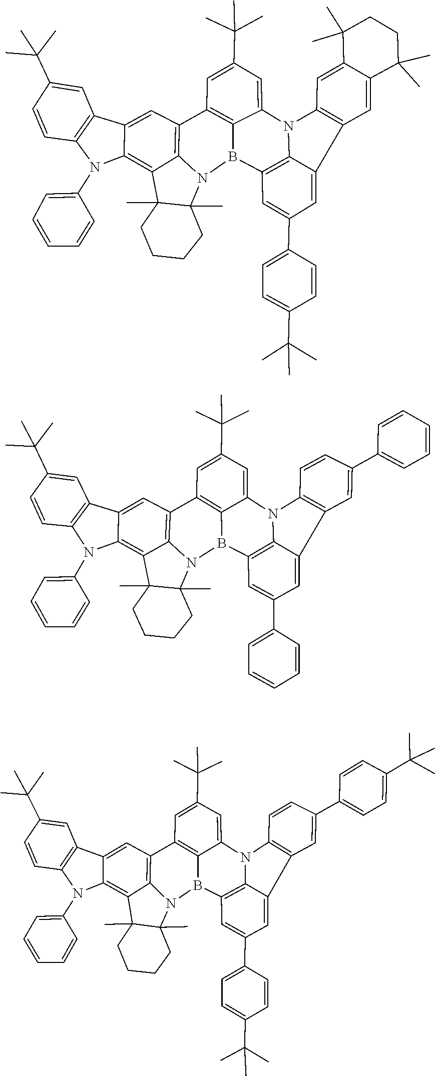

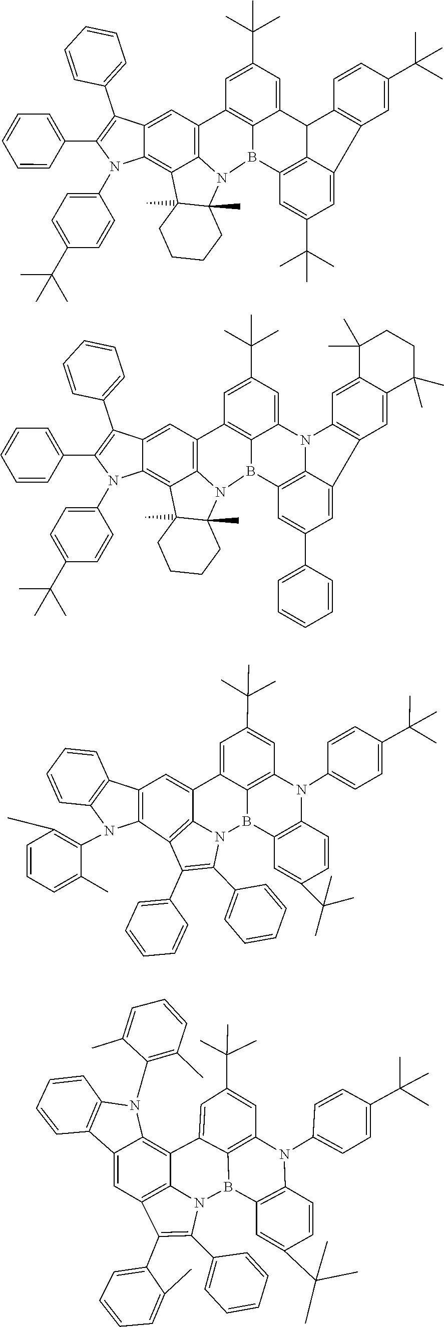

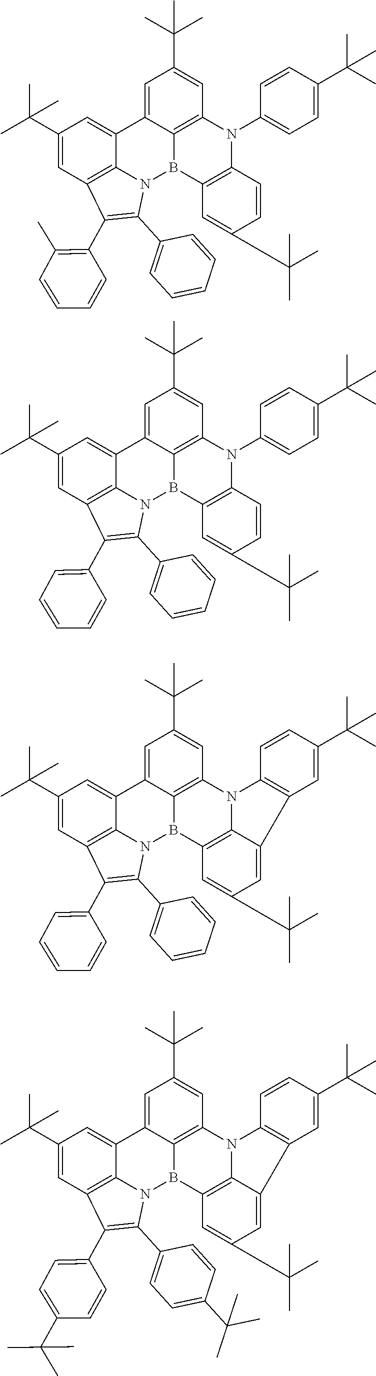

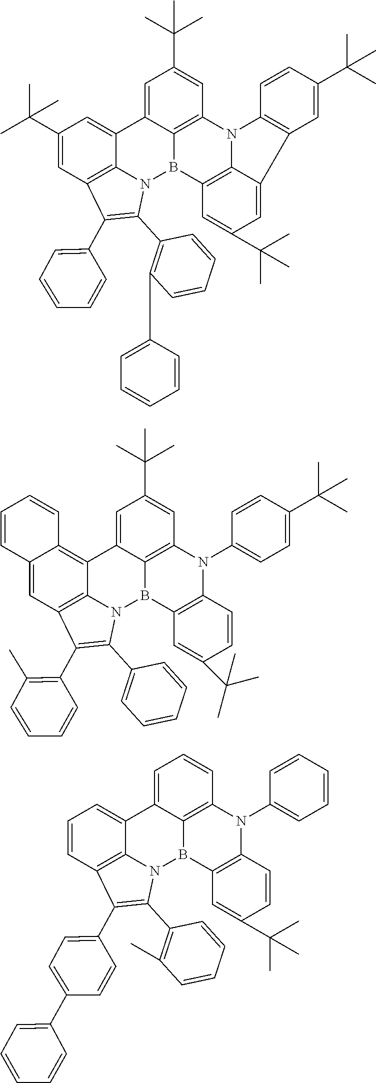

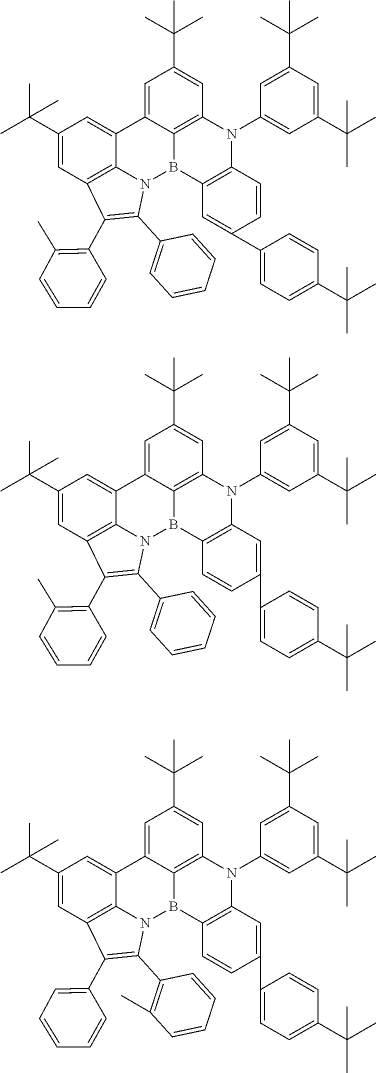

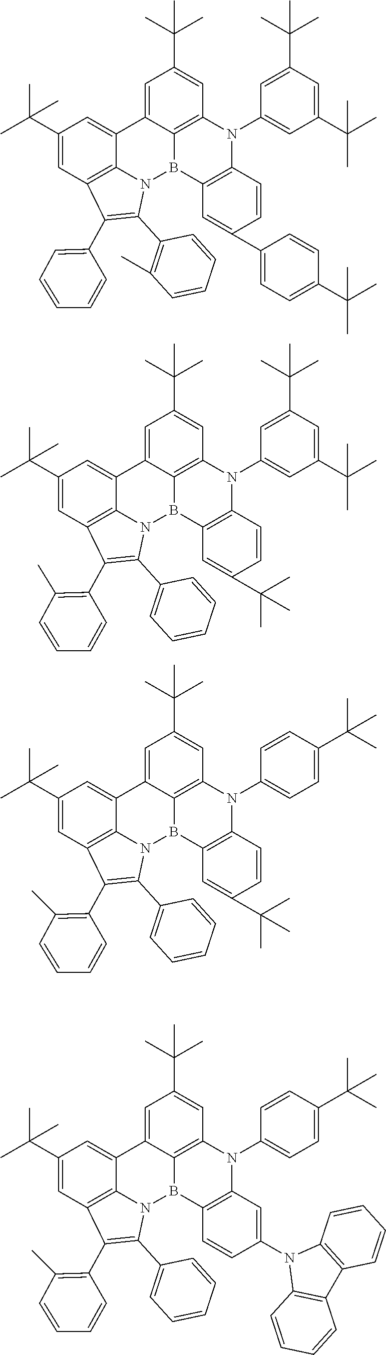

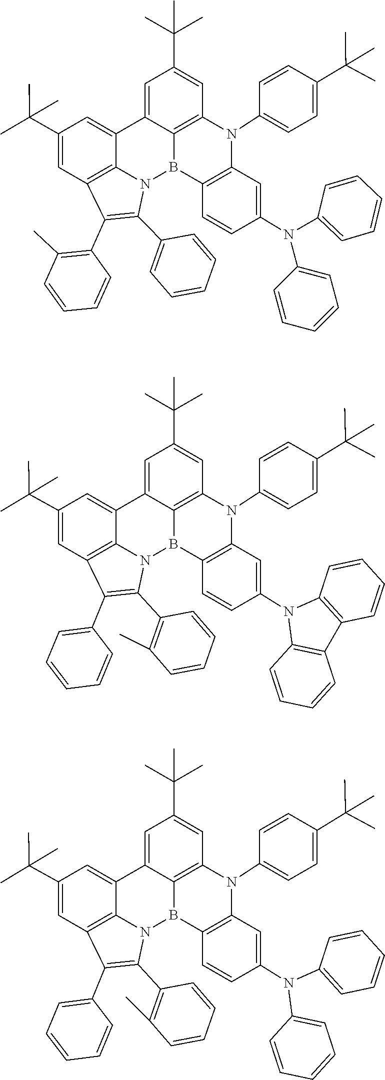 [SMILES: Cc1ccccc1-c1c(-c2ccccc2)n2c3c(cc(C(C)(C)C)cc13)-c1cc(C(C)(C)C)cc3c1B2c1ccc(N(c2ccccc2)c2ccccc2)cc1N3c1ccc(C(C)(C)C)cc1 ; Cc1ccccc1-c1c(-c2ccccc2)c2cc(C(C)(C)C)cc3c2n1B1c2ccc(-n4c5ccccc5c5ccccc54)cc2N(c2ccc(C(C)(C)C)cc2)c2cc(C(C)(C)C)cc-3c21 ; Cc1ccccc1-c1c(-c2ccccc2)c2cc(C(C)(C)C)cc3c2n1B1c2ccc(N(c4ccccc4)c4ccccc4)cc2N(c2ccc(C(C)(C)C)cc2)c2cc(C(C)(C)C)cc-3c21]

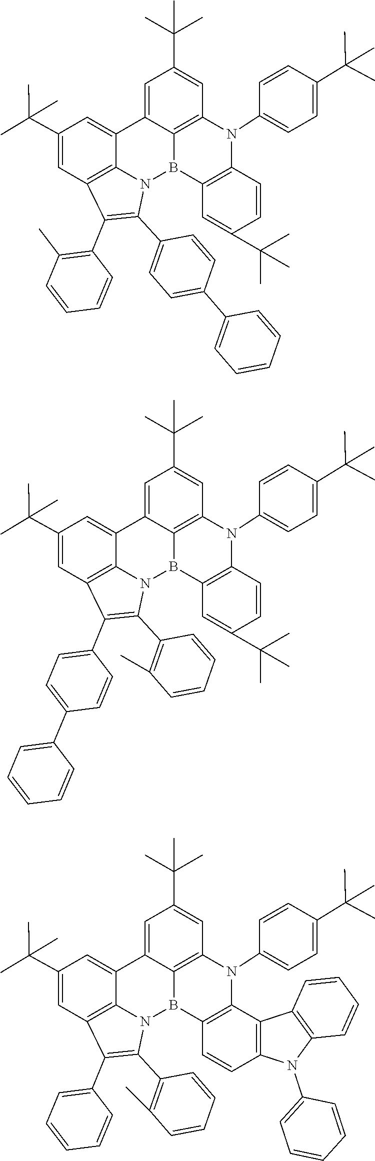

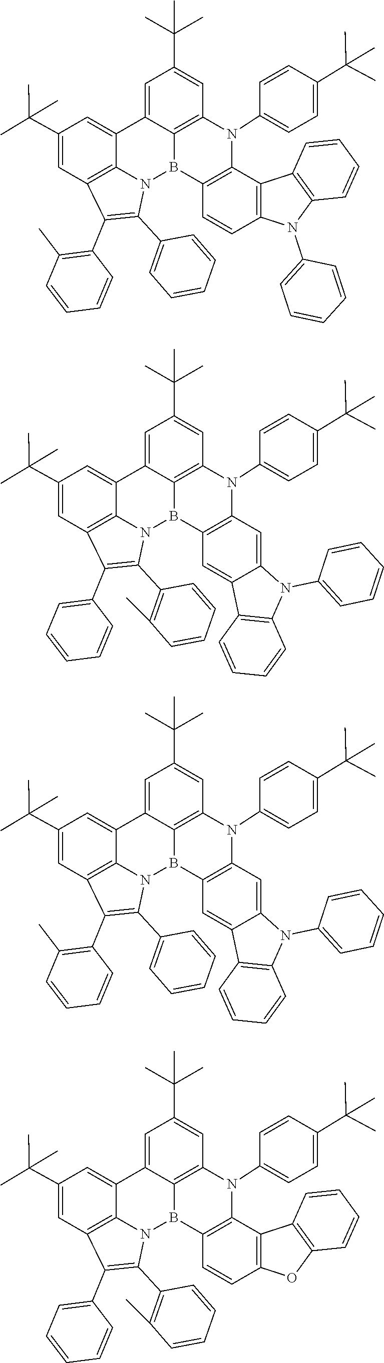

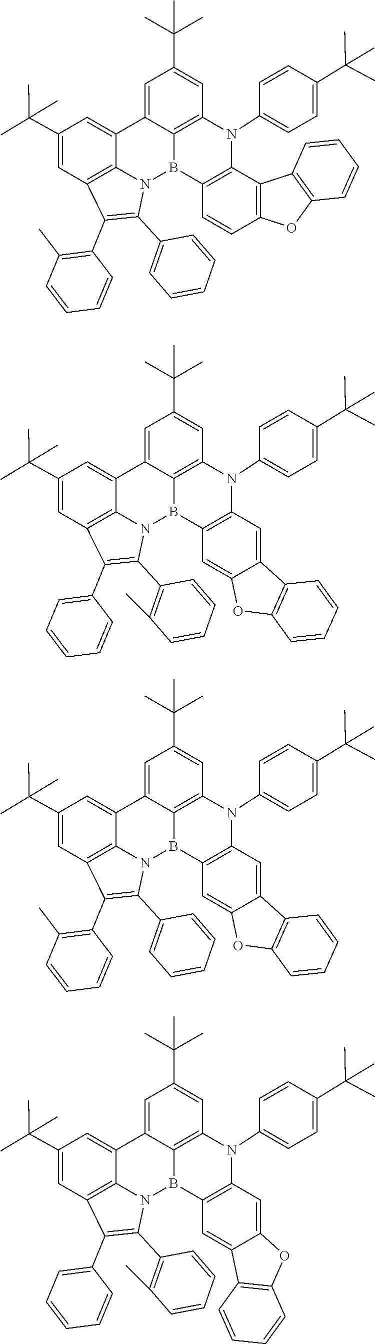

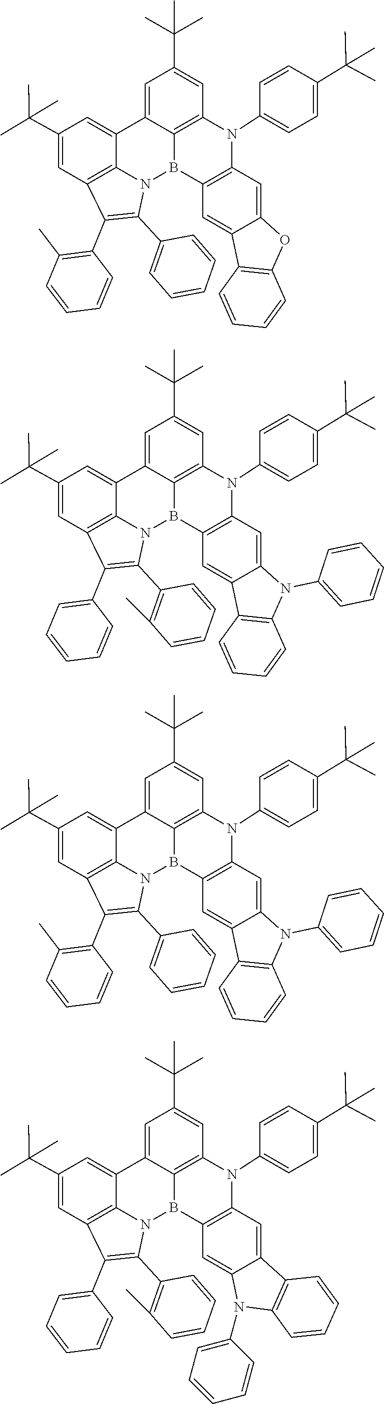

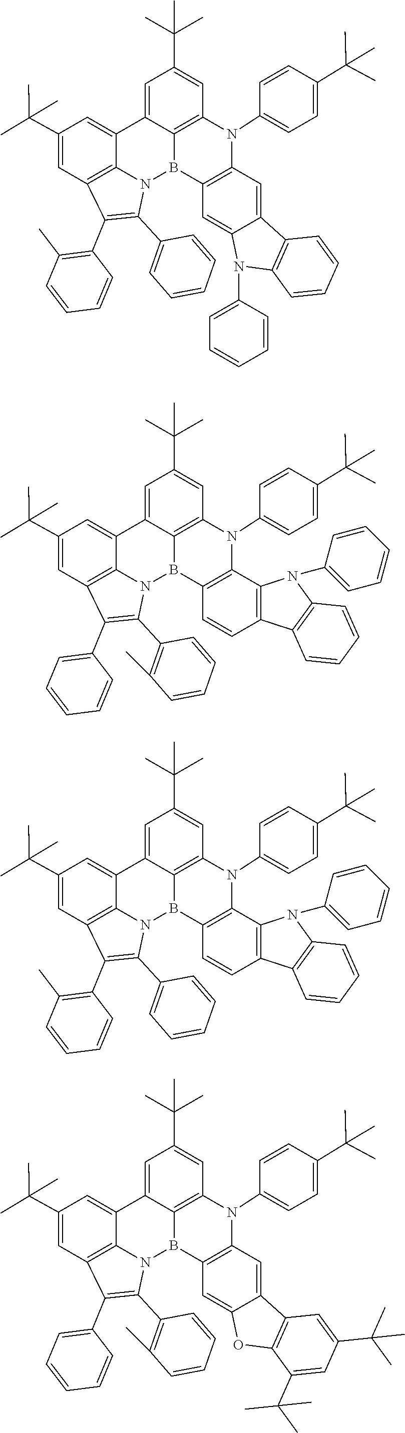

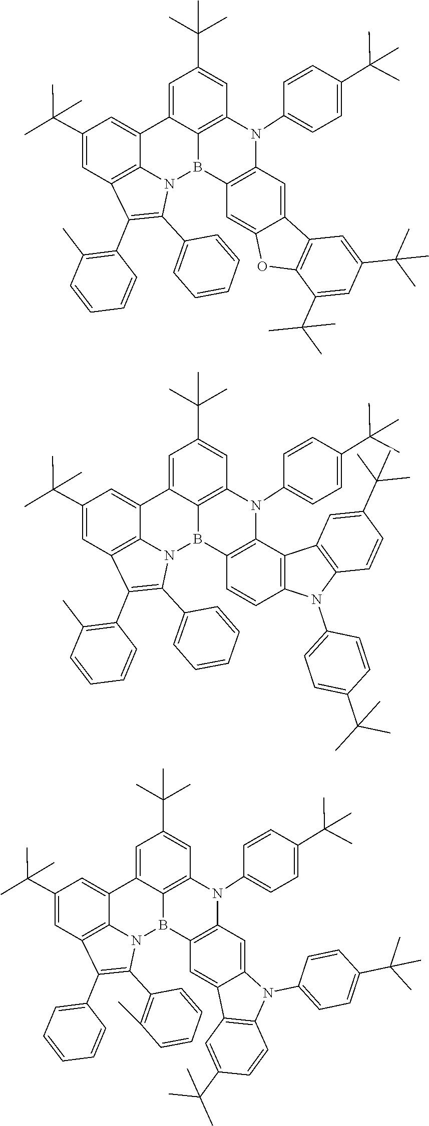

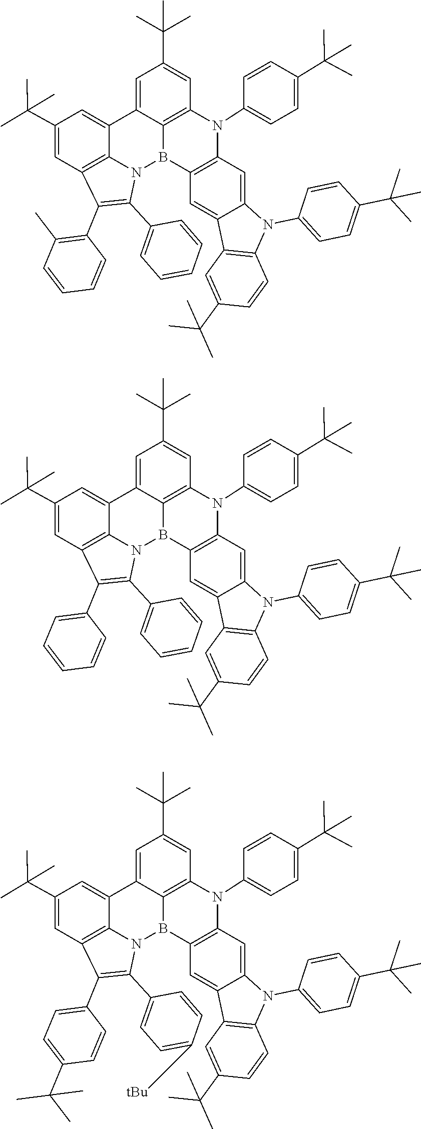

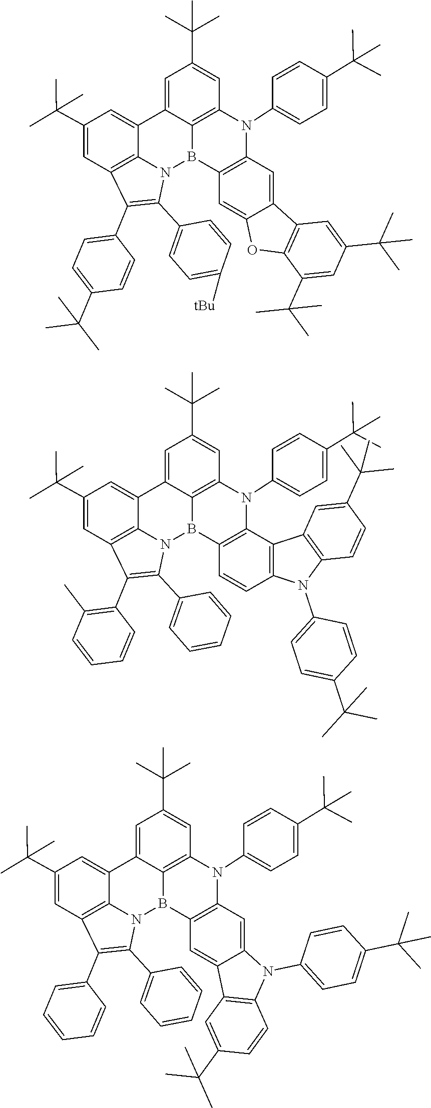

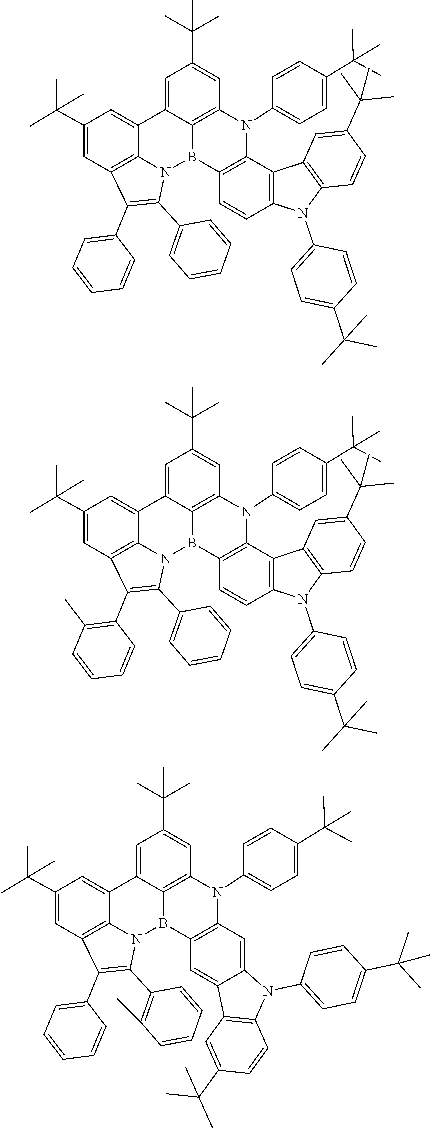

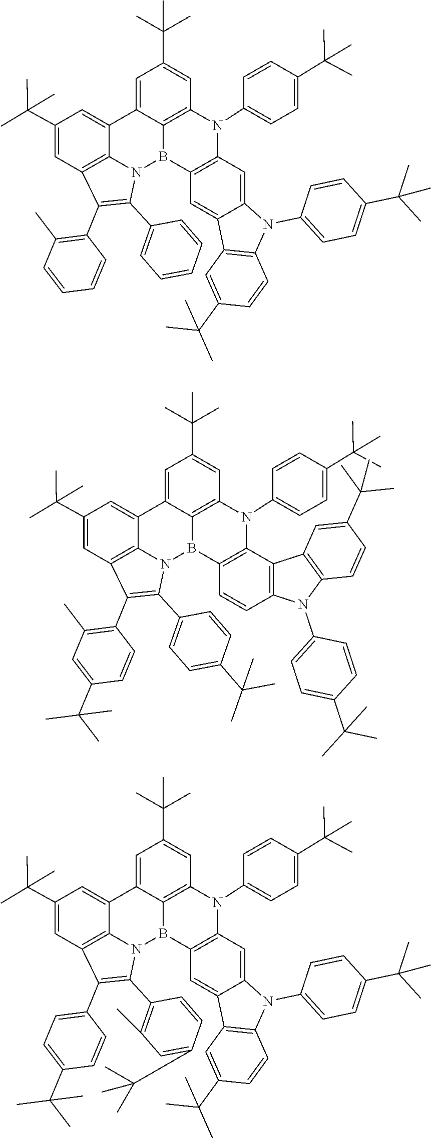

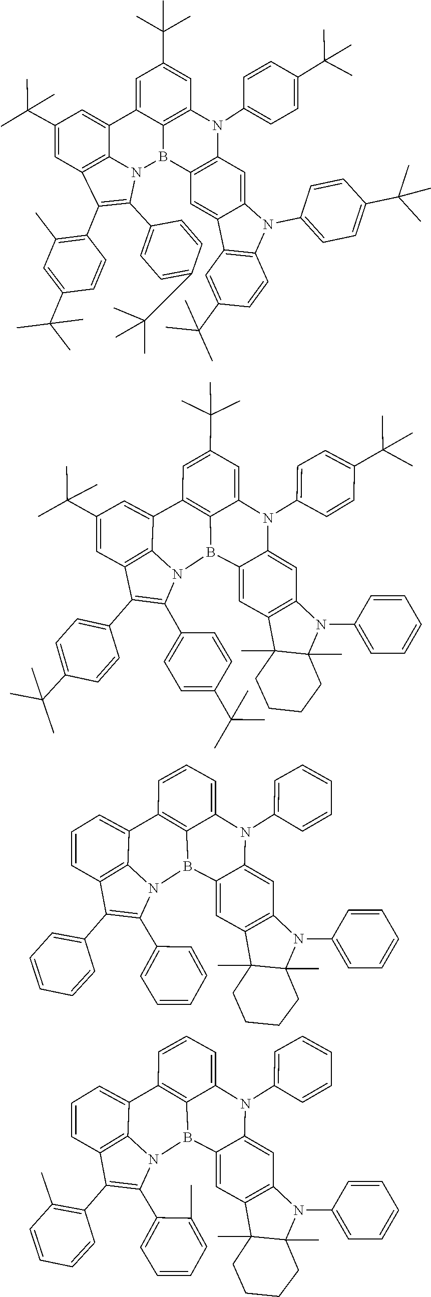

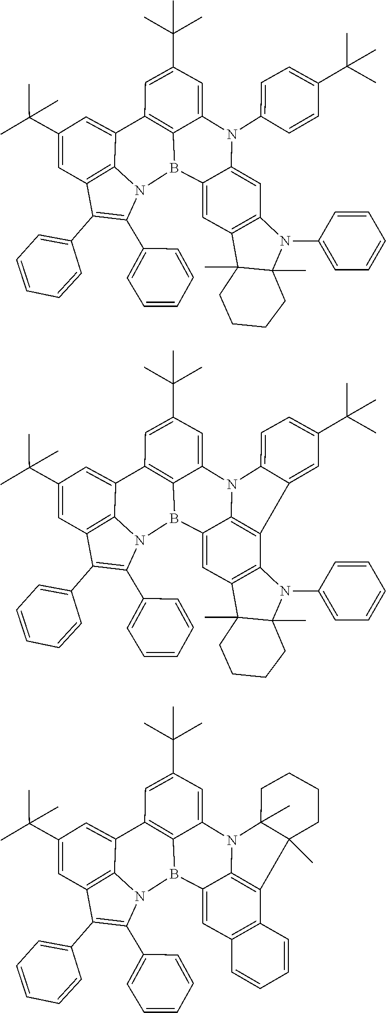

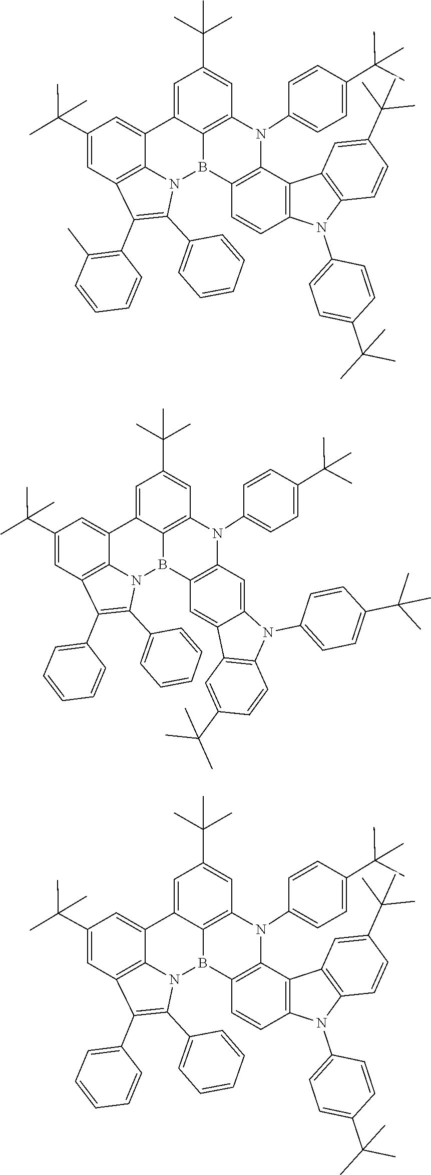

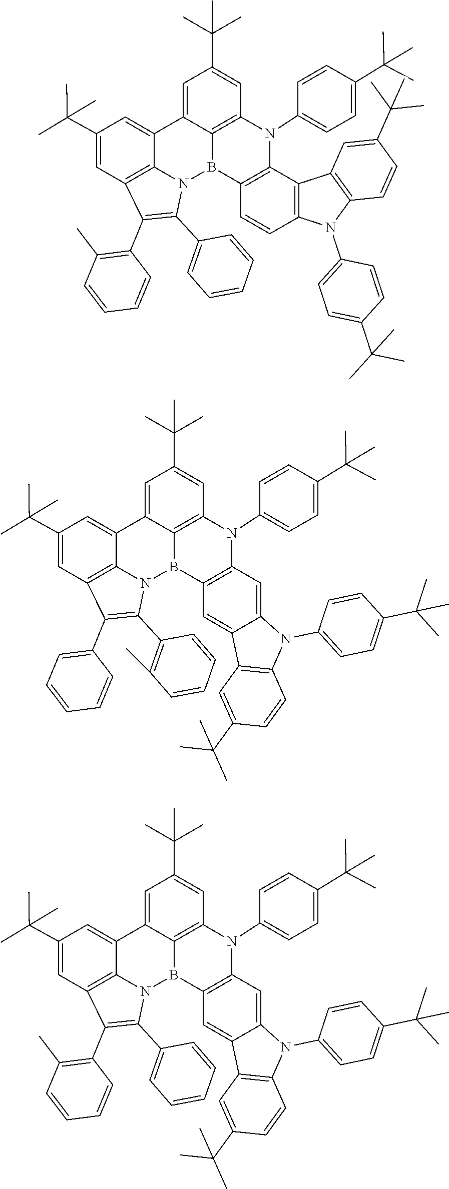

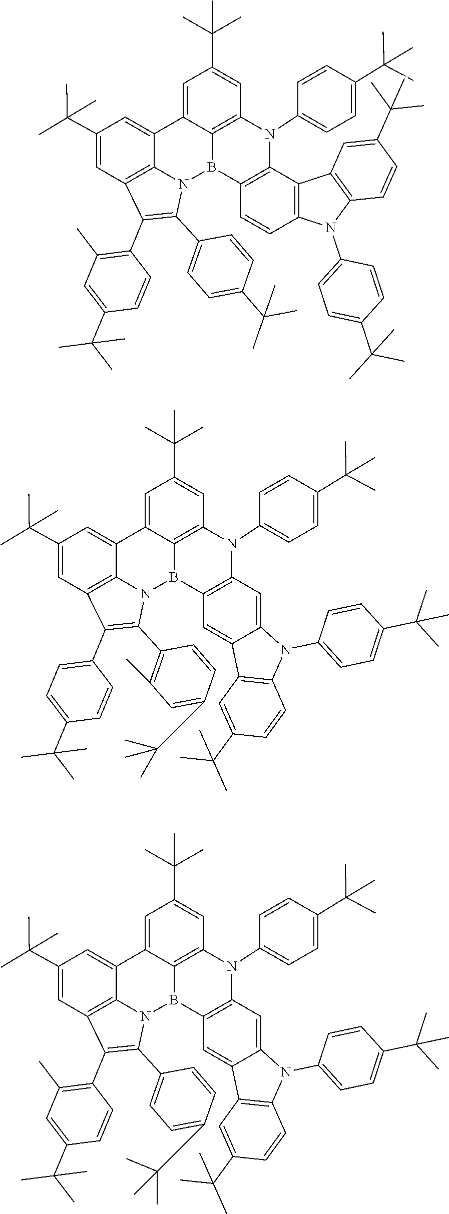

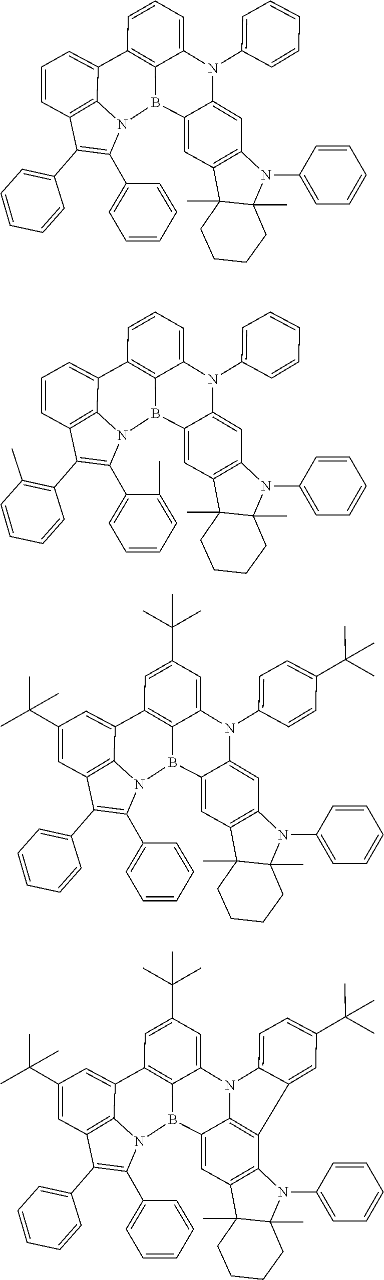

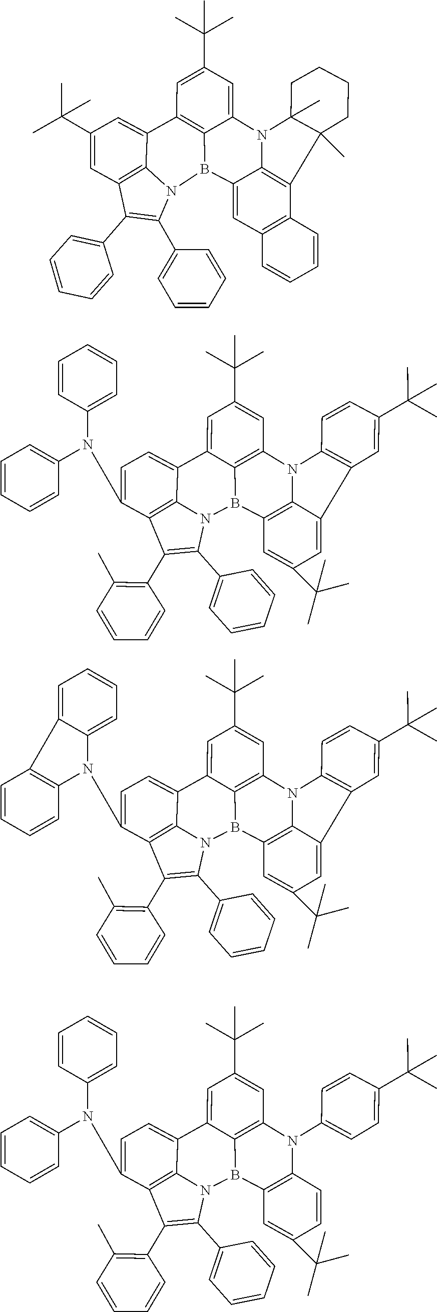

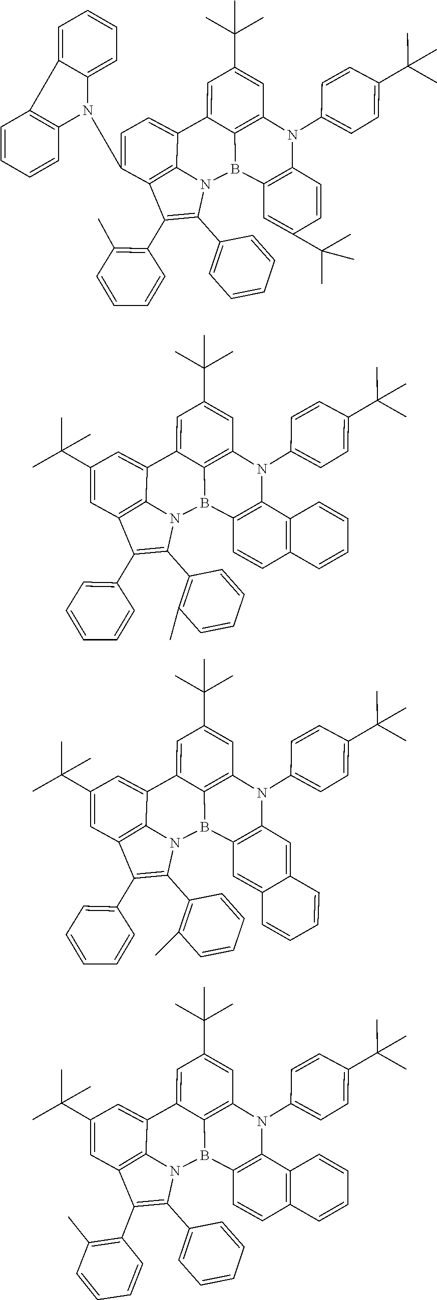

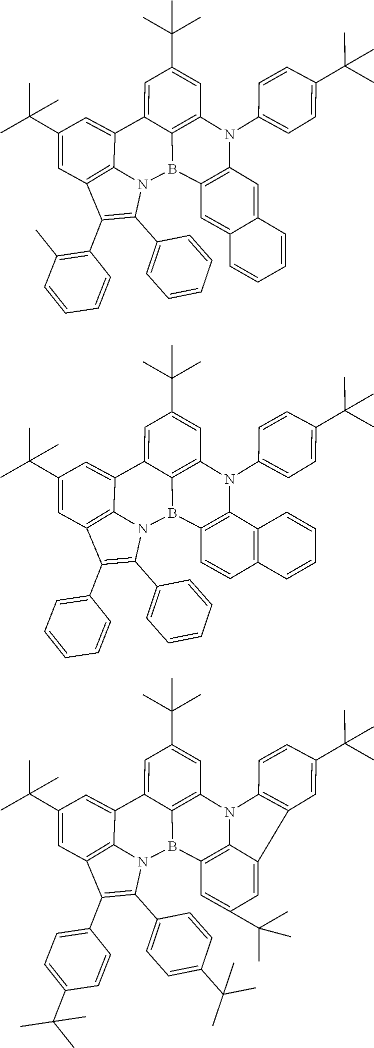

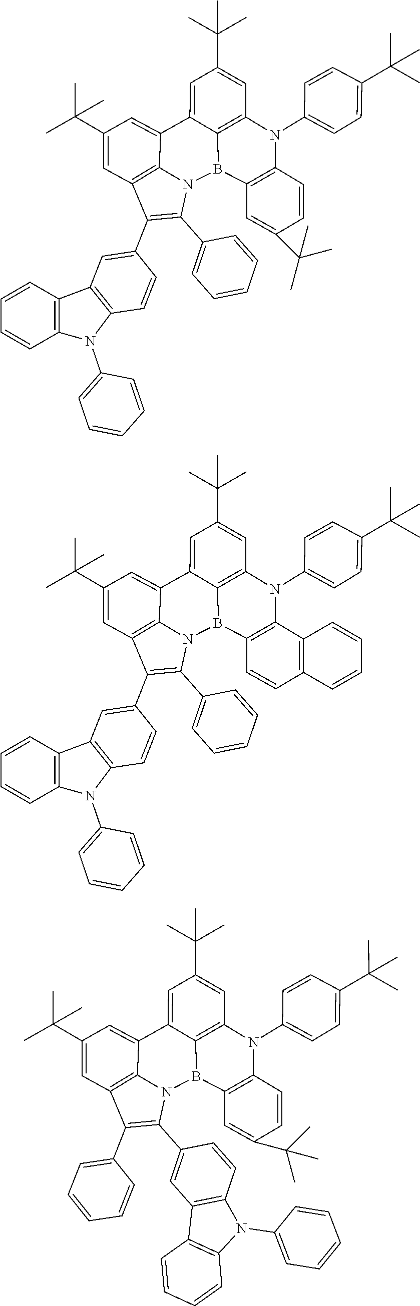

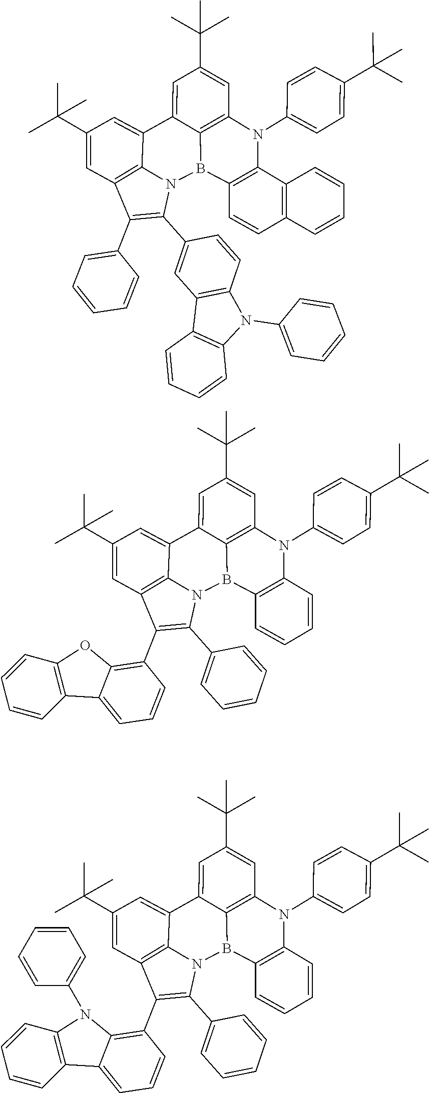

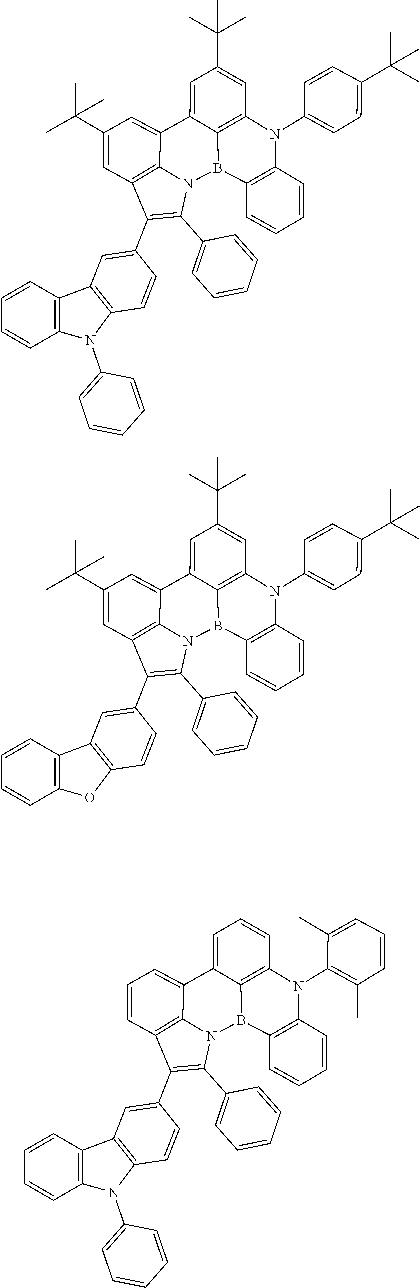 [SMILES: CC(C)(C)c1ccc(N2c3ccccc3B3c4c(cc(C(C)(C)C)cc42)-c2cc(C(C)(C)C)cc4c(-c5ccc6c(c5)c5ccccc5n6-c5ccccc5)c(-c5ccccc5)n3c24)cc1 ; CC(C)(C)c1ccc(N2c3ccccc3B3c4c(cc(C(C)(C)C)cc42)-c2cc(C(C)(C)C)cc4c(-c5ccc6oc7ccccc7c6c5)c(-c5ccccc5)n3c24)cc1 ; Cc1cccc(C)c1N1c2ccccc2B2c3c(cccc31)-c1cccc3c(-c4ccc5c(c4)c4ccccc4n5-c4ccccc4)c(-c4ccccc4)n2c13]

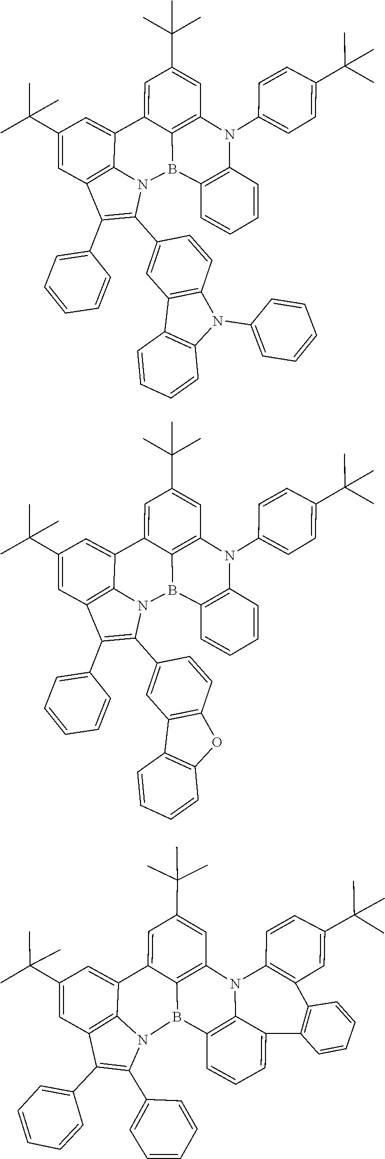

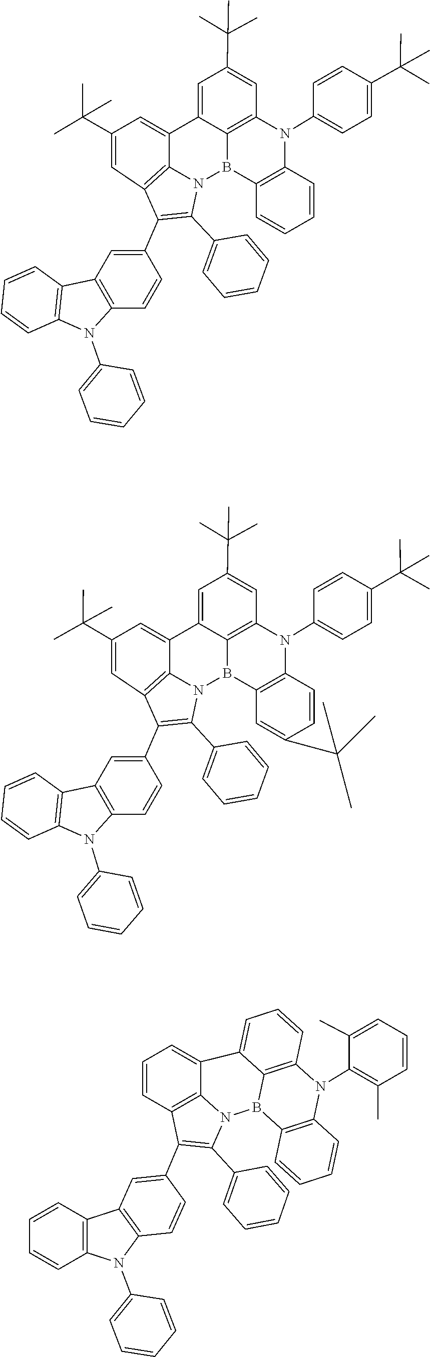 [SMILES: CC(C)(C)c1ccc(N2c3ccccc3B3c4c(cc(C(C)(C)C)cc42)-c2cc(C(C)(C)C)cc4c(-c5ccc6c(c5)c5ccccc5n6-c5ccccc5)c(-c5ccccc5)n3c24)cc1 ; CC(C)(C)c1ccc(N2c3ccc(C(C)(C)C)cc3B3c4c(cc(C(C)(C)C)cc42)-c2cc(C(C)(C)C)cc4c(-c5ccc6c(c5)c5ccccc5n6-c5ccccc5)c(-c5ccccc5)n3c24)cc1 ; Cc1cccc(C)c1N1c2ccccc2B2c3c(cccc31)-c1cccc3c(-c4ccc5c(c4)c4ccccc4n5-c4ccccc4)c(-c4ccccc4)n2c13]

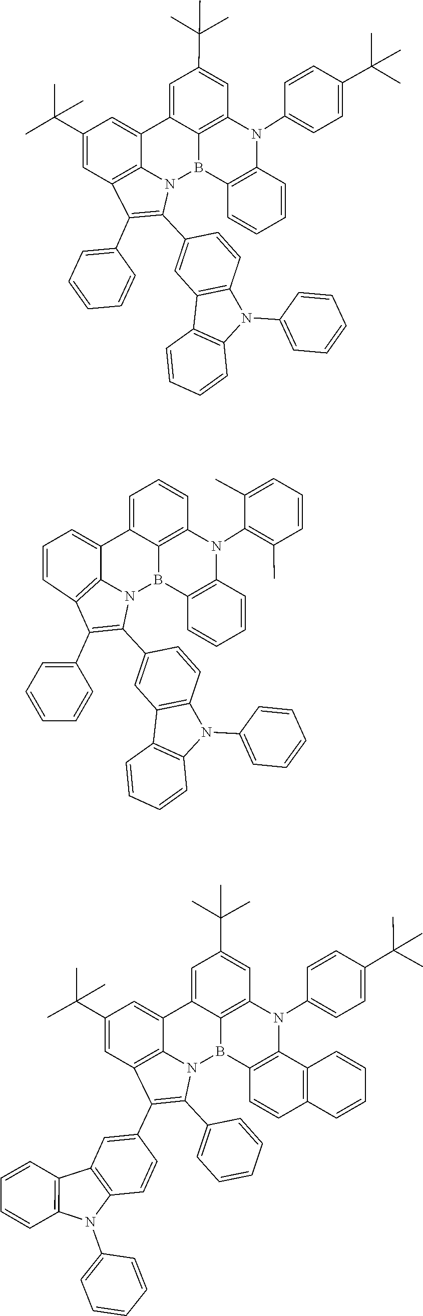 [SMILES: CC(C)(C)c1ccc(N2c3ccccc3B3c4c(cc(C(C)(C)C)cc42)-c2cc(C(C)(C)C)cc4c(-c5ccccc5)c(-c5ccc6c(c5)c5ccccc5n6-c5ccccc5)n3c24)cc1 ; Cc1cccc(C)c1N1c2ccccc2B2c3c(cccc31)-c1cccc3c(-c4ccccc4)c(-c4ccc5c(c4)c4ccccc4n5-c4ccccc4)n2c13 ; CC(C)(C)c1ccc(N2c3cc(C(C)(C)C)cc4c3B(c3ccc5ccccc5c32)n2c(-c3ccccc3)c(-c3ccc5c(c3)c3ccccc3n5-c3ccccc3)c3cc(C(C)(C)C)cc-4c32)cc1]

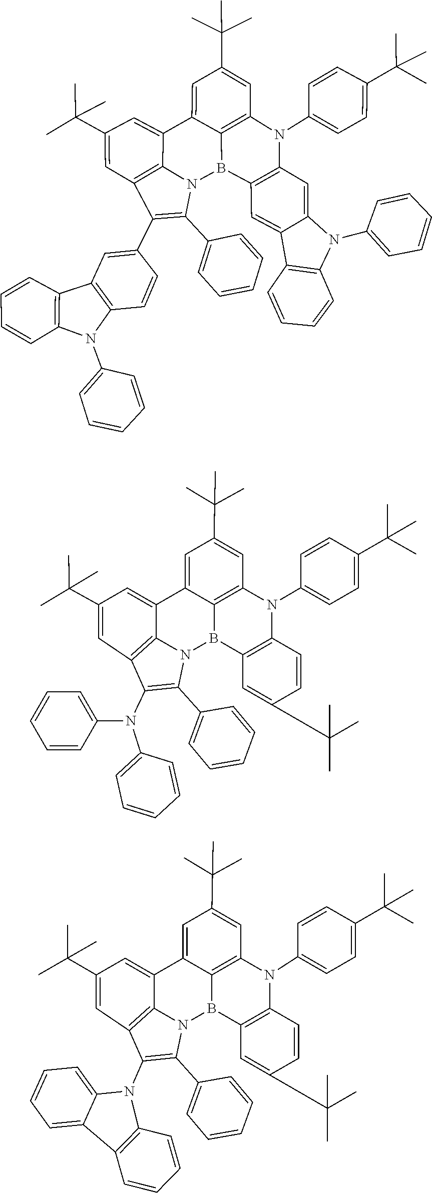 [SMILES: CC(C)(C)c1ccc(N2c3cc4c(cc3B3c5c(cc(C(C)(C)C)cc52)-c2cc(C(C)(C)C)cc5c(-c6ccc7c(c6)c6ccccc6n7-c6ccccc6)c(-c6ccccc6)n3c25)c2ccccc2n4-c2ccccc2)cc1 ; CC(C)(C)Cc1ccc2c(c1)B1c3c(cc(C(C)(C)C)cc3N2c2ccc(C(C)(C)C)cc2)-c2cc(C(C)(C)C)cc3c(N(c4ccccc4)c4ccccc4)c(-c4ccccc4)n1c23 ; CC(C)(C)Cc1ccc2c(c1)B1c3c(cc(C(C)(C)C)cc3N2c2ccc(C(C)(C)C)cc2)-c2cc(C(C)(C)C)cc3c(-n4c5ccccc5c5ccccc54)c(-c4ccccc4)n1c23]

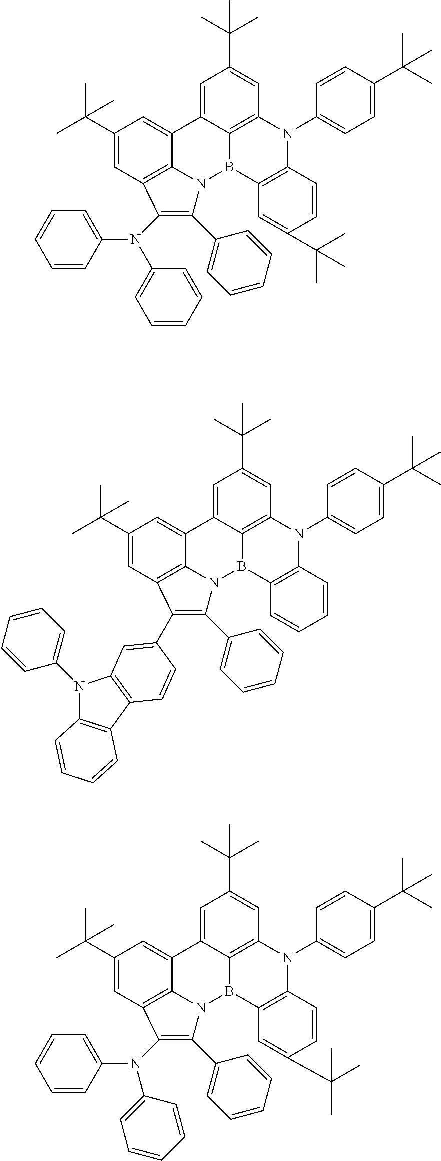 [SMILES: CC(C)(C)c1ccc(N2c3ccc(C(C)(C)C)cc3B3c4c(cc(C(C)(C)C)cc42)-c2cc(C(C)(C)C)cc4c(N(c5ccccc5)c5ccccc5)c(-c5ccccc5)n3c24)cc1 ; CC(C)(C)c1ccc(N2c3ccccc3B3c4c(cc(C(C)(C)C)cc42)-c2cc(C(C)(C)C)cc4c(-c5ccc6c7ccccc7n(-c7ccccc7)c6c5)c(-c5ccccc5)n3c24)cc1 ; CC(C)(C)c1ccc(N2c3ccc(C(C)(C)C)cc3B3c4c(cc(C(C)(C)C)cc42)-c2cc(C(C)(C)C)cc4c(N(c5ccccc5)c5ccccc5)c(-c5ccccc5)n3c24)cc1]

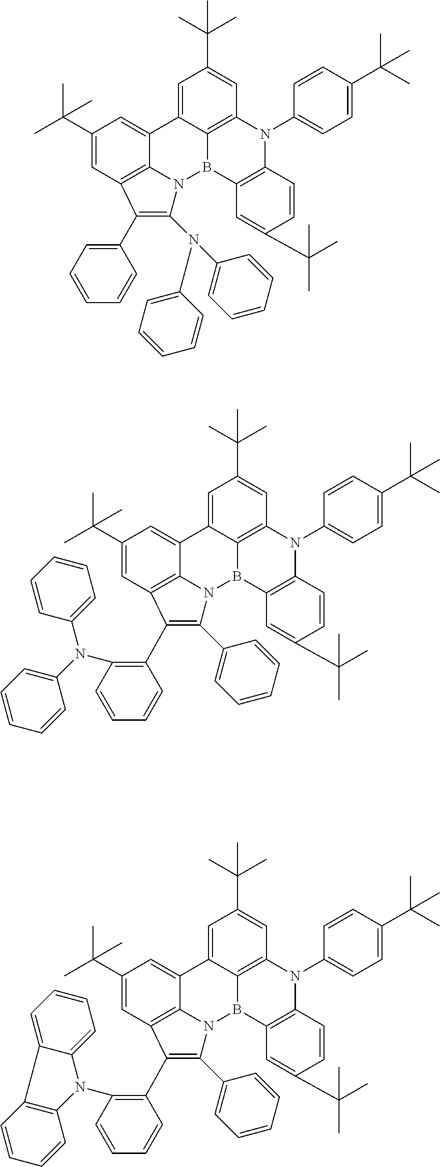 [SMILES: CC(C)(C)c1ccc(N2c3ccc(C(C)(C)C)cc3B3c4c(cc(C(C)(C)C)cc42)-c2cc(C(C)(C)C)cc4c(-c5ccccc5)c(N(c5ccccc5)c5ccccc5)n3c24)cc1 ; CC(C)(C)c1ccc(N2c3ccc(C(C)(C)C)cc3B3c4c(cc(C(C)(C)C)cc42)-c2cc(C(C)(C)C)cc4c(-c5ccccc5N(c5ccccc5)c5ccccc5)c(-c5ccccc5)n3c24)cc1 ; CC(C)(C)c1ccc(N2c3ccc(C(C)(C)C)cc3B3c4c(cc(C(C)(C)C)cc42)-c2cc(C(C)(C)C)cc4c(-c5ccccc5-n5c6ccccc6c6ccccc65)c(-c5ccccc5)n3c24)cc1]

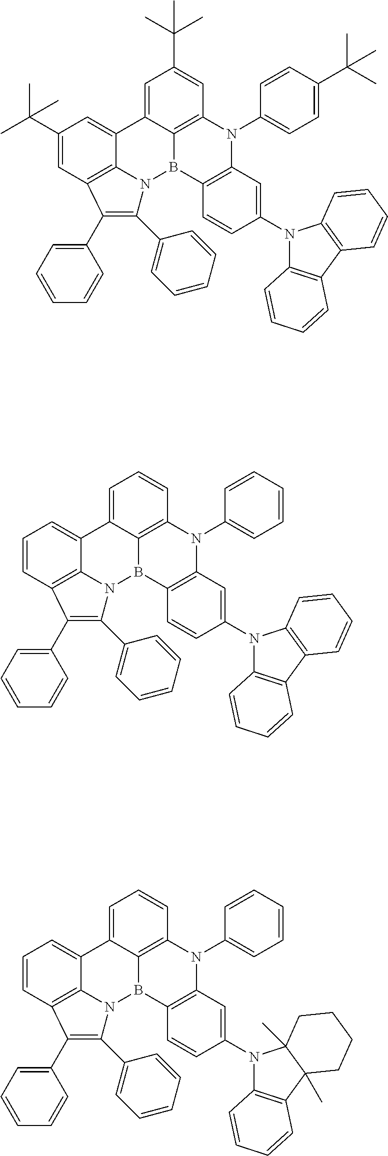 [SMILES: CC(C)(C)c1ccc(N2c3cc(-n4c5ccccc5c5ccccc54)ccc3B3c4c(cc(C(C)(C)C)cc42)-c2cc(C(C)(C)C)cc4c(-c5ccccc5)c(-c5ccccc5)n3c24)cc1 ; c1ccc(-c2c(-c3ccccc3)n3c4c(cccc24)-c2cccc4c2B3c2ccc(-n3c5ccccc5c5ccccc53)cc2N4c2ccccc2)cc1 ; CC12CCCCC1(C)N(c1ccc3c(c1)N(c1ccccc1)c1cccc4c1B3n1c(-c3ccccc3)c(-c3ccccc3)c3cccc-4c31)c1ccccc12]

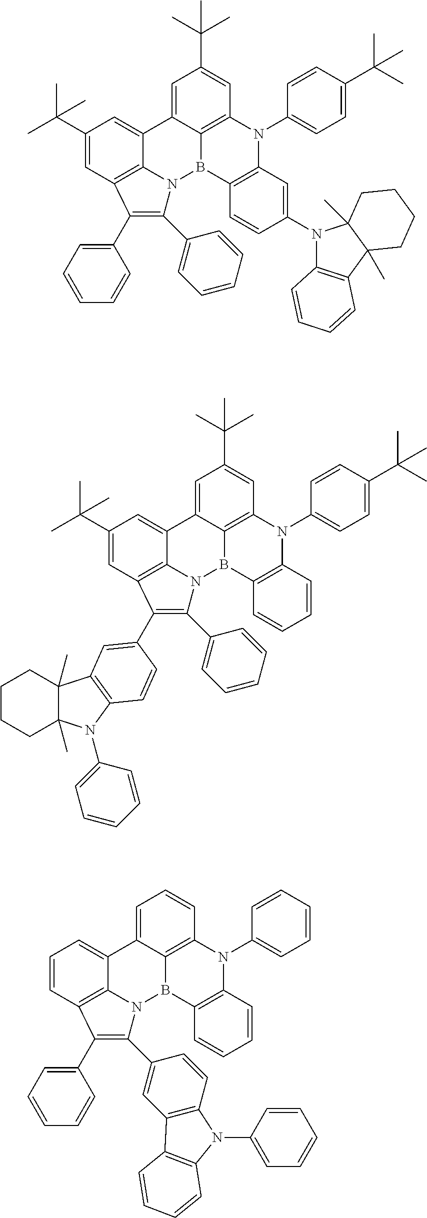 [SMILES: CC(C)(C)c1ccc(N2c3cc(N4c5ccccc5C5(C)CCCCC45C)ccc3B3c4c(cc(C(C)(C)C)cc42)-c2cc(C(C)(C)C)cc4c(-c5ccccc5)c(-c5ccccc5)n3c24)cc1 ; CC(C)(C)c1ccc(N2c3ccccc3B3c4c(cc(C(C)(C)C)cc42)-c2cc(C(C)(C)C)cc4c(-c5ccc6c(c5)C5(C)CCCCC5(C)N6c5ccccc5)c(-c5ccccc5)n3c24)cc1 ; c1ccc(-c2c(-c3ccc4c(c3)c3ccccc3n4-c3ccccc3)n3c4c(cccc24)-c2cccc4c2B3c2ccccc2N4c2ccccc2)cc1]

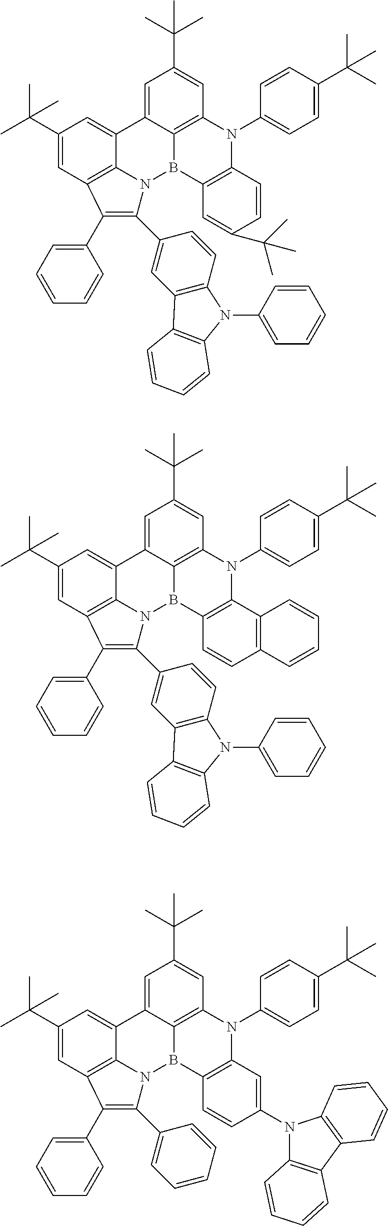

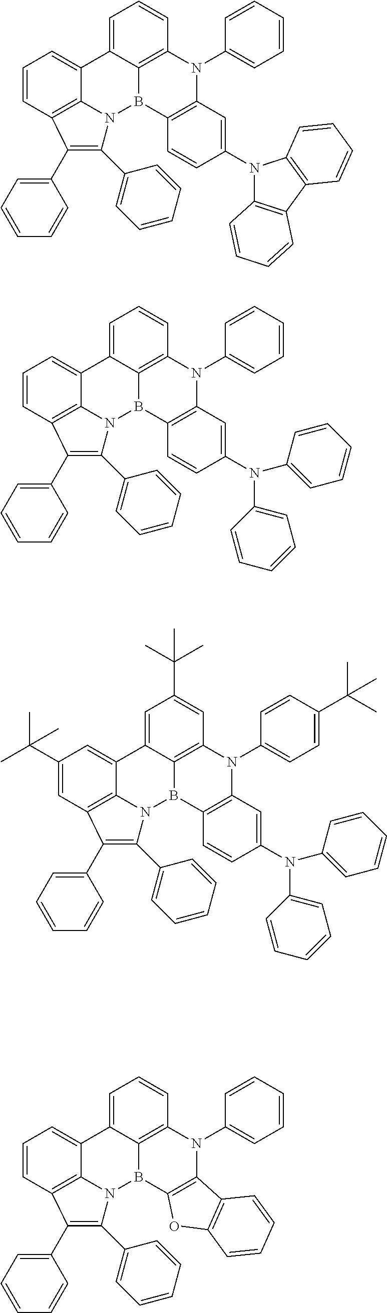

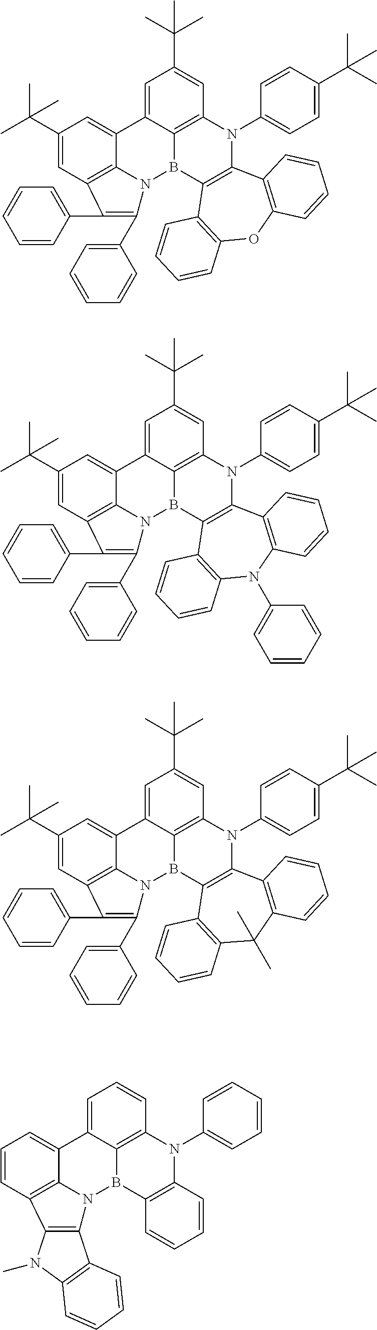

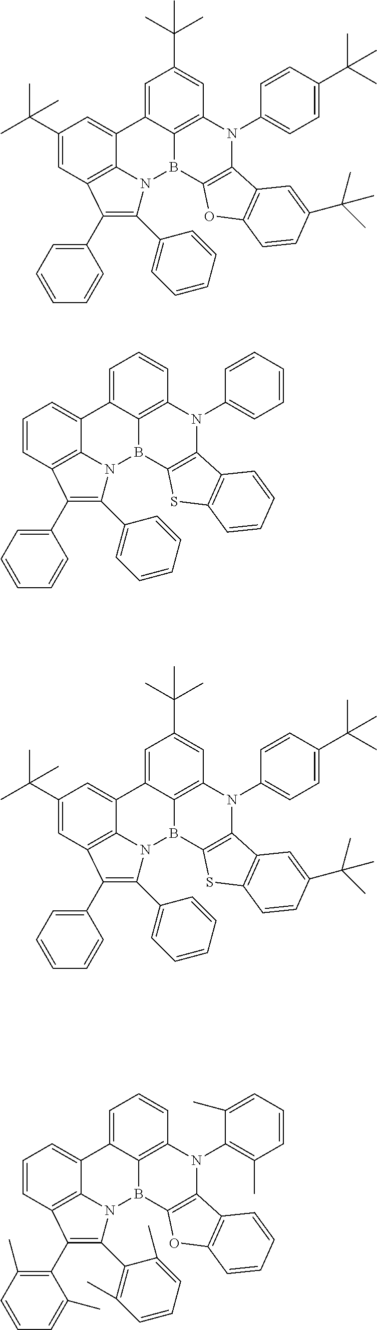

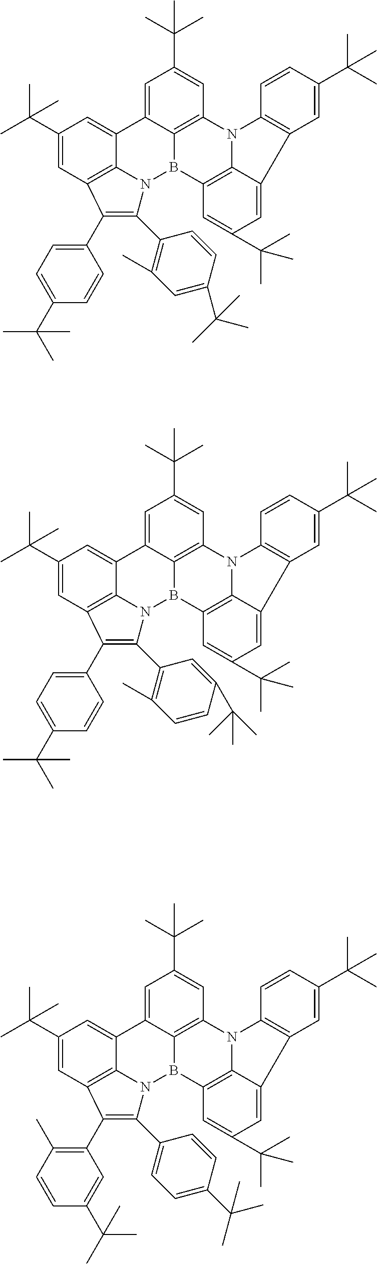

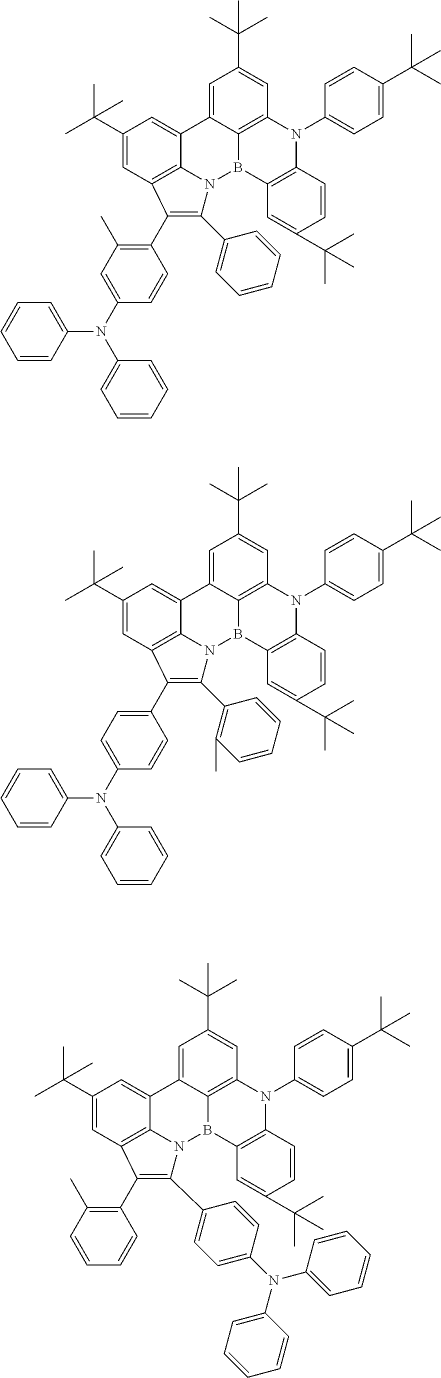

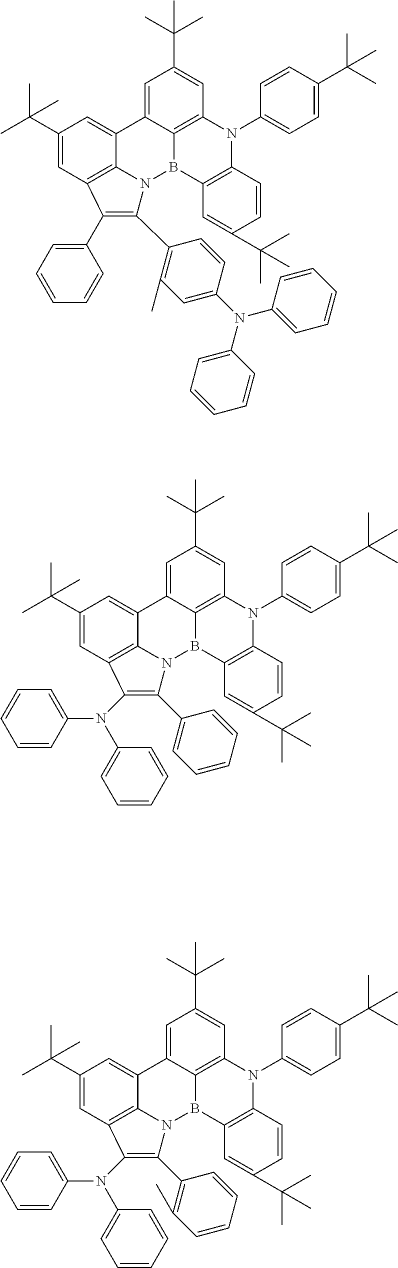 [SMILES: Cc1cc(N(c2ccccc2)c2ccccc2)ccc1-c1c(-c2ccccc2)c2cc(C(C)(C)C)cc3c2n1B1c2cc(C(C)(C)C)ccc2N(c2ccc(C(C)(C)C)cc2)c2cc(C(C)(C)C)cc-3c21 ; CC(C)(C)c1ccc(N2c3ccc(C(C)(C)C)cc3B3c4c(cc(C(C)(C)C)cc42)-c2cc(C(C)(C)C)cc4c(N(c5ccccc5)c5ccccc5)c(-c5ccccc5)n3c24)cc1 ; Cc1ccccc1-c1c(N(c2ccccc2)c2ccccc2)c2cc(C(C)(C)C)cc3c2n1B1c2cc(C(C)(C)C)ccc2N(c2ccc(C(C)(C)C)cc2)c2cc(C(C)(C)C)cc-3c21]

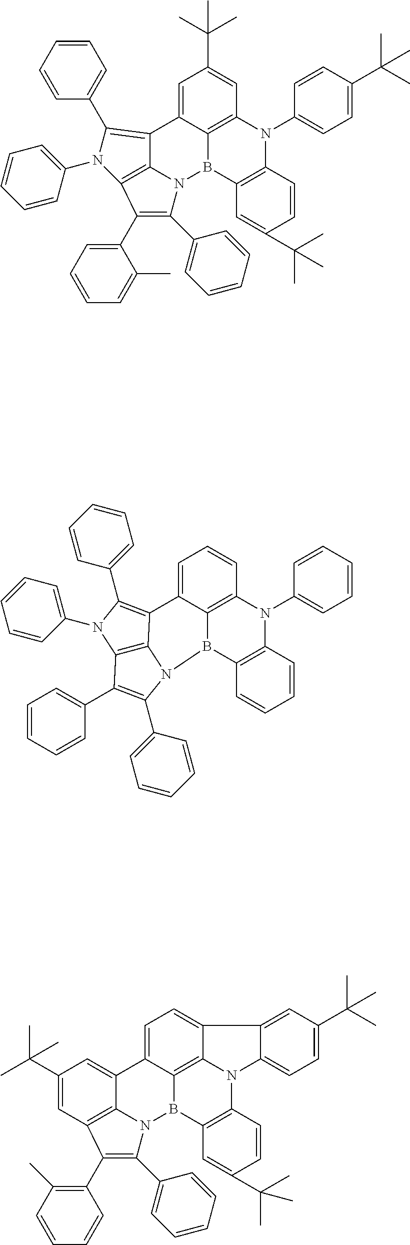

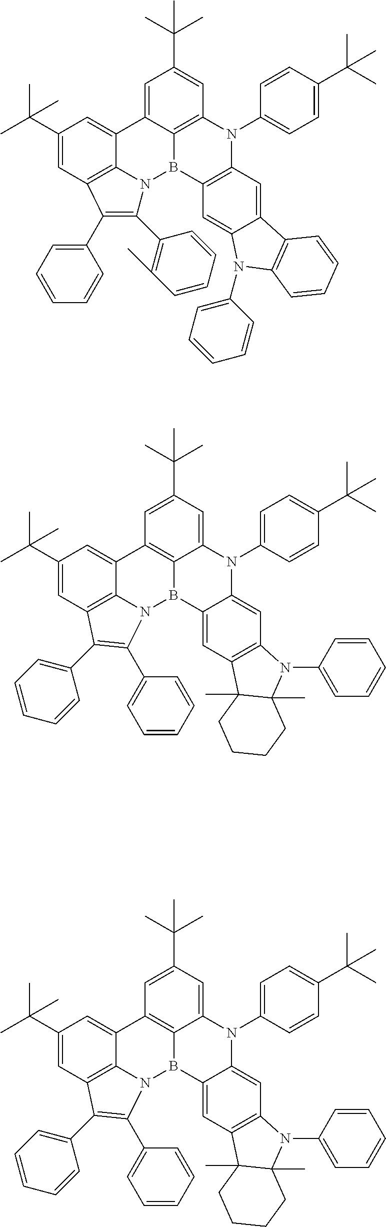

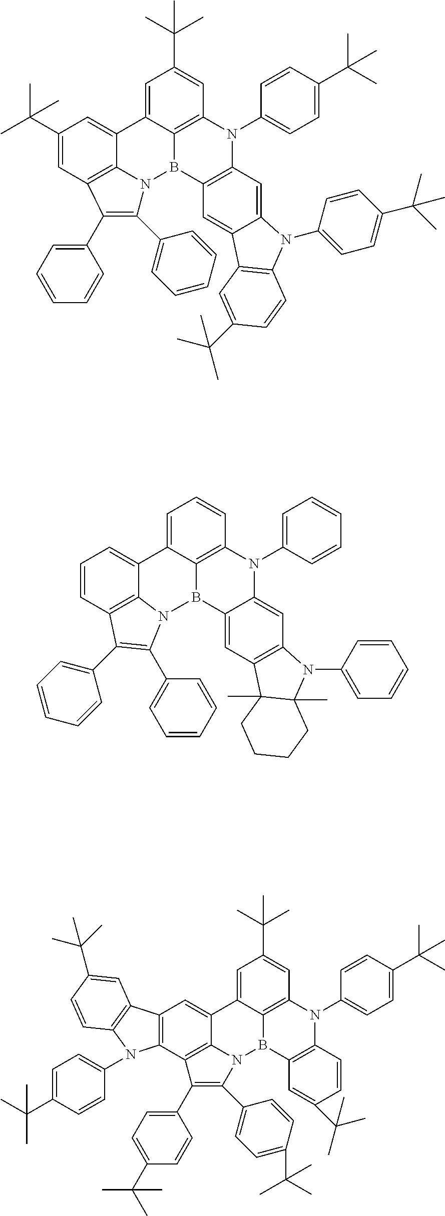

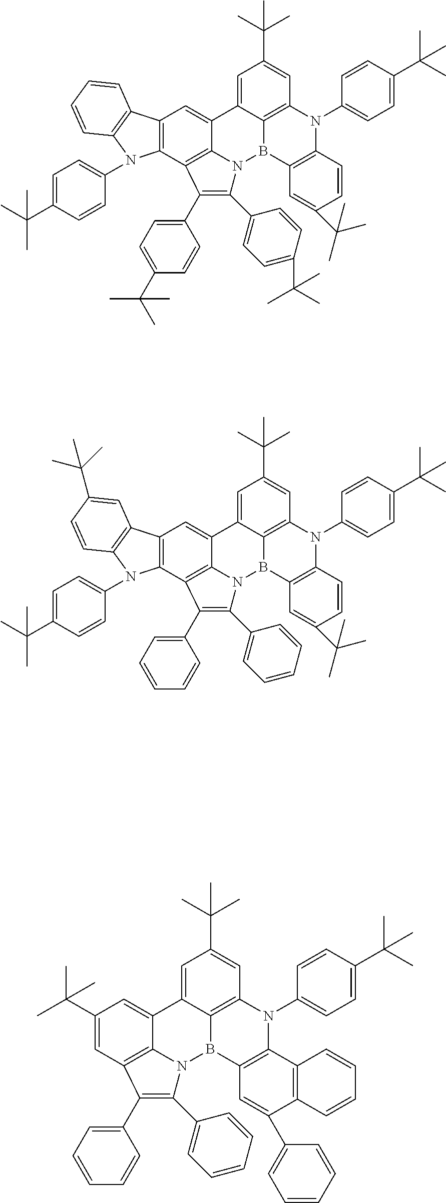

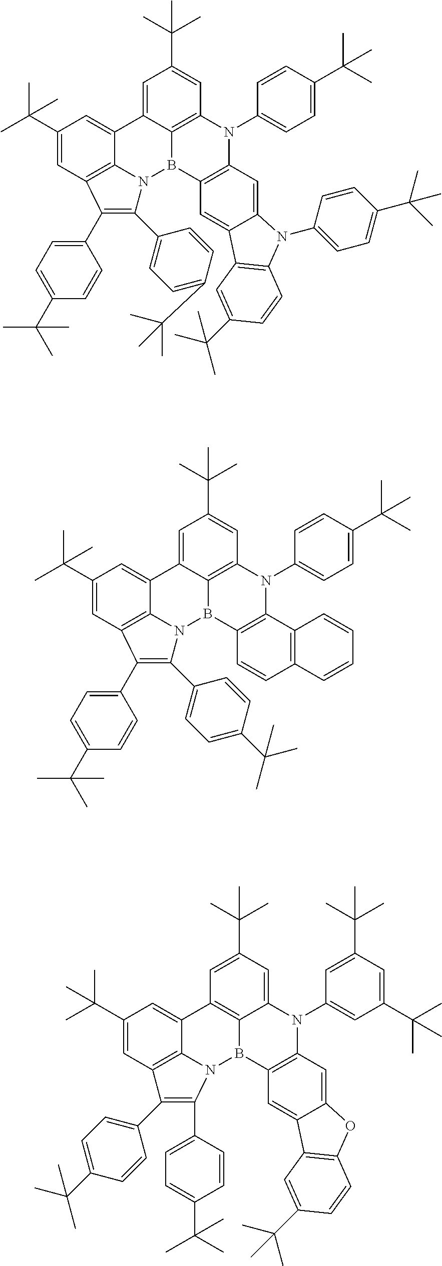

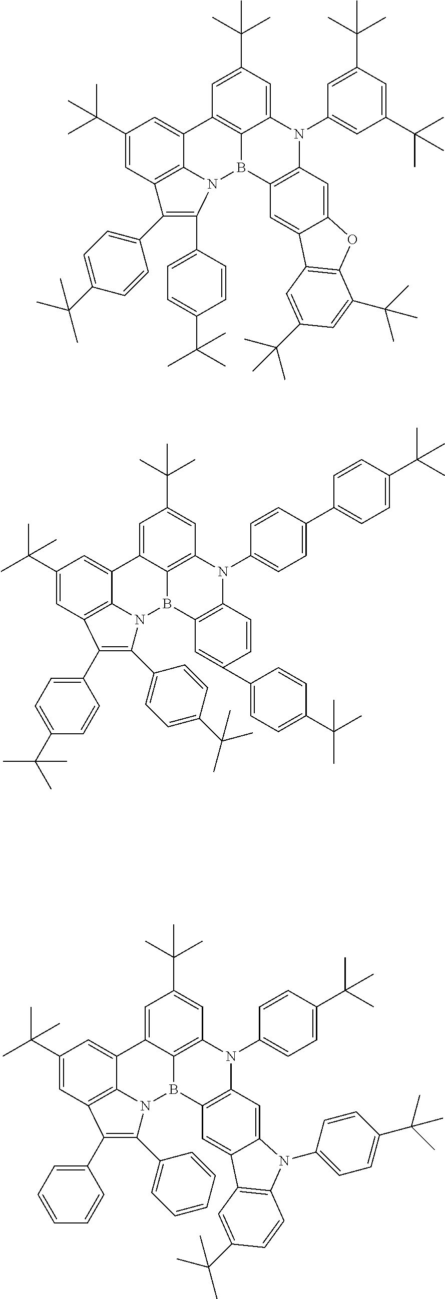

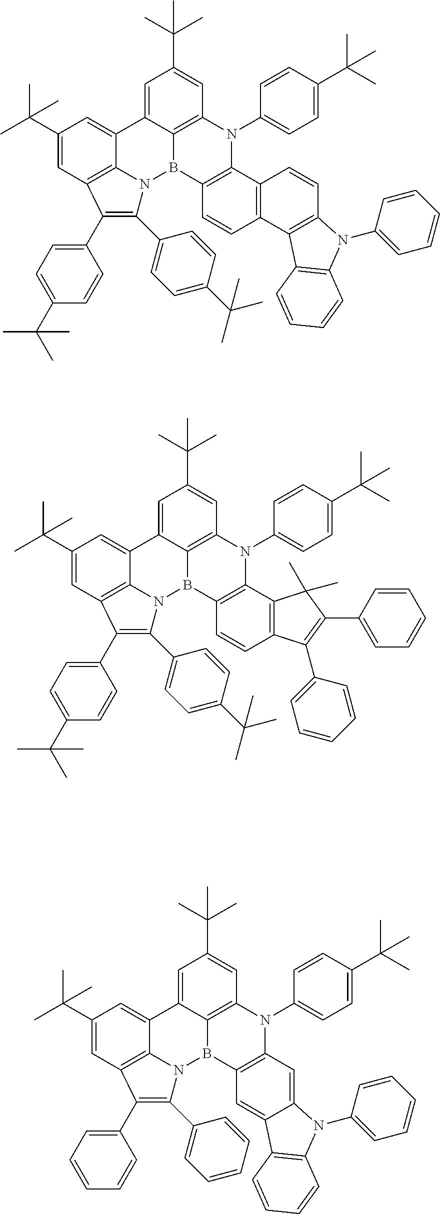 [SMILES: CC(C)(C)c1ccc(-c2c(-c3ccc(C(C)(C)C)cc3)n3c4c(cc(C(C)(C)C)cc24)-c2cc(C(C)(C)C)cc4c2B3c2ccc3c(ccc5c3c3ccccc3n5-c3ccccc3)c2N4c2ccc(C(C)(C)C)cc2)cc1 ; CC(C)(C)c1ccc(-c2c(-c3ccc(C(C)(C)C)cc3)n3c4c(cc(C(C)(C)C)cc24)-c2cc(C(C)(C)C)cc4c2B3c2ccc3c(c2N4c2ccc(C(C)(C)C)cc2)C(C)(C)C(c2ccccc2)=C3c2ccccc2)cc1 ; CC(C)(C)c1ccc(N2c3cc4c(cc3B3c5c(cc(C(C)(C)C)cc52)-c2cc(C(C)(C)C)cc5c(-c6ccccc6)c(-c6ccccc6)n3c25)c2ccccc2n4-c2ccccc2)cc1]

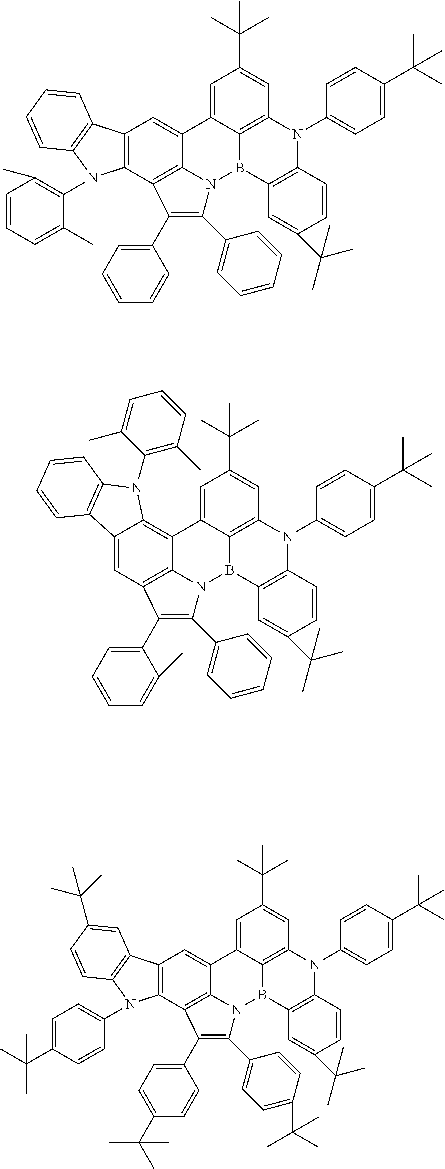

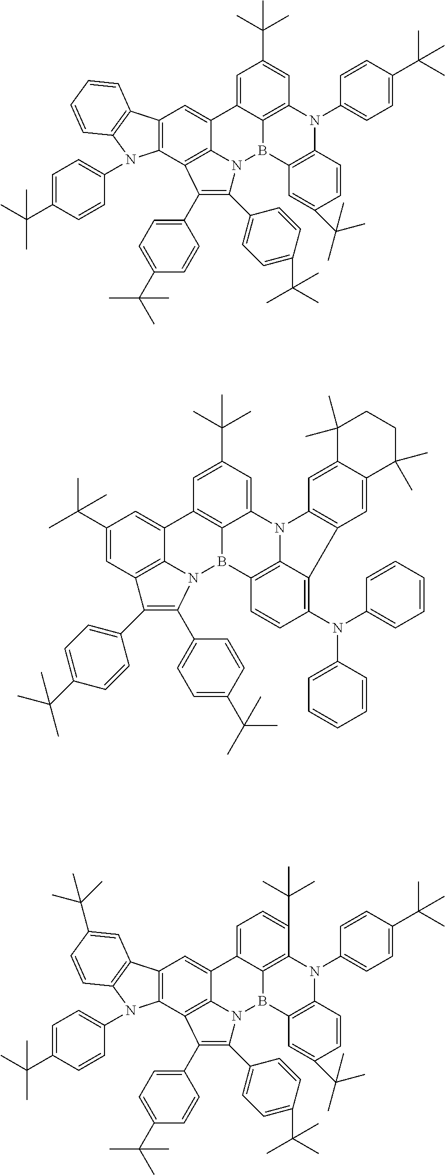

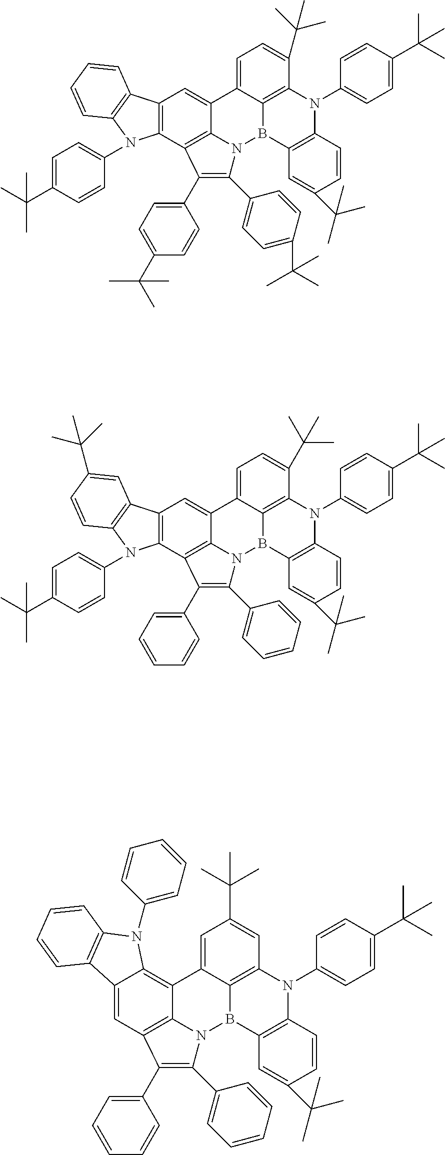

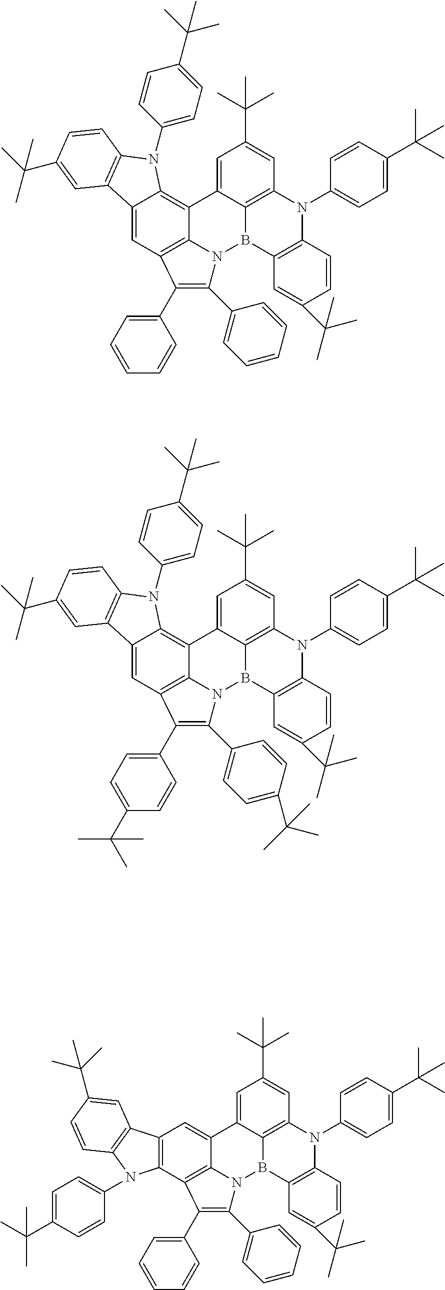

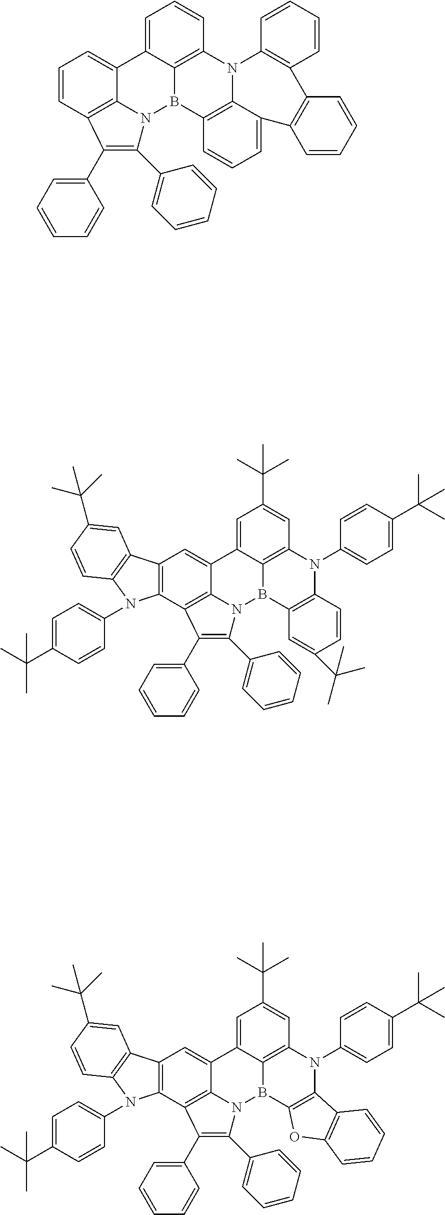

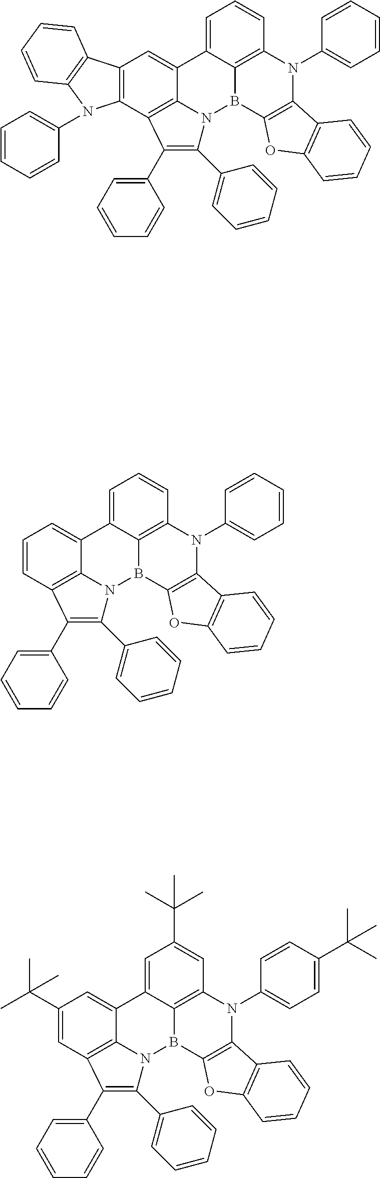 [SMILES: c1ccc(-c2c(-c3ccccc3)n3c4c(cc5c6ccccc6n(-c6ccccc6)c5c24)-c2cccc4c2B3c2oc3ccccc3c2N4c2ccccc2)cc1 ; c1ccc(-c2c(-c3ccccc3)n3c4c(cccc24)-c2cccc4c2B3c2oc3ccccc3c2N4c2ccccc2)cc1 ; CC(C)(C)c1ccc(N2c3cc(C(C)(C)C)cc4c3B(c3oc5ccccc5c32)n2c(-c3ccccc3)c(-c3ccccc3)c3cc(C(C)(C)C)cc-4c32)cc1]

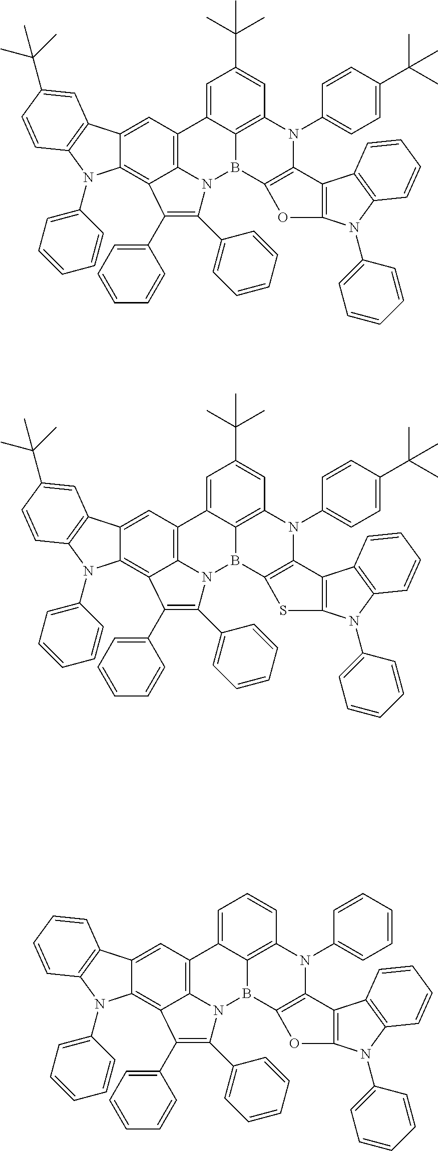

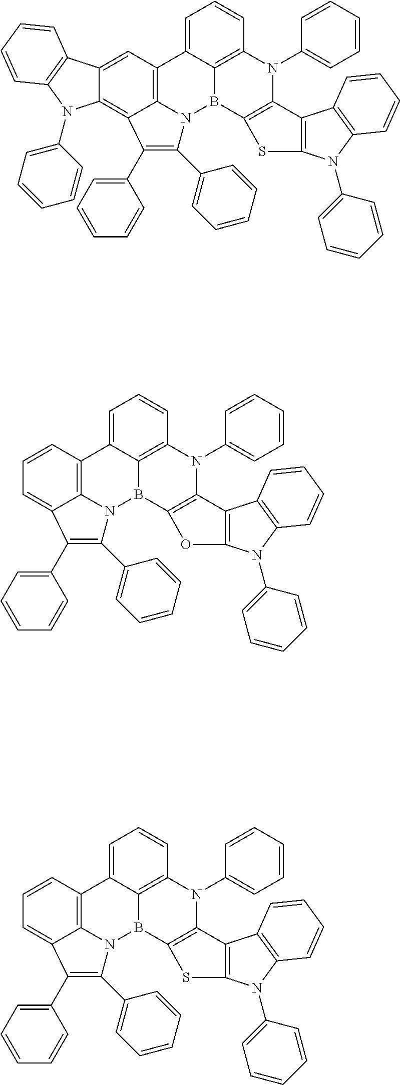 [SMILES: c1ccc(-c2c(-c3ccccc3)n3c4c(cc5c6ccccc6n(-c6ccccc6)c5c24)-c2cccc4c2B3c2sc3c(c2N4c2ccccc2)c2ccccc2n3-c2ccccc2)cc1 ; c1ccc(-c2c(-c3ccccc3)n3c4c(cccc24)-c2cccc4c2B3c2oc3c(c2N4c2ccccc2)c2ccccc2n3-c2ccccc2)cc1 ; c1ccc(-c2c(-c3ccccc3)n3c4c(cccc24)-c2cccc4c2B3c2sc3c(c2N4c2ccccc2)c2ccccc2n3-c2ccccc2)cc1]

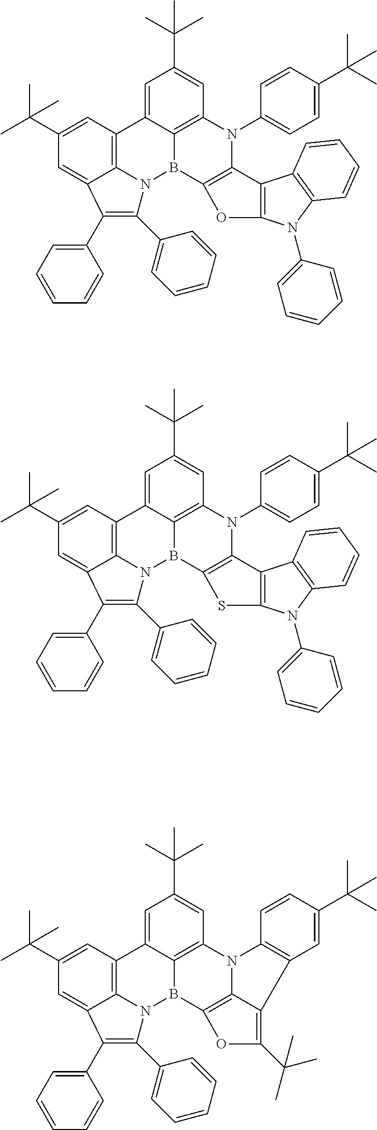

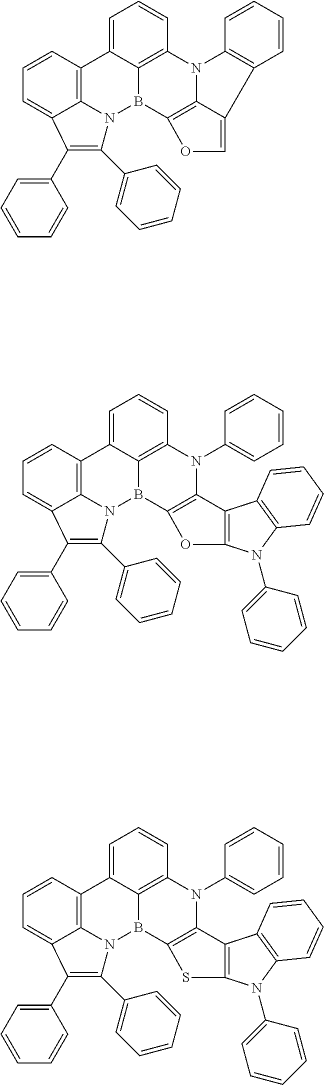 [SMILES: c1ccc(-c2c(-c3ccccc3)n3c4c(cccc24)-c2cccc4c2B3c2occ3c5ccccc5n-4c23)cc1 ; c1ccc(-c2c(-c3ccccc3)n3c4c(cccc24)-c2cccc4c2B3c2oc3c(c2N4c2ccccc2)c2ccccc2n3-c2ccccc2)cc1 ; c1ccc(-c2c(-c3ccccc3)n3c4c(cccc24)-c2cccc4c2B3c2sc3c(c2N4c2ccccc2)c2ccccc2n3-c2ccccc2)cc1]

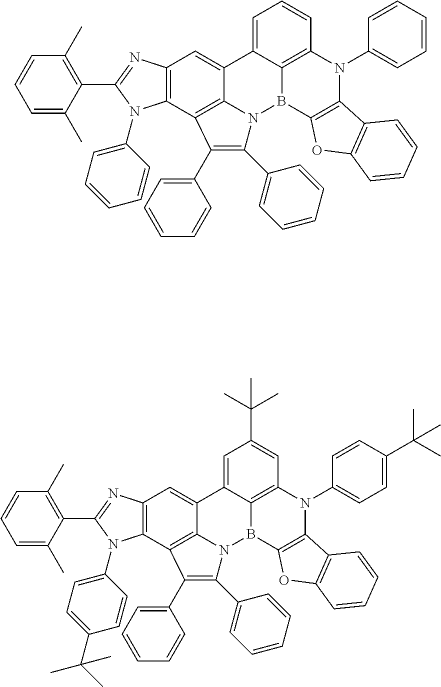 [SMILES: Cc1cccc(C)c1-c1nc2cc3c4c(c(-c5ccccc5)c(-c5ccccc5)n4B4c5oc6ccccc6c5N(c5ccccc5)c5cccc-3c54)c2n1-c1ccccc1 ; Cc1cccc(C)c1-c1nc2cc3c4c(c(-c5ccccc5)c(-c5ccccc5)n4B4c5oc6ccccc6c5N(c5ccc(C(C)(C)C)cc5)c5cc(C(C)(C)C)cc-3c54)c2n1-c1ccc(C(C)(C)C)cc1]

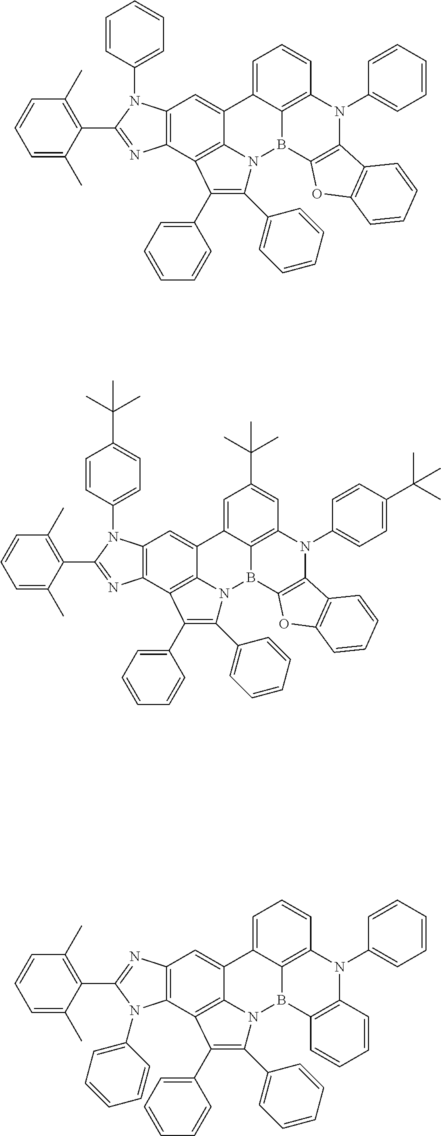 [SMILES: Cc1cccc(C)c1-c1nc2c3c(-c4ccccc4)c(-c4ccccc4)n4c3c(cc2n1-c1ccccc1)-c1cccc2c1B4c1oc3ccccc3c1N2c1ccccc1 ; Cc1cccc(C)c1-c1nc2c3c(-c4ccccc4)c(-c4ccccc4)n4c3c(cc2n1-c1ccc(C(C)(C)C)cc1)-c1cc(C(C)(C)C)cc2c1B4c1oc3ccccc3c1N2c1ccc(C(C)(C)C)cc1 ; Cc1cccc(C)c1-c1nc2cc3c4c(c(-c5ccccc5)c(-c5ccccc5)n4B4c5ccccc5N(c5ccccc5)c5cccc-3c54)c2n1-c1ccccc1]

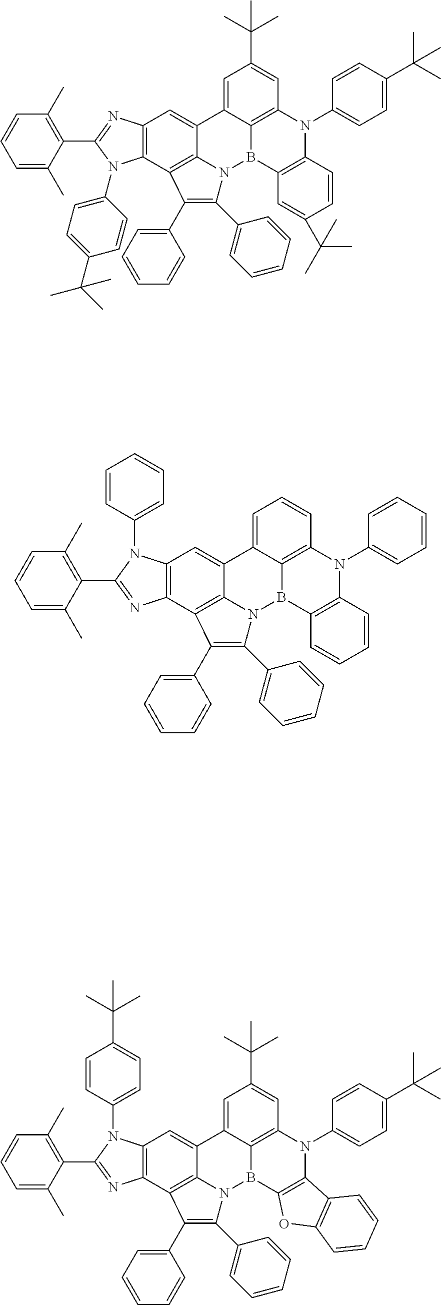 [SMILES: Cc1cccc(C)c1-c1nc2cc3c4c(c(-c5ccccc5)c(-c5ccccc5)n4B4c5cc(C(C)(C)C)ccc5N(c5ccc(C(C)(C)C)cc5)c5cc(C(C)(C)C)cc-3c54)c2n1-c1ccc(C(C)(C)C)cc1 ; Cc1cccc(C)c1-c1nc2c3c(-c4ccccc4)c(-c4ccccc4)n4c3c(cc2n1-c1ccccc1)-c1cccc2c1B4c1ccccc1N2c1ccccc1 ; Cc1cccc(C)c1-c1nc2c3c(-c4ccccc4)c(-c4ccccc4)n4c3c(cc2n1-c1ccc(C(C)(C)C)cc1)-c1cc(C(C)(C)C)cc2c1B4c1oc3ccccc3c1N2c1ccc(C(C)(C)C)cc1]

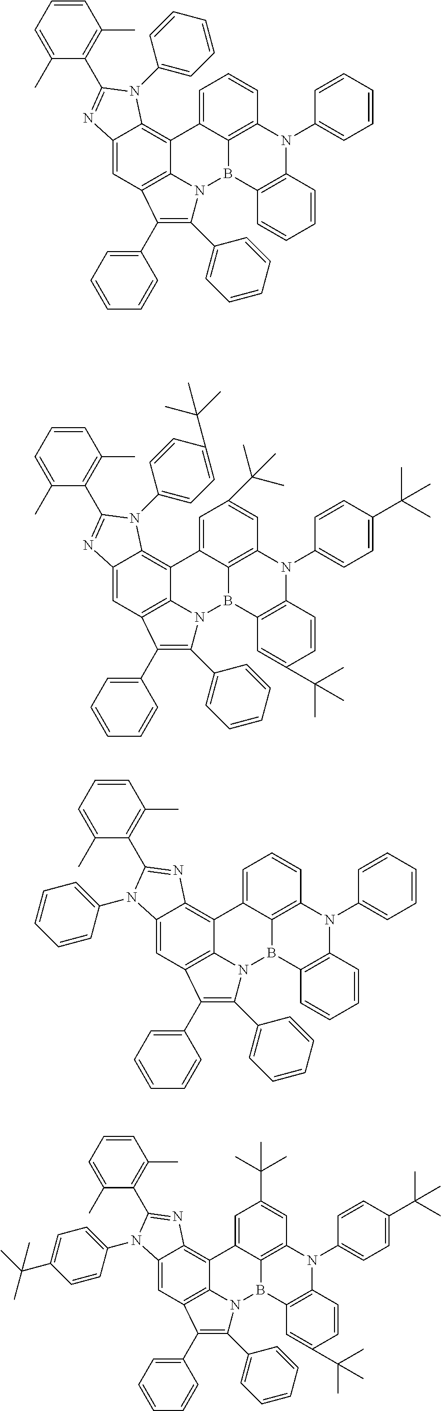

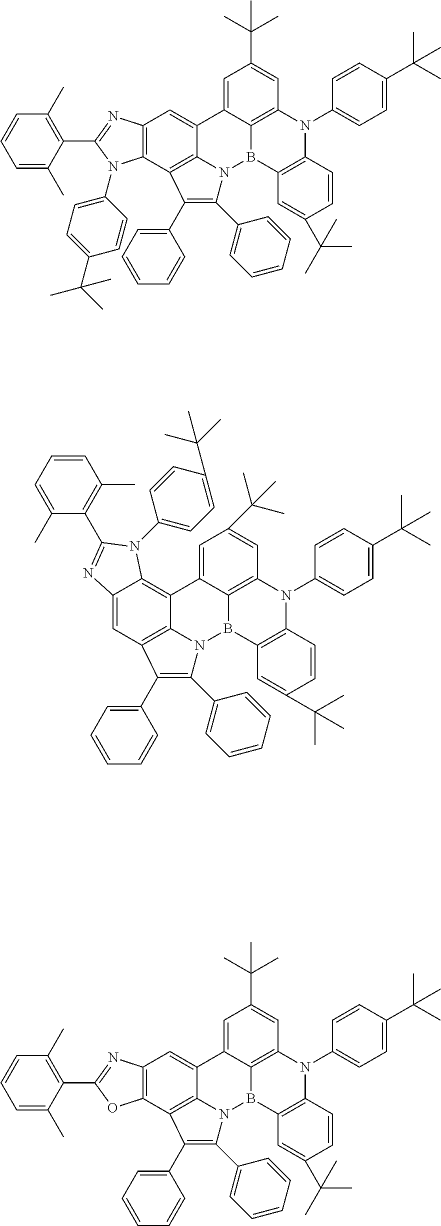 [SMILES: Cc1cccc(C)c1-c1nc2cc3c4c(c(-c5ccccc5)c(-c5ccccc5)n4B4c5cc(C(C)(C)C)ccc5N(c5ccc(C(C)(C)C)cc5)c5cc(C(C)(C)C)cc-3c54)c2n1-c1ccc(C(C)(C)C)cc1 ; Cc1cccc(C)c1-c1nc2cc3c(-c4ccccc4)c(-c4ccccc4)n4c3c(c2n1-c1ccc(C(C)(C)C)cc1)-c1cc(C(C)(C)C)cc2c1B4c1cc(C(C)(C)C)ccc1N2c1ccc(C(C)(C)C)cc1 ; Cc1cccc(C)c1-c1nc2cc3c4c(c(-c5ccccc5)c(-c5ccccc5)n4B4c5cc(C(C)(C)C)ccc5N(c5ccc(C(C)(C)C)cc5)c5cc(C(C)(C)C)cc-3c54)c2o1]

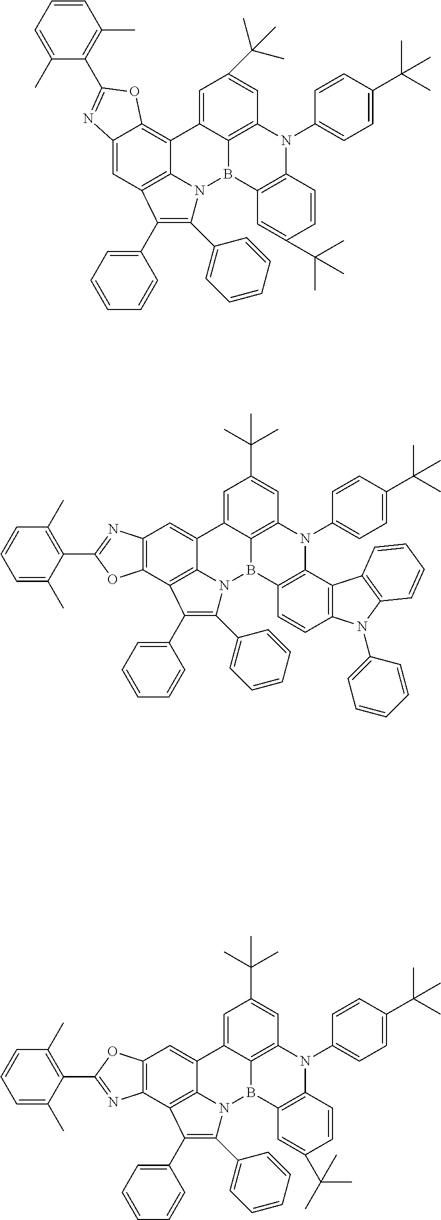 [SMILES: Cc1cccc(C)c1-c1nc2cc3c(-c4ccccc4)c(-c4ccccc4)n4c3c(c2o1)-c1cc(C(C)(C)C)cc2c1B4c1cc(C(C)(C)C)ccc1N2c1ccc(C(C)(C)C)cc1 ; Cc1cccc(C)c1-c1nc2cc3c4c(c(-c5ccccc5)c(-c5ccccc5)n4B4c5ccc6c(c5N(c5ccc(C(C)(C)C)cc5)c5cc(C(C)(C)C)cc-3c54)c3ccccc3n6-c3ccccc3)c2o1 ; Cc1cccc(C)c1-c1nc2c(cc3c4c2c(-c2ccccc2)c(-c2ccccc2)n4B2c4cc(C(C)(C)C)ccc4N(c4ccc(C(C)(C)C)cc4)c4cc(C(C)(C)C)cc-3c42)o1]

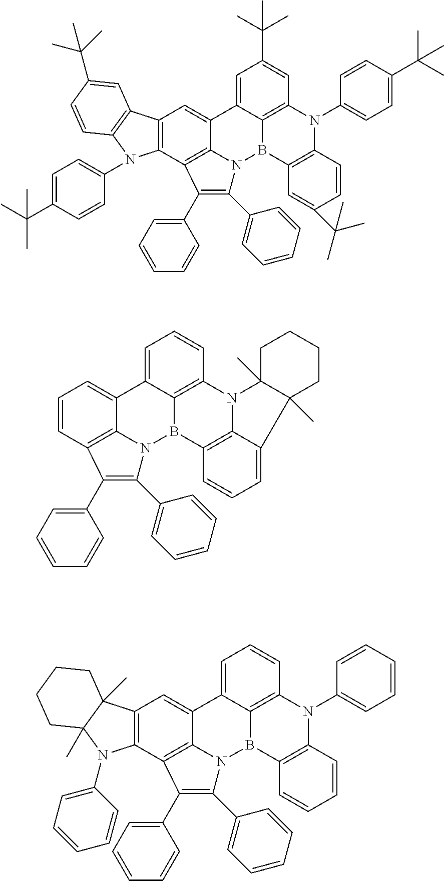 [SMILES: CC(C)(C)c1ccc(N2c3ccc(C(C)(C)C)cc3B3c4c(cc(C(C)(C)C)cc42)-c2cc4c5cc(C(C)(C)C)ccc5n(-c5ccc(C(C)(C)C)cc5)c4c4c(-c5ccccc5)c(-c5ccccc5)n3c24)cc1 ; CC12CCCCC1(C)N1c3cccc4c3B(c3cccc2c31)n1c(-c2ccccc2)c(-c2ccccc2)c2cccc-4c21 ; CC12CCCCC1(C)N(c1ccccc1)c1c2cc2c3c1c(-c1ccccc1)c(-c1ccccc1)n3B1c3ccccc3N(c3ccccc3)c3cccc-2c31]

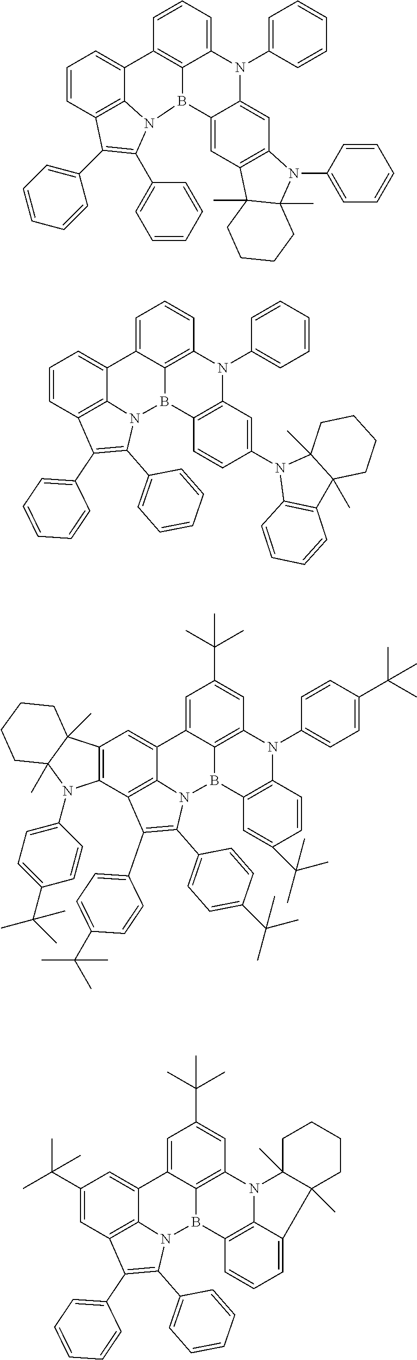

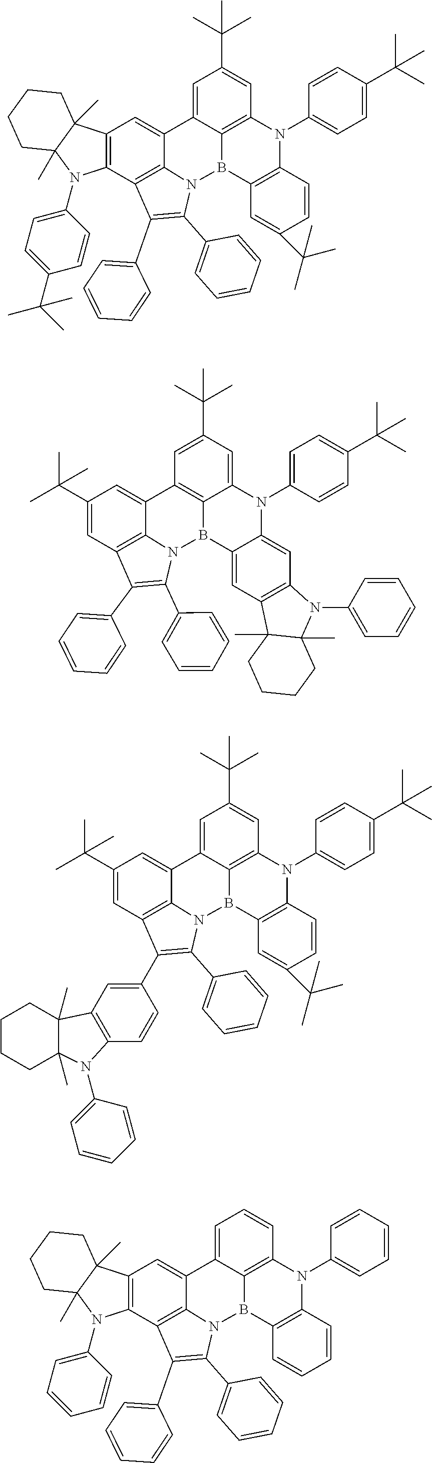

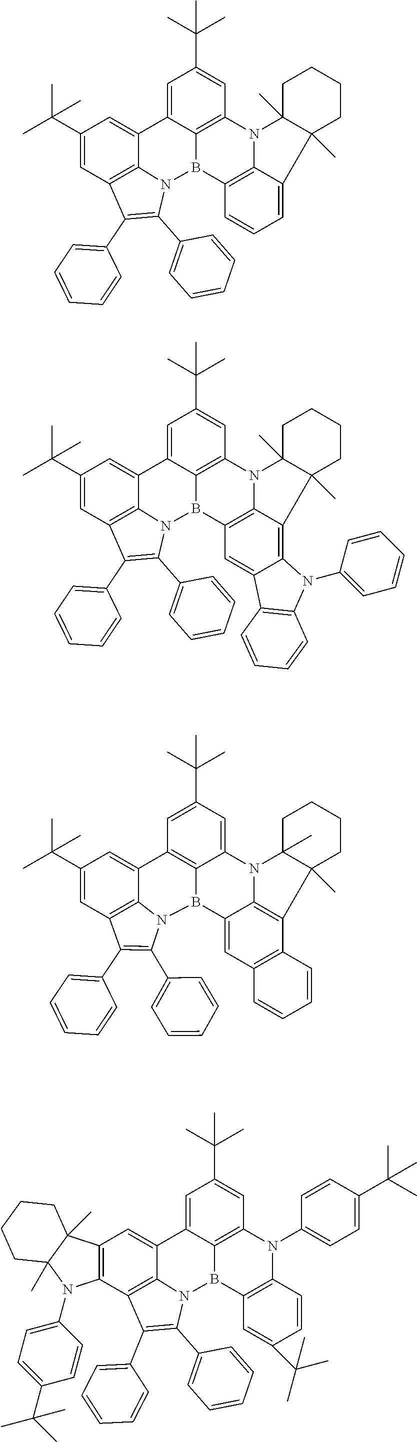

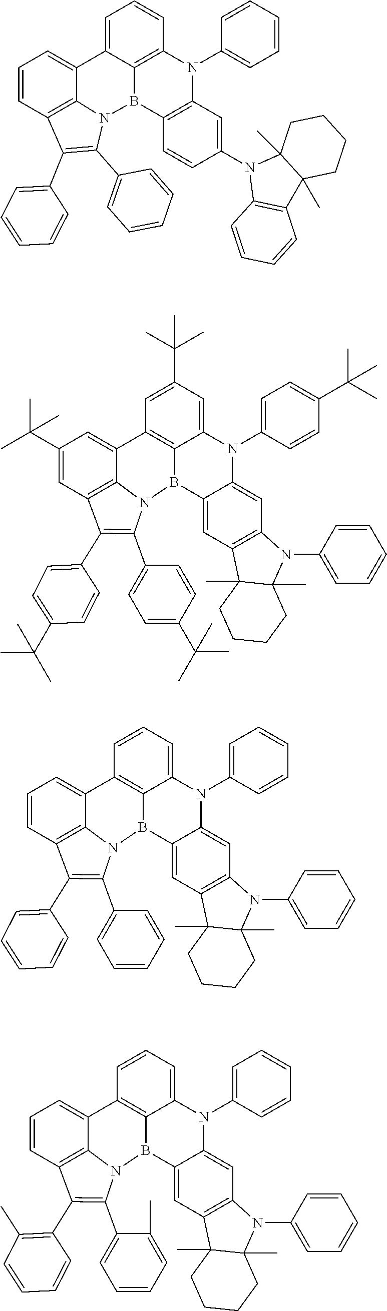 [SMILES: CC12CCCCC1(C)N(c1ccc3c(c1)N(c1ccccc1)c1cccc4c1B3n1c(-c3ccccc3)c(-c3ccccc3)c3cccc-4c31)c1ccccc12 ; CC(C)(C)c1ccc(-c2c(-c3ccc(C(C)(C)C)cc3)n3c4c(cc(C(C)(C)C)cc24)-c2cc(C(C)(C)C)cc4c2B3c2cc3c(cc2N4c2ccc(C(C)(C)C)cc2)N(c2ccccc2)C2(C)CCCCC32C)cc1 ; CC12CCCCC1(C)N(c1ccccc1)c1cc3c(cc12)B1c2c(cccc2N3c2ccccc2)-c2cccc3c(-c4ccccc4)c(-c4ccccc4)n1c23 ; Cc1ccccc1-c1c(-c2ccccc2C)n2c3c(cccc13)-c1cccc3c1B2c1cc2c(cc1N3c1ccccc1)N(c1ccccc1)C1(C)CCCCC21C]

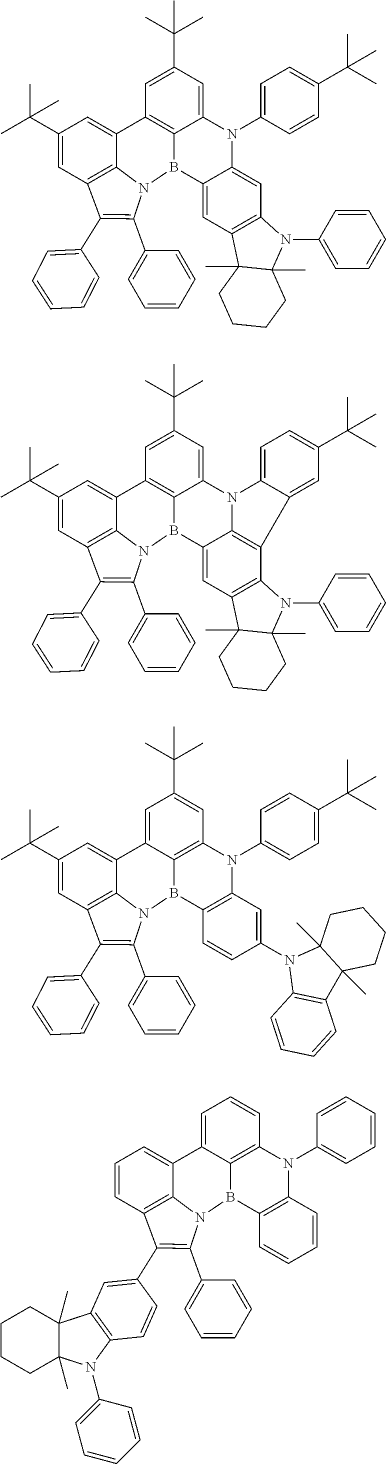 [SMILES: CC(C)(C)c1ccc(N2c3cc4c(cc3B3c5c(cc(C(C)(C)C)cc52)-c2cc(C(C)(C)C)cc5c(-c6ccccc6)c(-c6ccccc6)n3c25)C2(C)CCCCC2(C)N4c2ccccc2)cc1 ; CC(C)(C)c1cc2c3c(c1)-n1c4ccc(C(C)(C)C)cc4c4c5c(cc(c41)B3n1c(-c3ccccc3)c(-c3ccccc3)c3cc(C(C)(C)C)cc-2c31)C1(C)CCCCC1(C)N5c1ccccc1 ; CC(C)(C)c1ccc(N2c3cc(N4c5ccccc5C5(C)CCCCC45C)ccc3B3c4c(cc(C(C)(C)C)cc42)-c2cc(C(C)(C)C)cc4c(-c5ccccc5)c(-c5ccccc5)n3c24)cc1 ; CC12CCCCC1(C)N(c1ccccc1)c1ccc(-c3c(-c4ccccc4)n4c5c(cccc35)-c3cccc5c3B4c3ccccc3N5c3ccccc3)cc12]

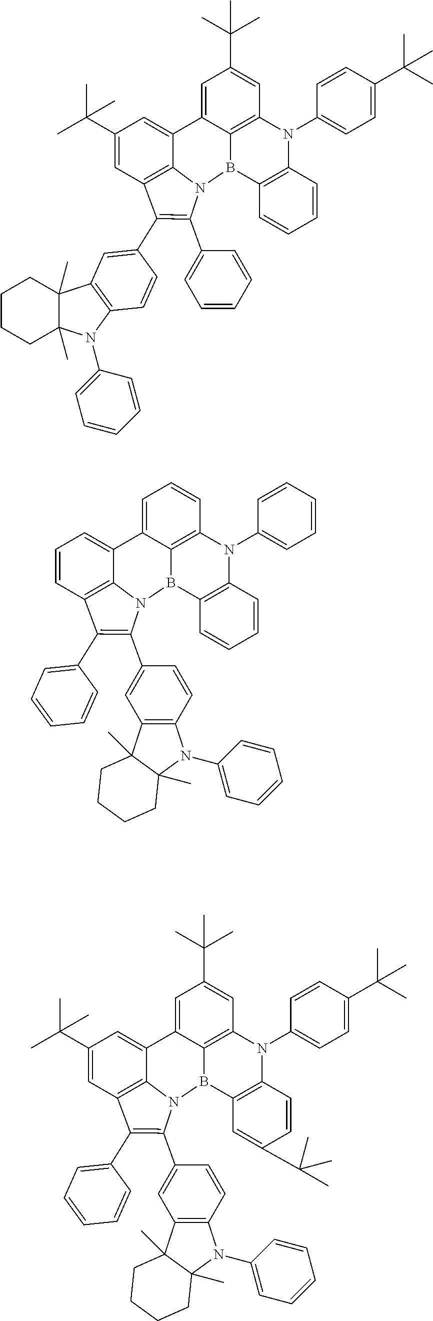

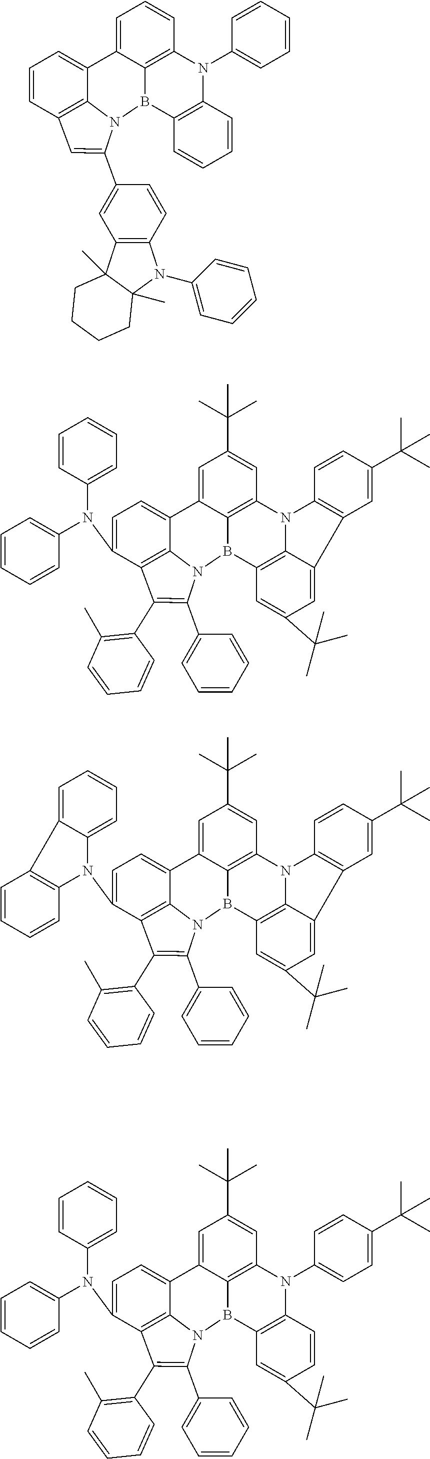

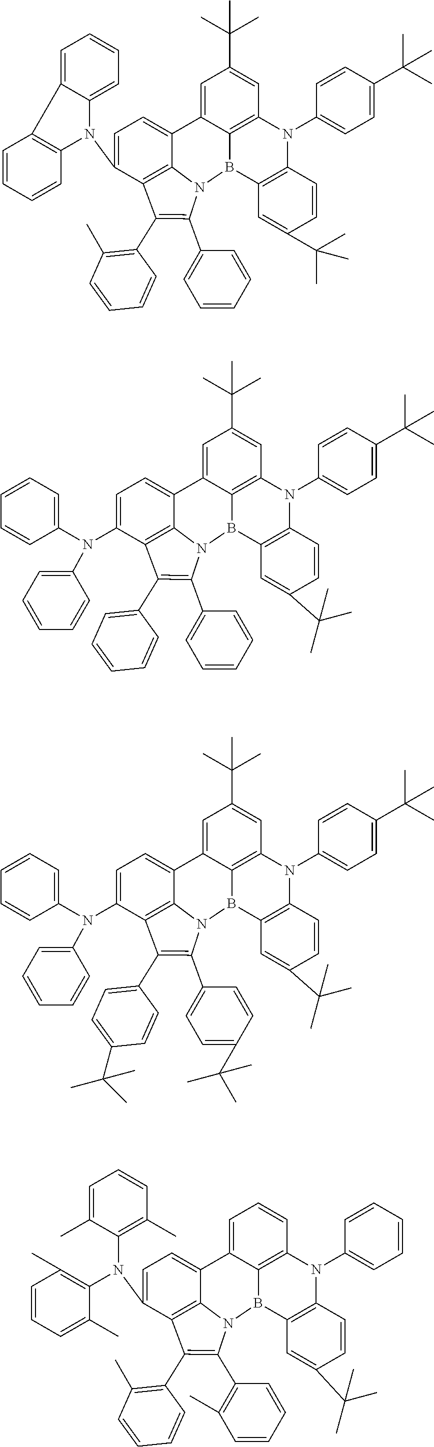 [SMILES: Cc1ccccc1-c1c(-c2ccccc2)n2c3c(ccc(-n4c5ccccc5c5ccccc54)c13)-c1cc(C(C)(C)C)cc3c1B2c1cc(C(C)(C)C)ccc1N3c1ccc(C(C)(C)C)cc1 ; CC(C)(C)c1ccc(N2c3ccc(C(C)(C)C)cc3B3c4c(cc(C(C)(C)C)cc42)-c2ccc(N(c4ccccc4)c4ccccc4)c4c(-c5ccccc5)c(-c5ccccc5)n3c24)cc1 ; CC(C)(C)c1ccc(-c2c(-c3ccc(C(C)(C)C)cc3)n3c4c(ccc(N(c5ccccc5)c5ccccc5)c24)-c2cc(C(C)(C)C)cc4c2B3c2cc(C(C)(C)C)ccc2N4c2ccc(C(C)(C)C)cc2)cc1 ; Cc1ccccc1-c1c(-c2ccccc2C)n2c3c(ccc(N(c4c(C)cccc4C)c4c(C)cccc4C)c13)-c1cccc3c1B2c1cc(C(C)(C)C)ccc1N3c1ccccc1]

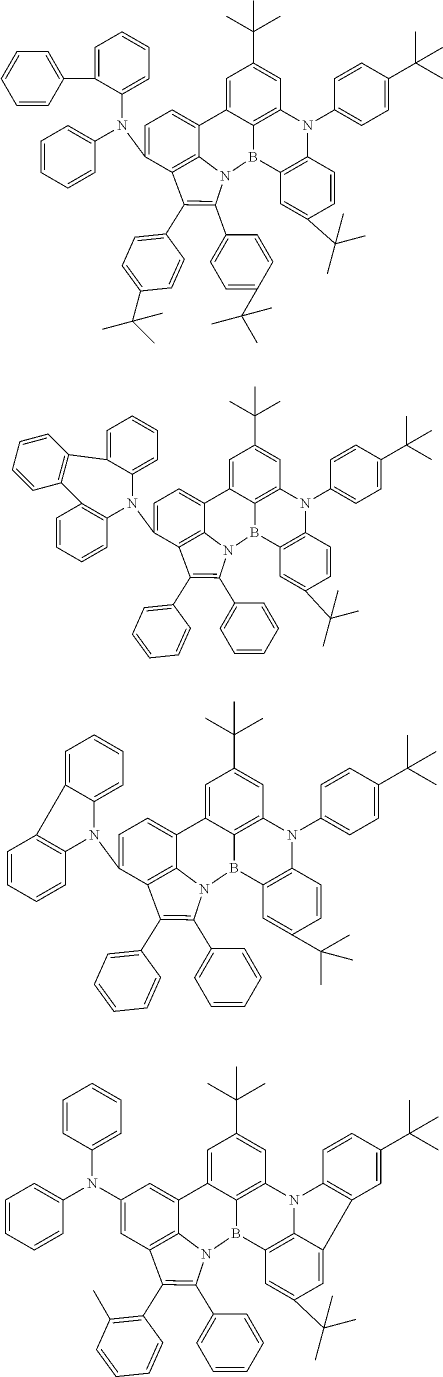

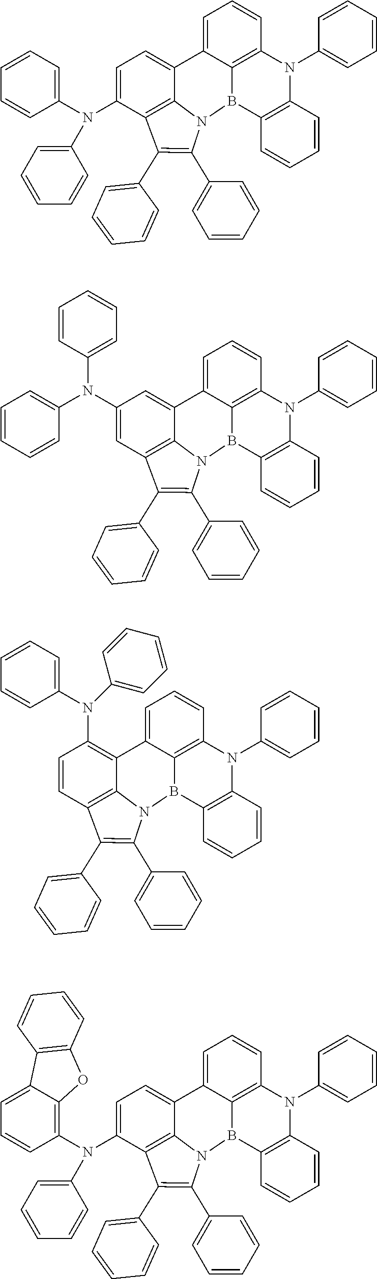

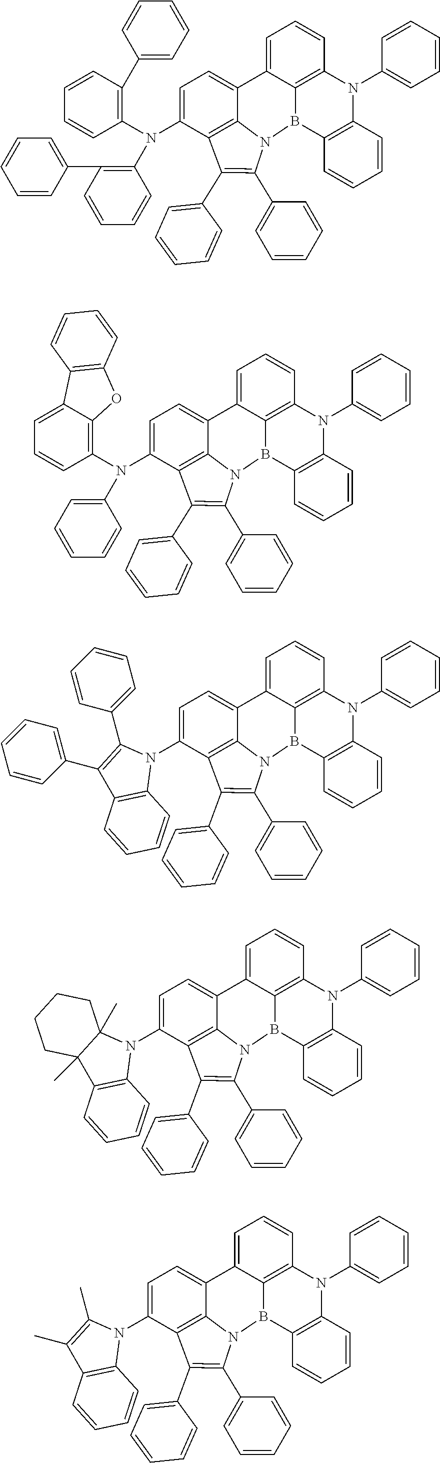

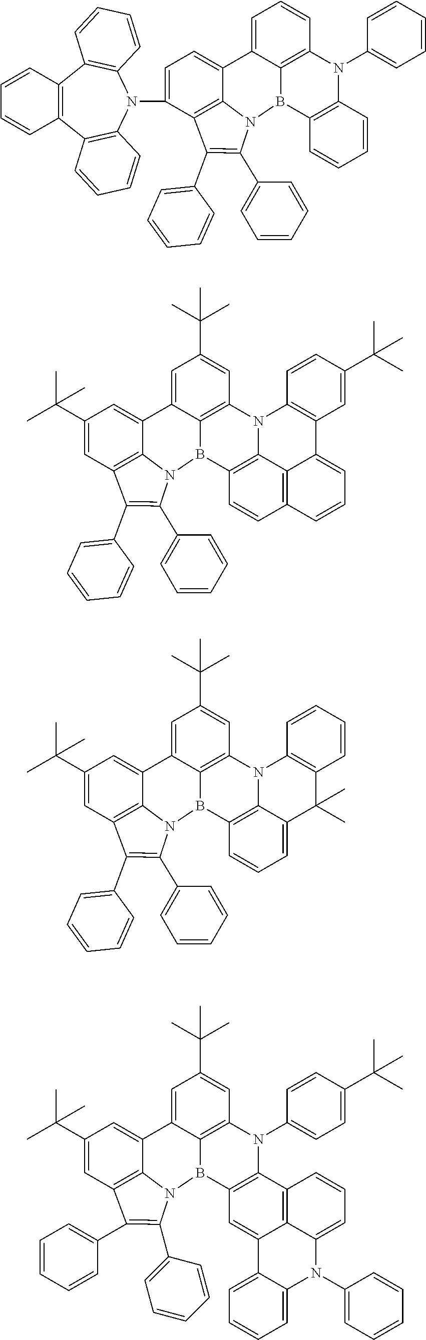

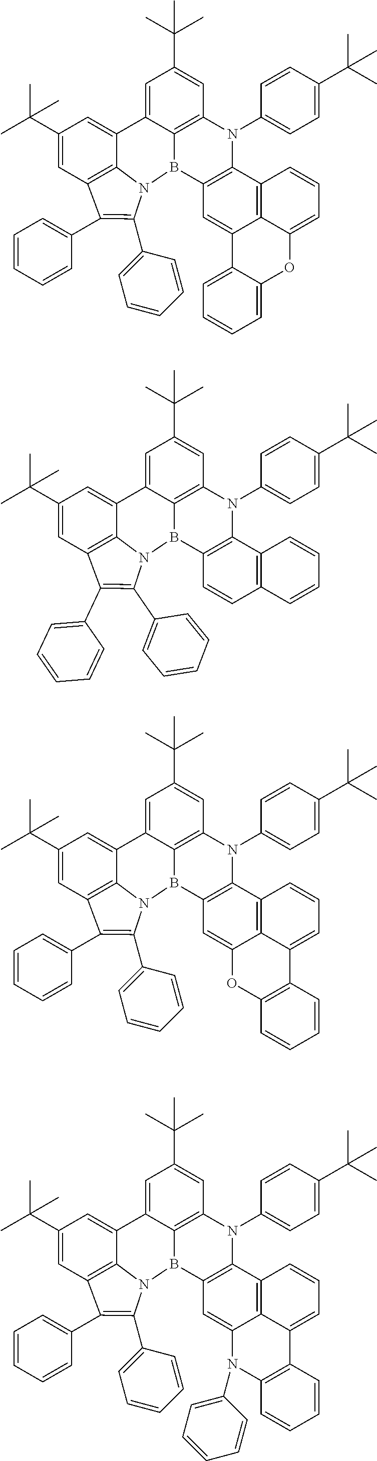

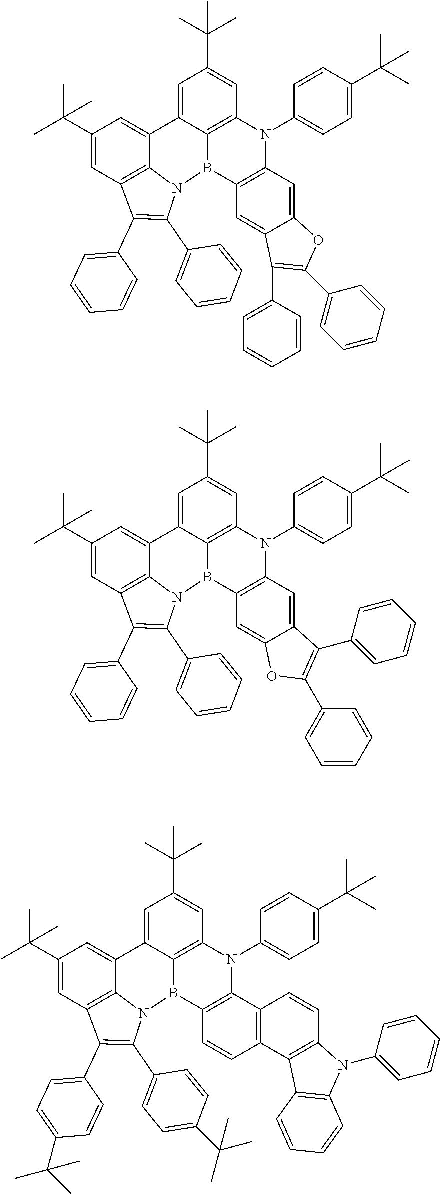

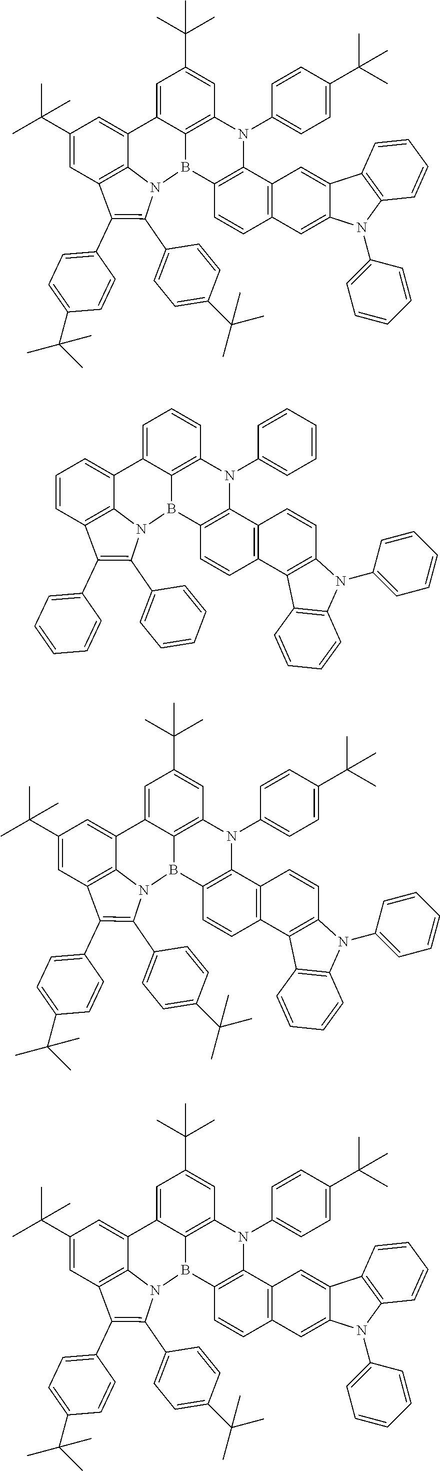

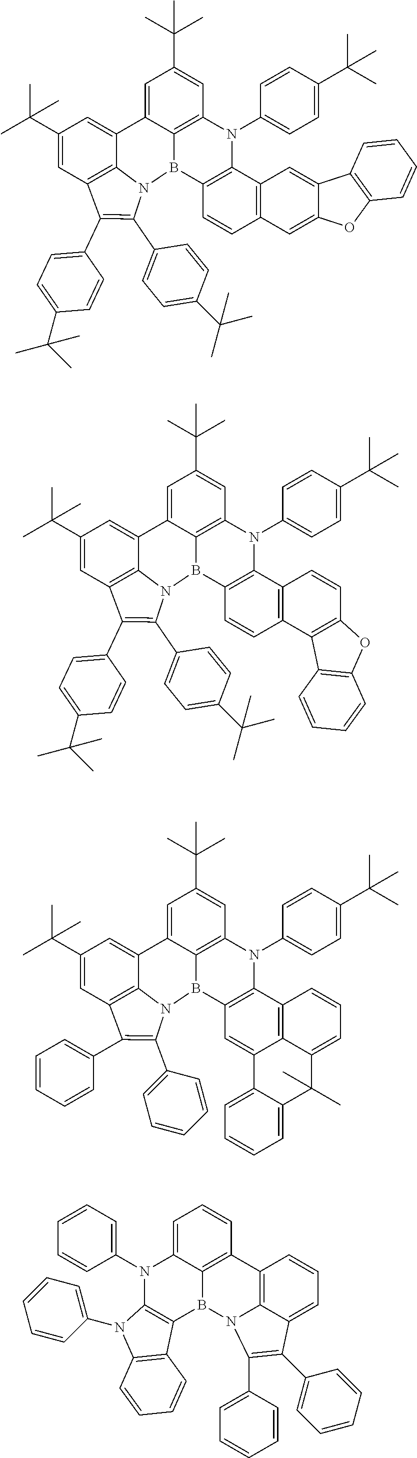

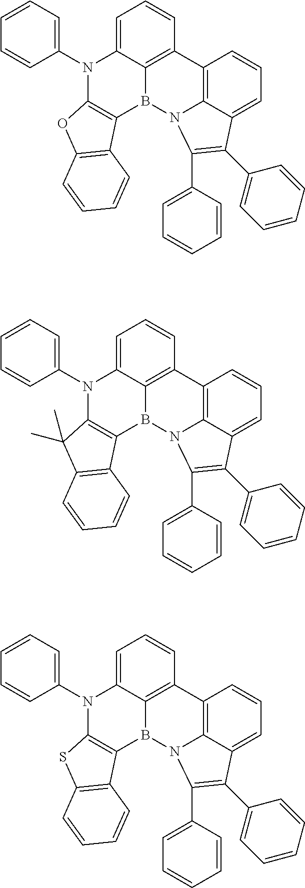 [SMILES: c1ccc(-c2c(-c3ccccc3)n3c4c(cccc24)-c2cccc4c2B3c2c(oc3ccccc23)N4c2ccccc2)cc1 ; CC1(C)C2=C(B3c4c(cccc4N2c2ccccc2)-c2cccc4c(-c5ccccc5)c(-c5ccccc5)n3c24)c2ccccc21 ; c1ccc(-c2c(-c3ccccc3)n3c4c(cccc24)-c2cccc4c2B3c2c(sc3ccccc23)N4c2ccccc2)cc1]

### Preparation of the Compounds of Formula (I)

The compounds represented by formula (I) can be synthesized in accordance with the reactions conducted in the examples of the present application, and by using alternative reactions or raw materials suited to an intended product, in analogy to reactions and raw materials known in the art.

The compounds of formula (I) are for example prepared by the following step:
(i) Addition of BHaI₃ to the intermediate (VIII), whereby the compound of formula (I) is obtained:

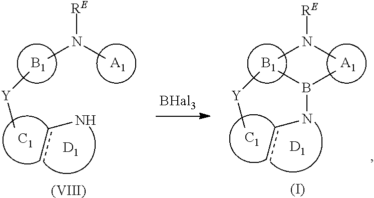

wherein
HaI represents halogen, preferably F, Cl, Br or I, more preferably Cl or Br and most preferably Br;
and
all other residues and indices are as defined before.

Suitable reaction conditions are mentioned in the examples of the present application.

The intermediate (VIII) is for example prepared by the following step:
(iiia) Coupling of a compound of formula (Xa) with a compound of formula (XIa), e.g. in the presence of Pd (e.g. via a Suzuki coupling)

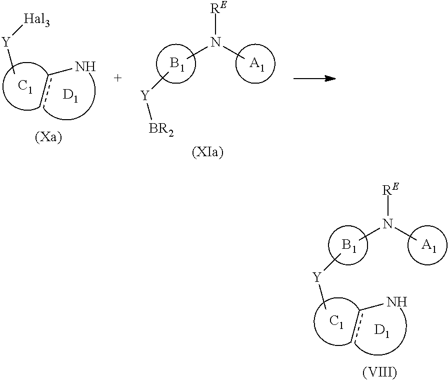

or
(iiib) Coupling of a compound of formula (Xb) with a compound of formula (XIb), e.g. in the presence of Pd (e.g. via a Suzuki coupling)

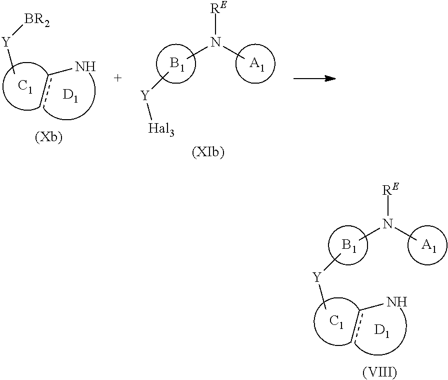

wherein
BR₂ is B(OR′)₂, B(OH)₂, B(NR′₂)₂ or BF₃K, wherein R′ is C₁ to C₄ alkyl, or two residues R together with B form a ring, e.g.

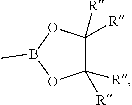

wherein R″ is C₁ to C₄ alkyl and the dotted line is a bonding site;
HaI₃ represents Cl or Br, preferably Br;
in the case that Y in formula (VIII) represents a direct bond, Y in formula (Xa), (Xb), (XIa) and (XIb) is a direct bond;
in the case that Y in formula (VIII) represents O, S, NR²³, SiR²⁴R²⁵ or CR²⁷R²⁸, Y in one of formulae (Xa) and (XIa) respectively one of formulae (Xb) and (XIb) is O, S, NR²³, SiR²⁴R²⁵ or CR²⁷R²⁸, and the other Y is a direct bond:
and all other residues and indices are as defined before.

The compounds of formula (XIa) and (XIb) are for example prepared starting from a compound of formula (IX)

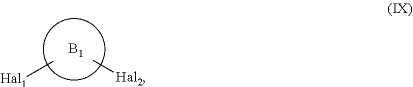

and
(i) reaction of HaI₂ of compound (IX) with an amino compound (XII) which may be further modified after reaction with compound (IX), or with amino compound (XIII) or with an amino compound (XIV),
wherein
HaI₁ represents Cl or Br, preferably Br;
HaI₂ represents Br or I, preferably I;
and B₁ is as defined before,
wherein a compound of formula (XV) is obtained, which corresponds to compound (XIb) in the case that Y is a direct bond:

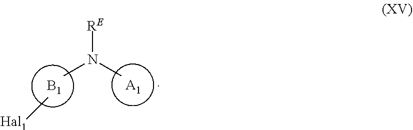

### Amino Compounds (XII), (XIII) and (XIV):

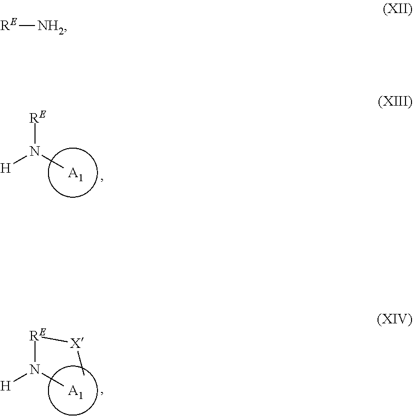

wherein X′ is a direct bond (i.e. R^{E} and the ring A₁ are connected via a direct bond), O, S, NR²³, SiR²⁴R²⁵, CR²⁷R²⁸ or BR²¹, preferably a direct bond;
and R^{E} and A₁ are as defined before.

In step (ii) compound (XIa) is for example prepared starting from compound (XV):
(ii) transforming of HaI₁ of compound (XV) into a boronic acid, an boronic acid ester or an organotrifluorborate (RBF₃K), wherein compound (XIa) is obtained.

Compound (Xa) or (Xb) are for example prepared as follows, in the case that D₁ is

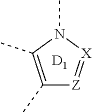

### and X and Z are CR²⁹: Compound (Xb-1):

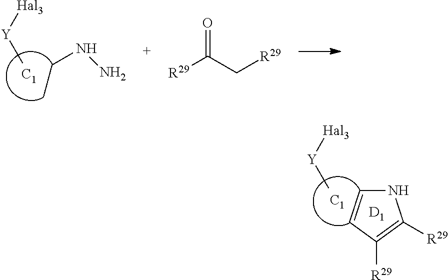

### Compound (Xa-1):

Transforming of HaI₃ of compound (Xb-1) into an boronic acid, a boronic acid ester or an organotrifluorborate (RBF₃K), wherein compound (Xa-1) is obtained.

A more specific example for the preparation of compound (Xb-1) (halo indoles) is shown below:

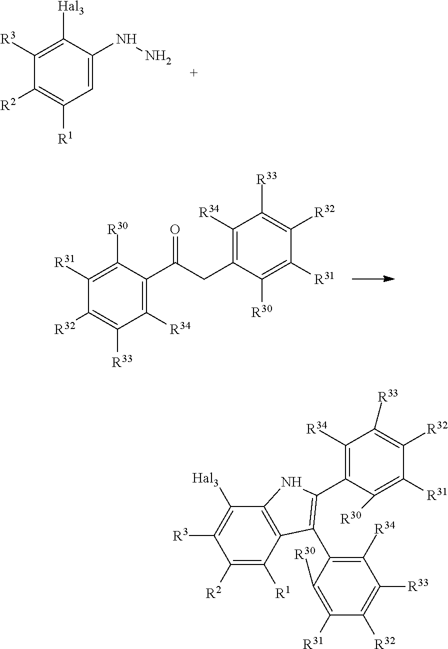

wherein the residues are defined above.

The halo indoles mentioned above can for example be prepared as described in Org. Lett. 2002, 4, 4053.

Compound (Xa) or (Xb) are for example prepared as follows, in the case that D₁ is

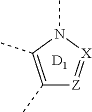

### and X is CR²⁹ and Z is N:

### Compound (Xb-2):

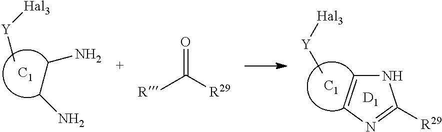

wherein R″′ represents H or OR″″ and R″″ represents a C₁-C₄ alkyl group.

### Compound (Xa-2):

Transforming of HaI₃ of compound (Xb-2) into an boronic acid, a boronic acid ester or an organotrifluorborate (RBF₃K), wherein compound (Xa-2) is obtained.

A more specific example for the preparation of compound (Xb-2) (halo benzimidazoles) is shown below:

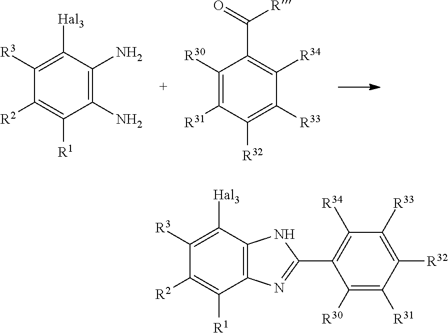

wherein R″′ is H, OCH₃ or OC₂H₅ and wherein the other residues are defined above.

The halo benzimidazols mentioned above can for example be prepared as described in Chemical Communications (2013), 49(39), 4304-4306, Journal of Medicinal Chemistry (2014), 57(17), 7355-7366, WO2015171628 A1, WO2020/217229 or Tetrahedron Letters (2014), 55(35), 4853-4855.

Compound (Xa) or (Xb) wherein D₁ is

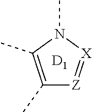

and Z is CR²⁹ and X is N (halo indazoles) are for example prepared as described in US 20040110815 or Organic Letters (2008), 10(5), 1021-1023 or starting from commercially available

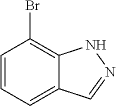

### (CAS 53857-58-2)

Generally, the compounds of formula (I) and intermediates useful for the preparation of the compounds of formula (I) can be prepared in analogy to reactions and raw materials known in the art.

Methods for transforming halogen into boronic acids, esters and organotrifluorborate (RBF₃K) are for example summarized in Angew. Chem. 2009, 121, 9404-9425.

Examples for suitable preparation processes are mentioned below.

### Organic Electroluminescence Device

According to one aspect of the present invention a material for an organic electroluminescence device comprising at least one compound of formula (I) is provided.

According to another aspect of the present invention, an organic electroluminescence device comprising at least one compound of formula (I) is provided.

According to another aspect of the invention, the following organic electroluminescence device is provided: An organic electroluminescence device comprising a cathode, an anode, and one or more organic thin film layers comprising a light emitting layer disposed between the cathode and the anode, wherein at least one layer of the organic thin film layers comprises at least one compound of formula (I).

According to another aspect of the invention an organic electroluminescence device is provided, wherein the light emitting layer comprises at least one compound of formula (I).

According to another aspect of the invention an organic electroluminescence device is provided, wherein the light emitting layer comprises at least one compound of formula (I) as a dopant material and an anthracene compound as a host material.

According to another aspect of the invention an electronic equipment provided with the organic electroluminescence device according to the present invention is provided.

According to another aspect of the invention an emitter material is provided comprising at least one compound of formula (I).

According to another aspect of the invention a light emitting layer is provided comprising at least one host and at least one dopant, wherein the dopant comprises at least one compound of formula (I).

According to another aspect of the invention the use of a compound of formula (I) according to the present invention in an organic electroluminescence device is provided.

In one embodiment, the organic EL device comprises a hole-transporting layer between the anode and the emitting layer.

In one embodiment, the organic EL device comprises an electron-transporting layer between the cathode and the emitting layer.

In the present specification, regarding the “one or more organic thin film layers between the emitting layer and the anode”, if only one organic layer is present between the emitting layer and the anode, it means that layer, and if plural organic layers are present, it means at least one layer thereof. For example, if two or more organic layers are present between the emitting layer and the anode, an organic layer nearer to the emitting layer is called the “hole-transporting layer”, and an organic layer nearer to the anode is called the “hole-injecting layer”. Each of the “hole-transporting layer” and the “hole-injecting layer” may be a single layer or may be formed of two or more layers. One of these layers may be a single layer and the other may be formed of two or more layers.

Similarly, regarding the “one or more organic thin film layers between the emitting layer and the cathode”, if only one organic layer is present between the emitting layer and the cathode, it means that layer, and if plural organic layers are present, it means at least one layer thereof. For example, if two or more organic layers are present between the emitting layer and the cathode, an organic layer nearer to the emitting layer is called the “electron-transporting layer”, and an organic layer nearer to the cathode is called the “electron-injecting layer”. Each of the “electron-transporting layer” and the “electron-injecting layer” may be a single layer or may be formed of two or more layers. One of these layers may be a single layer and the other may be formed of two or more layers.

The “one or more organic thin film layers comprising an emitting layer” mentioned above, prefer-ably the emitting layer, comprises a compound represented by formula (I). The compound represented by formula (I) preferably functions as an emitter material, more preferably as a fluorescent emitter material, most preferably as a blue fluorescent emitter material. By the presence of a compound of formula (I) in the organic EL device, preferably in the emitting layer, organic EL devices characterized by high external quantum efficiencies (EQE) and long lifetimes are provided.

According to another aspect of the invention, an emitting layer of the organic electroluminescence device is provided which comprises at least one compound of formula (I).

Preferably, the emitting layer comprises at least one emitting material (dopant material) and at least one host material, wherein the emitting material is at least one compound of formula (I).

Preferred host materials are substituted or unsubstituted polyaromatic hydrocarbon (PAH) compounds, substituted or unsubstituted polyheteroaromatic compounds, substituted or unsubstituted anthracene compounds, or substituted or unsubstituted pyrene compounds.

More preferably, the organic electroluminescence device according to the present invention comprises in the emitting layer at least one compound of formula (I) as a dopant material and at least one host material selected from the group consisting of substituted or unsubstituted polyaromatic hydrocarbon (PAH) compounds, substituted or unsubstituted polyheteroaromatic compounds, substituted or unsubstituted anthracene compounds, and substituted or unsubstituted pyrene compounds. Preferably, the at least one host is at least one substituted or unsubstituted anthracene compound.

According to another aspect of the invention, an emitting layer of the organic electroluminescence device is provided which comprises at least one compound of formula (I) as a dopant material and an anthracene compound as a host material.

Suitable anthracene compounds are represented by the following formula (10):

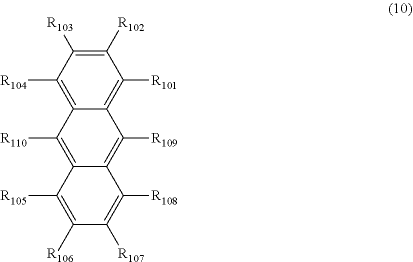

wherein
one or more pairs of two or more adjacent R₁₀₁ to R₁₁₀ may form a substituted or unsubstituted, saturated or unsaturated ring;
R₁₀₁ to R₁₁₀ that do not form the substituted or unsubstituted, saturated or unsaturated ring are independently a hydrogen atom, a substituted or unsubstituted alkyl group including 1 to 50 carbon atoms, a substituted or unsubstituted haloalkyl group including 1 to 50 carbon atoms, a substituted or unsubstituted alkenyl group including 2 to 50 carbon atoms, a substituted or un-substituted alkynyl group including 2 to 50 carbon atoms, a substituted or unsubstituted cycloalkyl group including 3 to 50 ring carbon atoms, a substituted or unsubstituted alkoxy group including 1 to 50 carbon atoms, a substituted or unsubstituted alkylene group including 1 to 50 carbon atoms, a substituted or unsubstituted aryloxy group including 6 to 50 ring carbon atoms, a substituted or unsubstituted arylthio group including 6 to 50 ring carbon atoms, a substituted or unsubstituted aralkyl group including 7 to 50 carbon atoms, —Si(R₁₂₁)(R₁₂₂)(R₁₂₃), —C(═O)R₁₂₄, —COOR₁₂₅, —N(R₁₂₆)(R₁₂₇), a halogen atom, a cyano group, a nitro group, a substituted or unsubstituted aryl group including 6 to 50 ring carbon atoms, a substituted or unsubstituted monovalent heterocyclic group including 5 to 50 ring atoms, or a group represented by the following formula (31);
R₁₂₁ to R₁₂₇ are independently a hydrogen atom, a substituted or unsubstituted alkyl group including 1 to 50 carbon atoms, a substituted or unsubstituted cycloalkyl group including 3 to 50 ring carbon atoms, a substituted or unsubstituted aryl group including 6 to 50 ring carbon atoms or a substituted or unsubstituted monovalent heterocyclic group including 5 to 50 ring atoms; when each of R₁₂₁ to R₁₂₇ is present in plural, each of the plural R₁₂₁ to R₁₂₇ may be the same or different;
provided that at least one of R₁₀₁ to R₁₁₀ that do not form the substituted or unsubstituted, saturated or unsaturated ring is a group represented by the following formula (31). If two or more groups represented by the formula (31) are present, each of these groups may be the same or different;

-L₁₀₁-Ar₁₀₁ (31)

wherein in the formula (31),
L₁₀₁ is a single bond, a substituted or unsubstituted arylene group including 6 to 30 ring carbon atoms or a substituted or unsubstituted divalent heterocyclic group including 5 to 30 ring atoms;
Ar₁₀₁ is a substituted or unsubstituted aryl group including 6 to 50 ring carbon atoms or a substituted or unsubstituted monovalent heterocyclic group including 5 to 50 ring atoms.

Specific examples of each substituent, substituents for “substituted or unsubstituted” and the halogen atom in the compound (10) are the same as those mentioned above.

An explanation will be given on “one or more pairs of two or more adjacent R₁₀₁ to R₁₁₀ may form a substituted or unsubstituted, saturated or unsaturated ring”.

The “one pair of two or more adjacent R₁₀₁ to R₁₁₀” is a combination of R₁₀₁ and R₁₀₂, R₁₀₂ and R₁₀₃, R₁₀₃ and R₁₀₄, R₁₀₅ and R₁₀₆, R₁₀₆ and R₁₀₇, R₁₀₇ and R₁₀₈, R₁₀₈ and R₁₀₉, R₁₀₁ and R₁₀₂ and R₁₀₃ or the like, for example.

The substituent in “substituted” in the “substituted or unsubstituted” for the saturated or unsaturated ring is the same as those for “substituted or unsubstituted” mentioned in the formula (10).

The “saturated or unsaturated ring” means, when R₁₀₁ and R₁₀₂ form a ring, for example, a ring formed by a carbon atom with which R₁₀₁ is bonded, a carbon atom with which R₁₀₂ is bonded and one or more arbitrary elements. Specifically, when a ring is formed by R₁₀₁ and R₁₀₂, when an unsaturated ring is formed by a carbon atom with which R₁₀₁ is bonded, a carbon atom with R₁₀₂ is bonded and four carbon atoms, the ring formed by R₁₀₁ and R₁₀₂ is a benzene ring.

The “arbitrary element” is preferably a C element, a N element, an O element or a S element. In the arbitrary element (C element or N element, for example), atomic bondings that do not form a ring may be terminated by a hydrogen atom, or the like. The “one or more arbitrary element” is preferably 2 or more and 15 or less, more preferably 3 or more and 12 or less, and further preferably 3 or more and 5 or less arbitrary elements.

For example, R₁₀₁ and R₁₀₂ may form a ring, and simultaneously, R₁₀₅ and R₁₀₆ may form a ring. In this case, the compound represented by the formula (10) is a compound represented by the following formula (10A), for example:

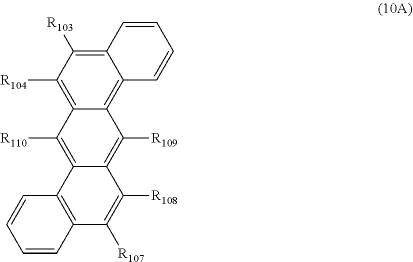

In one embodiment, R₁₀₁ to R₁₁₀ are independently a hydrogen atom, a substituted or unsubstituted alkyl group including 1 to 50 carbon atoms, a substituted or unsubstituted aryl group including 6 to 50 ring carbon atoms, a substituted or unsubstituted heterocyclic group including 5 to 50 ring atoms or a group represented by the formula (31).

Preferably, R₁₀₁ to R₁₁₀ are independently a hydrogen atom, a substituted or unsubstituted aryl group including 6 to 50 ring carbon atoms, a substituted or unsubstituted heterocyclic group including 5 to 50 ring atoms or a group represented by the formula (31).

More preferably, R₁₀₁ to R₁₁₀ are independently a hydrogen atom, a substituted or unsubstituted aryl group including 6 to 18 ring carbon atoms, a substituted or unsubstituted heterocyclic group including 5 to 18 ring atoms or a group represented by the formula (31).

Most preferably, at least one of R₁₀₉ and R₁₁₀ is a group represented by the formula (31).

Further most preferably, R₁₀₉ and R₁₁₀ are independently a group represented by the formula (31).

In one embodiment, the compound (10) is a compound represented by the following formula (10-1):

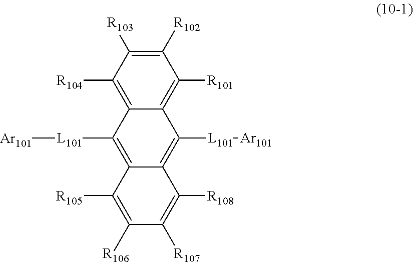

wherein in the formula (10-1), R₁₀₁ to R₁₀₈, L₁₀₁ and Ar₁₀₁ are as defined in the formula (10).

In one embodiment, the compound (10) is a compound represented by the following formula (10-2):

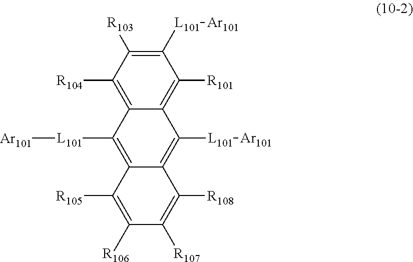

wherein in the formula (10-2), R₁₀₁, R₁₀₃ to R₁₀₈, L₁₀₁ and Ar₁₀₁ are as defined in the formula (10).

In one embodiment, the compound (10) is a compound represented by the following formula (10-3):

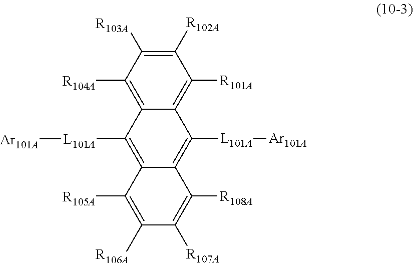

wherein in the formula (10-3),
R_{101A} to R_{108A} are independently a hydrogen atom or a substituted or unsubstituted aryl group including 6 to 50 ring carbon atoms;
L_{101A} is a single bond or a substituted or unsubstituted arylene group including 6 to 30 ring carbon atoms, and the two L_{101A}s may be the same or different;
Ar_{101A} is a substituted or unsubstituted aryl group including 6 to 50 ring carbon atoms, and the two Ar_{101A}s may be the same or different.

In one embodiment, the compound (10) is a compound represented by the following formula (10-4):

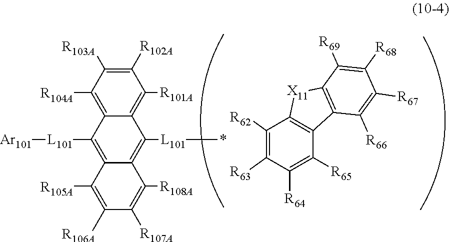

wherein in the formula (10-4),
L₁₀₁ and Ar₁₀₁ are as defined in the formula (10);
R_{101A} to R_{108A} are independently a hydrogen atom or a substituted or unsubstituted aryl group including 6 to 50 ring carbon atoms;
X₁₁ is O, S, or N(R₆₁);
R₆₁ is a hydrogen atom, a substituted or unsubstituted alkyl group including 1 to 50 carbon atoms or a substituted or unsubstituted aryl group including 6 to 50 ring carbon atoms; one of R₆₂ to R₆₉ is an atomic bonding that is bonded with L₁₀₁;
one or more pairs of adjacent R₆₂ to R₆₉ that are not bonded with L₁₀₁ may be bonded with each other to form a substituted or unsubstituted, saturated or unsaturated ring; and
R₆₂ to R₆₉ that are not bonded with L₁₀₁ and do not form the substituted or unsubstituted, saturated or unsaturated ring are independently a hydrogen atom, a substituted or unsubstituted alkyl group including 1 to 50 carbon atoms or a substituted or unsubstituted aryl group including 6 to 50 ring carbon atoms.

In one embodiment, the compound (10) is a compound represented by the following formula (10-4A):

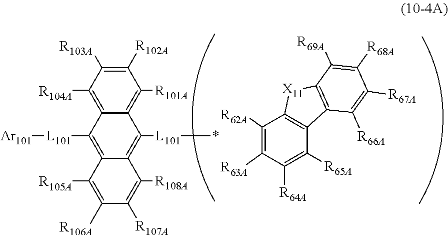

wherein in the formula (10-4A),
L₁₀₁ and Ar₁₀₁ are as defined in the formula (10);
R_{101A} to R_{108A} are independently a hydrogen atom or a substituted or unsubstituted aryl group including 6 to 50 ring carbon atoms;
X₁₁ is O, S or N(R₆₁);
R₆₁ is a hydrogen atom, a substituted or unsubstituted alkyl group including 1 to 50 carbon atoms or a substituted or unsubstituted aryl group including 6 to 50 ring carbon atoms; one or more pairs of adjacent two or more of R_{62A} to R_{69A} may form a substituted or unsubstituted, saturated or unsaturated ring, and adjacent two of R_{62A} to R_{69A} form a ring represented by the following formula (10-4A-1); and
R_{62A} to R_{69A} that do not form a substituted or unsubstituted, saturated or unsaturated ring are independently a hydrogen atom, a substituted or unsubstituted alkyl group including 1 to 50 carbon atoms or a substituted or unsubstituted aryl group including 6 to 50 ring carbon atoms.

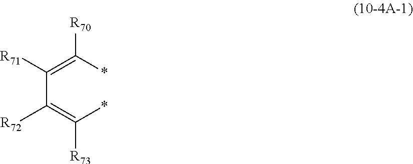

wherein in the formula (10-4A-1),
each of the two atomic bondings * is bonded with adjacent two of R_{62A} to R_{69A}; one of R₇₀ to R₇₃ is an atomic bonding that is bonded with L₁₀₁; and
R₇₀ to R₇₃ that are not bonded with L₁₀₁ are independently a hydrogen atom, a substituted or un-substituted alkyl group including 1 to 50 carbon atoms or a substituted or unsubstituted aryl group including 6 to 50 ring carbon atoms.

In one embodiment, the compound (10) is a compound represented by the following formula (10-6):

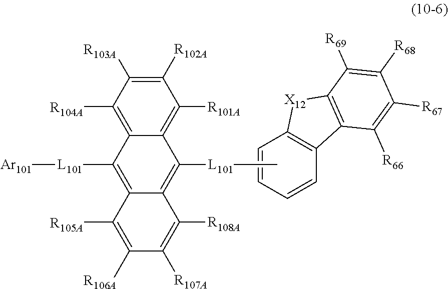

wherein in the formula (10-6),
L₁₀₁ and Ar₁₀₁ are as defined in the formula (10);
R_{101A} to R_{108A} are as defined in the formula (10-4);
R₆₆ to R₆₉ are as defined in the formula (10-4); and
X₁₂ is O or S.

In one embodiment, the compound represented by the formula (10-6) is a compound represented by the following formula (10-6H):

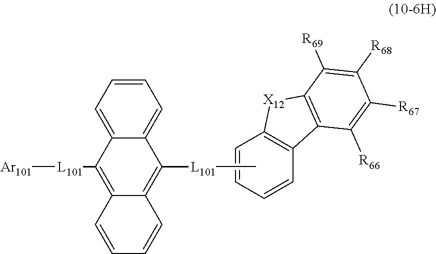

wherein in the formula (10-6H),
L₁₀₁ and Ar₁₀₁ are as defined in the formula (10);
R₆₆ to R₆₉ are as defined in the formula (10-4); and
X₁₂ is O or S.

In one embodiment, the compound represented by the formulae (10-6) and (10-6H) is a compound represented by the following formula (10-6Ha):

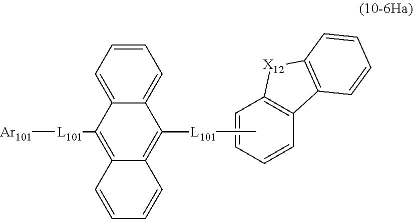

wherein in the formula (10-6Ha),
L₁₀₁ and Ar₁₀₁ are as defined in the formula (10); and
X₁₂ is O or S.

In one embodiment, the compound represented by the formulae (10-6), (10-6H) and (10-6Ha) is a compound represented by the following formula (10-6Ha-1) or (10-6Ha-2):

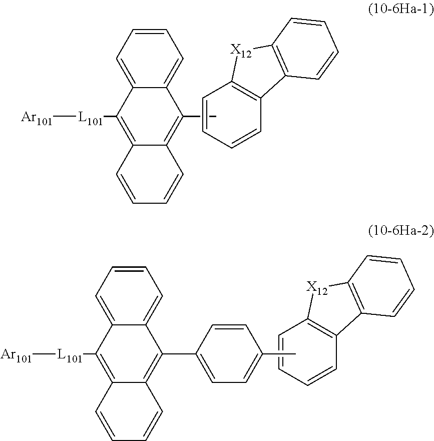

wherein in the formula (10-6Ha-1) and (10-6Ha-2),
L₁₀₁ and Ar₁₀₁ are as defined in the formula (10); and
X₁₂ is O or S.

In one embodiment, the compound (10) is a compound represented by the following formula (10-7):

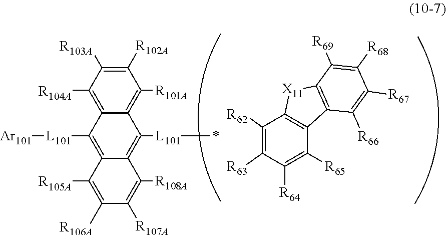

wherein in the formula (10-7),
L₁₀₁ and Ar₁₀₁ are as defined in the formula (10);
R^{101A} to R_{108A} are as defined in the formula (10-4);
X₁₁ is as defined in the formula (10-4); and
R₆₂ to R₆₉ are as defined in the formula (10-4), provided that any one pair of R₆₆ and R₆₇, R₆₇ and Res, and R₆₈ and R₆₉ are bonded with each other to form a substituted or unsubstituted, saturated or unsaturated ring.

In one embodiment, the compound (10) is a compound represented by the following formula (10-7H):

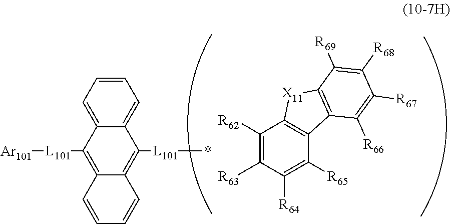

wherein in the formula (10-7H),
L₁₀₁ and Ar₁₀₁ are as defined in the formula (10);
X₁₁ is as defined in the formula (10-4); and
R₆₂ to R₆₉ are as defined in the formula (10-4), provided that any one pair of R₆₆ and R₆₇, R₆₇ and R₆₈, and R₆₈ and R₆₉ are bonded with each other to form a substituted or unsubstituted, saturated or unsaturated ring.

In one embodiment, the compound (10) is a compound represented by the following formula (10-8):

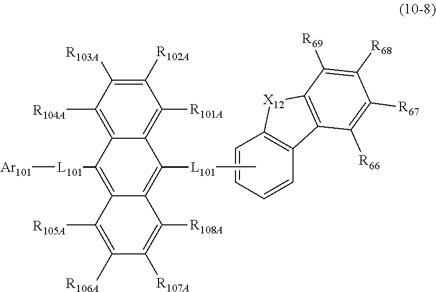

wherein in the formula (10-8),
L₁₀₁ and Ar₁₀₁ are as defined in the formula (10);
R^{101A} to R_{108A} are as defined in the formula (10-4);
X₁₂ is O or S; and
R₆₆ to R₆₉ are as defined in the formula (10-4), provided that any one pair of R₆₆ and R₆₇, R₆₇ and R₆₈, as well as R₆₈ and R₆₉ are bonded with each other to form a substituted or unsubstituted, saturated or unsaturated ring.

In one embodiment, the compound represented by the formula (10-8) is a compound represented by the following formula (10-8H):

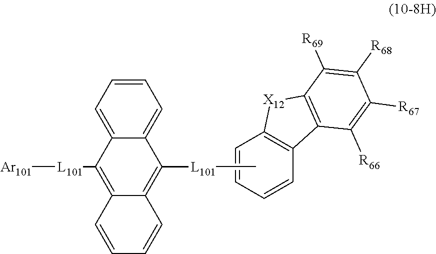

In the formula (10-8H), L₁₀₁ and Ar₁₀₁ are as defined in the formula (10).

R₆₆ to R₆₉ are as defined in the formula (10-4), provided that any one pair of R₆₆ and R₆₇, R₆₇ and R₆₈, as well as R₆₈ and R₆₉ are bonded with each other to form a substituted or unsubstituted, saturated or unsaturated ring. Any one pair of R₆₆ and R₆₇, R₆₇ and R₆₈, as well as R₆₈ and R₆₉ may preferably be bonded with each other to form an unsubstituted benzene ring; and
X₁₂ is O or S.

In one embodiment, as for the compound represented by the formula (10-7), (10-8) or (10-8H), any one pair of R₆₆ and R₆₇, R₆₇ and R₆₈, as well as R₆₈ and R₆₉ are bonded with each other to form a ring represented by the following formula (10-8-1) or (10-8-2), and R₆₆ to R₆₉ that do not form the ring represented by the formula (10-8-1) or (10-8-2) do not form a substituted or unsubstituted, saturated or unsaturated ring.

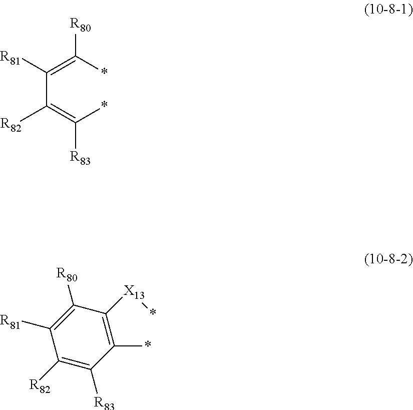

wherein in the formulae (10-8-1) and (10-8-2),
the two atomic bondings * are independently bonded with one pair of R₆₆ and R₆₇, R₆₇ and R₆₈, or R₆₈ and R₆₉;
R₈₀ to R₈₃ are independently a hydrogen atom, a substituted or unsubstituted alkyl group including 1 to 50 carbon atoms or a substituted or unsubstituted aryl group including 6 to 50 ring carbon atoms; and
X₁₃ is O or S.

In one embodiment, the compound (10) is a compound represented by the following formula (10-9):

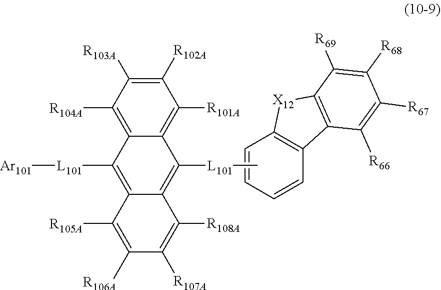

wherein in the formula (10-9),
L₁₀₁ and Ar₁₀₁ are as defined in the formula (10);
R^{101A} to R_{108A} are as defined in the formula (10-4);
R₆₆ to R₆₉ are as defined in the formula (10-4), provided that R₆₆ and R₆₇, R₆₇ and R₆₈, as well as R₆₈ and R₆₉ are not bonded with each other and do not form a substituted or unsubstituted, saturated or unsaturated ring; and
X₁₂ is O or S.

In one embodiment, the compound (10) is selected from the group consisting of compounds represented by the following formulae (10-10-1) to (10-10-4).

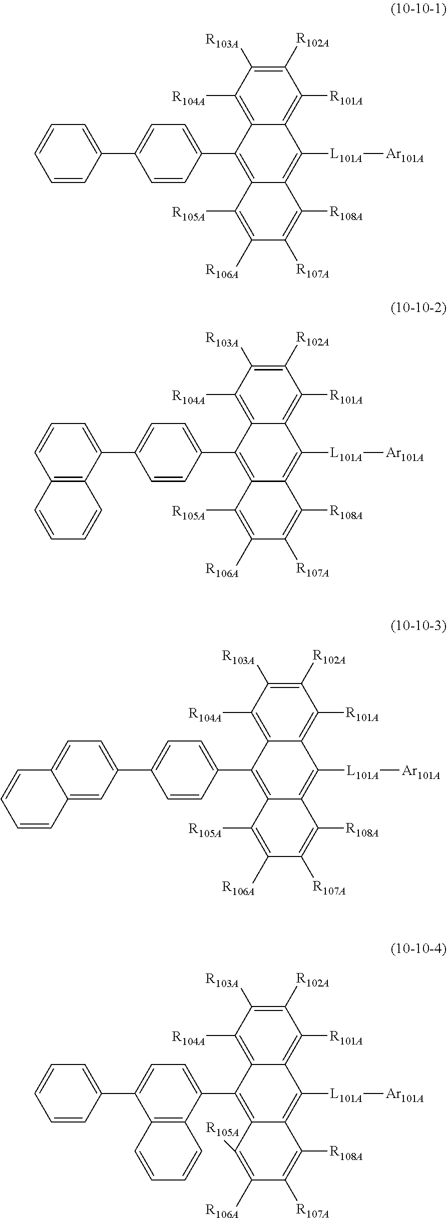

In the formulae (10-10-1H) to (10-10-4H), L_{101A} and Ar_{101A} are as defined in the formula (10-3).

In one embodiment, in the compound represented by the formula (10-1), at least one Ar₁₀₁ is a monovalent group having a structure represented by the following formula (50).

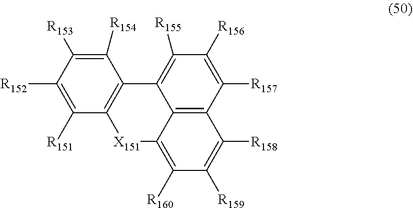

In the formula (50),
X₁₅₁ is O, S, or C(R₁₆₁)(R₁₆₂).

One of R₁₅₁ to R₁₆₀ is a single bond which bonds with L₁₀₁.

One or more sets of adjacent two or more of R₁₅₁ to R₁₅₄ and one or more sets of adjacent two or more of R₁₅₅ to R₁₆₀, which are not a single bond which bonds with L₁₀₁, form a substituted or unsubstituted, saturated or unsaturated ring by bonding with each other, or do not form a substituted or unsubstituted, saturated or unsaturated ring.

R₁₆₁ and R₁₆₂ form a substituted or unsubstituted, saturated or unsaturated ring by bonding with each other, or do not form a substituted or unsubstituted, saturated or unsaturated ring.

R₁₆₁ and R₁₆₂ which do not form the substituted or unsubstituted, saturated or unsaturated ring, and R₁₅₁ to R₁₆₀ which are not a single bond which bonds with L₁₀₁ and do not form the substituted or unsubstituted, saturated or unsaturated ring are independently a hydrogen atom, a substituted or unsubstituted alkyl group including 1 to 50 carbon atoms, a substituted or unsubstituted haloalkyl group including 1 to 50 carbon atoms, a substituted or unsubstituted alkenyl group including 2 to 50 carbon atoms, a substituted or unsubstituted alkynyl group including 2 to 50 carbon atoms, a substituted or unsubstituted cycloalkyl group including 3 to 50 ring carbon atoms, a substituted or unsubstituted alkoxy group including 1 to 50 carbon atoms, a substituted or unsubstituted alkylene group including 1 to 50 carbon atoms, a substituted or unsubstituted aryloxy group including 6 to 50 ring carbon atoms, a substituted or unsubstituted arylthio group including 6 to 50 ring carbon atoms, a substituted or unsubstituted aralkyl group including 7 to 50 carbon atoms, —Si(R121)(R122)(R123), —C(═O)R124, —COOR125, —N(R126)(R127), a halo-gen atom, a cyano group, a nitro group, a substituted or unsubstituted aryl group including 6 to 50 ring carbon atoms, or a substituted or unsubstituted monovalent heterocyclic group including 5 to 50 ring atoms.

Ar₁₀₁, which is not a monovalent group having the structure represented by the formula (50) is a substituted or unsubstituted aryl group including 6 to 50 ring carbon atoms, or a substituted or unsubstituted divalent heterocyclic group including 5 to 50 ring atoms.

The position to be the single bond which bonds with L₁₀₁ in the formula (50) is not particularly limited. In one embodiment, one of R₁₅₁ to R₁₆₀ in the formula (50) is a single bond which bonds with L₁₀₁.

In one embodiment, Ar₁₀₁ is a monovalent group represented by the following formula (50-R₁₅₂), (50-R₁₅₃), (50-R₁₅₄), (50-R₁₅₇), or (50-R₁₅₈).

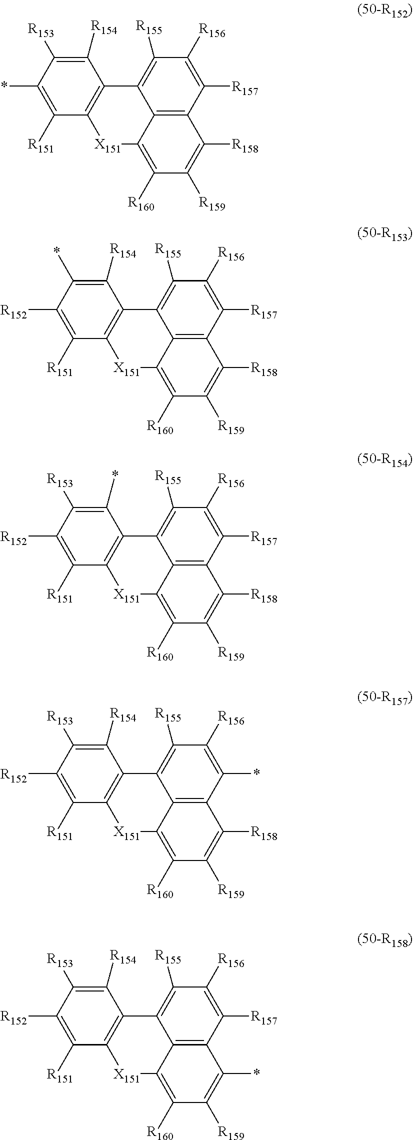

In the formulas (50-R₁₅₂), (50-R₁₅₃), (50-R₁₅₄), (50-R₁₅₇), and (50-R₁₅₈), X₁₅₁, R₁₅₁ to R₁₆₀ are as defined in the formula (50).
* is a single bond which bonds with L₁₀₁.

As for the compound represented by the formula (10), the following compounds can be given as specific examples. The compound represented by the formula (10) is not limited to these specific examples. In the following specific examples, “D” represents a deuterium atom.

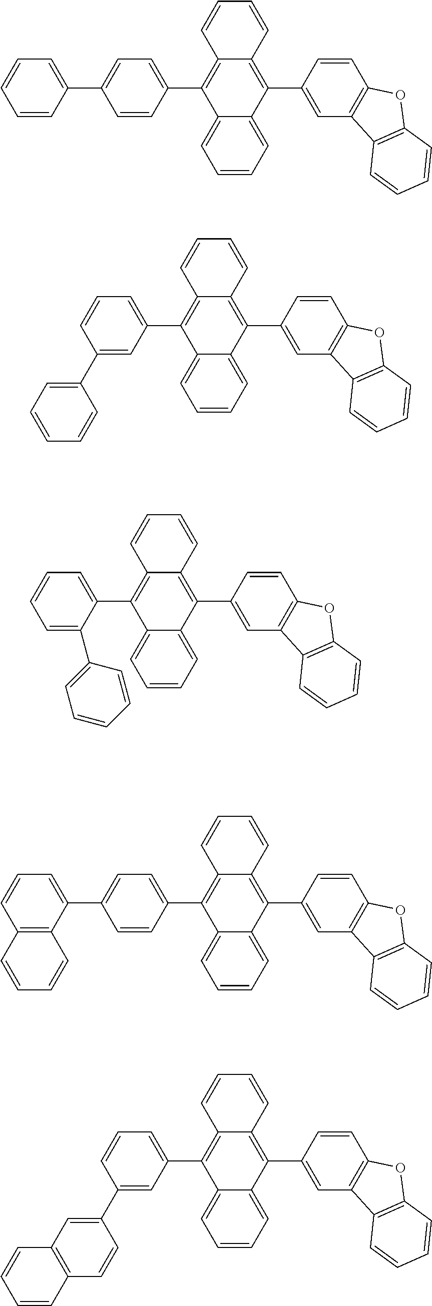 [SMILES: c1ccc(-c2ccc(-c3c4ccccc4c(-c4ccc5oc6ccccc6c5c4)c4ccccc34)cc2)cc1 ; c1ccc(-c2cccc(-c3c4ccccc4c(-c4ccc5oc6ccccc6c5c4)c4ccccc34)c2)cc1 ; c1ccc(-c2ccccc2-c2c3ccccc3c(-c3ccc4oc5ccccc5c4c3)c3ccccc23)cc1 ; c1ccc2c(-c3ccc(-c4c5ccccc5c(-c5ccc6oc7ccccc7c6c5)c5ccccc45)cc3)cccc2c1 ; c1cc(-c2ccc3ccccc3c2)cc(-c2c3ccccc3c(-c3ccc4oc5ccccc5c4c3)c3ccccc23)c1]

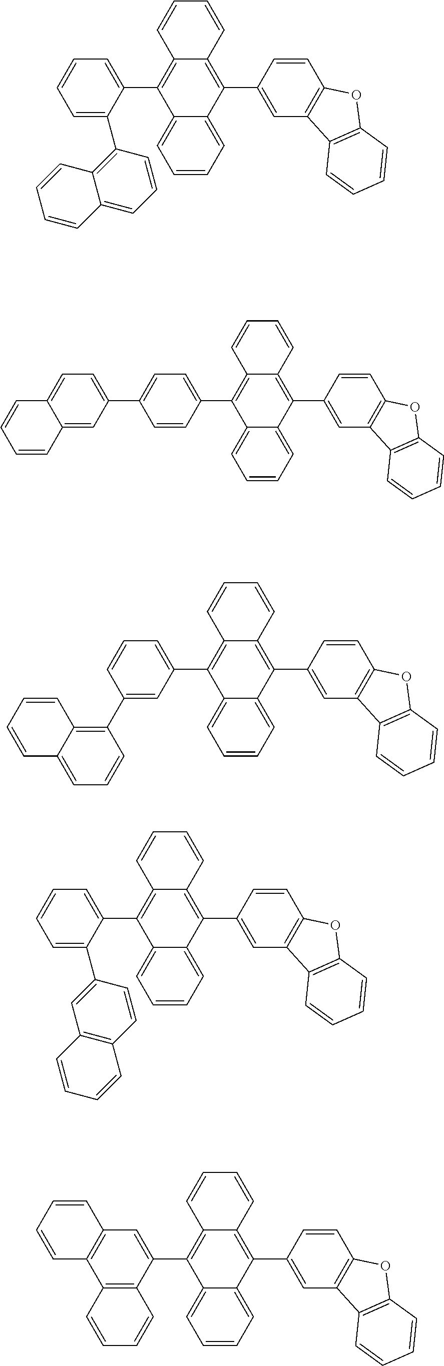 [SMILES: c1ccc(-c2c3ccccc3c(-c3ccc4oc5ccccc5c4c3)c3ccccc23)c(-c2cccc3ccccc23)c1 ; c1ccc2cc(-c3ccc(-c4c5ccccc5c(-c5ccc6oc7ccccc7c6c5)c5ccccc45)cc3)ccc2c1 ; c1cc(-c2cccc3ccccc23)cc(-c2c3ccccc3c(-c3ccc4oc5ccccc5c4c3)c3ccccc23)c1 ; c1ccc(-c2c3ccccc3c(-c3ccc4oc5ccccc5c4c3)c3ccccc23)c(-c2ccc3ccccc3c2)c1 ; c1ccc2c(c1)cc(-c1c3ccccc3c(-c3ccc4oc5ccccc5c4c3)c3ccccc13)c1ccccc12]

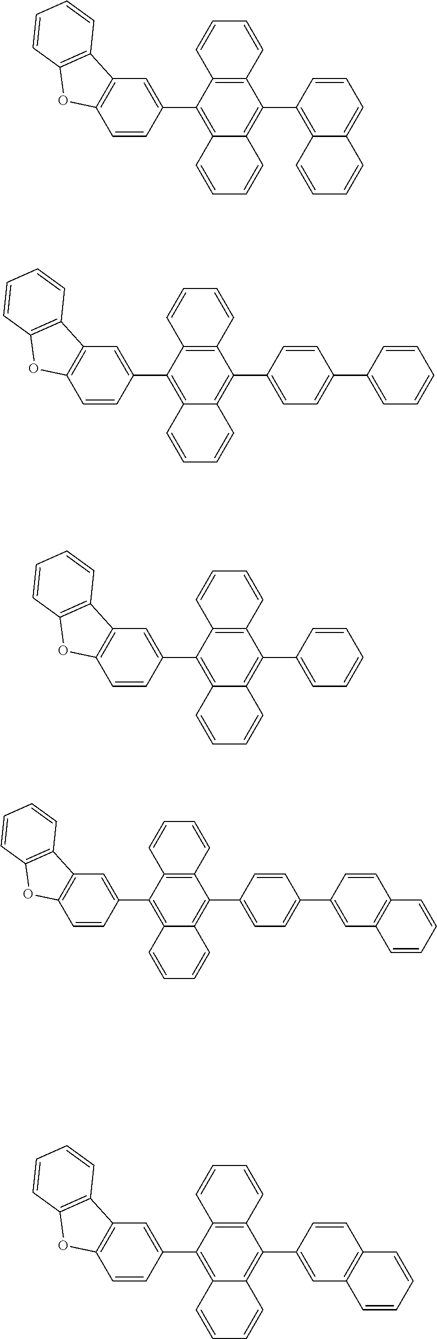 [SMILES: c1ccc2c(-c3c4ccccc4c(-c4ccc5oc6ccccc6c5c4)c4ccccc34)cccc2c1 ; c1ccc(-c2ccc(-c3c4ccccc4c(-c4ccc5oc6ccccc6c5c4)c4ccccc34)cc2)cc1 ; c1ccc(-c2c3ccccc3c(-c3ccc4oc5ccccc5c4c3)c3ccccc23)cc1 ; c1ccc2cc(-c3ccc(-c4c5ccccc5c(-c5ccc6oc7ccccc7c6c5)c5ccccc45)cc3)ccc2c1 ; c1ccc2cc(-c3c4ccccc4c(-c4ccc5oc6ccccc6c5c4)c4ccccc34)ccc2c1]

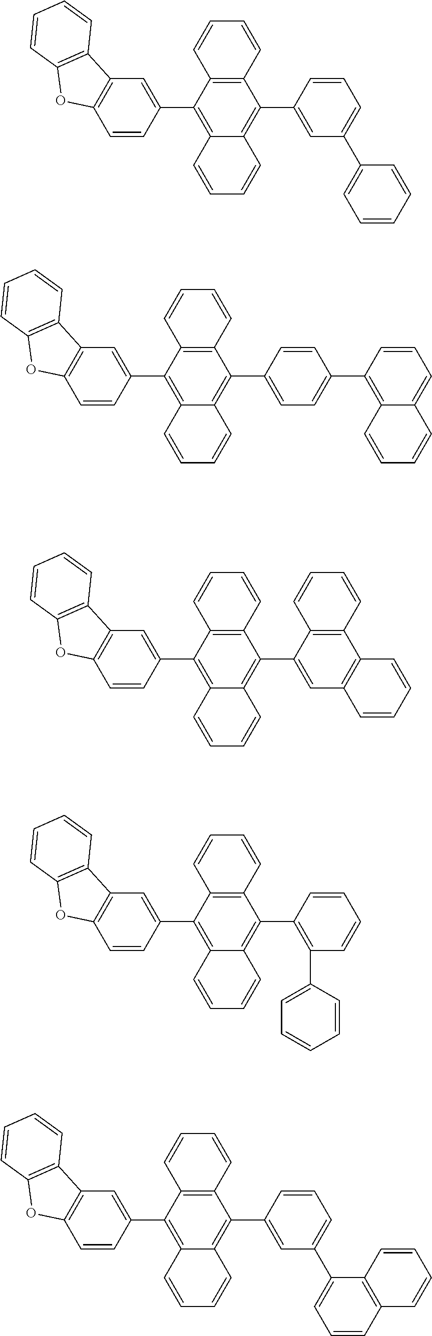 [SMILES: c1ccc(-c2cccc(-c3c4ccccc4c(-c4ccc5oc6ccccc6c5c4)c4ccccc34)c2)cc1 ; c1ccc2c(-c3ccc(-c4c5ccccc5c(-c5ccc6oc7ccccc7c6c5)c5ccccc45)cc3)cccc2c1 ; c1ccc2c(c1)cc(-c1c3ccccc3c(-c3ccc4oc5ccccc5c4c3)c3ccccc13)c1ccccc12 ; c1ccc(-c2ccccc2-c2c3ccccc3c(-c3ccc4oc5ccccc5c4c3)c3ccccc23)cc1 ; c1cc(-c2cccc3ccccc23)cc(-c2c3ccccc3c(-c3ccc4oc5ccccc5c4c3)c3ccccc23)c1]

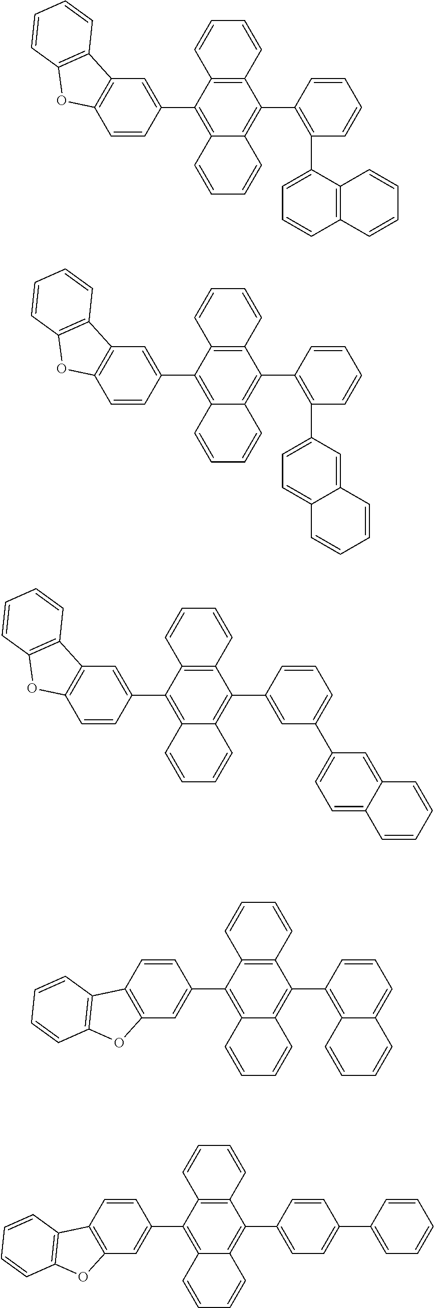 [SMILES: c1ccc(-c2c3ccccc3c(-c3ccc4oc5ccccc5c4c3)c3ccccc23)c(-c2cccc3ccccc23)c1 ; c1ccc(-c2c3ccccc3c(-c3ccc4oc5ccccc5c4c3)c3ccccc23)c(-c2ccc3ccccc3c2)c1 ; c1cc(-c2ccc3ccccc3c2)cc(-c2c3ccccc3c(-c3ccc4oc5ccccc5c4c3)c3ccccc23)c1 ; c1ccc2c(-c3c4ccccc4c(-c4ccc5c(c4)oc4ccccc45)c4ccccc34)cccc2c1 ; c1ccc(-c2ccc(-c3c4ccccc4c(-c4ccc5c(c4)oc4ccccc45)c4ccccc34)cc2)cc1]

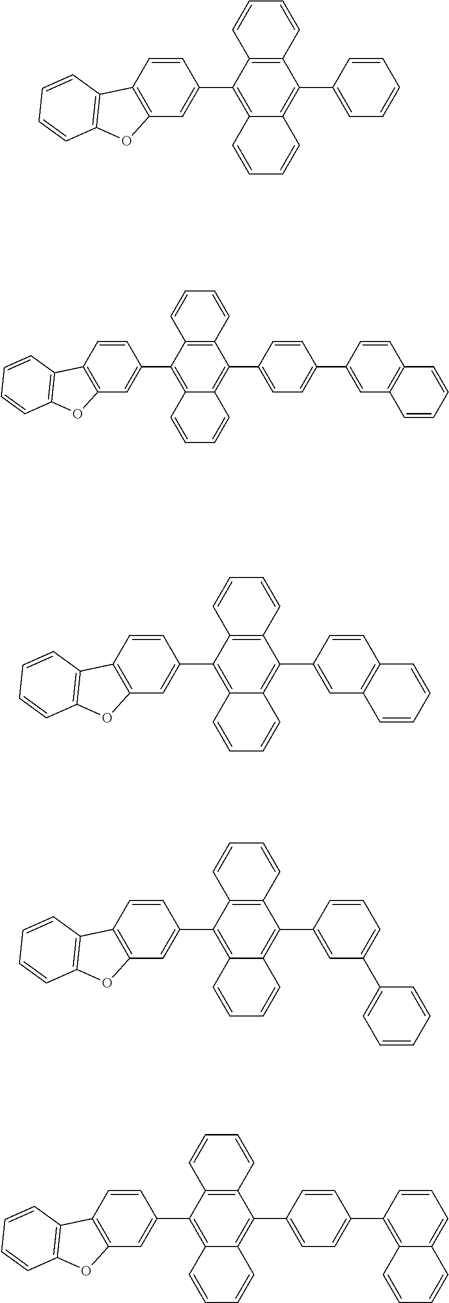 [SMILES: c1ccc(-c2c3ccccc3c(-c3ccc4c(c3)oc3ccccc34)c3ccccc23)cc1 ; c1ccc2cc(-c3ccc(-c4c5ccccc5c(-c5ccc6c(c5)oc5ccccc56)c5ccccc45)cc3)ccc2c1 ; c1ccc2cc(-c3c4ccccc4c(-c4ccc5c(c4)oc4ccccc45)c4ccccc34)ccc2c1 ; c1ccc(-c2cccc(-c3c4ccccc4c(-c4ccc5c(c4)oc4ccccc45)c4ccccc34)c2)cc1 ; c1ccc2c(-c3ccc(-c4c5ccccc5c(-c5ccc6c(c5)oc5ccccc56)c5ccccc45)cc3)cccc2c1]

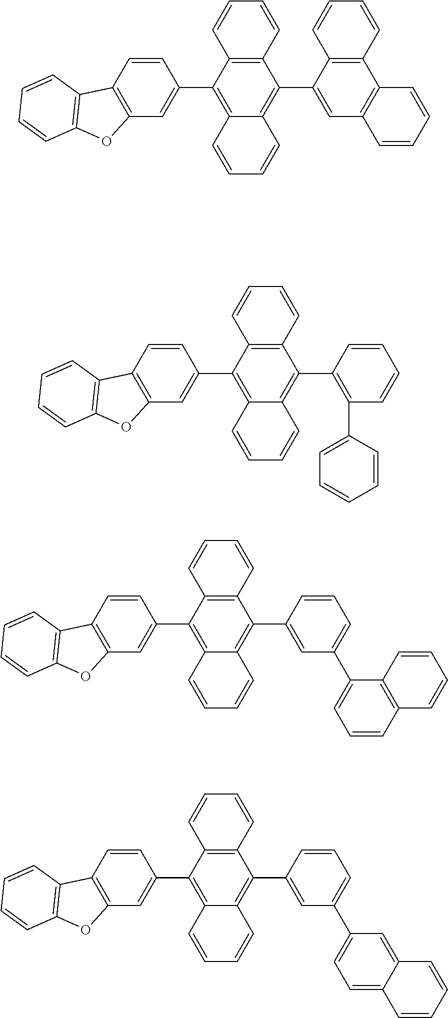 [SMILES: c1ccc2c(c1)cc(-c1c3ccccc3c(-c3ccc4c(c3)oc3ccccc34)c3ccccc13)c1ccccc12 ; c1ccc(-c2ccccc2-c2c3ccccc3c(-c3ccc4c(c3)oc3ccccc34)c3ccccc23)cc1 ; c1cc(-c2cccc3ccccc23)cc(-c2c3ccccc3c(-c3ccc4c(c3)oc3ccccc34)c3ccccc23)c1 ; c1cc(-c2ccc3ccccc3c2)cc(-c2c3ccccc3c(-c3ccc4c(c3)oc3ccccc34)c3ccccc23)c1]

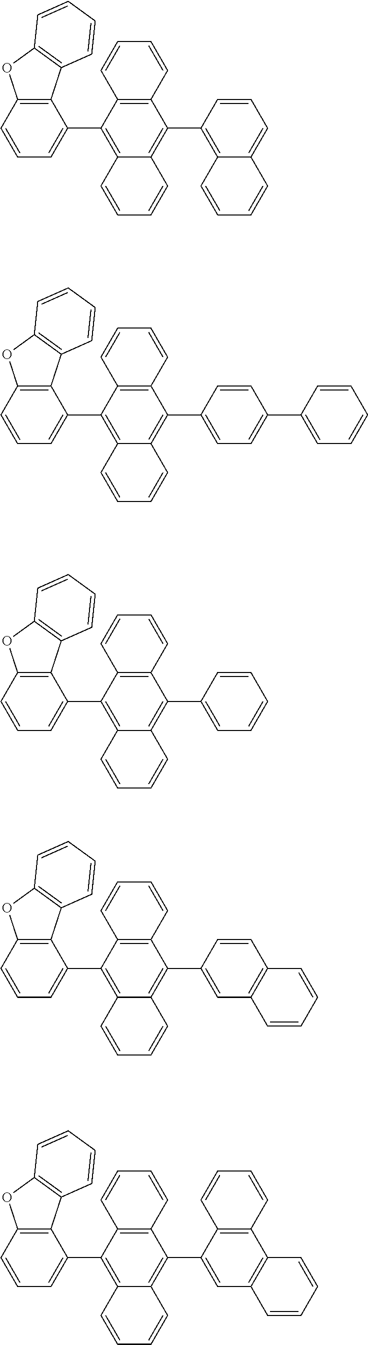 [SMILES: c1ccc2c(-c3c4ccccc4c(-c4cccc5oc6ccccc6c45)c4ccccc34)cccc2c1 ; c1ccc(-c2ccc(-c3c4ccccc4c(-c4cccc5oc6ccccc6c45)c4ccccc34)cc2)cc1 ; c1ccc(-c2c3ccccc3c(-c3cccc4oc5ccccc5c34)c3ccccc23)cc1 ; c1ccc2cc(-c3c4ccccc4c(-c4cccc5oc6ccccc6c45)c4ccccc34)ccc2c1 ; c1ccc2c(c1)cc(-c1c3ccccc3c(-c3cccc4oc5ccccc5c34)c3ccccc13)c1ccccc12]

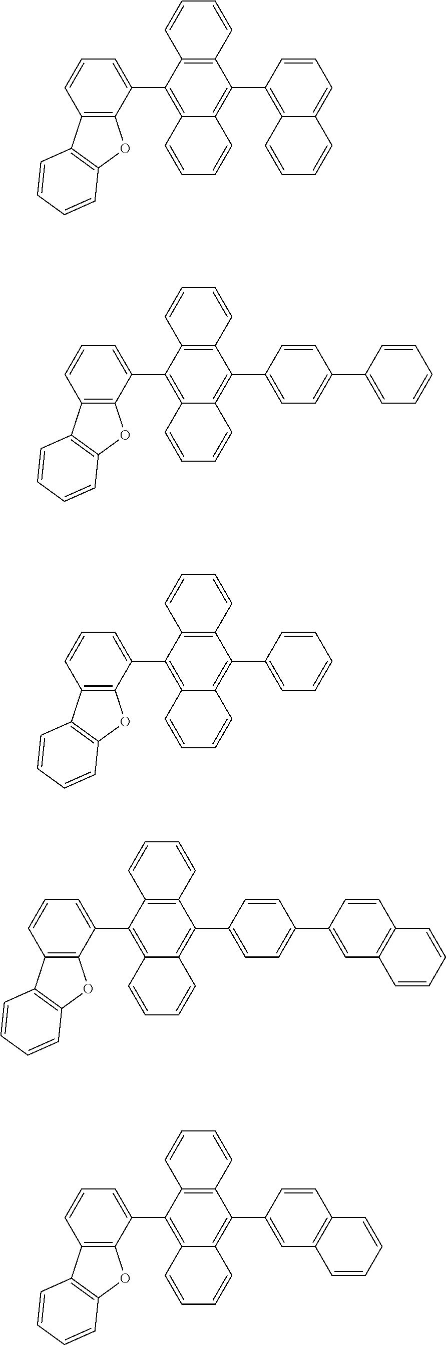 [SMILES: c1ccc2c(-c3c4ccccc4c(-c4cccc5c4oc4ccccc45)c4ccccc34)cccc2c1 ; c1ccc(-c2ccc(-c3c4ccccc4c(-c4cccc5c4oc4ccccc45)c4ccccc34)cc2)cc1 ; c1ccc(-c2c3ccccc3c(-c3cccc4c3oc3ccccc34)c3ccccc23)cc1 ; c1ccc2cc(-c3ccc(-c4c5ccccc5c(-c5cccc6c5oc5ccccc56)c5ccccc45)cc3)ccc2c1 ; c1ccc2cc(-c3c4ccccc4c(-c4cccc5c4oc4ccccc45)c4ccccc34)ccc2c1]

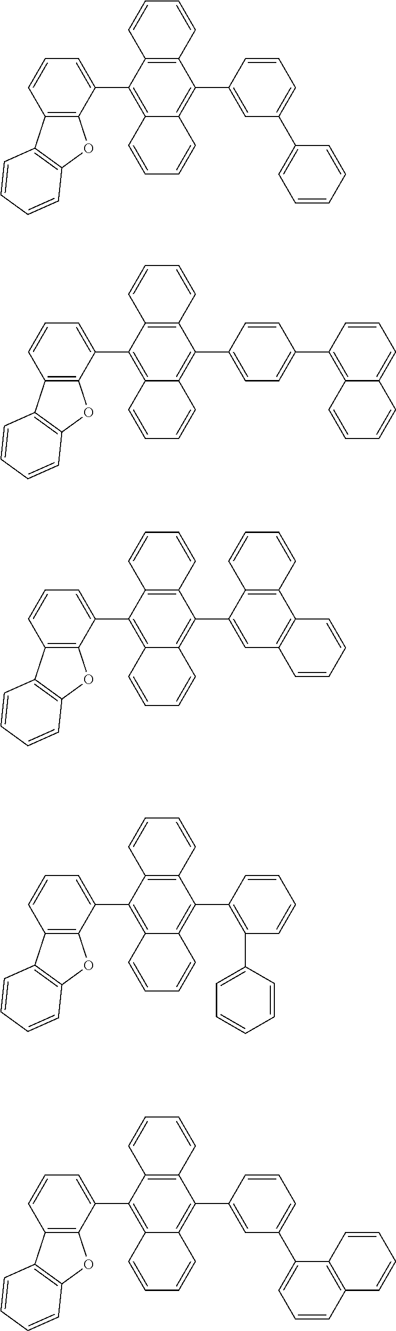 [SMILES: c1ccc(-c2cccc(-c3c4ccccc4c(-c4cccc5c4oc4ccccc45)c4ccccc34)c2)cc1 ; c1ccc2c(-c3ccc(-c4c5ccccc5c(-c5cccc6c5oc5ccccc56)c5ccccc45)cc3)cccc2c1 ; c1ccc2c(c1)cc(-c1c3ccccc3c(-c3cccc4c3oc3ccccc34)c3ccccc13)c1ccccc12 ; c1ccc(-c2ccccc2-c2c3ccccc3c(-c3cccc4c3oc3ccccc34)c3ccccc23)cc1 ; c1cc(-c2cccc3ccccc23)cc(-c2c3ccccc3c(-c3cccc4c3oc3ccccc34)c3ccccc23)c1]

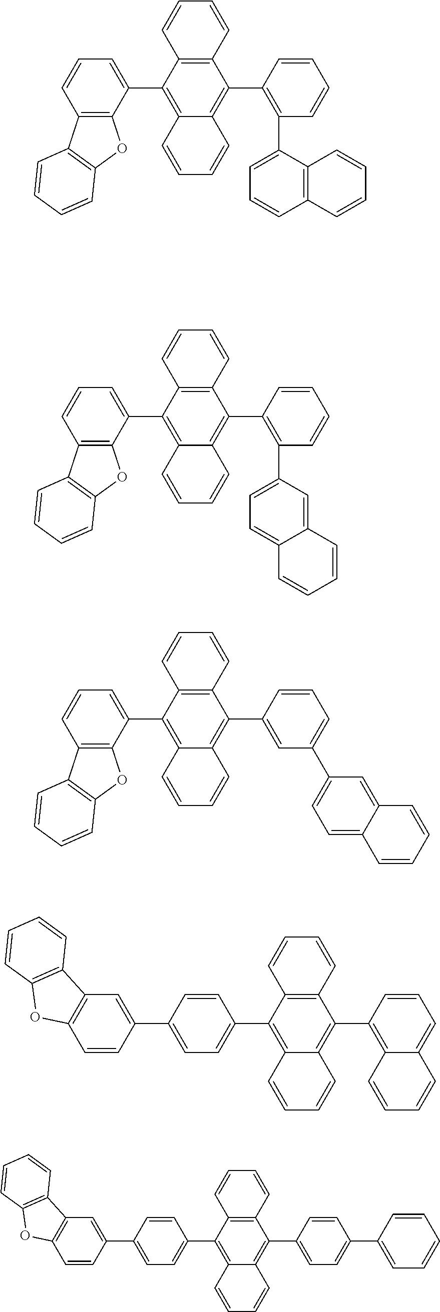 [SMILES: c1ccc(-c2c3ccccc3c(-c3cccc4c3oc3ccccc34)c3ccccc23)c(-c2cccc3ccccc23)c1 ; c1ccc(-c2c3ccccc3c(-c3cccc4c3oc3ccccc34)c3ccccc23)c(-c2ccc3ccccc3c2)c1 ; c1cc(-c2ccc3ccccc3c2)cc(-c2c3ccccc3c(-c3cccc4c3oc3ccccc34)c3ccccc23)c1 ; c1ccc2c(-c3c4ccccc4c(-c4ccc(-c5ccc6oc7ccccc7c6c5)cc4)c4ccccc34)cccc2c1 ; c1ccc(-c2ccc(-c3c4ccccc4c(-c4ccc(-c5ccc6oc7ccccc7c6c5)cc4)c4ccccc34)cc2)cc1]

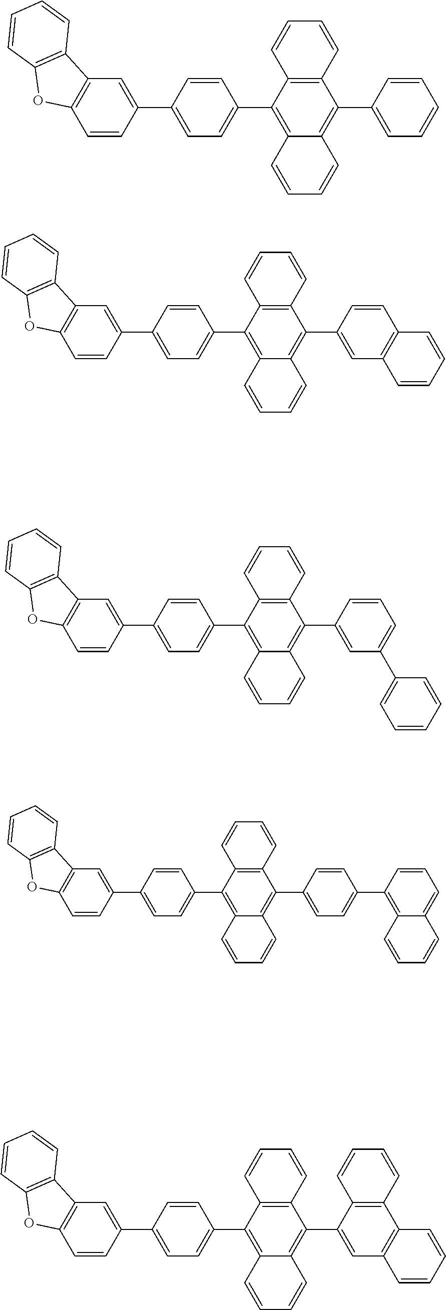 [SMILES: c1ccc(-c2c3ccccc3c(-c3ccc(-c4ccc5oc6ccccc6c5c4)cc3)c3ccccc23)cc1 ; c1ccc2cc(-c3c4ccccc4c(-c4ccc(-c5ccc6oc7ccccc7c6c5)cc4)c4ccccc34)ccc2c1 ; c1ccc(-c2cccc(-c3c4ccccc4c(-c4ccc(-c5ccc6oc7ccccc7c6c5)cc4)c4ccccc34)c2)cc1 ; c1ccc2c(-c3ccc(-c4c5ccccc5c(-c5ccc(-c6ccc7oc8ccccc8c7c6)cc5)c5ccccc45)cc3)cccc2c1 ; c1ccc2c(c1)cc(-c1c3ccccc3c(-c3ccc(-c4ccc5oc6ccccc6c5c4)cc3)c3ccccc13)c1ccccc12]

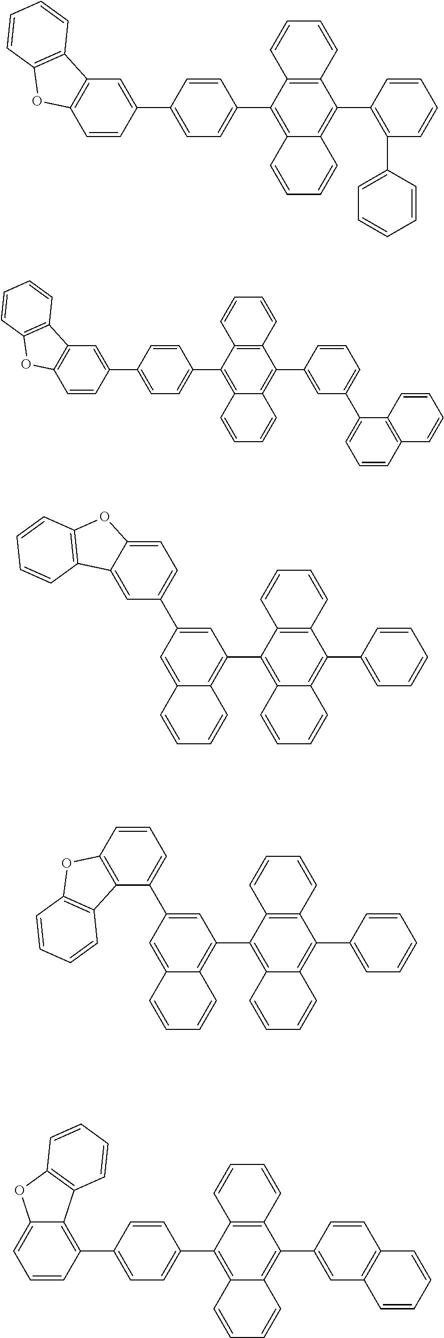 [SMILES: c1ccc(-c2ccccc2-c2c3ccccc3c(-c3ccc(-c4ccc5oc6ccccc6c5c4)cc3)c3ccccc23)cc1 ; c1cc(-c2cccc3ccccc23)cc(-c2c3ccccc3c(-c3ccc(-c4ccc5oc6ccccc6c5c4)cc3)c3ccccc23)c1 ; c1ccc(-c2c3ccccc3c(-c3cc(-c4ccc5oc6ccccc6c5c4)cc4ccccc34)c3ccccc23)cc1 ; c1ccc(-c2c3ccccc3c(-c3cc(-c4cccc5oc6ccccc6c45)cc4ccccc34)c3ccccc23)cc1 ; c1ccc2cc(-c3c4ccccc4c(-c4ccc(-c5cccc6oc7ccccc7c56)cc4)c4ccccc34)ccc2c1]

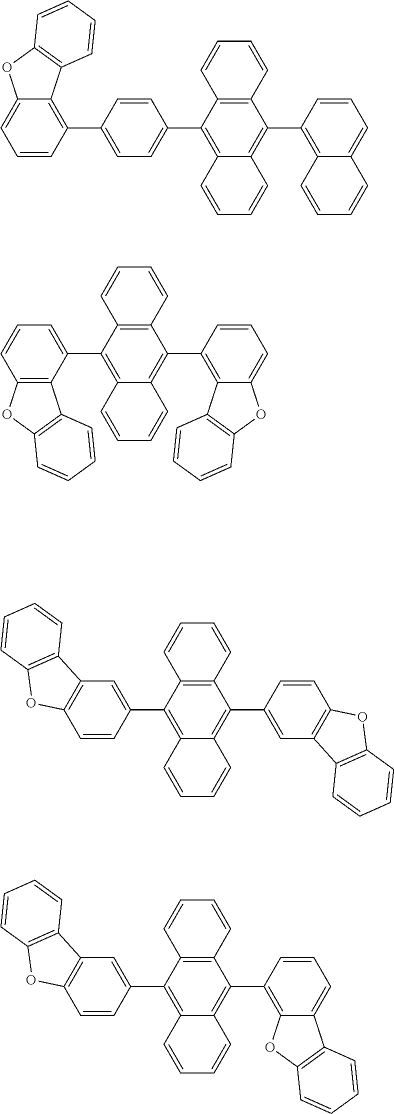 [SMILES: c1ccc2c(-c3c4ccccc4c(-c4ccc(-c5cccc6oc7ccccc7c56)cc4)c4ccccc34)cccc2c1 ; c1ccc2c(c1)oc1cccc(-c3c4ccccc4c(-c4cccc5oc6ccccc6c45)c4ccccc34)c12 ; c1ccc2c(c1)oc1ccc(-c3c4ccccc4c(-c4ccc5oc6ccccc6c5c4)c4ccccc34)cc12 ; c1ccc2c(c1)oc1ccc(-c3c4ccccc4c(-c4cccc5c4oc4ccccc45)c4ccccc34)cc12]

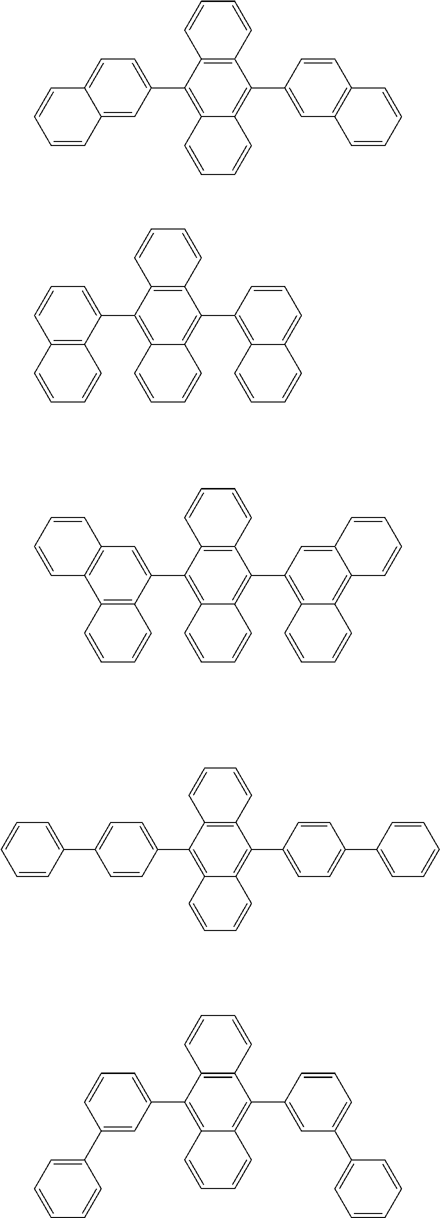

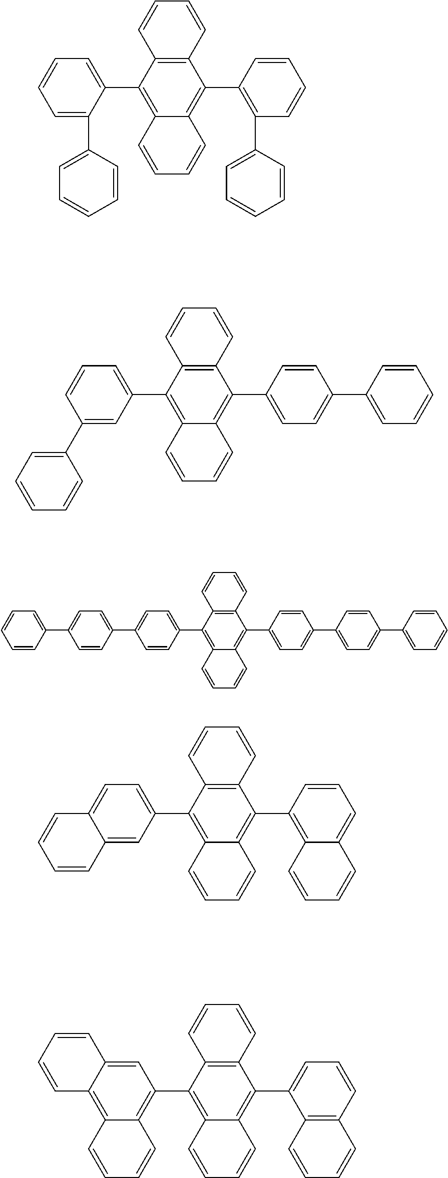

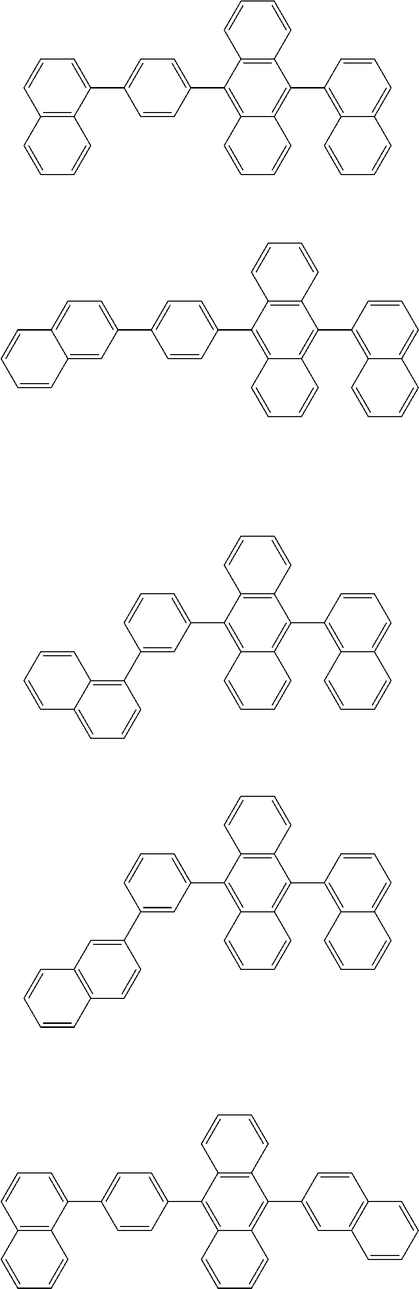

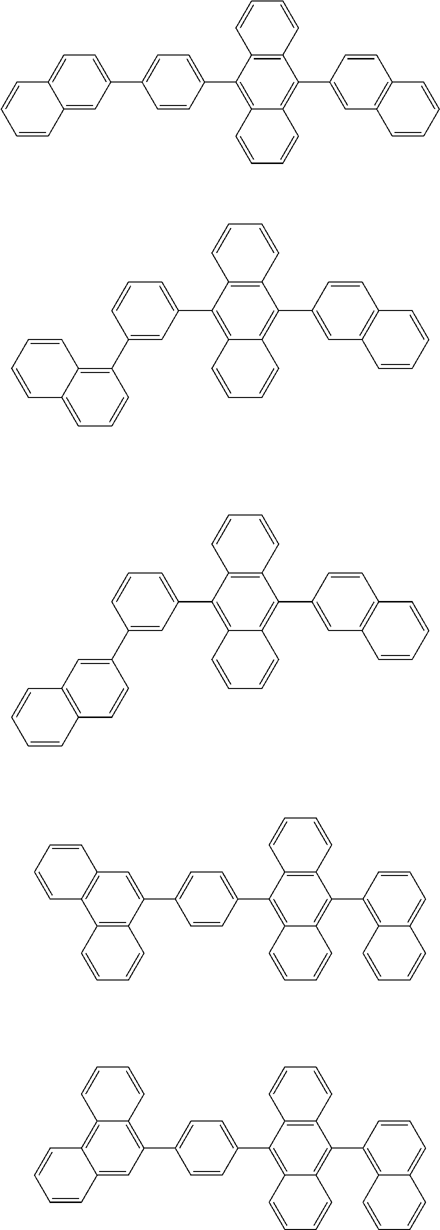

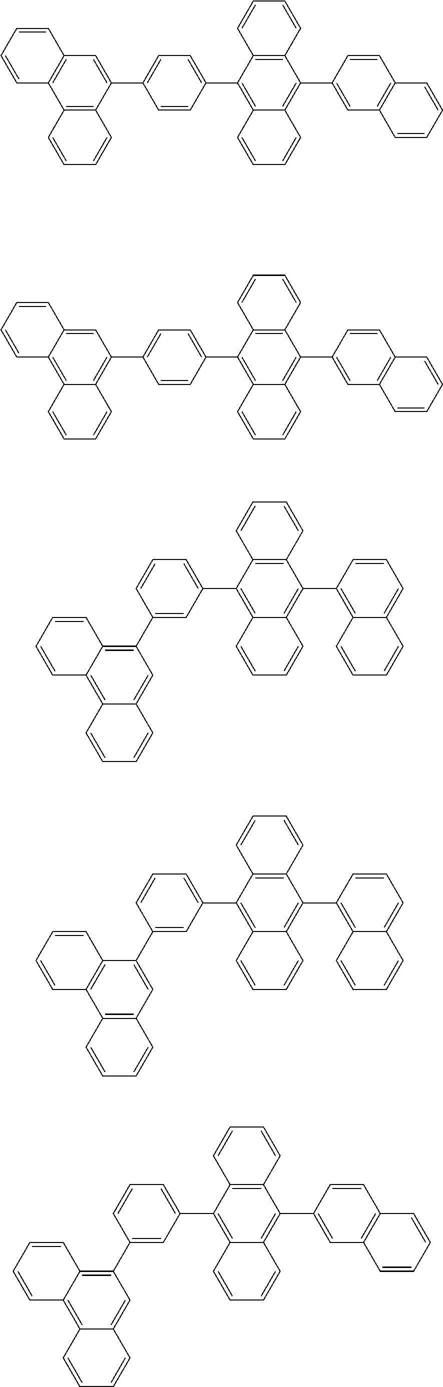

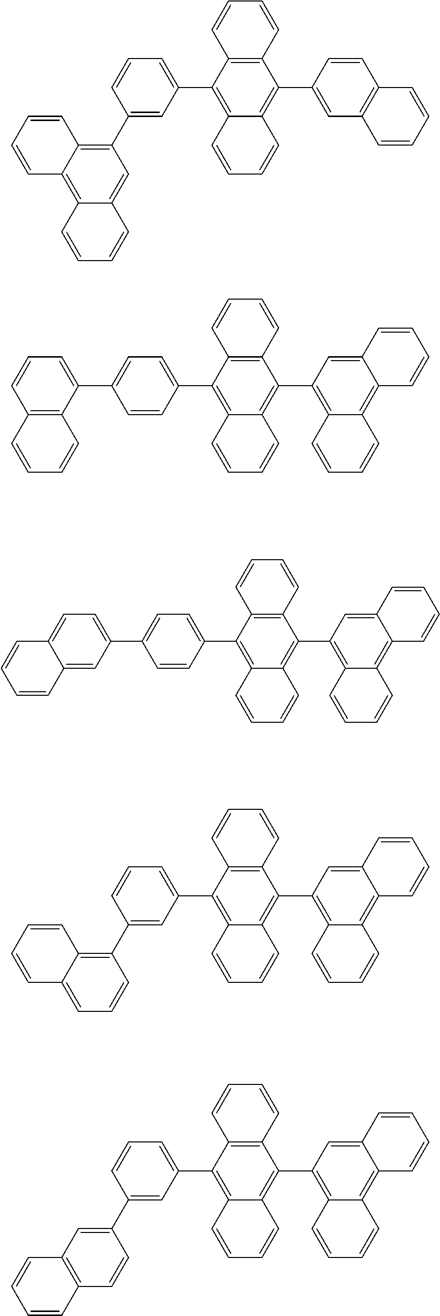

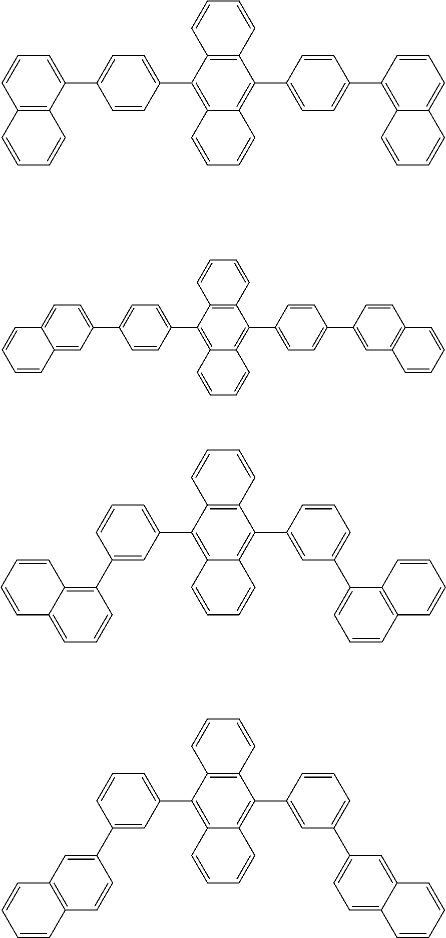

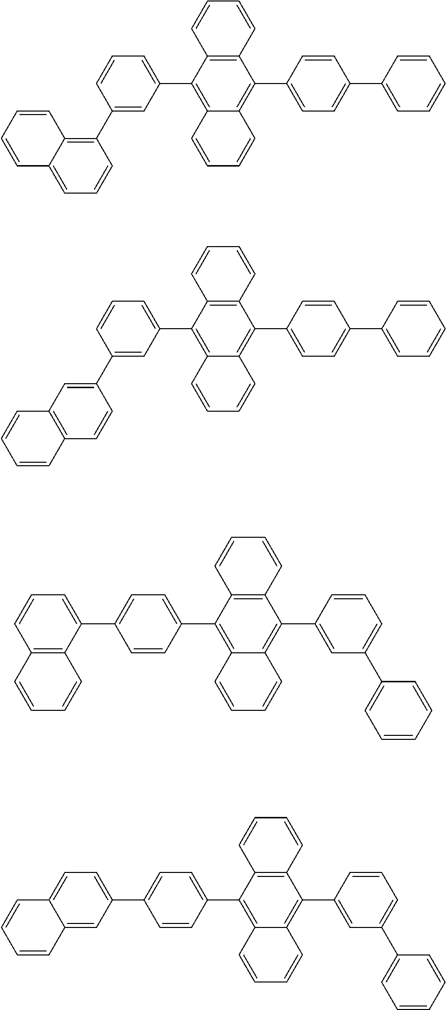

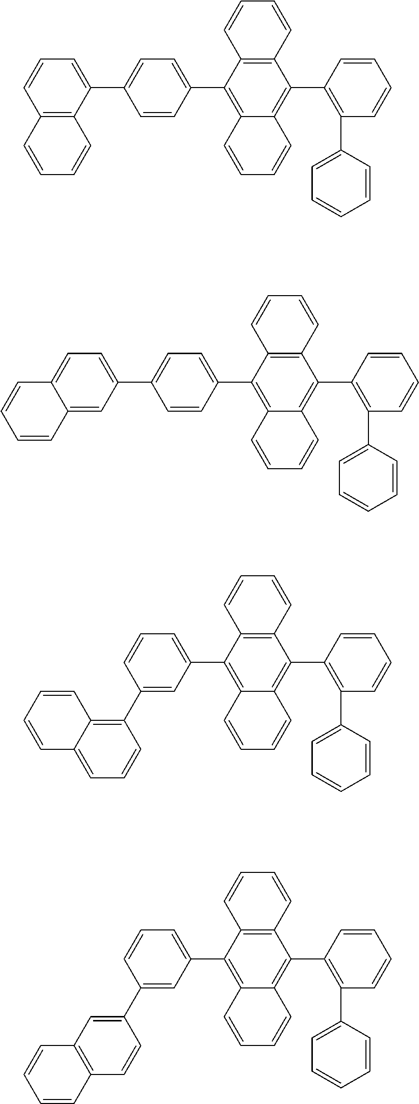

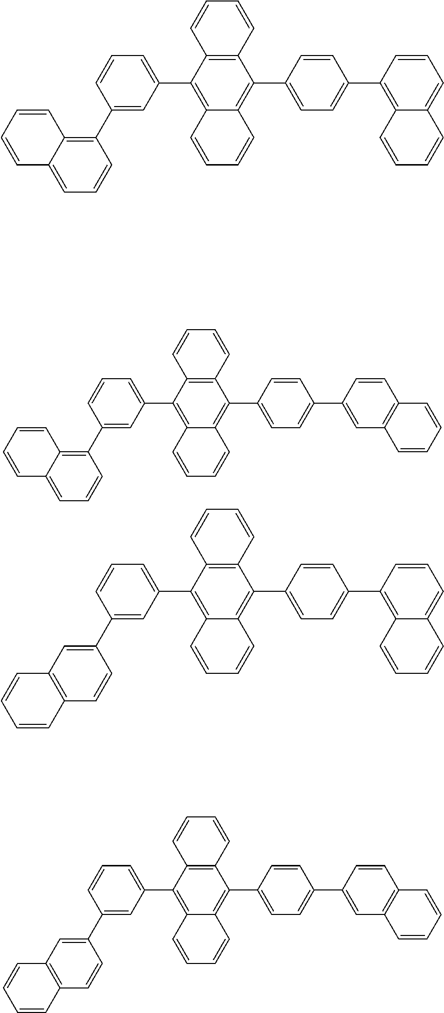

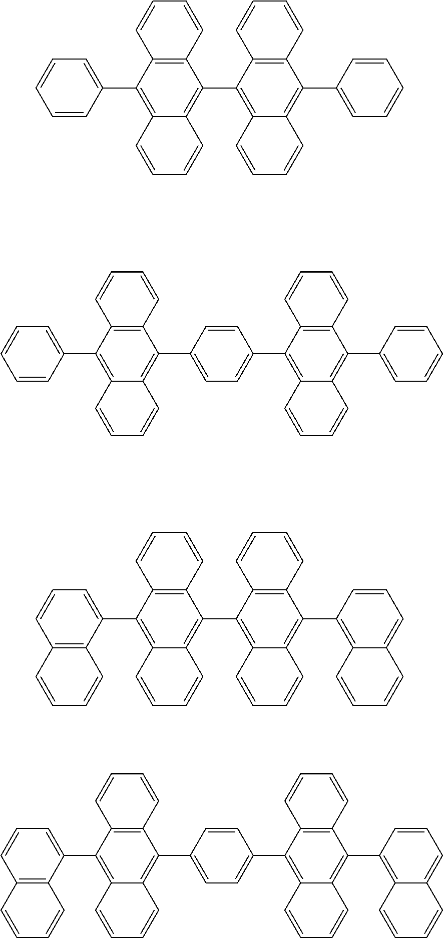

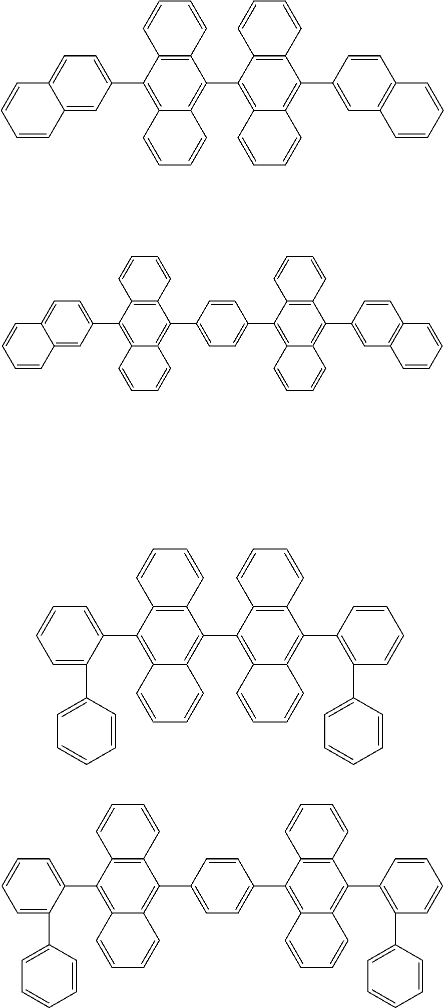

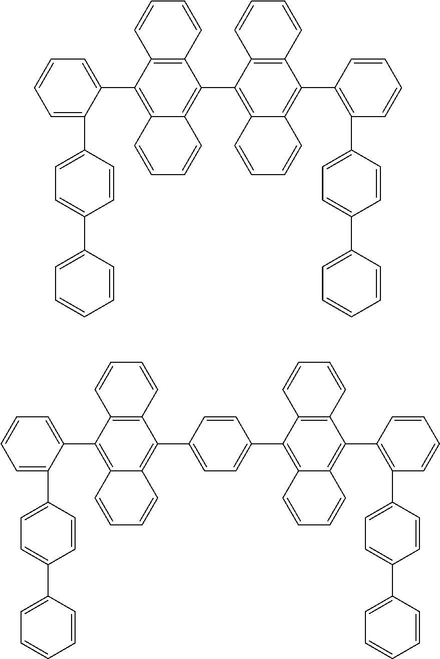

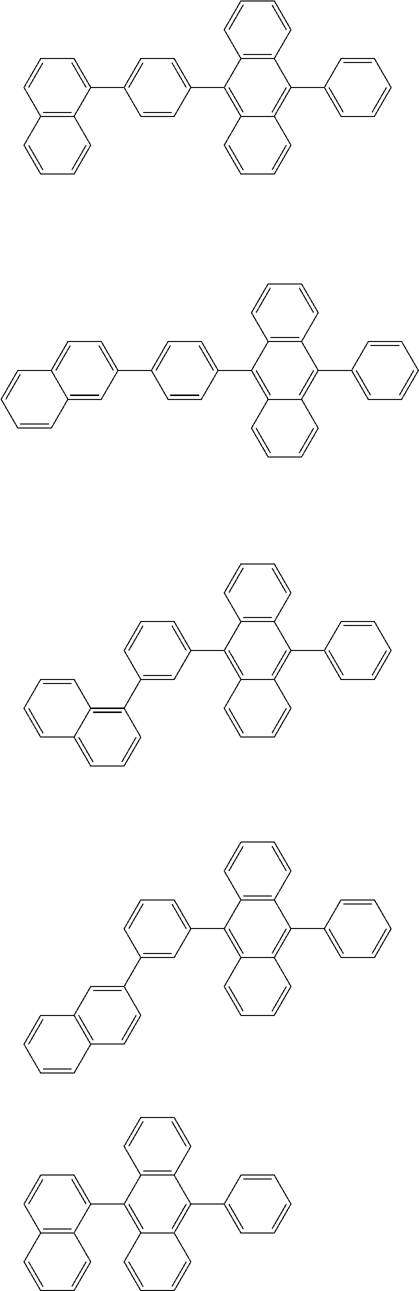

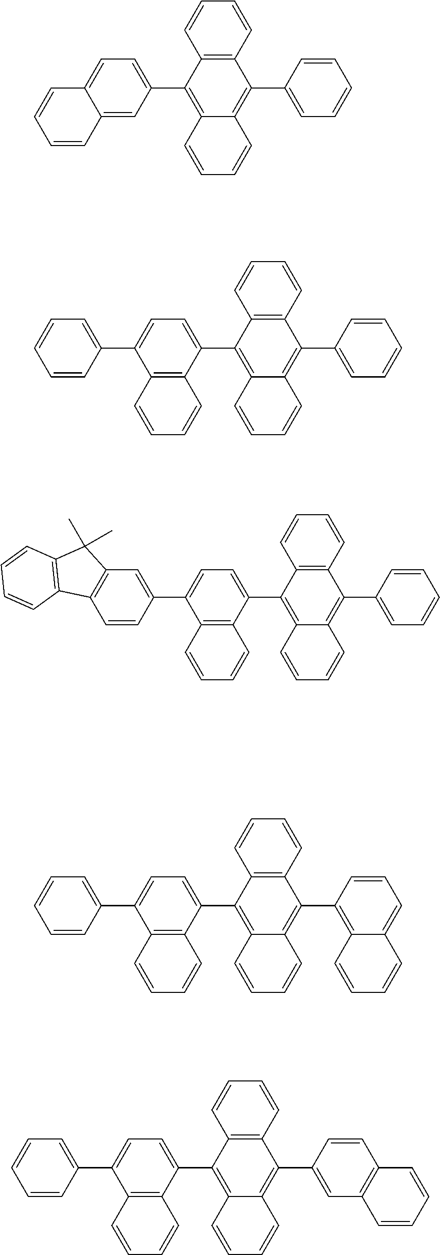

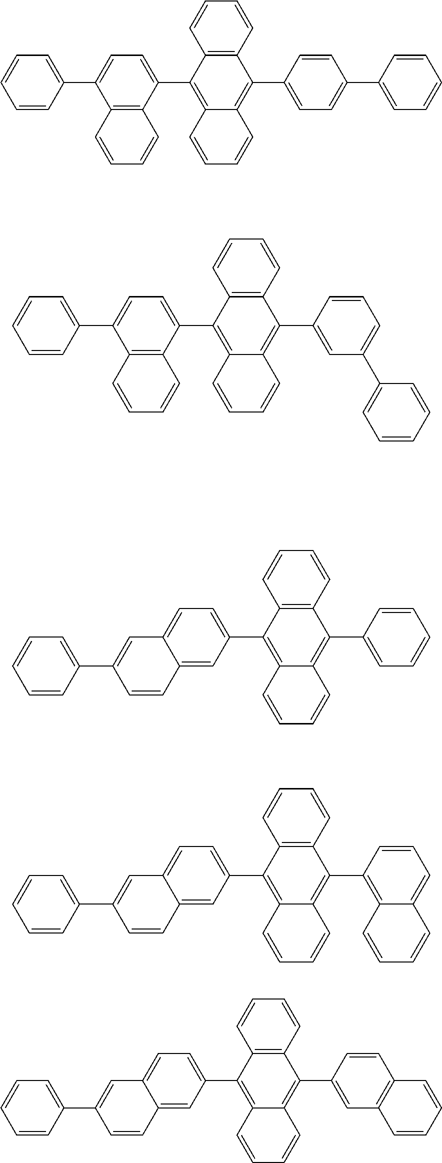

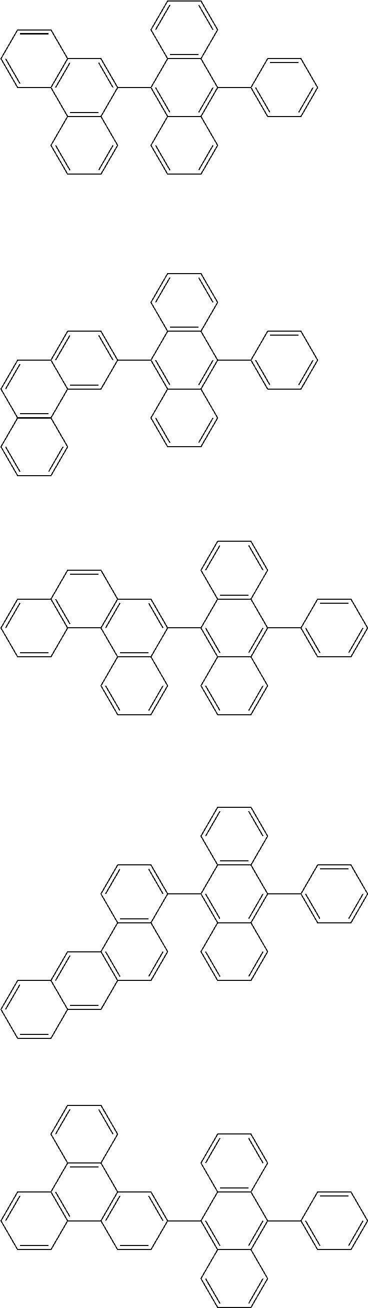

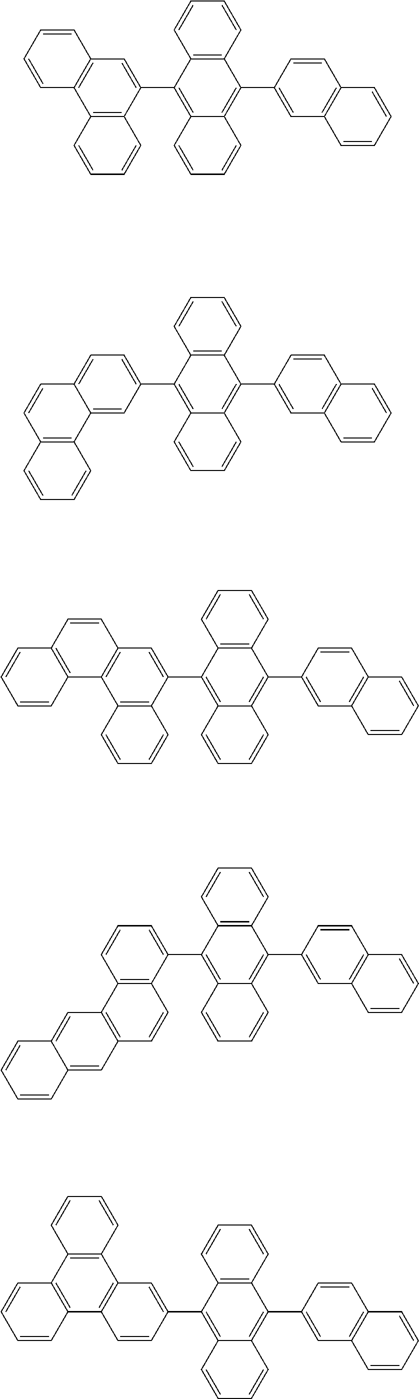

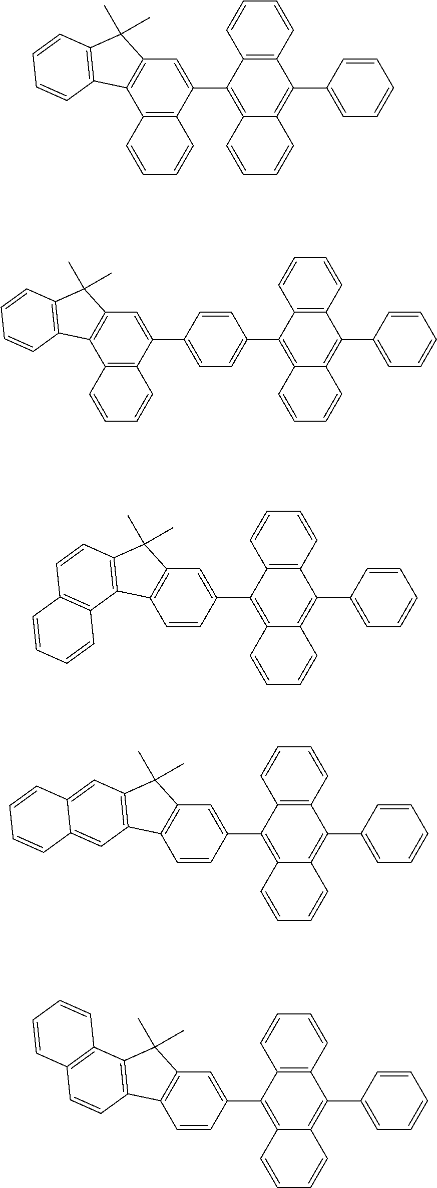

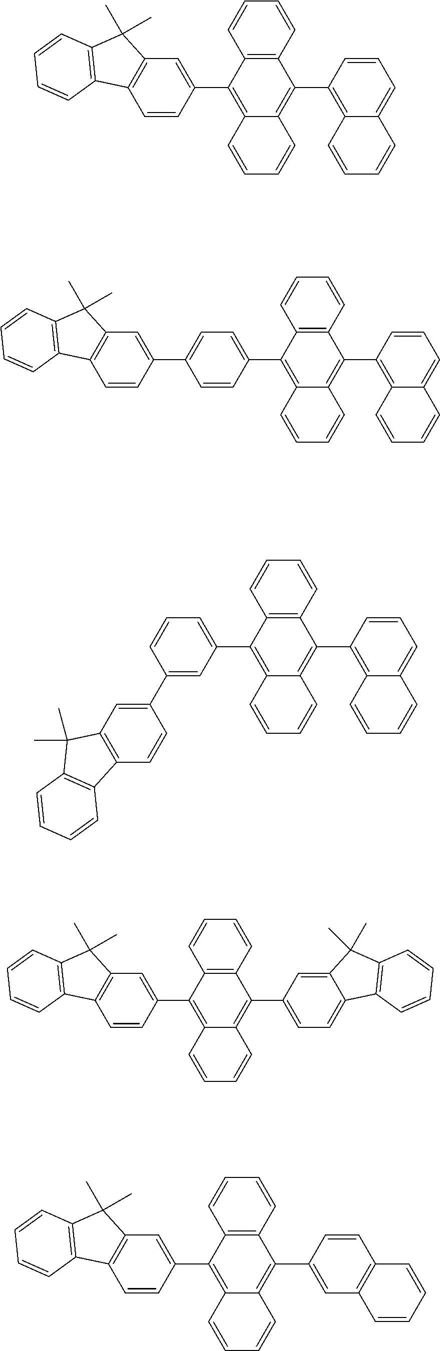

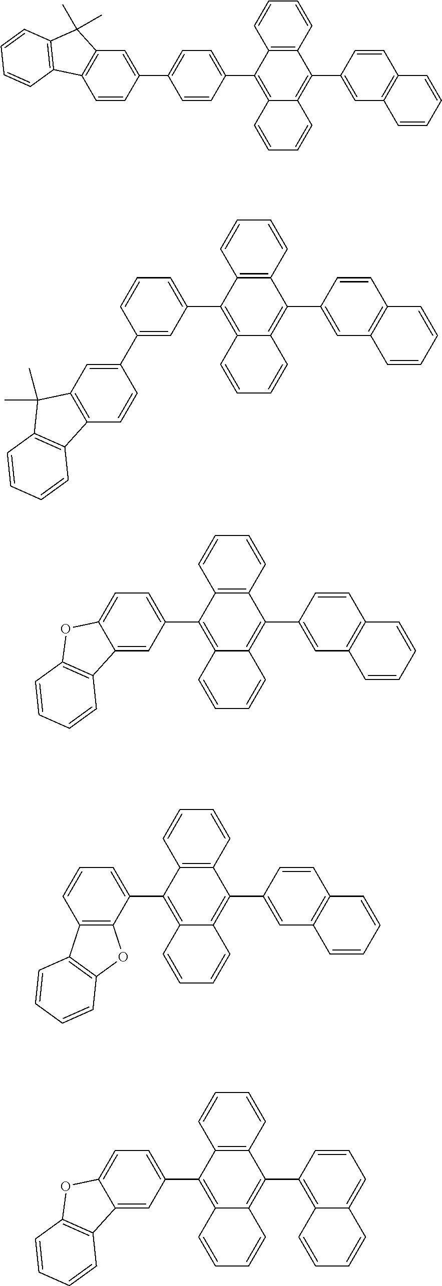

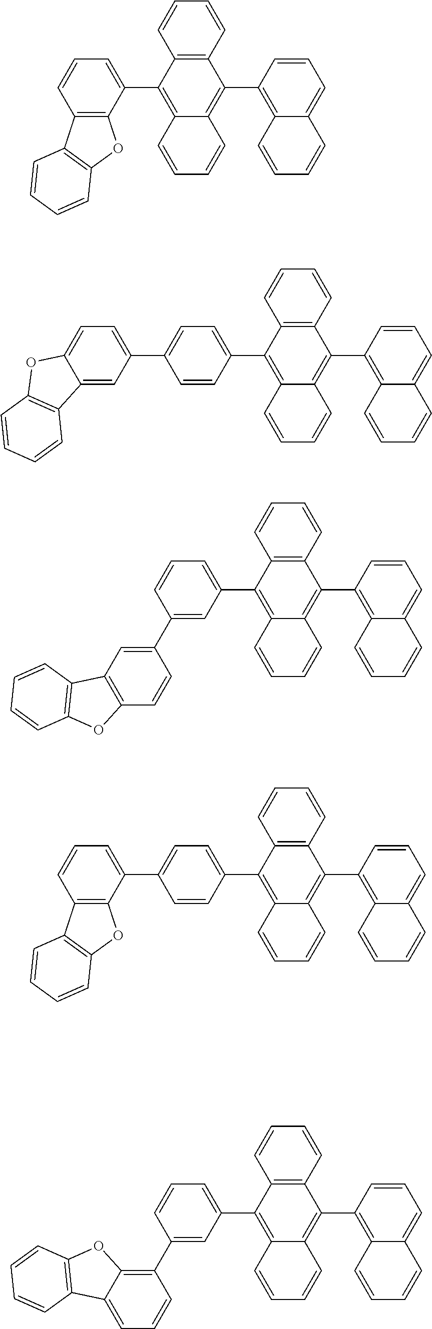 [SMILES: c1ccc2c(-c3c4ccccc4c(-c4cccc5c4oc4ccccc45)c4ccccc34)cccc2c1 ; c1ccc2c(-c3c4ccccc4c(-c4ccc(-c5ccc6oc7ccccc7c6c5)cc4)c4ccccc34)cccc2c1 ; c1cc(-c2ccc3oc4ccccc4c3c2)cc(-c2c3ccccc3c(-c3cccc4ccccc34)c3ccccc23)c1 ; c1ccc2c(-c3c4ccccc4c(-c4ccc(-c5cccc6c5oc5ccccc56)cc4)c4ccccc34)cccc2c1 ; c1cc(-c2c3ccccc3c(-c3cccc4ccccc34)c3ccccc23)cc(-c2cccc3c2oc2ccccc23)c1]

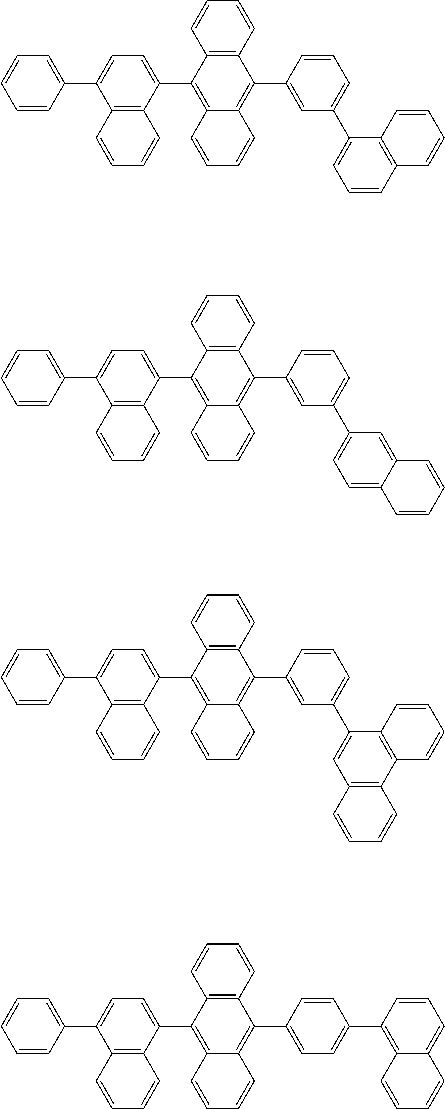

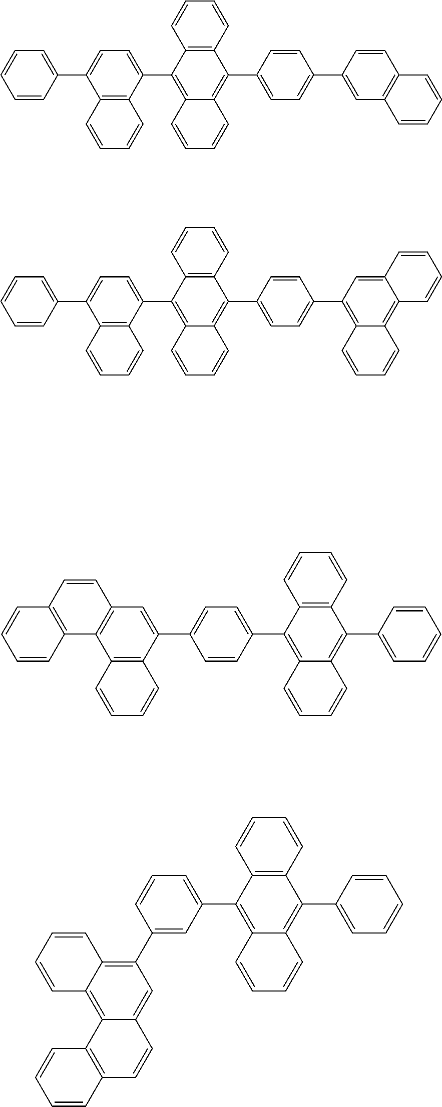

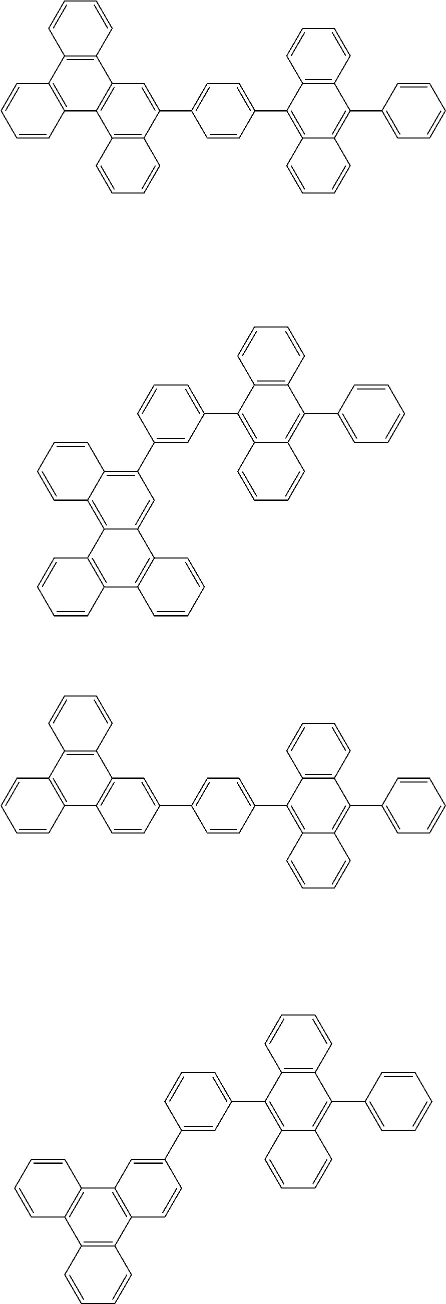

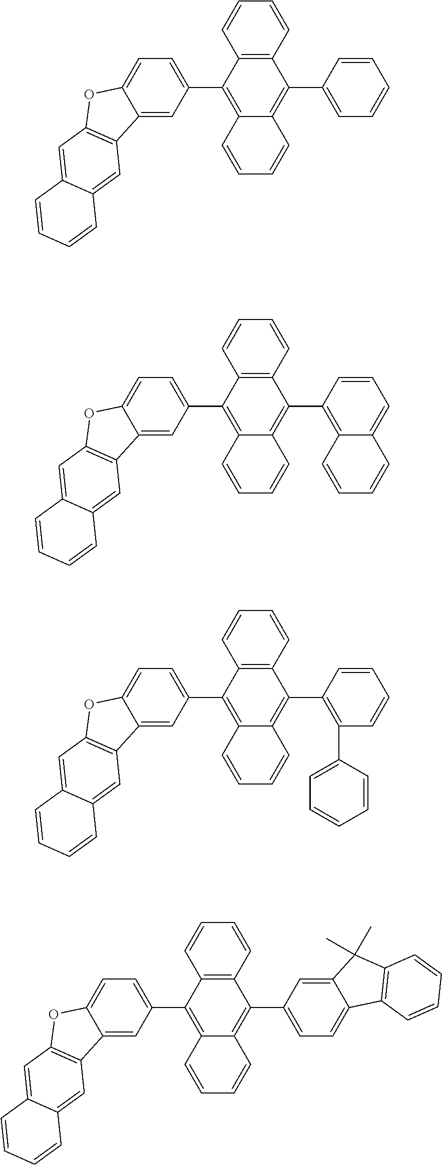 [SMILES: c1ccc(-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cccc5ccccc45)c4ccccc24)cc13 ; c1ccc(-c2ccccc2-c2c3ccccc3c(-c3ccc4oc5cc6ccccc6cc5c4c3)c3ccccc23)cc1 ; CC1(C)c2ccccc2-c2ccc(-c3c4ccccc4c(-c4ccc5oc6cc7ccccc7cc6c5c4)c4ccccc34)cc21]

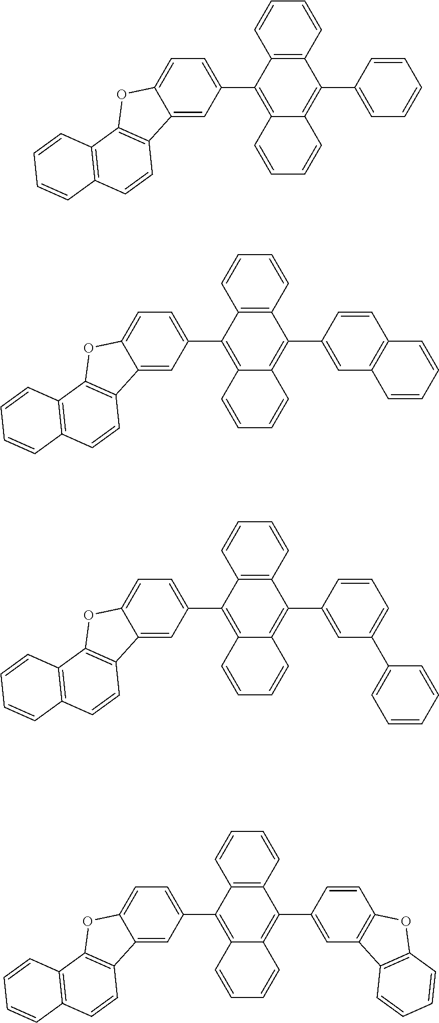 [SMILES: c1ccc(-c2c3ccccc3c(-c3ccc4oc5c6ccccc6ccc5c4c3)c3ccccc23)cc1 ; c1ccc2cc(-c3c4ccccc4c(-c4ccc5oc6c7ccccc7ccc6c5c4)c4ccccc34)ccc2c1 ; c1ccc(-c2cccc(-c3c4ccccc4c(-c4ccc5oc6c7ccccc7ccc6c5c4)c4ccccc34)c2)cc1 ; c1ccc2c(c1)ccc1c3cc(-c4c5ccccc5c(-c5ccc6oc7ccccc7c6c5)c5ccccc45)ccc3oc21]

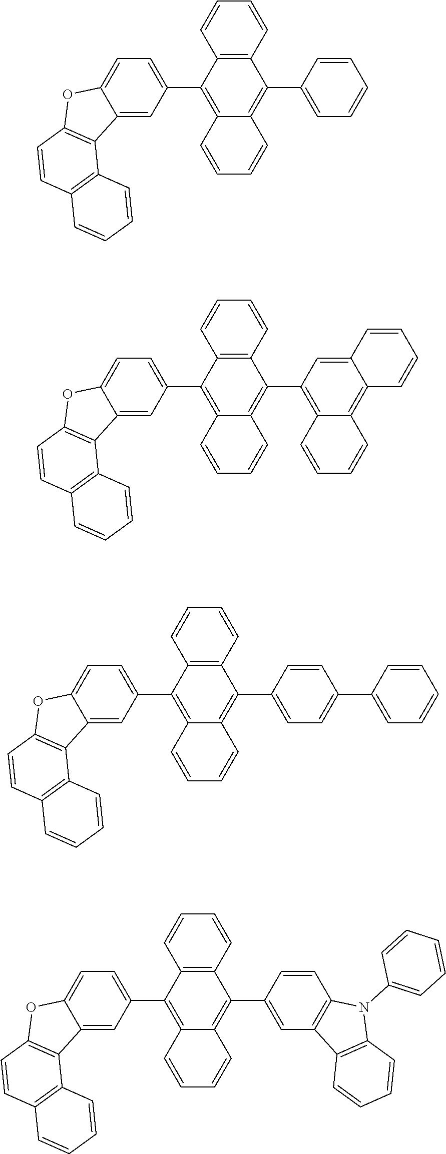 [SMILES: c1ccc(-c2c3ccccc3c(-c3ccc4oc5ccc6ccccc6c5c4c3)c3ccccc23)cc1 ; c1ccc2c(c1)cc(-c1c3ccccc3c(-c3ccc4oc5ccc6ccccc6c5c4c3)c3ccccc13)c1ccccc12 ; c1ccc(-c2ccc(-c3c4ccccc4c(-c4ccc5oc6ccc7ccccc7c6c5c4)c4ccccc34)cc2)cc1 ; c1ccc(-n2c3ccccc3c3cc(-c4c5ccccc5c(-c5ccc6oc7ccc8ccccc8c7c6c5)c5ccccc45)ccc32)cc1]

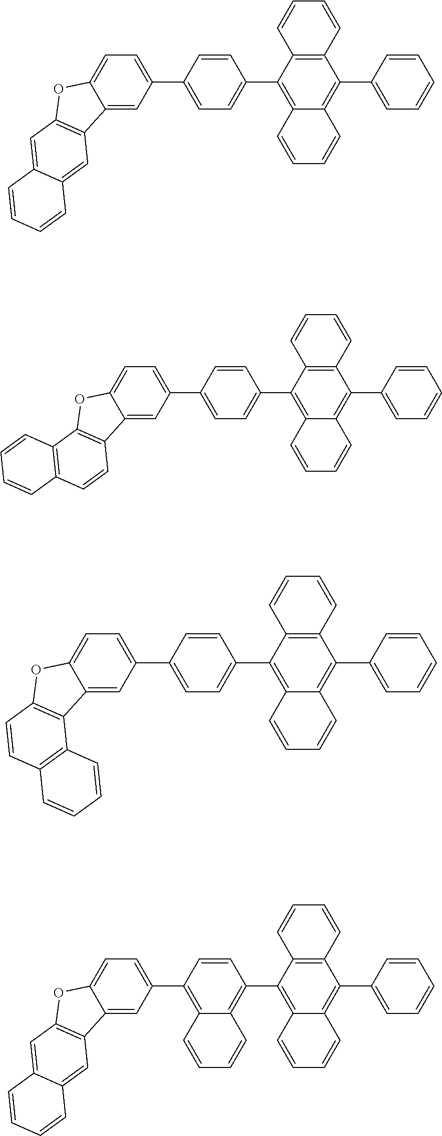 [SMILES: c1ccc(-c2c3ccccc3c(-c3ccc(-c4ccc5oc6cc7ccccc7cc6c5c4)cc3)c3ccccc23)cc1 ; c1ccc(-c2c3ccccc3c(-c3ccc(-c4ccc5oc6c7ccccc7ccc6c5c4)cc3)c3ccccc23)cc1 ; c1ccc(-c2c3ccccc3c(-c3ccc(-c4ccc5oc6ccc7ccccc7c6c5c4)cc3)c3ccccc23)cc1 ; c1ccc(-c2c3ccccc3c(-c3ccc(-c4ccc5oc6cc7ccccc7cc6c5c4)c4ccccc34)c3ccccc23)cc1]

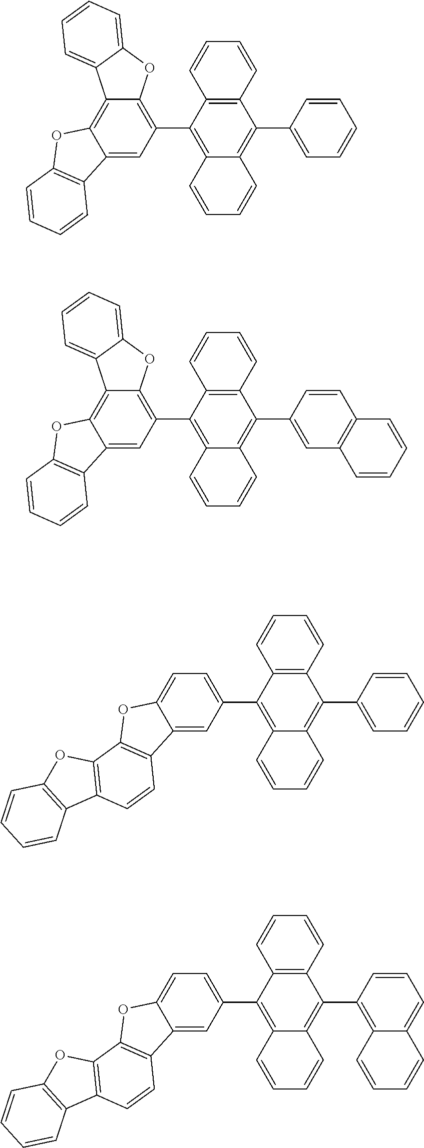 [SMILES: c1ccc(-c2c3ccccc3c(-c3cc4c5ccccc5oc4c4c3oc3ccccc34)c3ccccc23)cc1 ; c1ccc2cc(-c3c4ccccc4c(-c4cc5c6ccccc6oc5c5c4oc4ccccc45)c4ccccc34)ccc2c1 ; c1ccc(-c2c3ccccc3c(-c3ccc4oc5c(ccc6c7ccccc7oc65)c4c3)c3ccccc23)cc1 ; c1ccc2c(-c3c4ccccc4c(-c4ccc5oc6c(ccc7c8ccccc8oc76)c5c4)c4ccccc34)cccc2c1]

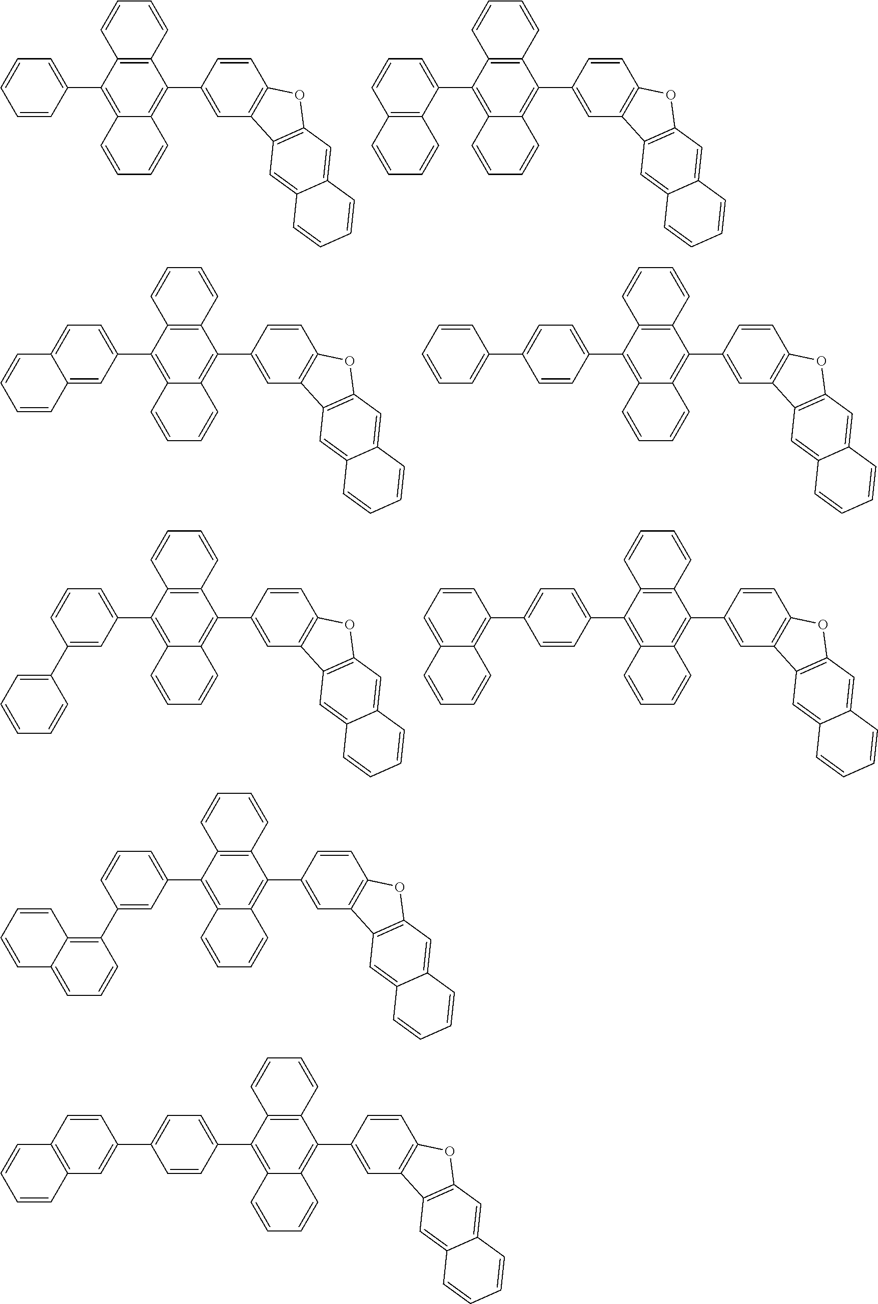

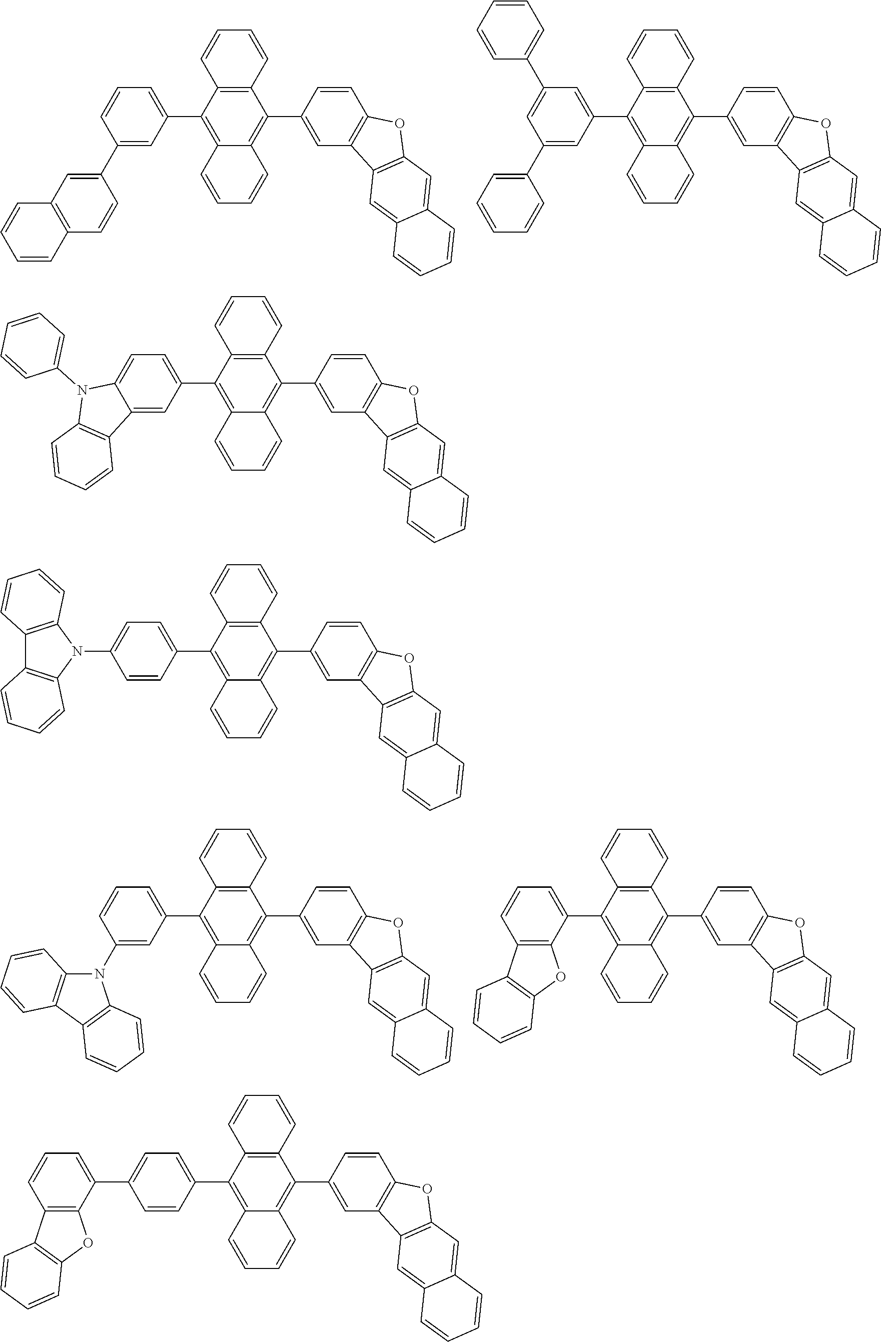

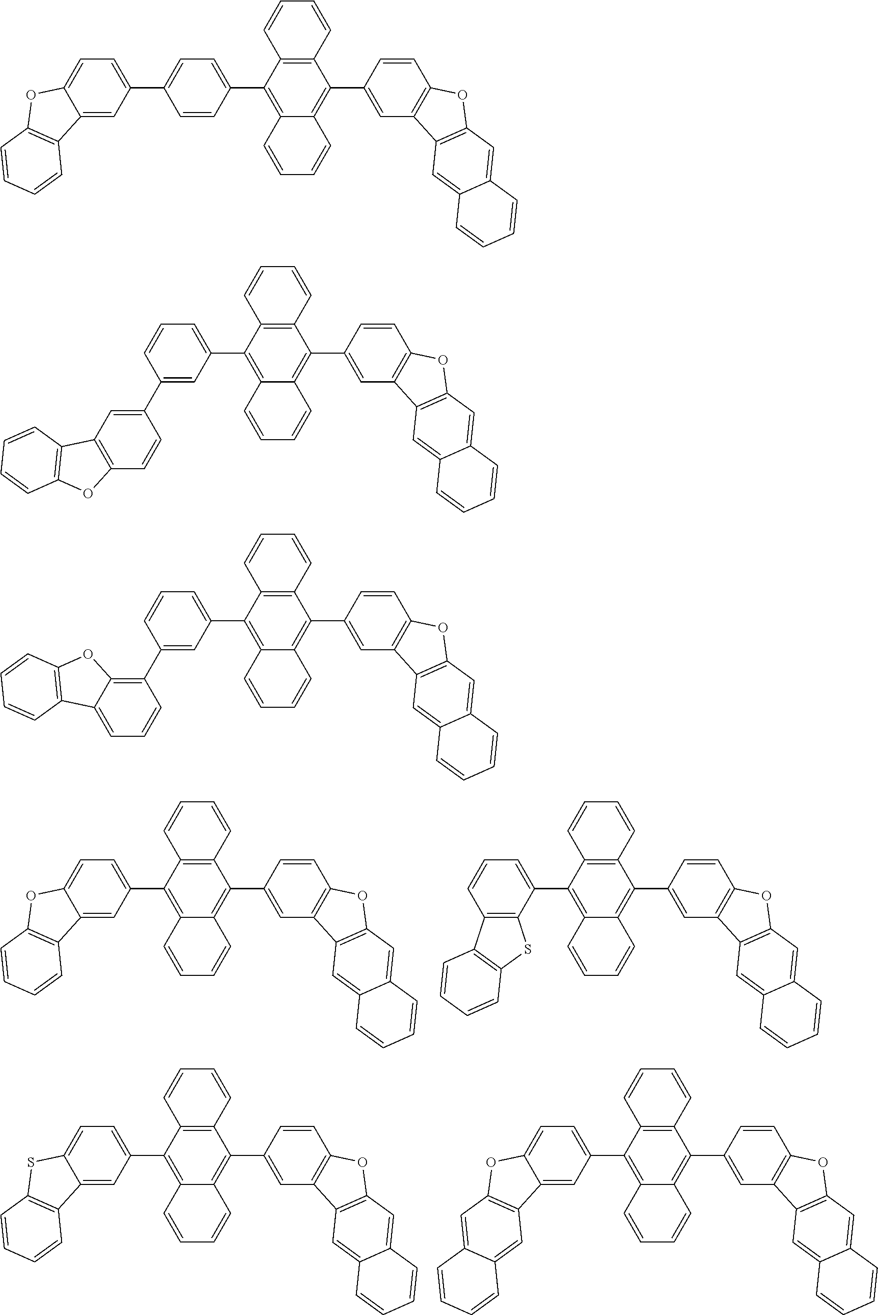

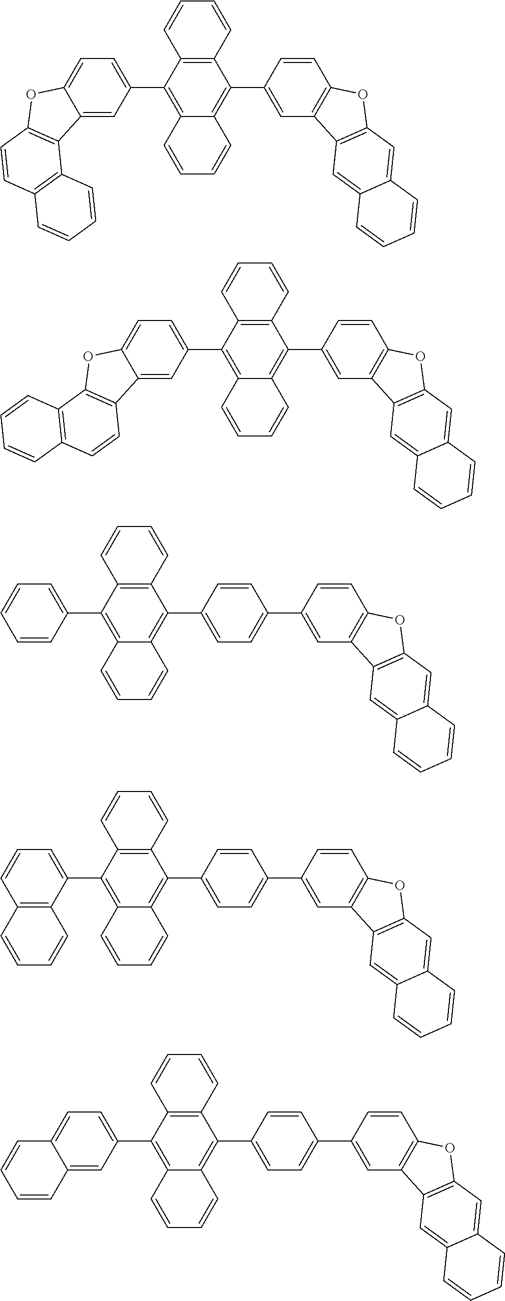 [SMILES: c1ccc2cc3c(cc2c1)oc1ccc(-c2c4ccccc4c(-c4ccc5oc6ccc7ccccc7c6c5c4)c4ccccc24)cc13 ; c1ccc2cc3c(cc2c1)oc1ccc(-c2c4ccccc4c(-c4ccc5oc6c7ccccc7ccc6c5c4)c4ccccc24)cc13 ; c1ccc(-c2c3ccccc3c(-c3ccc(-c4ccc5oc6cc7ccccc7cc6c5c4)cc3)c3ccccc23)cc1 ; c1ccc2cc3c(cc2c1)oc1ccc(-c2ccc(-c4c5ccccc5c(-c5cccc6ccccc56)c5ccccc45)cc2)cc13 ; c1ccc2cc(-c3c4ccccc4c(-c4ccc(-c5ccc6oc7cc8ccccc8cc7c6c5)cc4)c4ccccc34)ccc2c1]

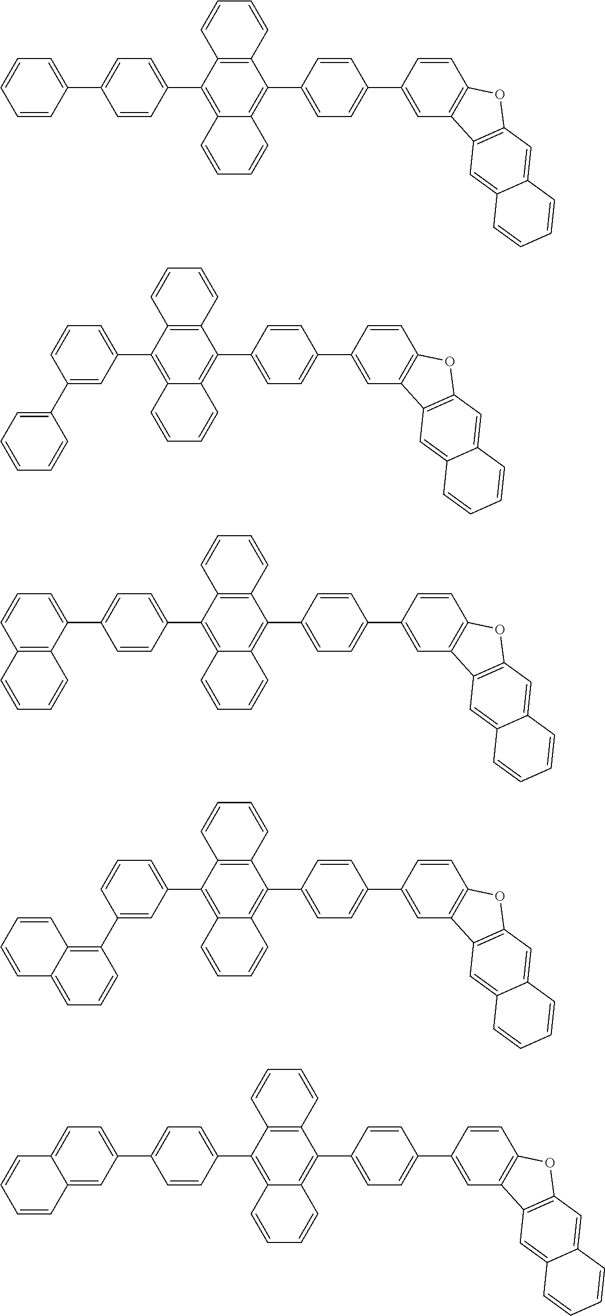 [SMILES: c1ccc(-c2ccc(-c3c4ccccc4c(-c4ccc(-c5ccc6oc7cc8ccccc8cc7c6c5)cc4)c4ccccc34)cc2)cc1 ; c1ccc(-c2cccc(-c3c4ccccc4c(-c4ccc(-c5ccc6oc7cc8ccccc8cc7c6c5)cc4)c4ccccc34)c2)cc1 ; c1ccc2cc3c(cc2c1)oc1ccc(-c2ccc(-c4c5ccccc5c(-c5ccc(-c6cccc7ccccc67)cc5)c5ccccc45)cc2)cc13 ; c1cc(-c2cccc3ccccc23)cc(-c2c3ccccc3c(-c3ccc(-c4ccc5oc6cc7ccccc7cc6c5c4)cc3)c3ccccc23)c1 ; c1ccc2cc(-c3ccc(-c4c5ccccc5c(-c5ccc(-c6ccc7oc8cc9ccccc9cc8c7c6)cc5)c5ccccc45)cc3)ccc2c1]

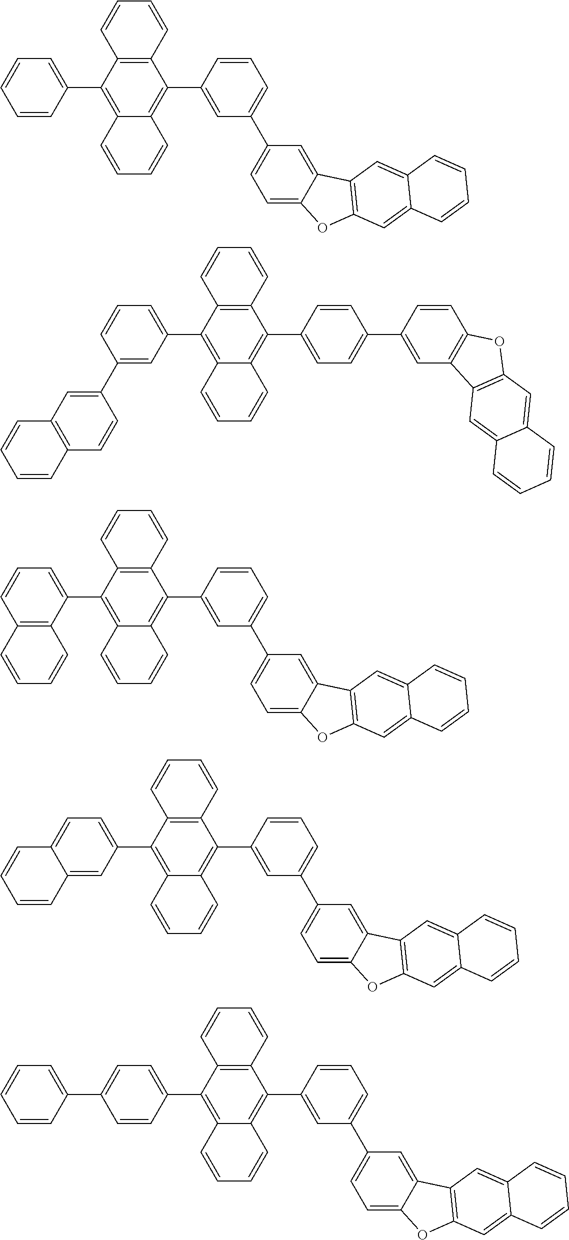 [SMILES: c1ccc(-c2c3ccccc3c(-c3cccc(-c4ccc5oc6cc7ccccc7cc6c5c4)c3)c3ccccc23)cc1 ; c1cc(-c2ccc3ccccc3c2)cc(-c2c3ccccc3c(-c3ccc(-c4ccc5oc6cc7ccccc7cc6c5c4)cc3)c3ccccc23)c1 ; c1cc(-c2ccc3oc4cc5ccccc5cc4c3c2)cc(-c2c3ccccc3c(-c3cccc4ccccc34)c3ccccc23)c1 ; c1cc(-c2ccc3oc4cc5ccccc5cc4c3c2)cc(-c2c3ccccc3c(-c3ccc4ccccc4c3)c3ccccc23)c1 ; c1ccc(-c2ccc(-c3c4ccccc4c(-c4cccc(-c5ccc6oc7cc8ccccc8cc7c6c5)c4)c4ccccc34)cc2)cc1]

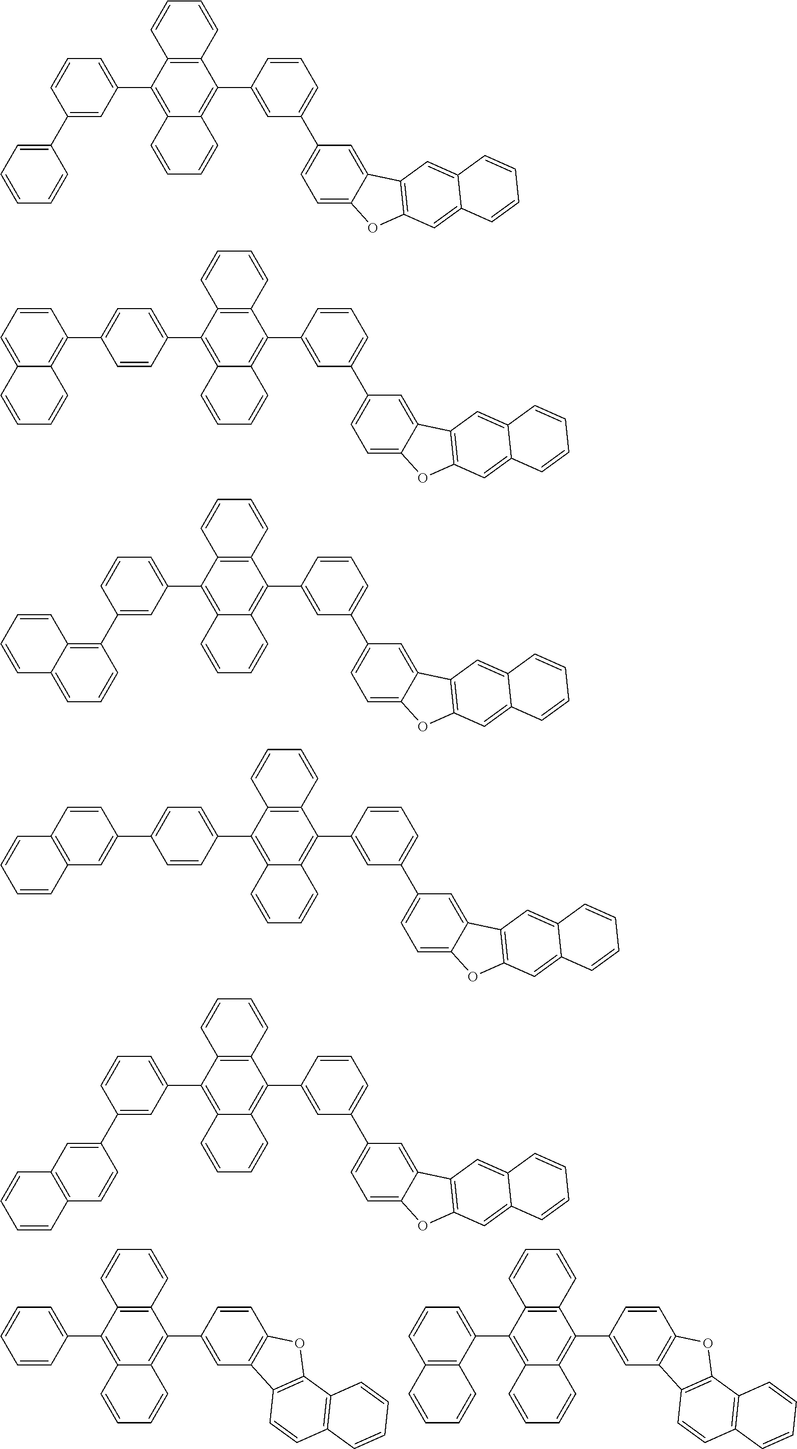

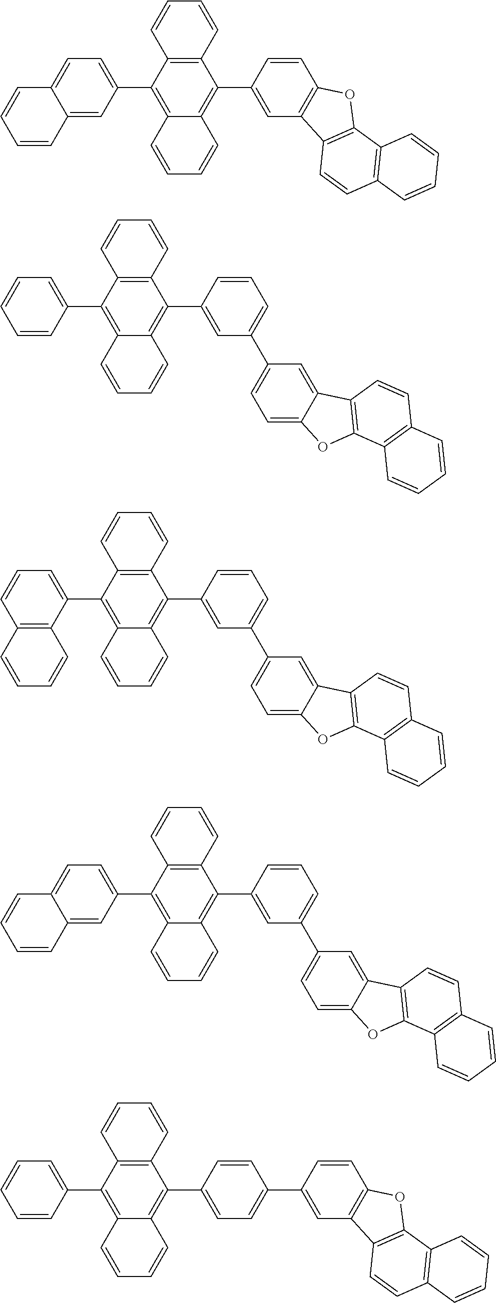 [SMILES: c1ccc2cc(-c3c4ccccc4c(-c4ccc5oc6c7ccccc7ccc6c5c4)c4ccccc34)ccc2c1 ; c1ccc(-c2c3ccccc3c(-c3cccc(-c4ccc5oc6c7ccccc7ccc6c5c4)c3)c3ccccc23)cc1 ; c1cc(-c2ccc3oc4c5ccccc5ccc4c3c2)cc(-c2c3ccccc3c(-c3cccc4ccccc34)c3ccccc23)c1 ; c1cc(-c2ccc3oc4c5ccccc5ccc4c3c2)cc(-c2c3ccccc3c(-c3ccc4ccccc4c3)c3ccccc23)c1 ; c1ccc(-c2c3ccccc3c(-c3ccc(-c4ccc5oc6c7ccccc7ccc6c5c4)cc3)c3ccccc23)cc1]

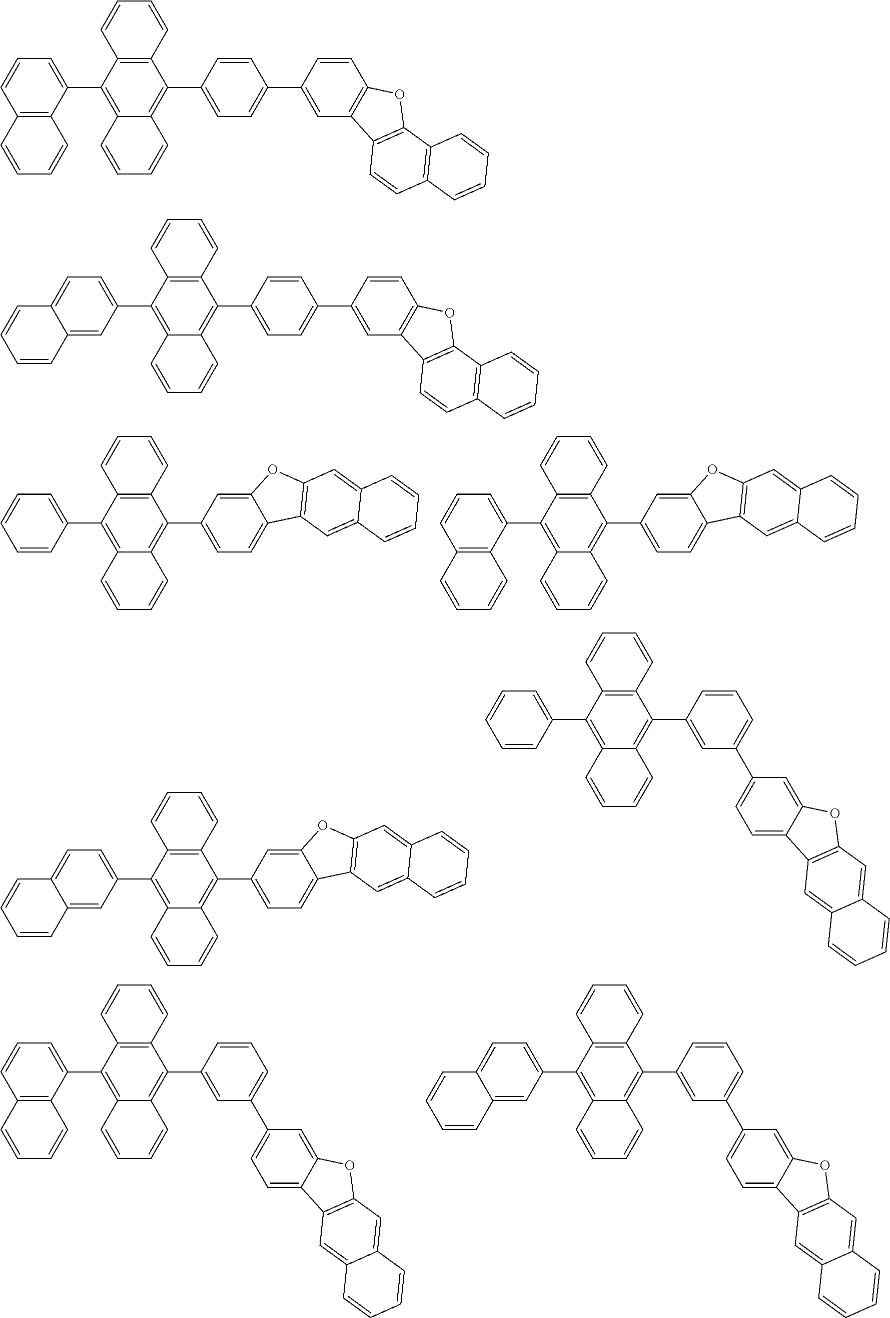

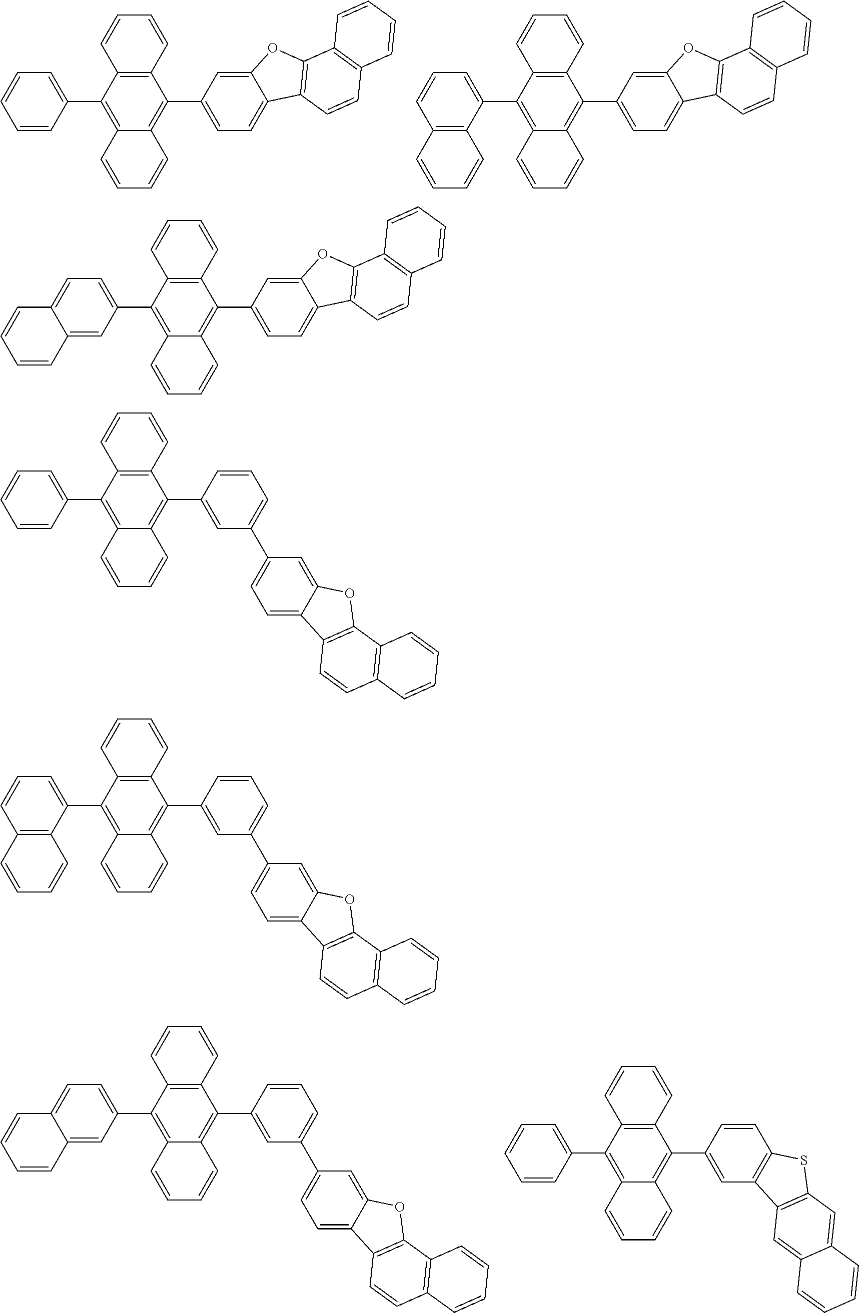

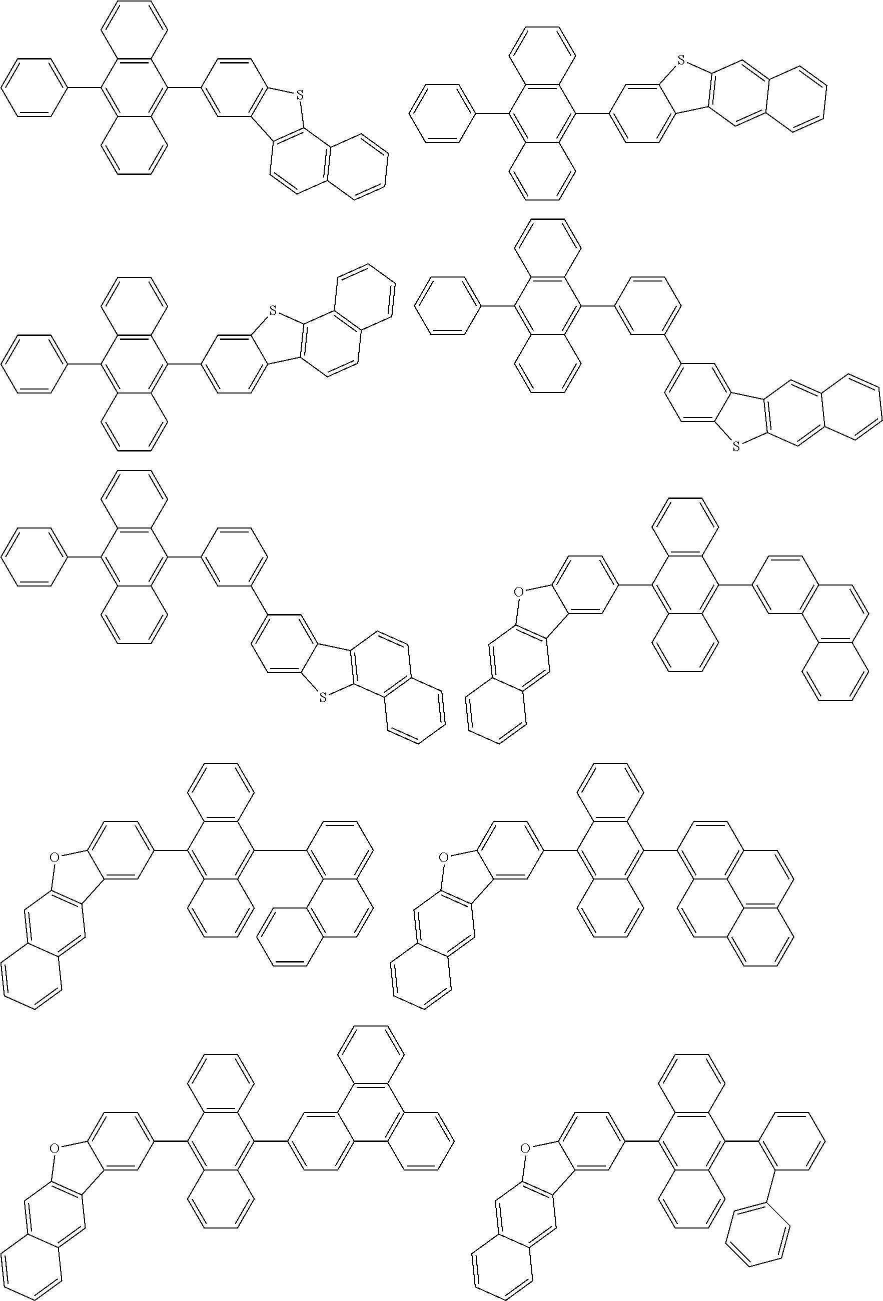

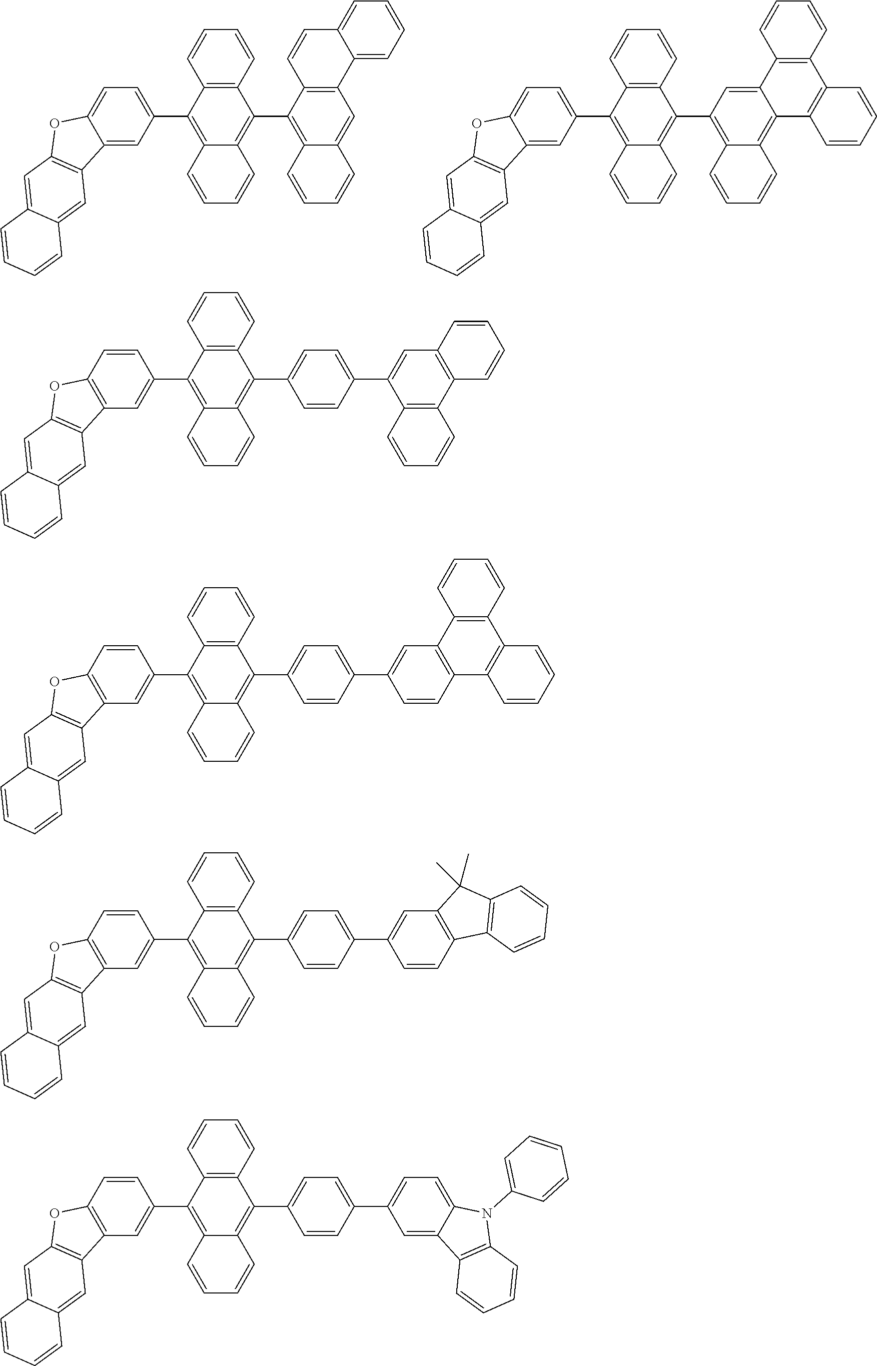

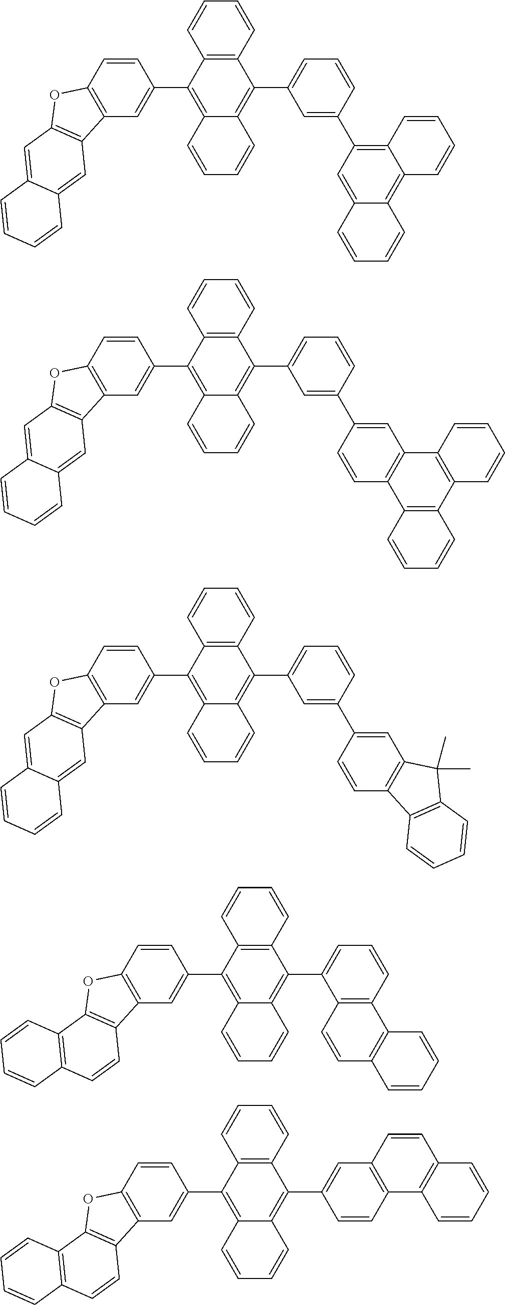

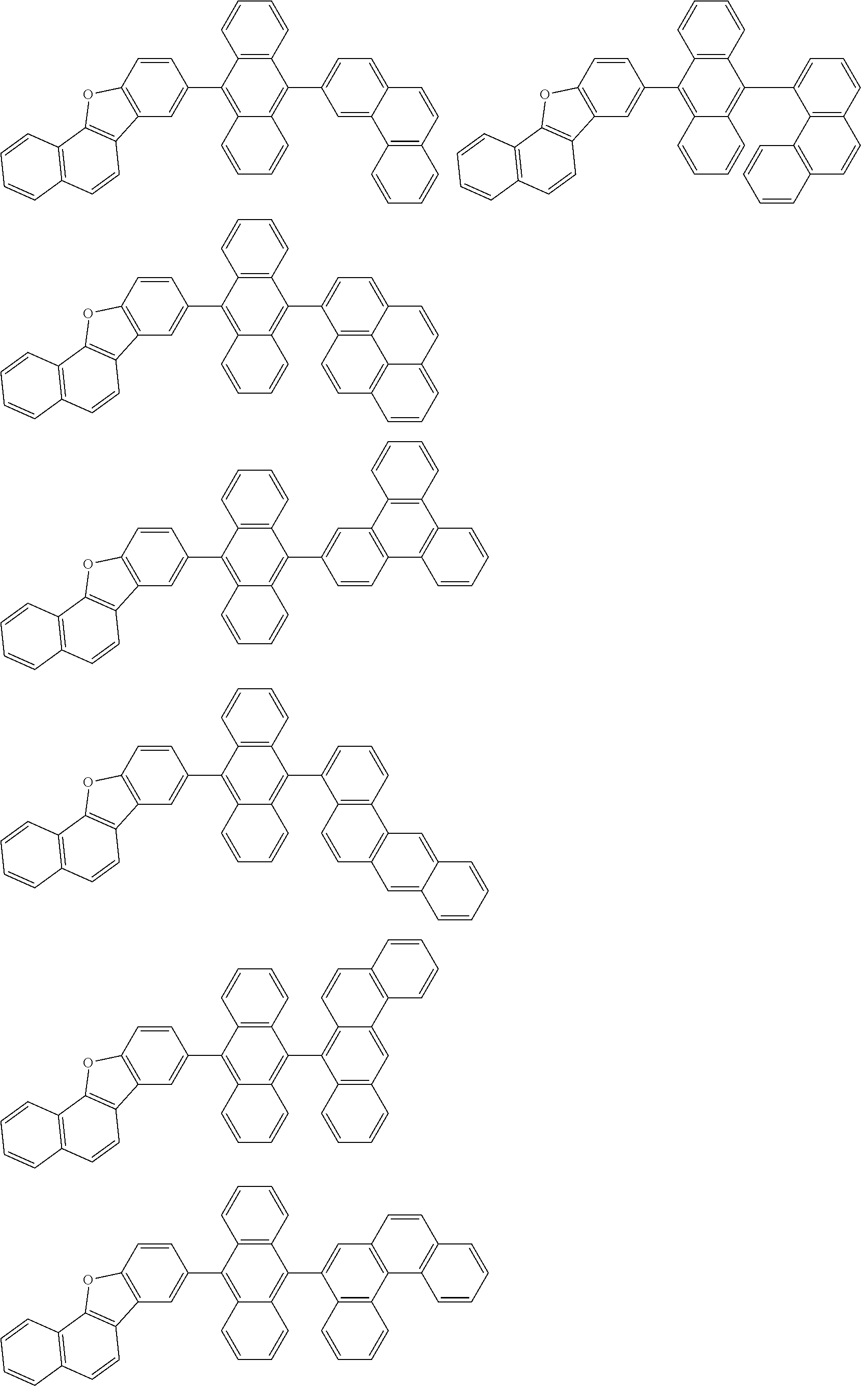

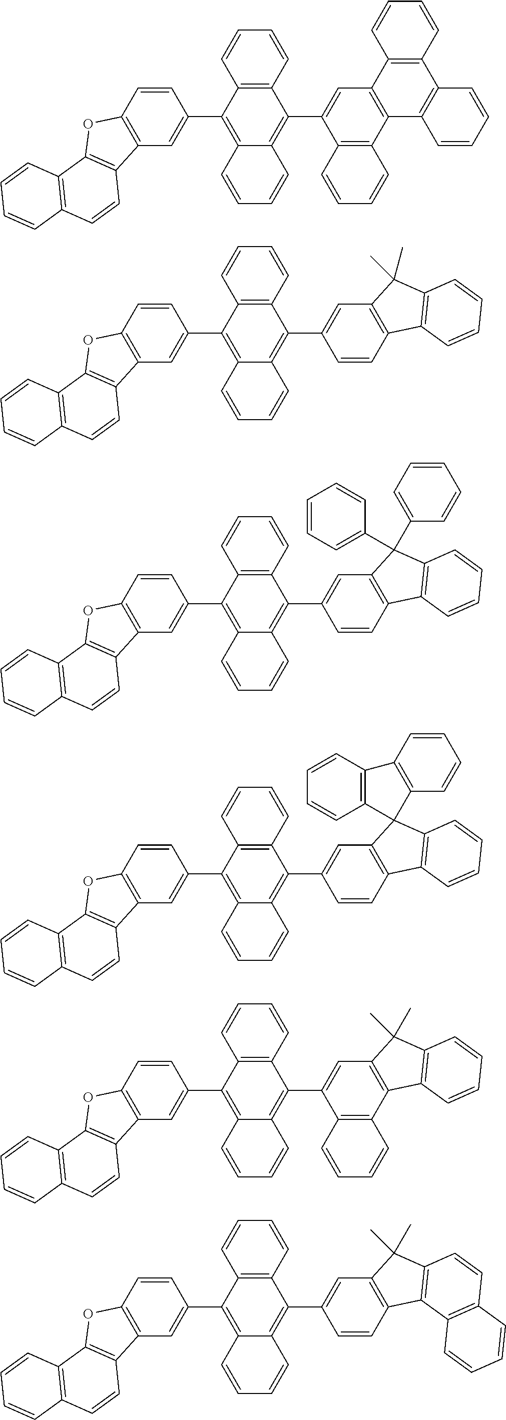

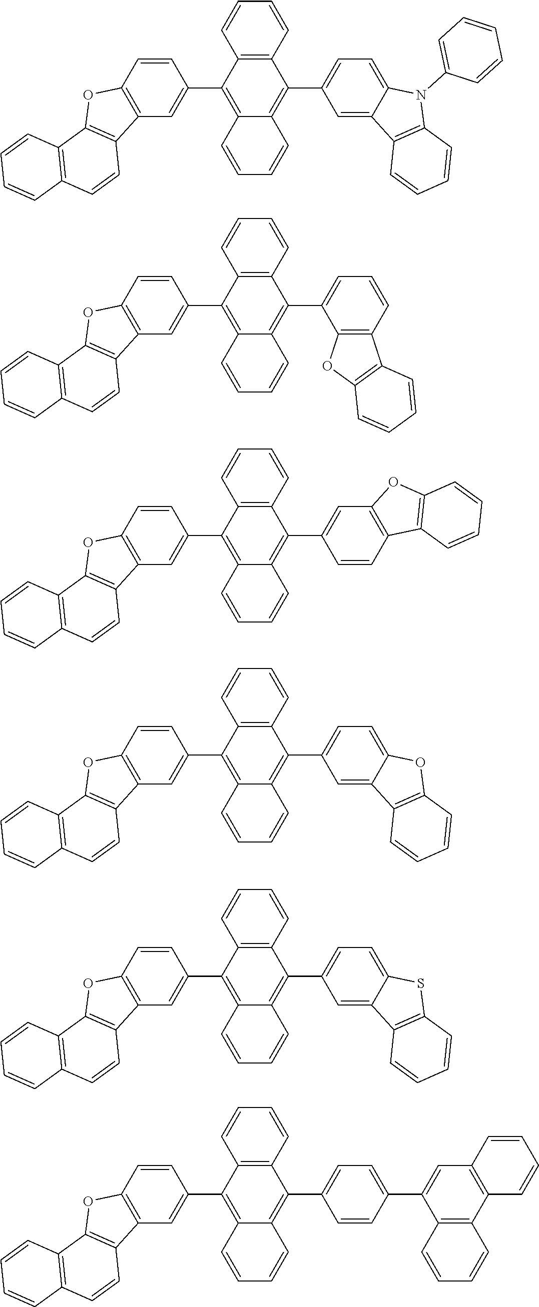

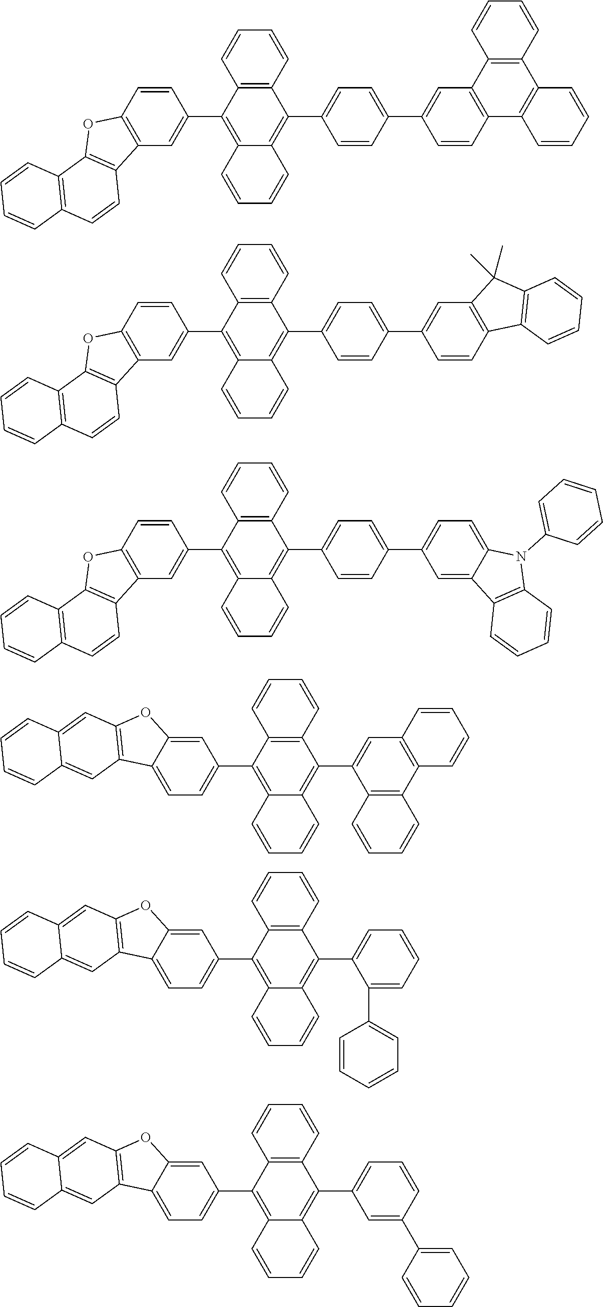

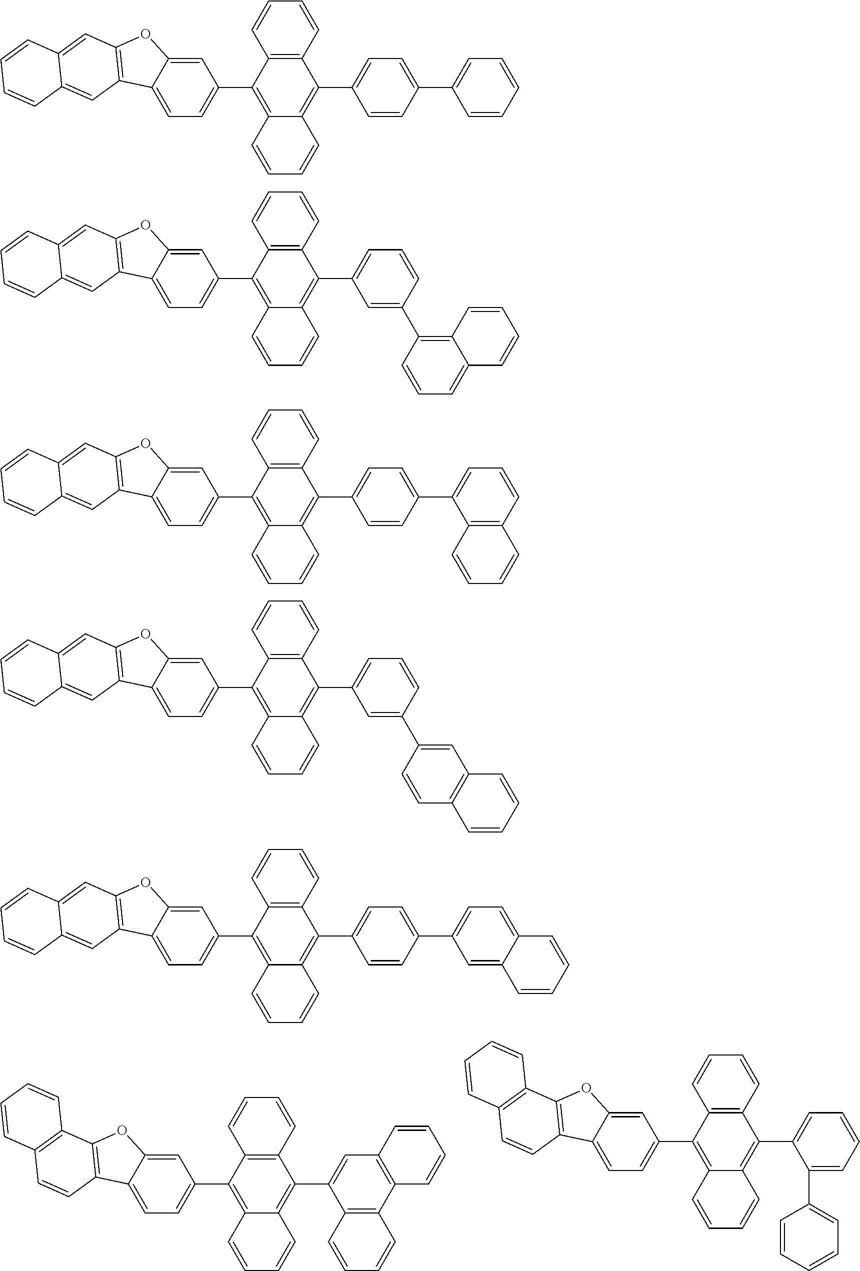

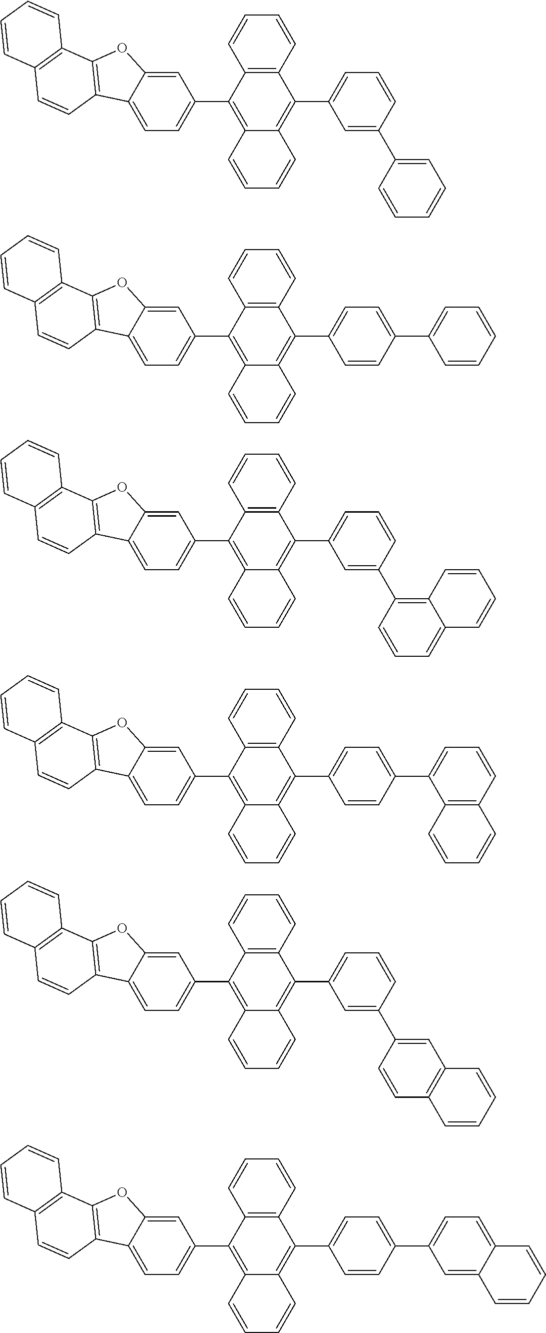

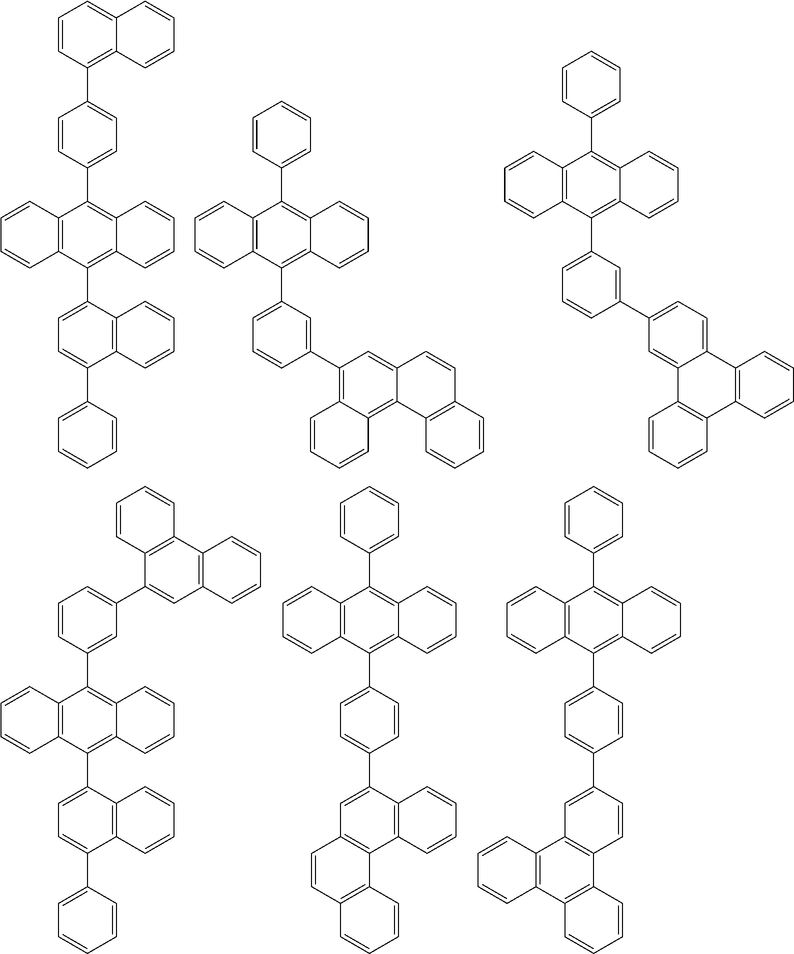

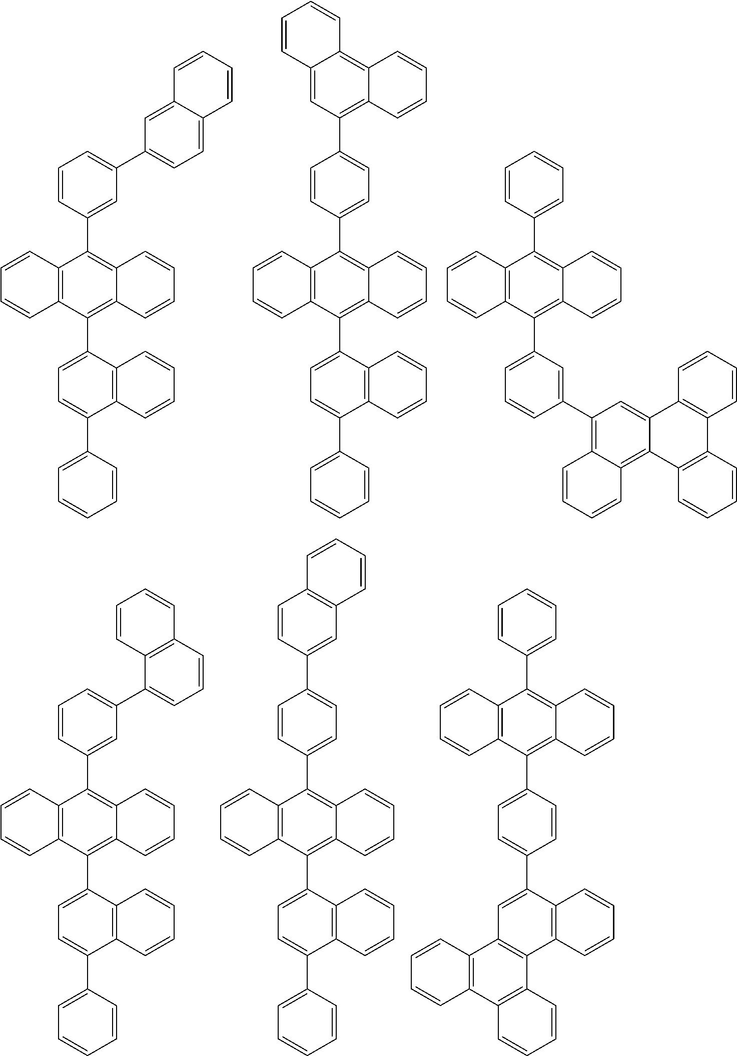

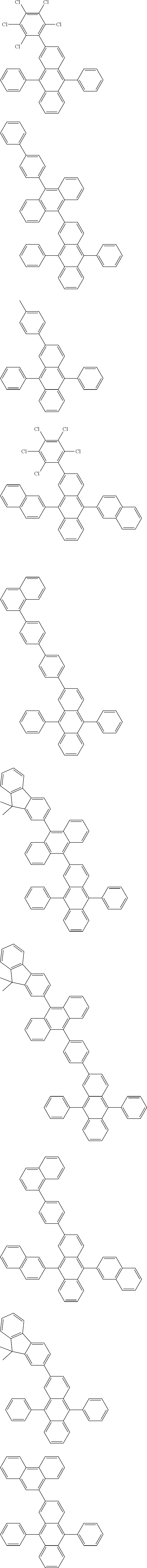

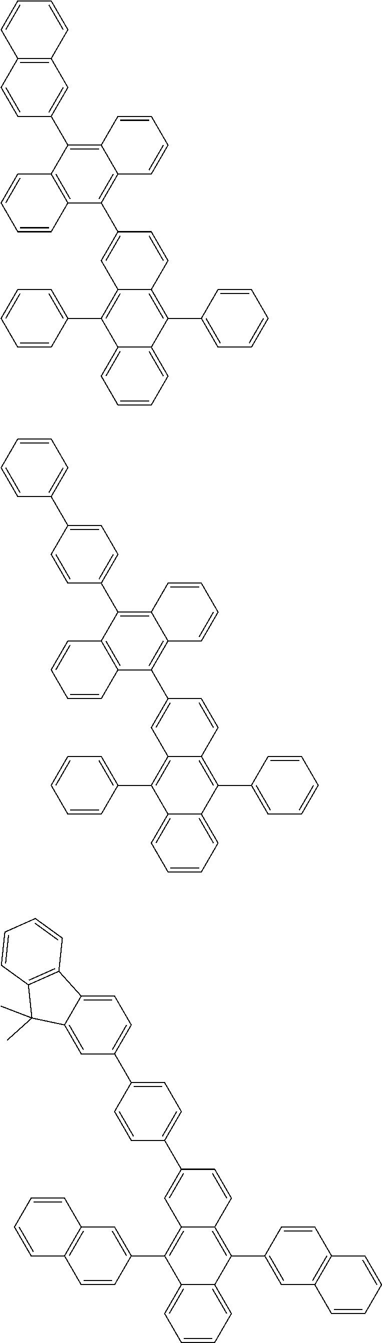

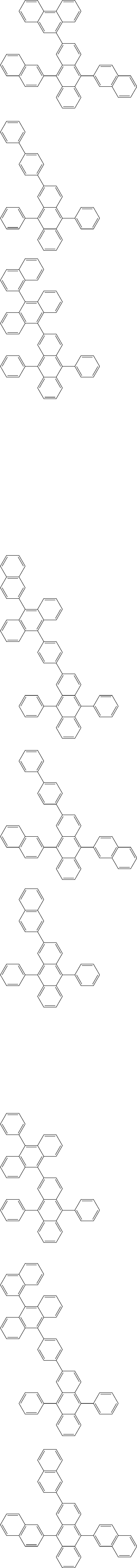

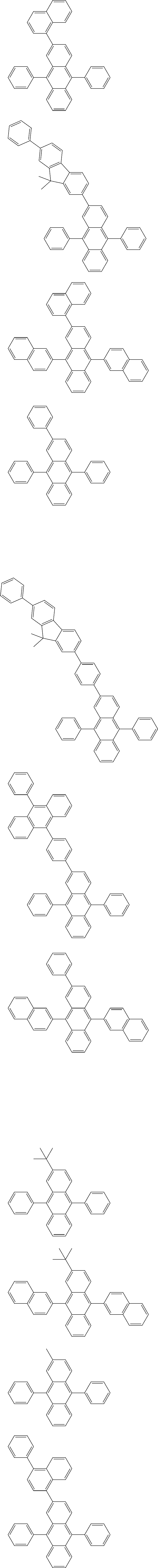

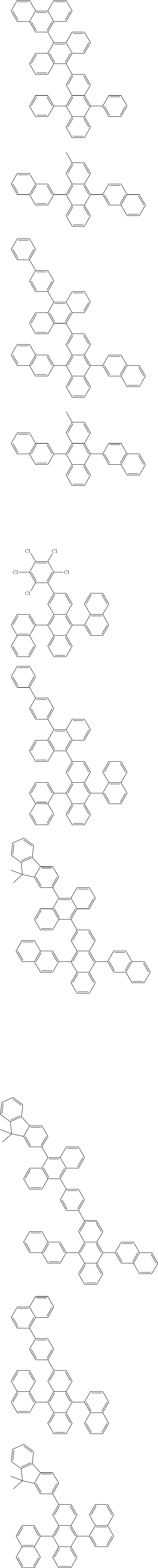

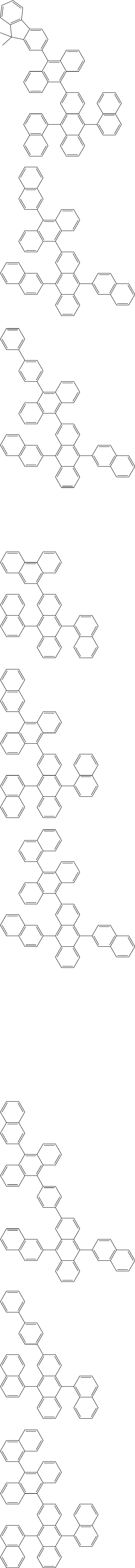

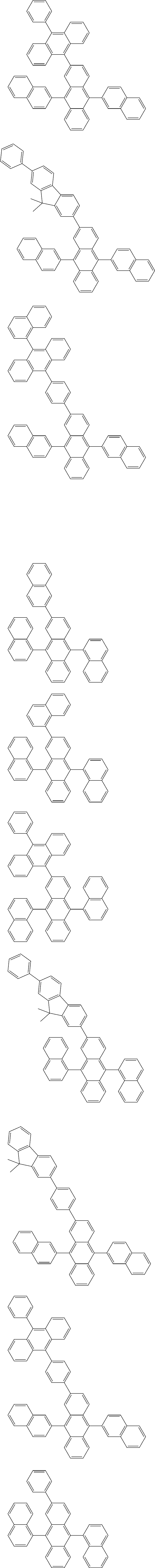

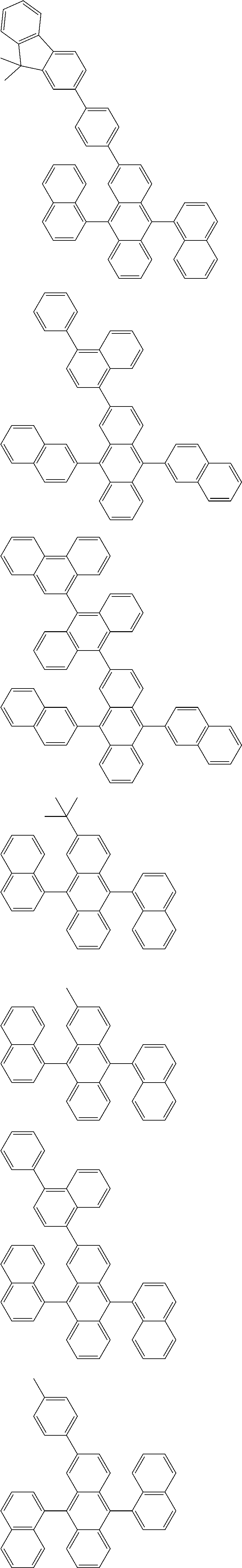

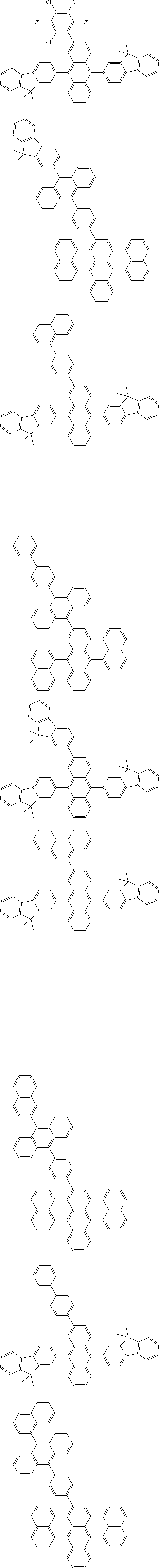

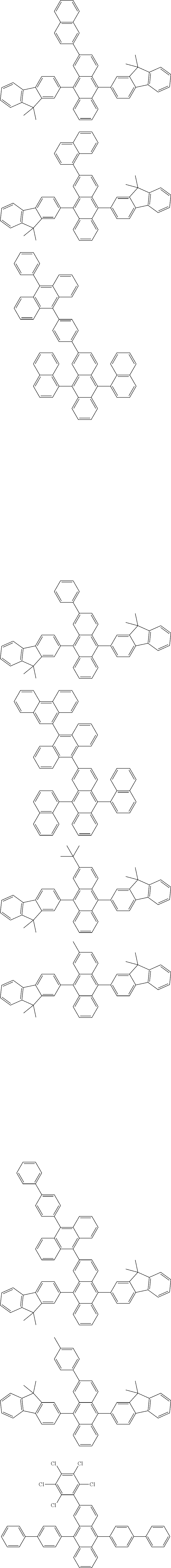

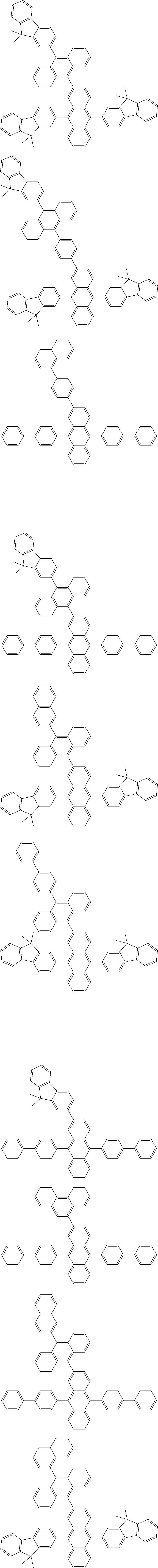

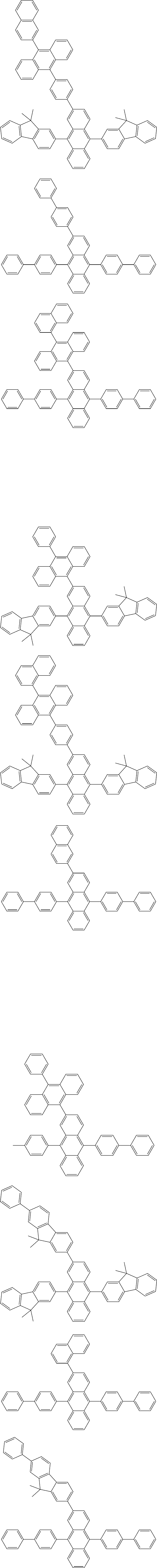

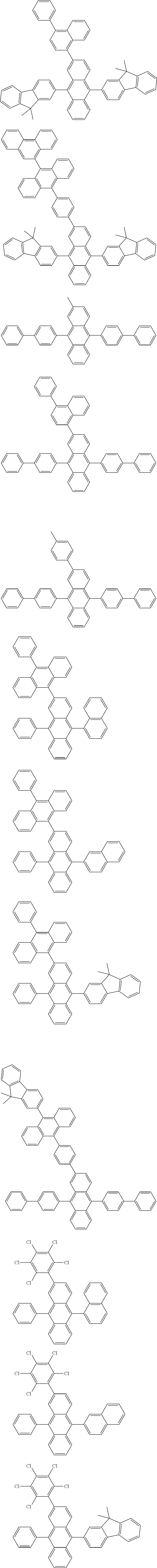

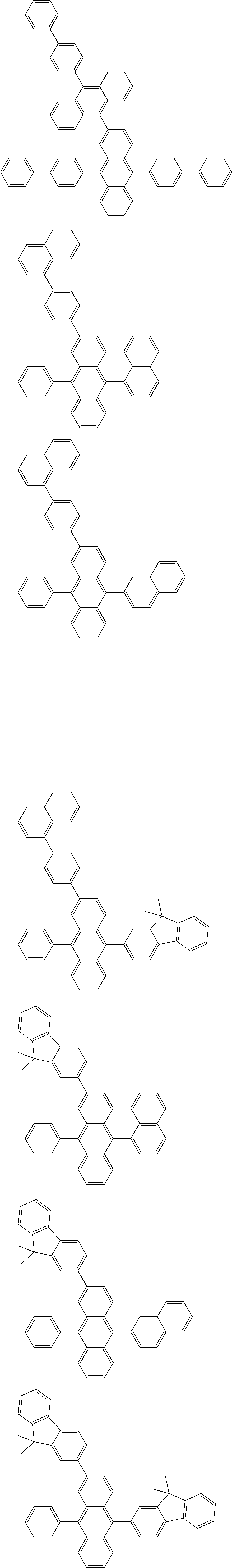

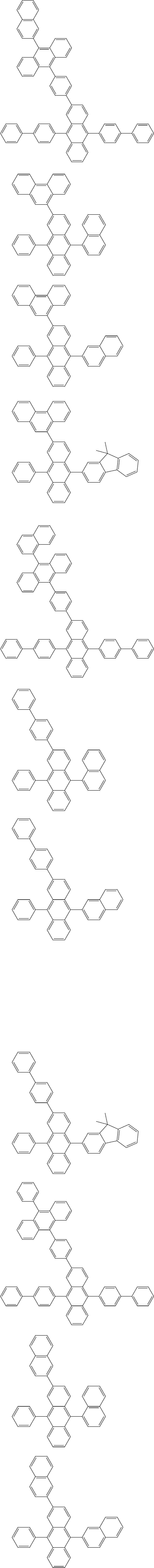

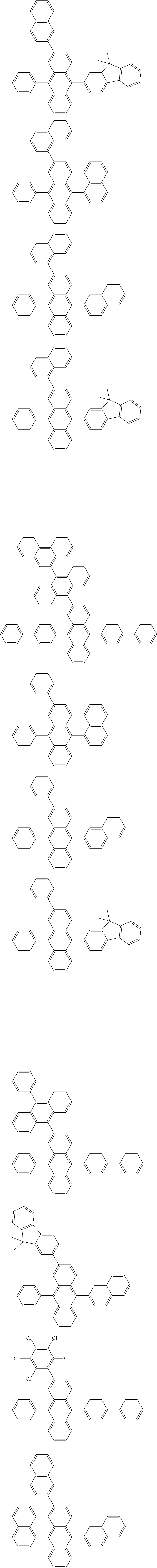

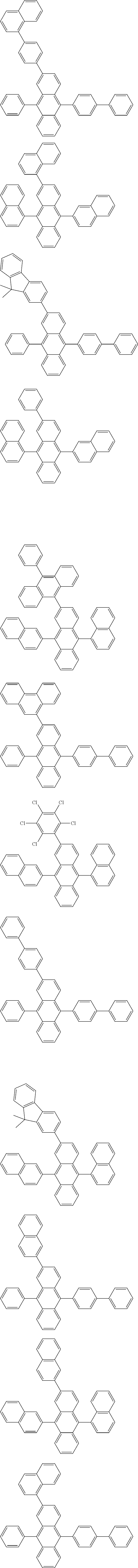

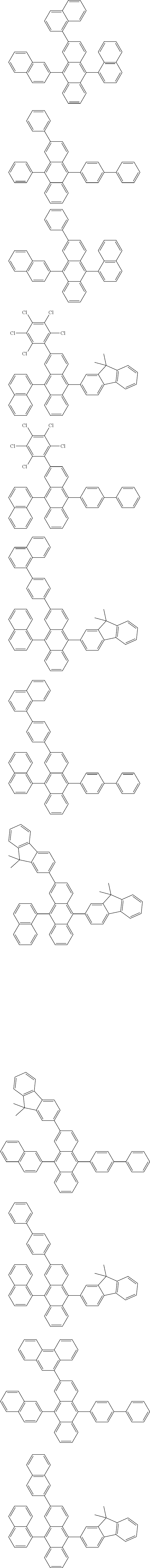

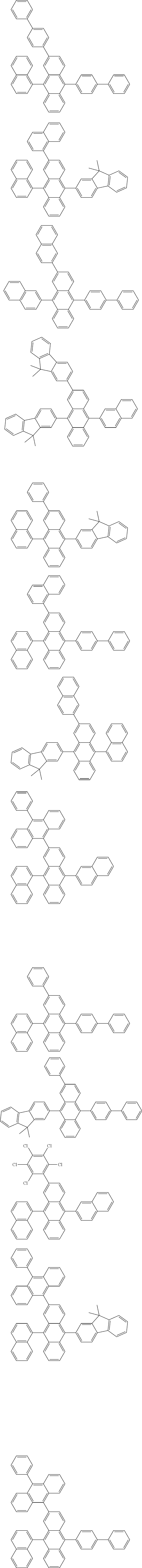

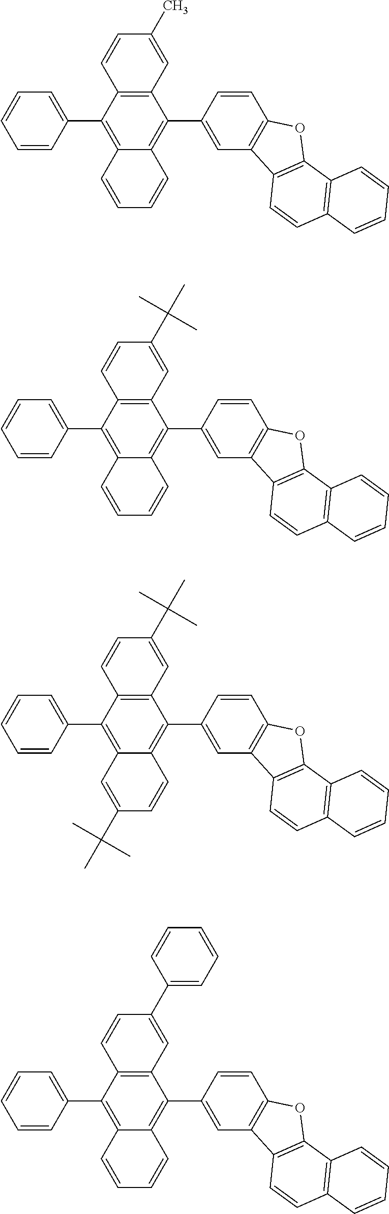 [SMILES: Cc1ccc2c(-c3ccccc3)c3ccccc3c(-c3ccc4oc5c6ccccc6ccc5c4c3)c2c1 ; CC(C)(C)c1ccc2c(-c3ccccc3)c3ccccc3c(-c3ccc4oc5c6ccccc6ccc5c4c3)c2c1 ; CC(C)(C)c1ccc2c(-c3ccc4oc5c6ccccc6ccc5c4c3)c3cc(C(C)(C)C)ccc3c(-c3ccccc3)c2c1 ; c1ccc(-c2ccc3c(-c4ccccc4)c4ccccc4c(-c4ccc5oc6c7ccccc7ccc6c5c4)c3c2)cc1]

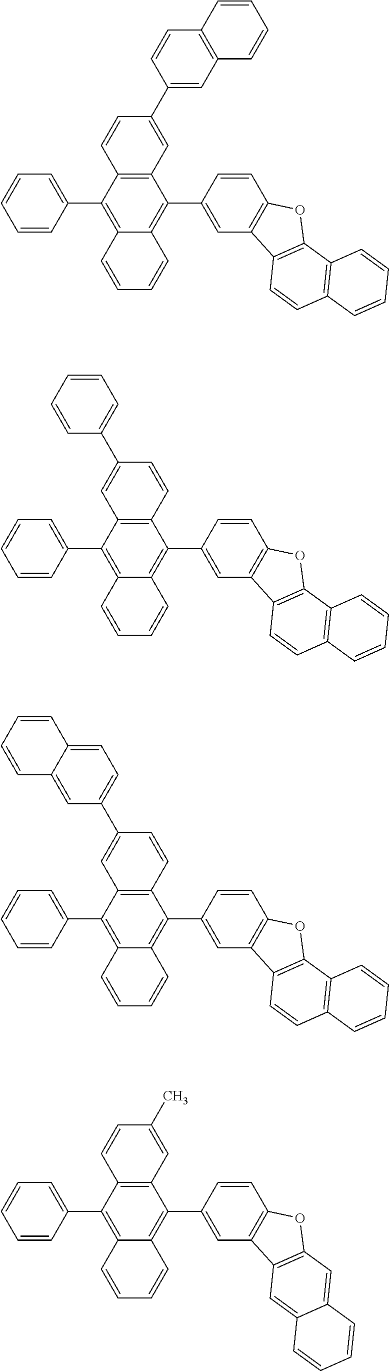 [SMILES: c1ccc(-c2c3ccccc3c(-c3ccc4oc5c6ccccc6ccc5c4c3)c3cc(-c4ccc5ccccc5c4)ccc23)cc1 ; c1ccc(-c2ccc3c(-c4ccc5oc6c7ccccc7ccc6c5c4)c4ccccc4c(-c4ccccc4)c3c2)cc1 ; c1ccc(-c2c3ccccc3c(-c3ccc4oc5c6ccccc6ccc5c4c3)c3ccc(-c4ccc5ccccc5c4)cc23)cc1 ; Cc1ccc2c(-c3ccccc3)c3ccccc3c(-c3ccc4oc5cc6ccccc6cc5c4c3)c2c1]

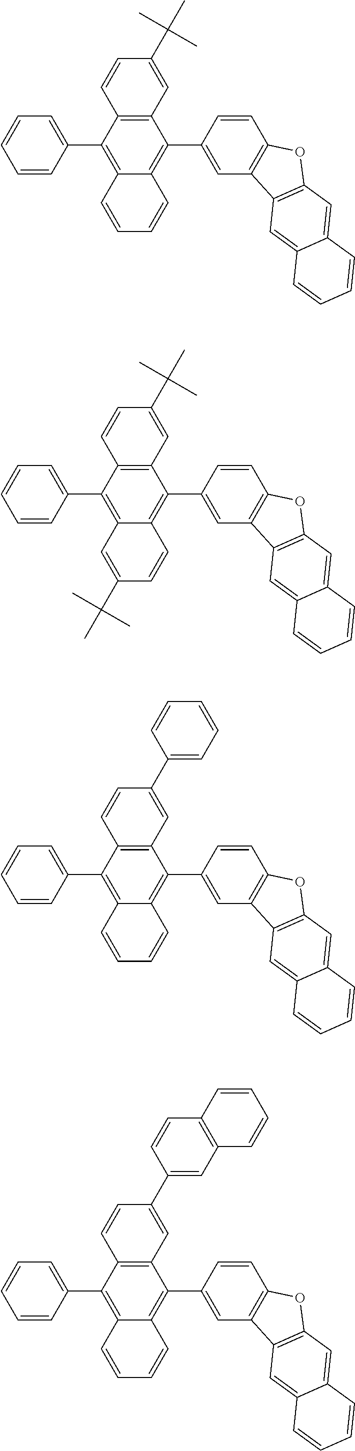 [SMILES: CC(C)(C)c1ccc2c(-c3ccccc3)c3ccccc3c(-c3ccc4oc5cc6ccccc6cc5c4c3)c2c1 ; CC(C)(C)c1ccc2c(-c3ccc4oc5cc6ccccc6cc5c4c3)c3cc(C(C)(C)C)ccc3c(-c3ccccc3)c2c1 ; c1ccc(-c2ccc3c(-c4ccccc4)c4ccccc4c(-c4ccc5oc6cc7ccccc7cc6c5c4)c3c2)cc1 ; c1ccc(-c2c3ccccc3c(-c3ccc4oc5cc6ccccc6cc5c4c3)c3cc(-c4ccc5ccccc5c4)ccc23)cc1]

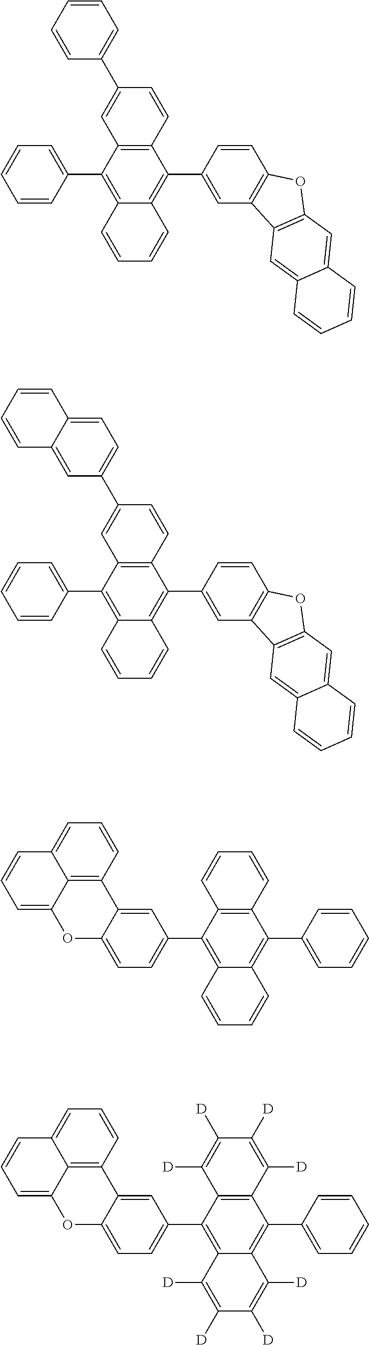 [SMILES: c1ccc(-c2ccc3c(-c4ccc5oc6cc7ccccc7cc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1 ; c1ccc(-c2c3ccccc3c(-c3ccc4c(c3)-c3cccc5cccc(c35)O4)c3ccccc23)cc1 ; [2H]c1c([2H])c([2H])c2c(-c3ccc4c(c3)-c3cccc5cccc(c35)O4)c3c([2H])c([2H])c([2H])c([2H])c3c(-c3ccccc3)c2c1[2H]]

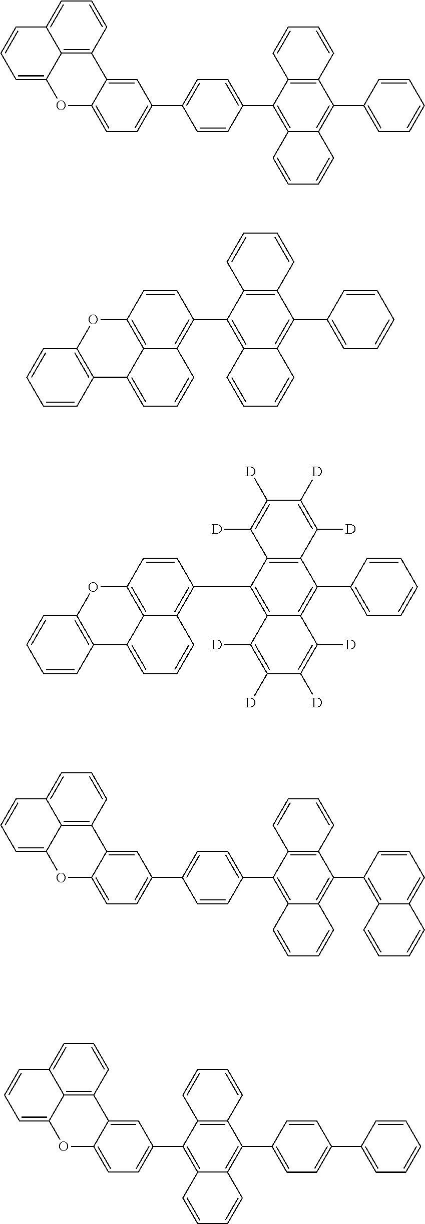 [SMILES: c1ccc(-c2c3ccccc3c(-c3ccc(-c4ccc5c(c4)-c4cccc6cccc(c46)O5)cc3)c3ccccc23)cc1 ; c1ccc(-c2c3ccccc3c(-c3ccc4c5c(cccc35)-c3ccccc3O4)c3ccccc23)cc1 ; [2H]c1c([2H])c([2H])c2c(-c3ccc4c5c(cccc35)-c3ccccc3O4)c3c([2H])c([2H])c([2H])c([2H])c3c(-c3ccccc3)c2c1[2H] ; c1ccc2c(-c3c4ccccc4c(-c4ccc(-c5ccc6c(c5)-c5cccc7cccc(c57)O6)cc4)c4ccccc34)cccc2c1 ; c1ccc(-c2ccc(-c3c4ccccc4c(-c4ccc5c(c4)-c4cccc6cccc(c46)O5)c4ccccc34)cc2)cc1]

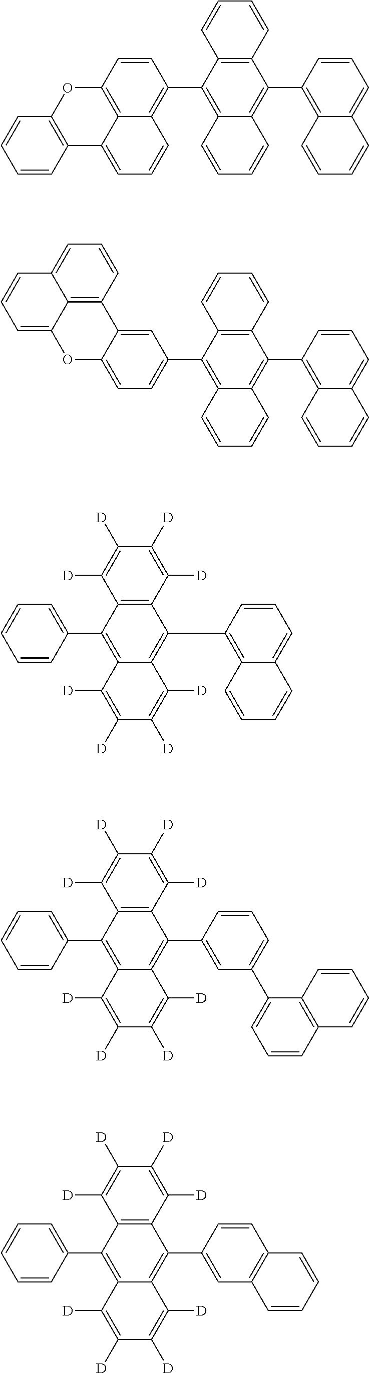 [SMILES: c1ccc2c(c1)Oc1ccc(-c3c4ccccc4c(-c4cccc5ccccc45)c4ccccc34)c3cccc-2c13 ; c1ccc2c(-c3c4ccccc4c(-c4ccc5c(c4)-c4cccc6cccc(c46)O5)c4ccccc34)cccc2c1 ; [2H]c1c([2H])c([2H])c2c(-c3cccc4ccccc34)c3c([2H])c([2H])c([2H])c([2H])c3c(-c3ccccc3)c2c1[2H] ; [2H]c1c([2H])c([2H])c2c(-c3cccc(-c4cccc5ccccc45)c3)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3ccccc3)c2c1[2H]]

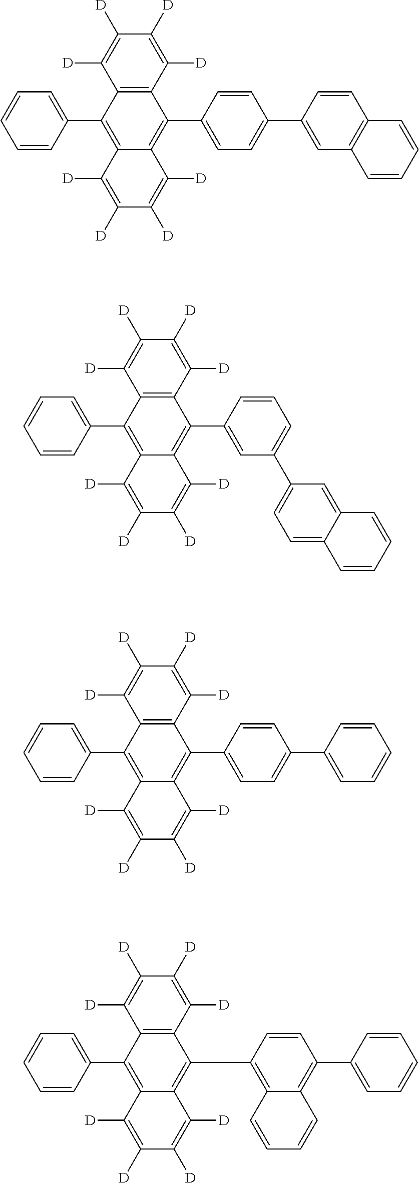 [SMILES: [2H]c1c([2H])c([2H])c2c(-c3ccc(-c4ccc5ccccc5c4)cc3)c3c([2H])c([2H])c([2H])c([2H])c3c(-c3ccccc3)c2c1[2H] ; [2H]c1c([2H])c([2H])c2c(-c3cccc(-c4ccc5ccccc5c4)c3)c3c([2H])c([2H])c([2H])c([2H])c3c(-c3ccccc3)c2c1[2H] ; [2H]c1c([2H])c([2H])c2c(-c3ccc(-c4ccccc4)cc3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccccc3)c2c1[2H]]

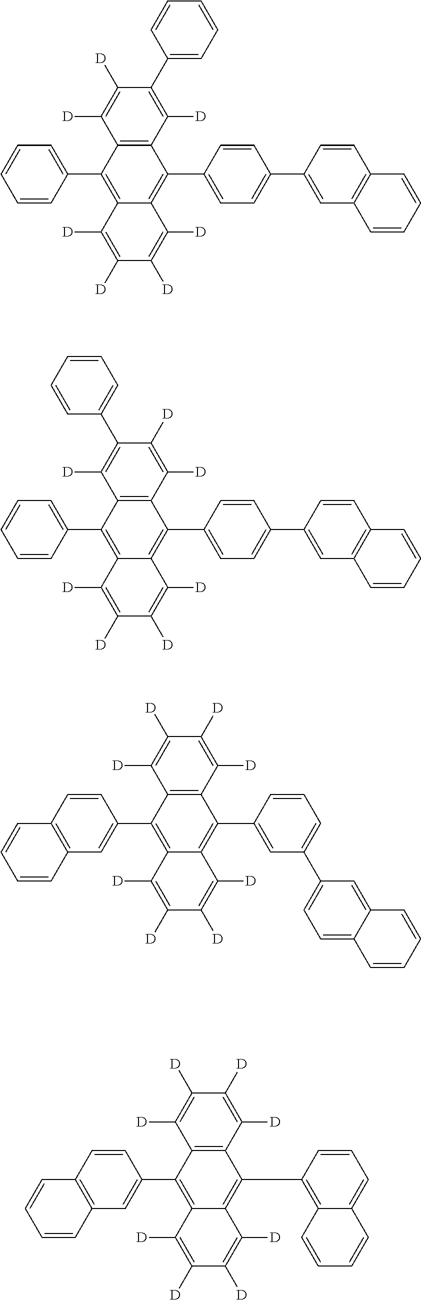 [SMILES: [2H]c1c([2H])c([2H])c2c(-c3ccc(-c4ccc5ccccc5c4)cc3)c3c([2H])c(-c4ccccc4)c([2H])c([2H])c3c(-c3ccccc3)c2c1[2H] ; [2H]c1c([2H])c([2H])c2c(-c3ccccc3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc4ccccc4c3)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3ccc4ccccc4c3)c2c1[2H]]

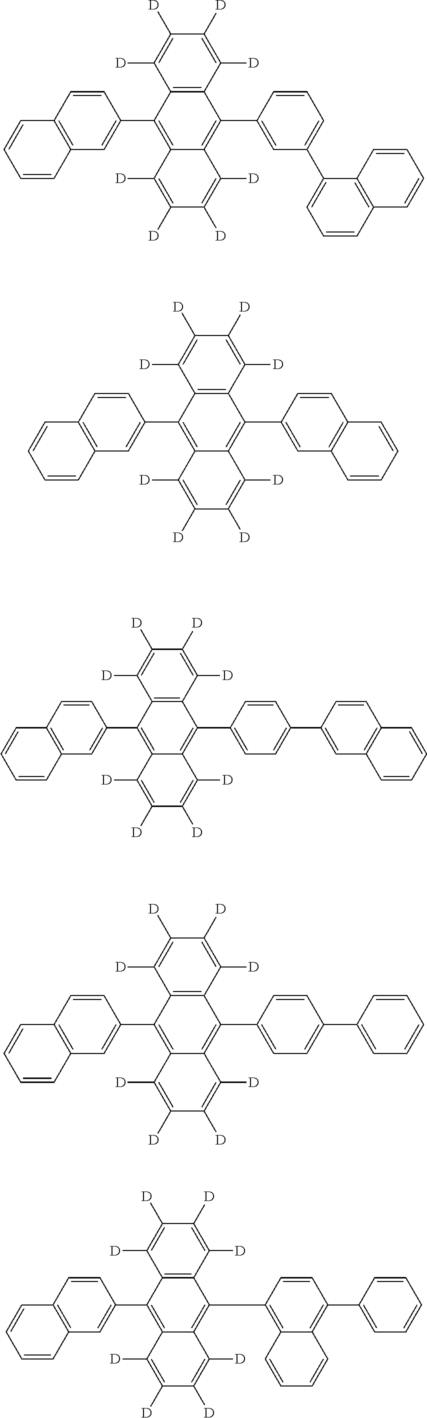

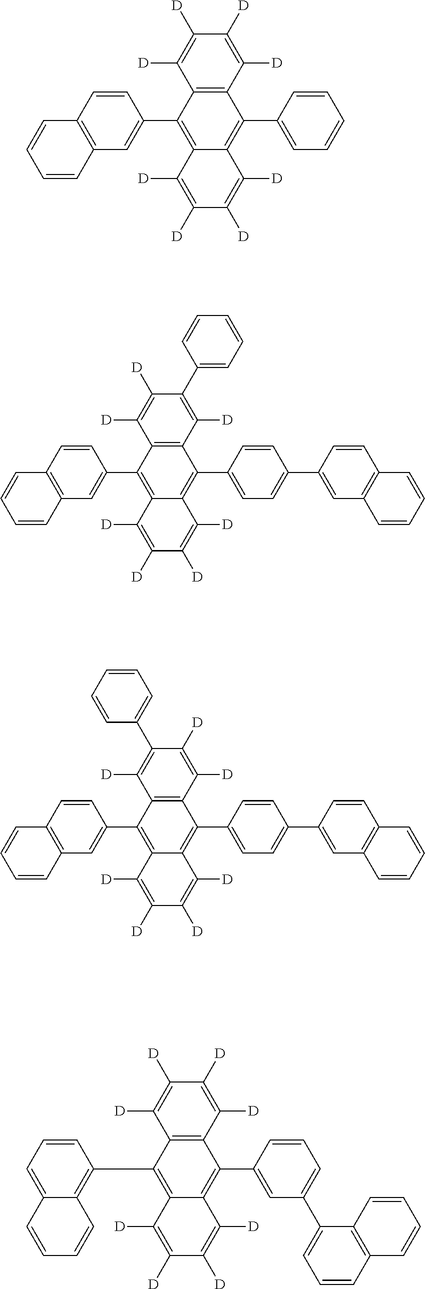 [SMILES: [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4ccccc4c3)c2c1[2H] ; [2H]c1c([2H])c([2H])c2c(-c3ccc4ccccc4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3cccc(-c4cccc5ccccc45)c3)c2c1[2H]]

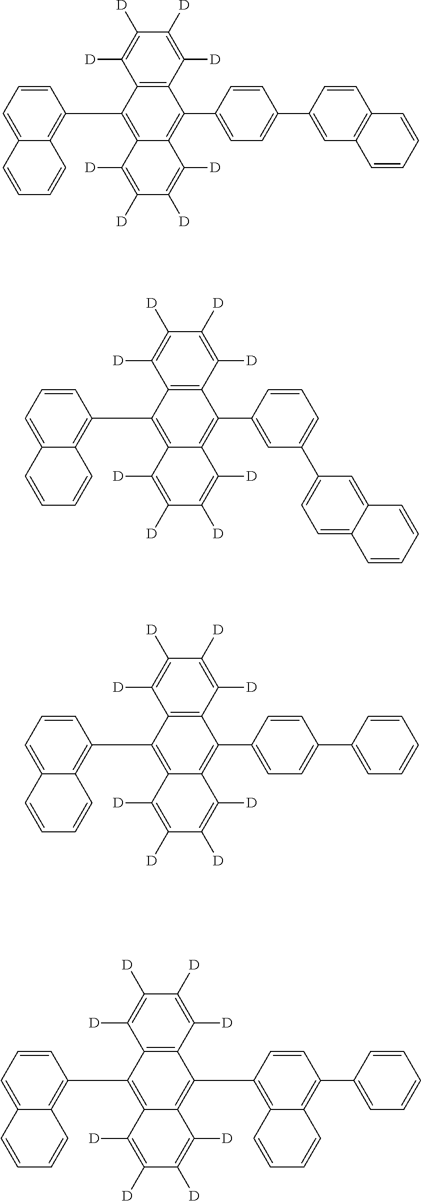 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3cccc4ccccc34)c2c1[2H]]

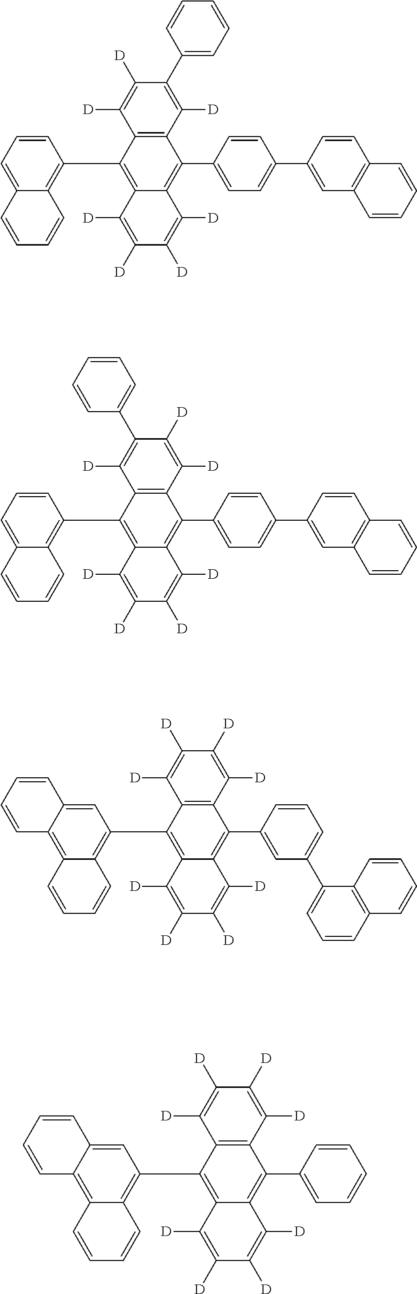 [SMILES: [2H]c1c([2H])c([2H])c2c(-c3cccc4ccccc34)c3c([2H])c([2H])c(-c4ccccc4)c([2H])c3c(-c3ccc(-c4ccc5ccccc5c4)cc3)c2c1[2H] ; [2H]c1c([2H])c([2H])c2c(-c3cccc4ccccc34)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3cc4ccccc4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cc4ccccc4c4ccccc34)c3c([2H])c([2H])c([2H])c([2H])c3c(-c3ccccc3)c2c1[2H]]

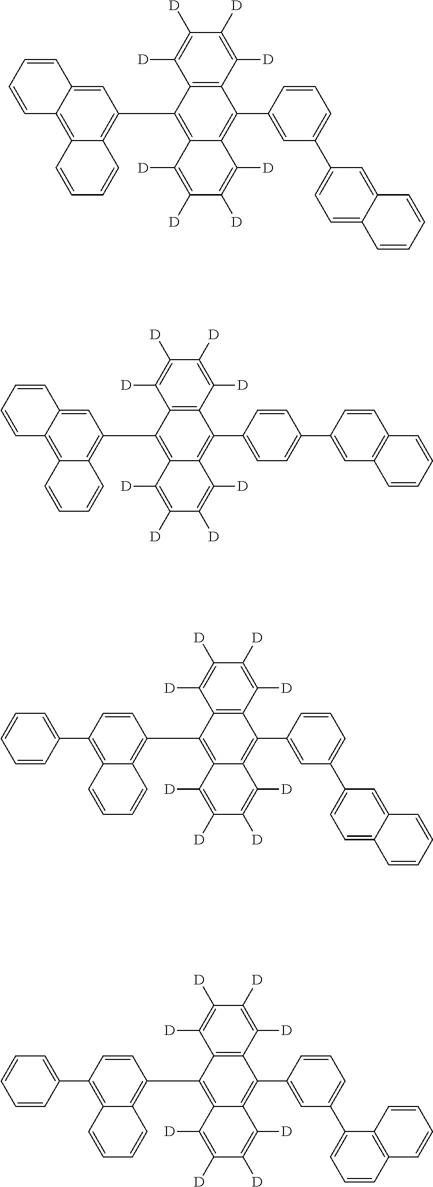 [SMILES: [2H]c1c([2H])c([2H])c2c(-c3cc4ccccc4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3ccc(-c4ccccc4)c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3ccc(-c4ccccc4)c4ccccc34)c3c([2H])c([2H])c([2H])c([2H])c3c(-c3cccc(-c4cccc5ccccc45)c3)c2c1[2H]]

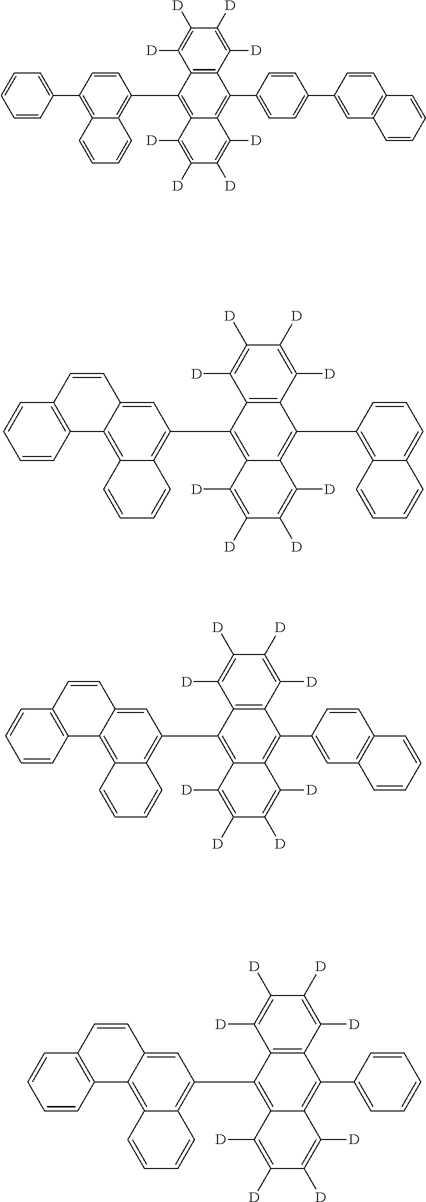 [SMILES: [2H]c1c([2H])c([2H])c2c(-c3ccc(-c4ccccc4)c4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc4ccccc34)c2c1[2H] ; [2H]c1c([2H])c([2H])c2c(-c3cc4ccc5ccccc5c4c4ccccc34)c3c([2H])c([2H])c([2H])c([2H])c3c(-c3ccc4ccccc4c3)c2c1[2H] ; [2H]c1c([2H])c([2H])c2c(-c3cc4ccc5ccccc5c4c4ccccc34)c3c([2H])c([2H])c([2H])c([2H])c3c(-c3ccccc3)c2c1[2H]]

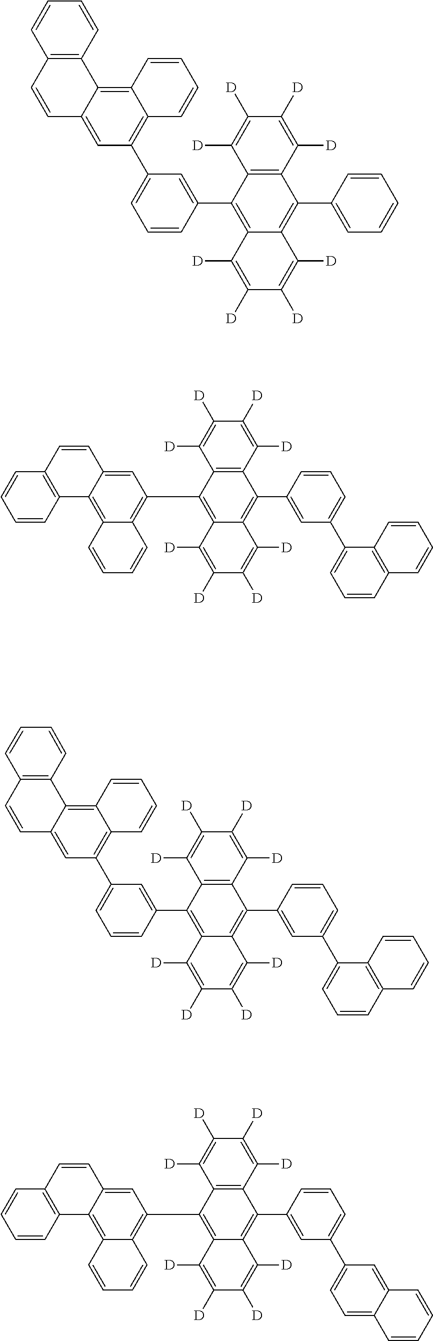 [SMILES: [2H]c1c([2H])c([2H])c2c(-c3cccc(-c4cc5ccc6ccccc6c5c5ccccc45)c3)c3c([2H])c([2H])c([2H])c([2H])c3c(-c3ccccc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3cccc(-c4cccc5ccccc45)c3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4ccc5ccccc5c4)c3)c2c1[2H]]

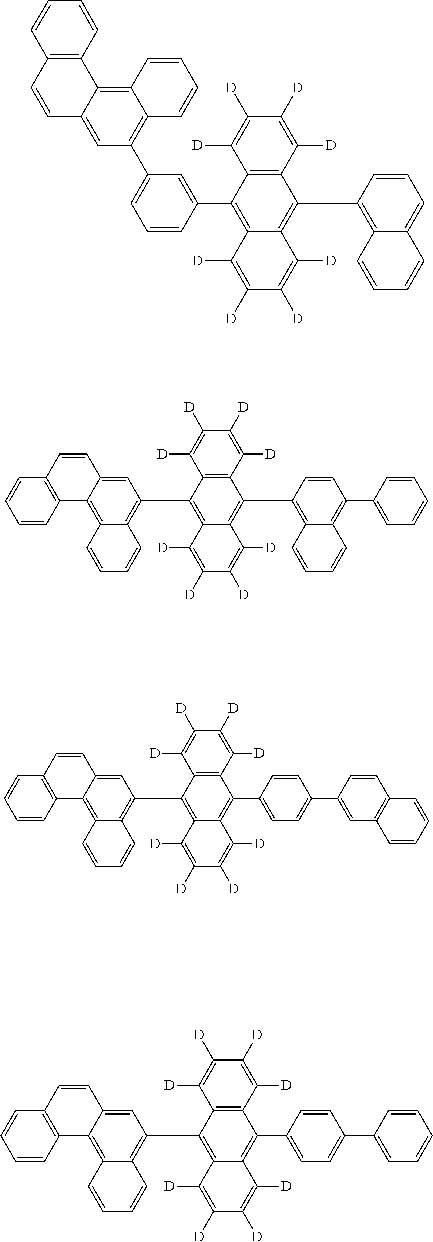 [SMILES: [2H]c1c([2H])c([2H])c2c(-c3cccc4ccccc34)c3c([2H])c([2H])c([2H])c([2H])c3c(-c3cccc(-c4cc5ccc6ccccc6c5c5ccccc45)c3)c2c1[2H] ; [2H]c1c([2H])c([2H])c2c(-c3cc4ccc5ccccc5c4c4ccccc34)c3c([2H])c([2H])c([2H])c([2H])c3c(-c3ccc(-c4ccccc4)c4ccccc34)c2c1[2H] ; [2H]c1c([2H])c([2H])c2c(-c3cc4ccc5ccccc5c4c4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cc4ccc5ccccc5c4c4ccccc34)c3c([2H])c([2H])c([2H])c([2H])c3c(-c3ccc(-c4ccccc4)cc3)c2c1[2H]]

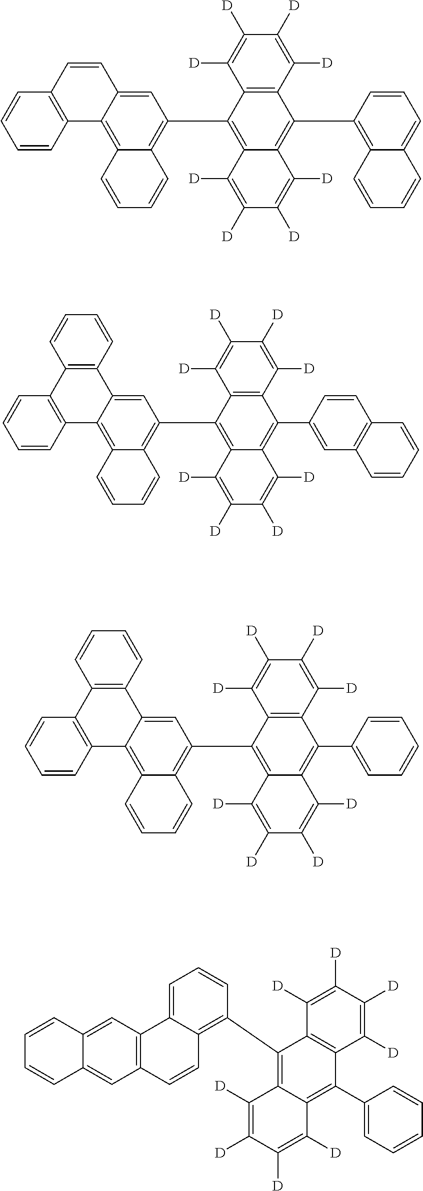 [SMILES: [2H]c1c([2H])c([2H])c2c(-c3cc4ccc5ccccc5c4c4ccccc34)c3c([2H])c([2H])c([2H])c([2H])c3c(-c3cccc4ccccc34)c2c1[2H] ; [2H]c1c([2H])c([2H])c2c(-c3cc4c5ccccc5c5ccccc5c4c4ccccc34)c3c([2H])c([2H])c([2H])c([2H])c3c(-c3ccc4ccccc4c3)c2c1[2H] ; [2H]c1c([2H])c([2H])c2c(-c3cc4c5ccccc5c5ccccc5c4c4ccccc34)c3c([2H])c([2H])c([2H])c([2H])c3c(-c3ccccc3)c2c1[2H] ; [2H]c1c([2H])c([2H])c2c(-c3cccc4c3ccc3cc5ccccc5cc34)c3c([2H])c([2H])c([2H])c([2H])c3c(-c3ccccc3)c2c1[2H]]

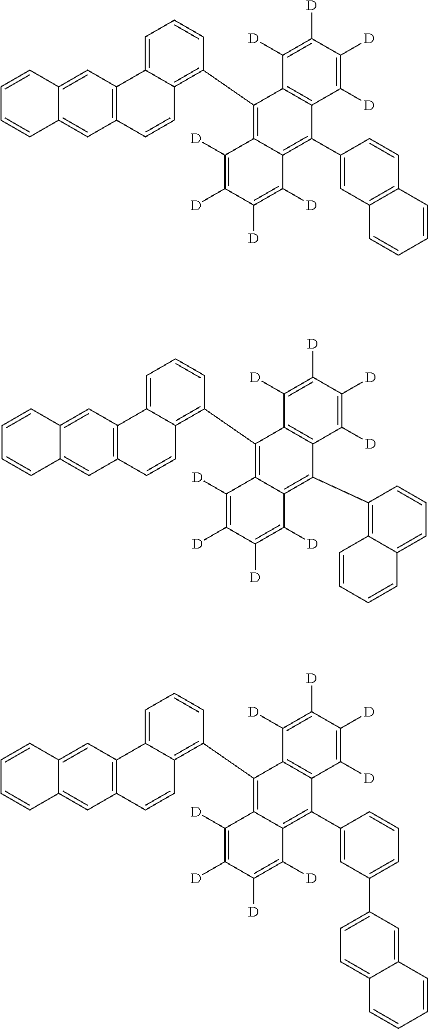 [SMILES: [2H]c1c([2H])c([2H])c2c(-c3cccc4c3ccc3cc5ccccc5cc34)c3c([2H])c([2H])c([2H])c([2H])c3c(-c3ccc4ccccc4c3)c2c1[2H] ; [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H] ; [2H]c1c([2H])c([2H])c2c(-c3cccc4c3ccc3cc5ccccc5cc34)c3c([2H])c([2H])c([2H])c([2H])c3c(-c3cccc(-c4ccc5ccccc5c4)c3)c2c1[2H]]

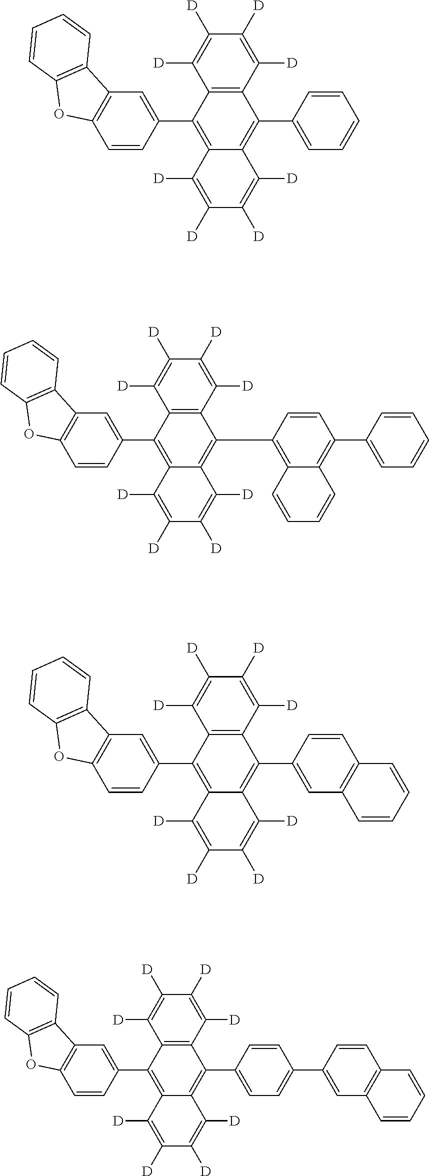 [SMILES: [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H] ; [2H]c1c([2H])c([2H])c2c(-c3ccc4oc5ccccc5c4c3)c3c([2H])c([2H])c([2H])c([2H])c3c(-c3ccc(-c4ccc5ccccc5c4)cc3)c2c1[2H]]

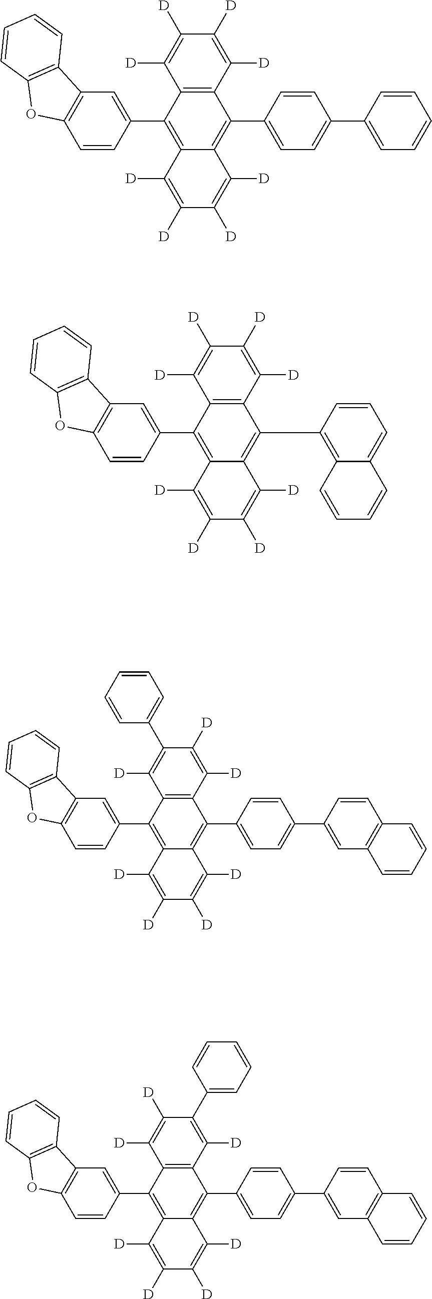 [SMILES: [2H]c1c([2H])c([2H])c2c(-c3ccc4oc5ccccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H]]

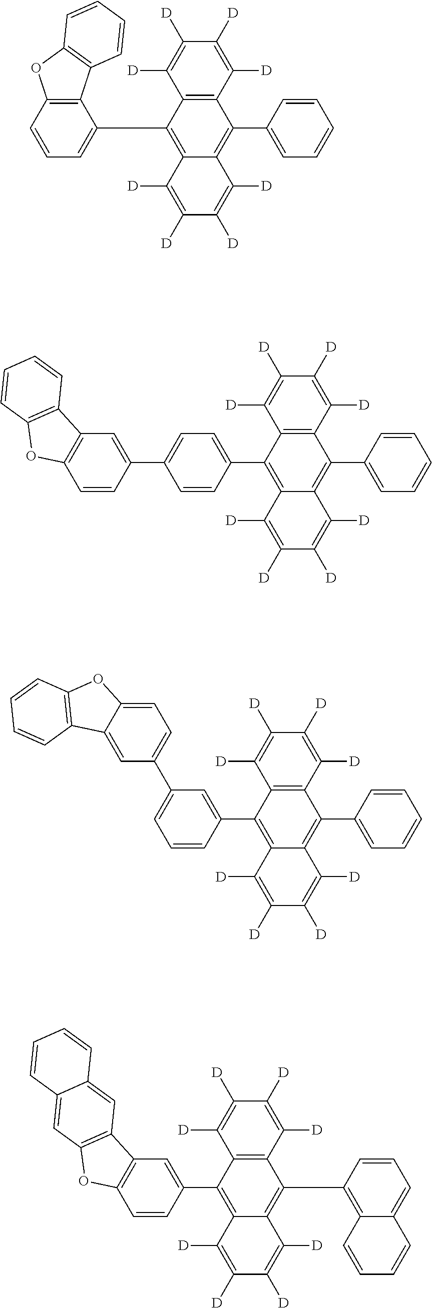 [SMILES: [2H]c1c([2H])c([2H])c2c(-c3cccc4oc5ccccc5c34)c3c([2H])c([2H])c([2H])c([2H])c3c(-c3ccccc3)c2c1[2H] ; [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H] ; [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H]]

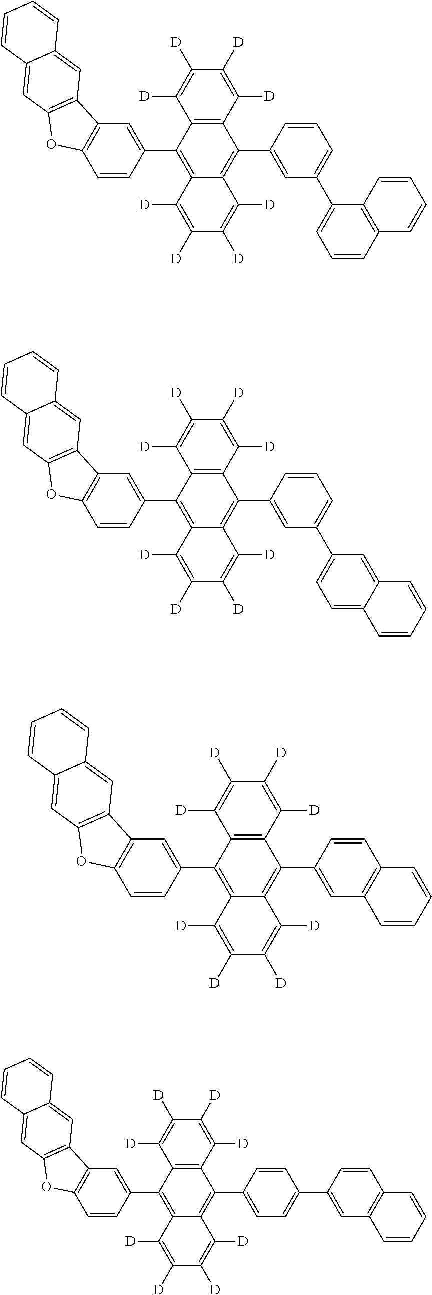 [SMILES: [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccc5ccccc5c4)cc3)c2c1[2H]]

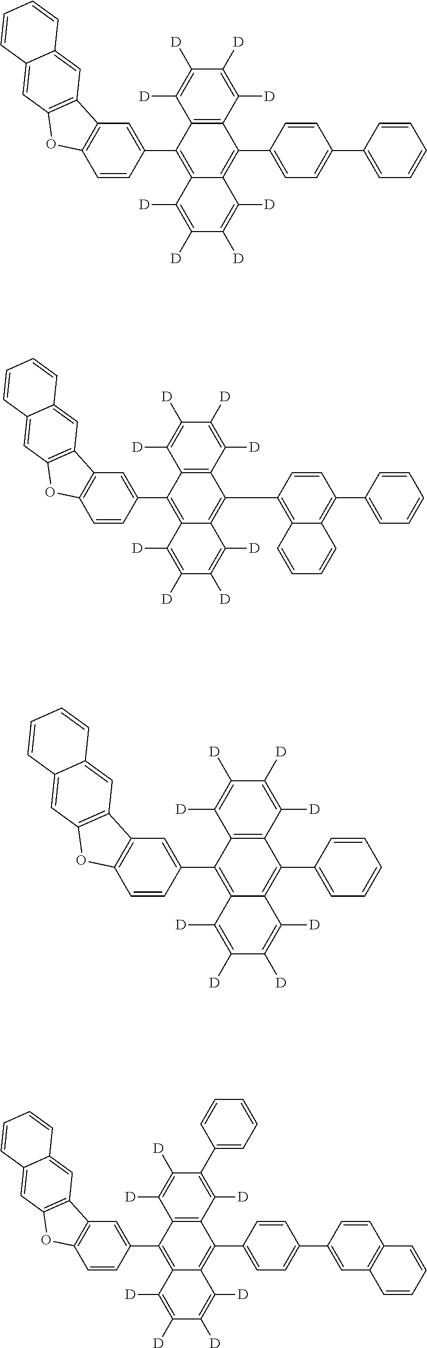 [SMILES: [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H]]

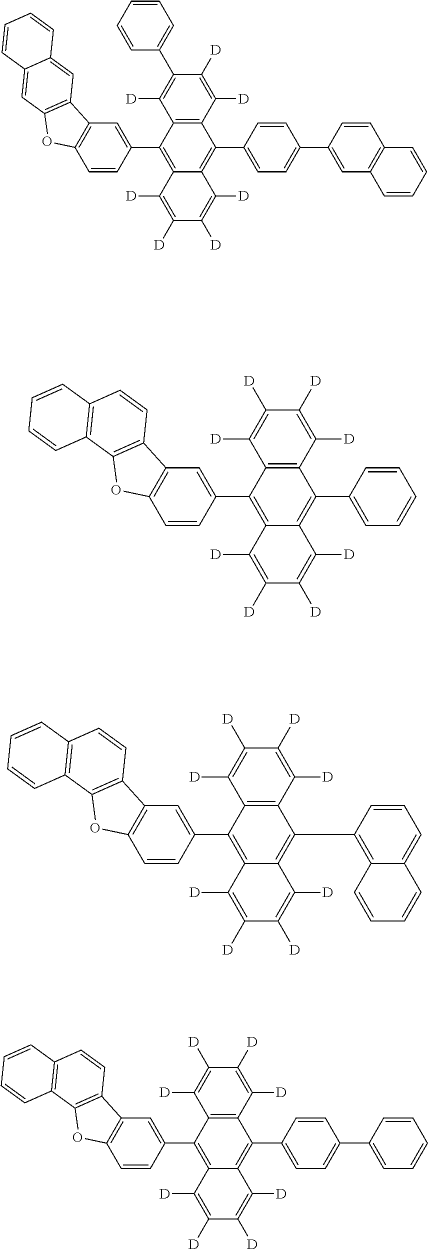 [SMILES: [2H]c1c([2H])c([2H])c2c(-c3ccc4oc5cc6ccccc6cc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc4oc5c6ccccc6ccc5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5c6ccccc6ccc5c4c3)c2c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H]]

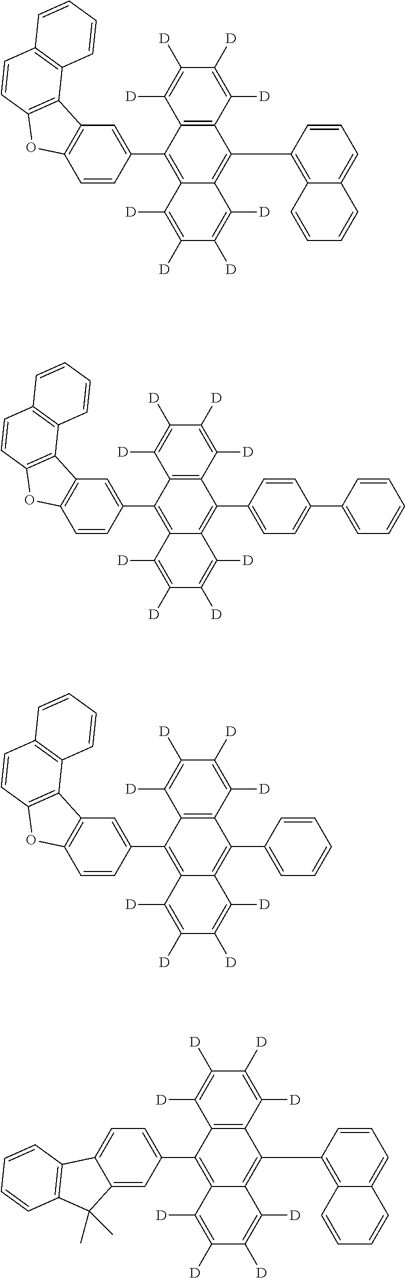 [SMILES: [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H] ; [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4c(c3)C(C)(C)c3ccccc3-4)c2c1[2H]]

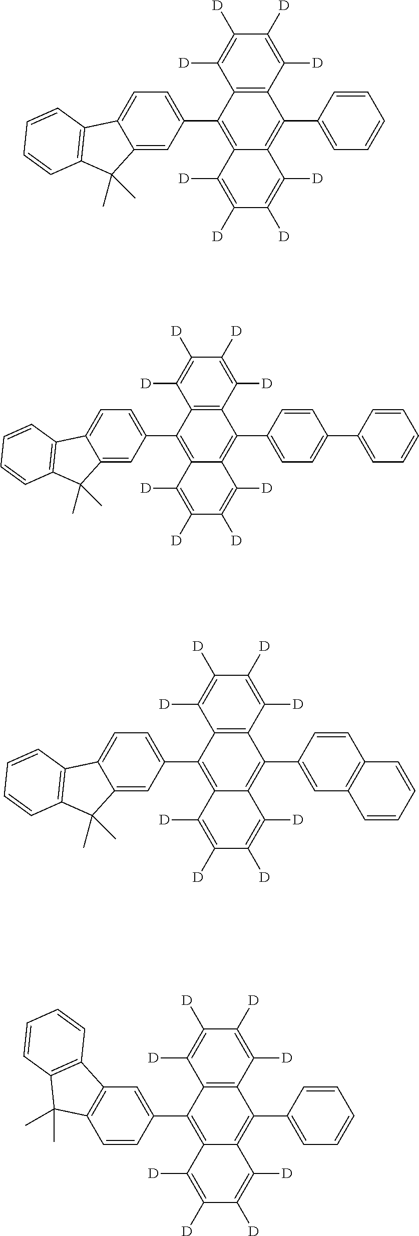 [SMILES: [2H]c1c([2H])c([2H])c2c(-c3ccc4c(c3)C(C)(C)c3ccccc3-4)c3c([2H])c([2H])c([2H])c([2H])c3c(-c3ccccc3)c2c1[2H] ; [2H]c1c([2H])c([2H])c2c(-c3ccc4c(c3)C(C)(C)c3ccccc3-4)c3c([2H])c([2H])c([2H])c([2H])c3c(-c3ccc(-c4ccccc4)cc3)c2c1[2H] ; [2H]c1c([2H])c([2H])c2c(-c3ccc4ccccc4c3)c3c([2H])c([2H])c([2H])c([2H])c3c(-c3ccc4c(c3)C(C)(C)c3ccccc3-4)c2c1[2H] ; [2H]c1c([2H])c([2H])c2c(-c3ccc4c(c3)-c3ccccc3C4(C)C)c3c([2H])c([2H])c([2H])c([2H])c3c(-c3ccccc3)c2c1[2H]]

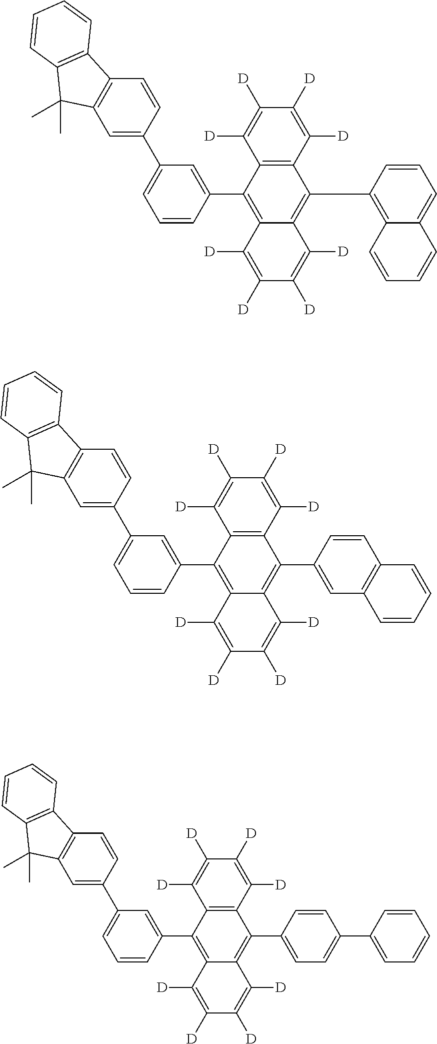 [SMILES: [2H]c1c([2H])c([2H])c2c(-c3cccc4ccccc34)c3c([2H])c([2H])c([2H])c([2H])c3c(-c3cccc(-c4ccc5c(c4)C(C)(C)c4ccccc4-5)c3)c2c1[2H] ; [2H]c1c([2H])c([2H])c2c(-c3ccc4ccccc4c3)c3c([2H])c([2H])c([2H])c([2H])c3c(-c3cccc(-c4ccc5c(c4)C(C)(C)c4ccccc4-5)c3)c2c1[2H] ; [2H]c1c([2H])c([2H])c2c(-c3cccc(-c4ccc5c(c4)C(C)(C)c4ccccc4-5)c3)c3c([2H])c([2H])c([2H])c([2H])c3c(-c3ccc(-c4ccccc4)cc3)c2c1[2H]]

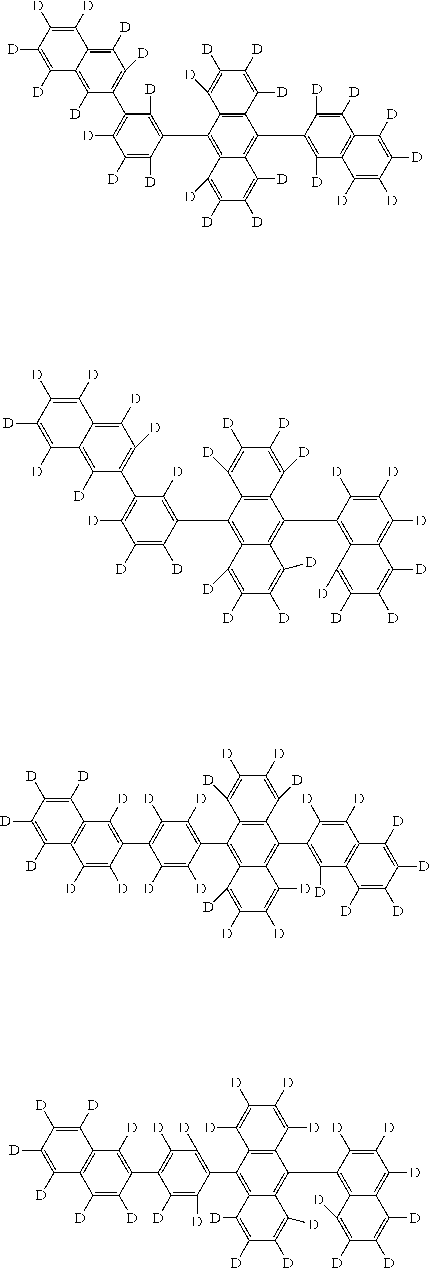

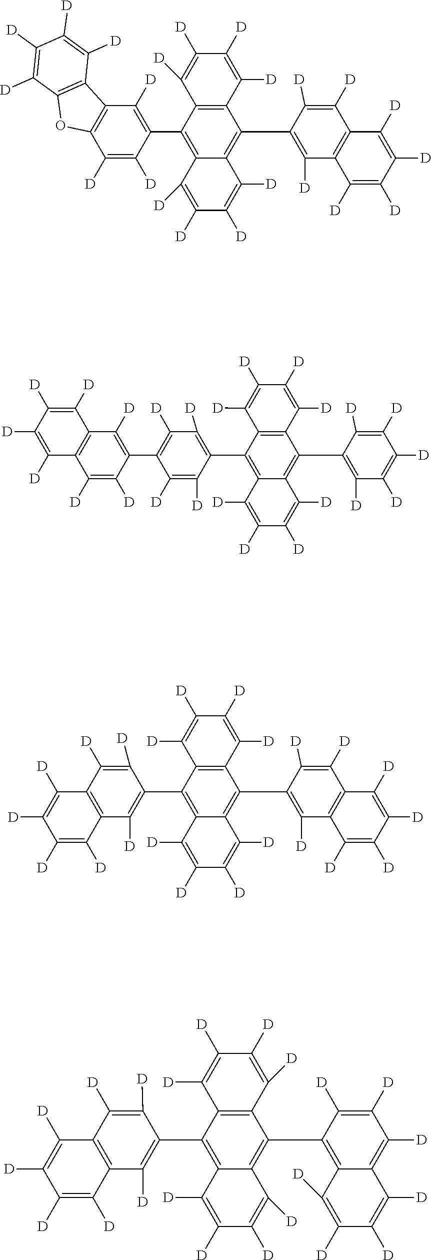

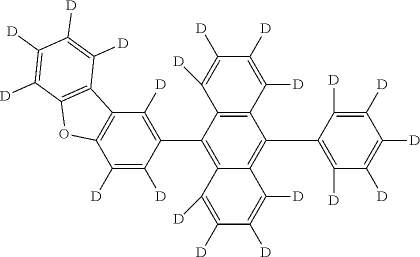 [SMILES: [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H]]

In the case that the emitting layer comprises the compound represented by formula (I) as a dopant and at least one host, wherein preferred hosts are mentioned above, and the host is more preferably at least one compound represented by formula (10), the content of the at least one compound represented by formula (I) is preferably 0.5 mass % to 70 mass %, more preferably to 30 mass %, further preferably 1 to 30 mass %, still further preferably 1 to 20 mass %, and particularly preferably 1 to 10 mass %, further particularly preferably 1 to 5 mass %, relative to the entire mass of the emitting layer.

The content of the at least one host, wherein preferred hosts are mentioned above, preferably the at least one compound represented by formula (10) is preferably 30 mass % to 99.9 mass %, more preferably 70 to 99.5 mass %, further preferably 70 to 99 mass %, still further preferably 80 to 99 mass %, and particularly preferably 90 to 99 mass %, further particularly preferably 95 to 99 mass %, relative to the entire mass of the emitting layer.

An explanation will be made on the layer configuration of the organic EL device according to one aspect of the invention.

An organic EL device according to one aspect of the invention comprises a cathode, an anode, and one or more organic thin film layers comprising an emitting layer disposed between the cathode and the anode. The organic layer comprises at least one layer composed of an organic compound. Alternatively, the organic layer is formed by laminating a plurality of layers composed of an organic compound. The organic layer may further comprise an inorganic compound in addition to the organic compound.

At least one of the organic layers is an emitting layer. The organic layer may be constituted, for example, as a single emitting layer, or may comprise other layers which can be adopted in the layer structure of the organic EL device. The layer that can be adopted in the layer structure of the organic EL device is not particularly limited, but examples thereof include a hole-transporting zone (comprising at least one hole-transporting layer and preferably in addition at least one of a hole-injecting layer, an electron-blocking layer, an exciton-blocking layer, etc.), an emitting layer, a spacing layer, and an electron-transporting zone (comprising at least one electron-transporting layer and preferably in addition at least one of an electron-injecting layer, a hole-blocking layer, etc.) provided between the cathode and the emitting layer.

The organic EL device according to one aspect of the invention may be, for example, a fluorescent or phosphorescent monochromatic light emitting device or a fluorescent/phosphorescent hybrid white light emitting device. Preferably, the organic EL device is a fluorescent monochromatic light emitting device, more preferably a blue fluorescent monochromatic light emitting device or a fluorescent/phosphorescent hybrid white light emitting device. Blue fluorescence means a fluorescence at 400 to 500 nm (peak maximum), preferably at 430 nm to 490 nm (peak maximum).

Further, it may be a simple type device having a single emitting unit or a tandem type device having a plurality of emitting units.

The “emitting unit” in the specification is the smallest unit that comprises organic layers, in which at least one of the organic layers is an emitting layer and light is emitted by recombination of injected holes and electrons.

In addition, the “emitting layer” described in the present specification is an organic layer having an emitting function. The emitting layer is, for example, a phosphorescent emitting layer, a fluorescent emitting layer or the like, preferably a fluorescent emitting layer, more preferably a blue fluorescent emitting layer, and may be a single layer or a stack of a plurality of layers.

The emitting unit may be a stacked type unit having a plurality of phosphorescent emitting layers or fluorescent emitting layers. In this case, for example, a spacing layer for preventing excitons generated in the phosphorescent emitting layer from diffusing into the fluorescent emitting layer may be provided between the respective light-emitting layers.

As the simple type organic EL device, a device configuration such as anode/emitting unit/cathode can be given.

Examples for representative layer structures of the emitting unit are shown below. The layers in parentheses are provided arbitrarily.
(a) (Hole-injecting layer/) Hole-transporting layer/Fluorescent emitting layer (/Electron-transporting layer/Electron-injecting layer)
(b) (Hole-injecting layer/) Hole-transporting layer/Phosphorescent emitting layer (/Electron-transporting layer/Electron-injecting layer)
(c) (Hole-injecting layer/) Hole-transporting layer/First fluorescent emitting layer/Second fluorescent emitting layer (/Electron-transporting layer/Electron-injecting layer)
(d) (Hole-injecting layer/) Hole-transporting layer/First phosphorescent layer/Second phosphorescent layer (/Electron-transporting layer/Electron-injecting layer)
(e) (Hole-injecting layer/) Hole-transporting layer/Phosphorescent emitting layer/Spacing layer/Fluorescent emitting layer (/Electron-transporting layer/Electron-injecting layer)
(f) (Hole-injecting layer/) Hole-transporting layer/First phosphorescent emitting layer/Second phosphorescent emitting layer/Spacing layer/Fluorescent emitting layer (/Electron-transporting layer/Electron-injecting layer)
(g) (Hole-injecting layer/) Hole-transporting layer/First phosphorescent layer/Spacing layer/Second phosphorescent emitting layer/Spacing layer/Fluorescent emitting layer (/Electron-transporting layer/Electron-injecting layer)
(h) (Hole-injecting layer/) Hole-transporting layer/Phosphorescent emitting layer/Spacing layer/First fluorescent emitting layer/Second fluorescent emitting layer (/Electron-transporting Layer/Electron-injecting Layer)
(i) (Hole-injecting layer/) Hole-transporting layer/Electron-blocking layer/Fluorescent emitting layer (/Electron-transporting layer/Electron-injecting layer)
(j) (Hole-injecting layer/) Hole-transporting layer/Electron-blocking layer/Phosphorescent emitting layer (/Electron-transporting layer/Electron-injecting layer)
(k) (Hole-injecting layer/) Hole-transporting layer/Exciton-blocking layer/Fluorescent emitting layer (/Electron-transporting layer/Electron-injecting layer)
(l) (Hole-injecting layer/) Hole-transporting layer/Exciton-blocking layer/Phosphorescent emitting layer (/Electron-transporting layer/Electron-injecting layer)
(m) (Hole-injecting layer/) First hole-transporting Layer/Second hole-transporting Layer/Fluorescent emitting layer (/Electron-transporting layer/electron-injecting Layer)
(n) (Hole-injecting layer/) First hole-transporting layer/Second hole-transporting layer/Fluorescent emitting layer (/First electron-transporting layer/Second electron-transporting layer/Electron-injection layer)
(o) (Hole-injecting layer/) First hole-transporting layer/Second hole-transporting layer/Phosphorescent emitting layer (/Electron-transporting layer/Electron-injecting Layer)
(p) (Hole-injecting layer/) First hole-transporting layer/Second hole-transporting layer/Phosphorescent emitting layer (/First electron-transporting Layer/Second electron-transporting layer/Electron-injecting layer)
(q) (Hole-injecting layer/) Hole-transporting layer/Fluorescent emitting layer/Hole-blocking layer (/Electron-transporting layer/Electron-injecting layer)
(r) (Hole-injecting layer/) Hole-transporting layer/Phosphorescent emitting layer/Hole-blocking layer (/Electron-transport layer/Electron-injecting layer)
(s) (Hole-injecting layer/) Hole-transporting layer/Fluorescent emitting layer/Exciton-blocking layer (/Electron-transporting layer/Electron-injecting layer)
(t) (Hole-injecting layer/) Hole-transporting layer/Phosphorescent emitting layer/Exciton-blocking layer (/Electron-transporting layer/Electron-injecting layer)

The layer structure of the organic EL device according to one aspect of the invention is not limited to the examples mentioned above.

For example, when the organic EL device has a hole-injecting layer and a hole-transporting layer, it is preferred that a hole-injecting layer be provided between the hole-transporting layer and the anode. Further, when the organic EL device has an electron-injecting layer and an electron-transporting layer, it is preferred that an electron-injecting layer be provided between the electron-transporting layer and the cathode. Further, each of the hole-injecting layer, the hole-transporting layer, the electron-transporting layer and the electron-injecting layer may be formed of a single layer or be formed of a plurality of layers.

The plurality of phosphorescent emitting layer, and the plurality of the phosphorescent emitting layer and the fluorescent emitting layer may be emitting layers that emit mutually different colors. For example, the emitting unit (f) may include a hole-transporting layer/first phosphorescent layer (red light emission)/second phosphorescent emitting layer (green light emission)/spacing layer/fluorescent emitting layer (blue light emission)/electron-transporting layer.

An electron-blocking layer may be provided between each light emitting layer and the hole-transporting layer or the spacing layer. Further, a hole-blocking layer may be provided between each emitting layer and the electron-transporting layer. By providing the electron-blocking layer or the hole-blocking layer, it is possible to confine electrons or holes in the emitting layer, thereby to improve the recombination probability of carriers in the emitting layer, and to improve light emitting efficiency.

As a representative device configuration of a tandem type organic EL device, for example, a device configuration such as anode/first emitting unit/intermediate layer/second emitting unit/cathode can be given.

The first emitting unit and the second emitting unit are independently selected from the above-mentioned emitting units, for example.

The intermediate layer is also generally referred to as an intermediate electrode, an intermediate conductive layer, a charge generating layer, an electron withdrawing layer, a connecting layer, a connector layer, or an intermediate insulating layer. The intermediate layer is a layer that supplies electrons to the first emitting unit and holes to the second emitting unit, and can be formed from known materials.

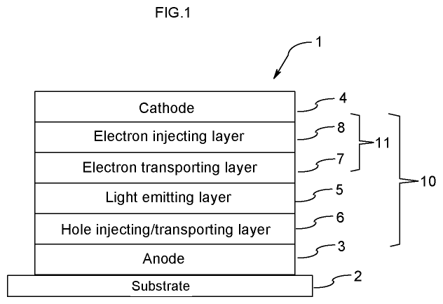

FIG. 1 shows a schematic configuration of one example of the organic EL device of the invention. The organic EL device 1 comprises a substrate 2, an anode 3, a cathode 4 and an emitting unit 10 provided between the anode 3 and the cathode 4. The emitting unit 10 comprises an emitting layer 5 preferably comprising a host material and a dopant. A hole injecting and transporting layer 6 or the like may be provided between the emitting layer 5 and the anode 3 and an electron injecting layer 8 and an electron transporting layer 7 or the like (electron injecting and transporting unit 11) may be provided between the emitting layer 5 and the cathode 4. An electron-barrier layer may be provided on the anode 3 side of the emitting layer 5 and a hole-barrier layer may be provided on the cathode 4 side of the emitting layer 5. Due to such configuration, electrons or holes can be confined in the emitting layer 5, whereby possibility of generation of excitons in the emitting layer 5 can be improved.

Hereinbelow, an explanation will be made on function, materials, etc. of each layer constituting the organic EL device described in the present specification.

### (Substrate)

The substrate is used as a support of the organic EL device. The substrate preferably has a light transmittance of 50% or more in the visible light region with a wavelength of 400 to 700 nm, and a smooth substrate is preferable. Examples of the material of the substrate include soda-lime glass, aluminosilicate glass, quartz glass, plastic and the like. As a substrate, a flexible substrate can be used. The flexible substrate means a substrate that can be bent (flexible), and examples thereof include a plastic substrate and the like. Specific examples of the material for forming the plastic substrate include polycarbonate, polyallylate, polyether sulfone, polypropyl-ene, polyester, polyvinyl fluoride, polyvinyl chloride, polyimide, polyethylene naphthalate and the like. Also, an inorganic vapor deposited film can be used.

### (Anode)

As the anode, for example, it is preferable to use a metal, an alloy, a conductive compound, a mixture thereof or the like and having a high work function (specifically, 4.0 eV or more). Specific examples of the material of the anode include indium oxide-tin oxide (ITO: Indium Tin Oxide), indium oxide-tin oxide containing silicon or silicon oxide, indium oxide-zinc oxide, indium oxide containing tungsten oxide or zinc oxide, graphene and the like. In addition, it is also possible to use gold, silver, platinum, nickel, tungsten, chromium, molybdenum, iron, cobalt, copper, palladium, titanium, and nitrides of these metals (e.g. titanium oxide).

The anode is normally formed by depositing these materials on the substrate by a sputtering method. For example, indium oxide-zinc oxide can be formed by a sputtering method by using a target in which 1 to 10 mass % zinc oxide is added relative to indium oxide. Further, indium oxide containing tungsten oxide or zinc oxide can be formed by a sputtering method by using a target in which 0.5 to 5 mass % of tungsten oxide or 0.1 to 1 mass % of zinc oxide is added relative to indium oxide.

As other methods for forming the anode, a vacuum deposition method, a coating method, an inkjet method, a spin coating method or the like can be given. When silver paste or the like is used, it is possible to use a coating method, an inkjet method or the like.

The hole-injecting layer formed in contact with the anode is formed by using a material that allows easy hole injection regardless of the work function of the anode. For this reason, in the anode, it is possible to use a common electrode material, e.g. a metal, an alloy, a conductive compound and a mixture thereof. Specifically, a material having a small work function such as alkaline metals such as lithium and cesium; alkaline earth metals such as calcium and strontium; alloys containing these metals (for example, magnesium-silver and aluminum-lithium); rare earth metals such as europium and ytterbium; and an alloy containing rare earth metals.

### (Hole-Transporting Layer)/(Hole-Injecting Layer)

The hole-transporting layer is an organic layer that is formed between the emitting layer and the anode, and has a function of transporting holes from the anode to the emitting layer. If the hole-transporting layer is composed of plural layers, an organic layer that is nearer to the anode may often be defined as the hole-injecting layer. The hole-injecting layer has a function of injecting holes efficiently to the organic layer unit from the anode. Said hole injection layer is generally used for stabilizing hole injection from anode to hole transporting layer which is generally consist of organic materials. Organic material having good contact with anode or organic material with p-type doping is preferably used for the hole injection layer.

p-doping usually consists of one or more p-dopant materials and one or more matrix materials. Matrix materials preferably have shallower HOMO level and p-dopant preferably have deeper LUMO level to enhance the carrier density of the layer. Specific examples for p-dopants are the below mentioned acceptor materials. Suitable matrix materials are the hole transport materials mentioned below, preferably aromatic or heterocyclic amine compounds.

Acceptor materials, or fused aromatic hydrocarbon materials or fused heterocycles which have high planarity, are preferably used as p-dopant materials for the hole injection layer. Specific examples for acceptor materials are, quinone compounds with one or more electron withdrawing groups, such as F₄TCNQ (2,3,5,6-tetrafluoro-7,7,8,8-tetracyanoquinodimethane), and 1,2,3-tris[(cyano)(4-cyano-2,3,5,6-tetrafluorophenyl)methylene]cyclopropane; hexa-azatriphenylene compounds with one or more electron withdrawing groups, such as hexa-azatriphenylene-hexanitrile; aromatic hydrocarbon compounds with one or more electron withdrawing groups; and aryl boron compounds with one or more electron withdrawing groups. Preferred p-dopants are quinone compounds with one or more electron withdrawing groups, such as F₄TCNQ, 1,2,3-Tris[(cyano)(4-cyano-2,3,5,6-tetrafluorophenyl)methylene]cyclopropane.

The ratio of the p-type dopant is preferably less than 20% of molar ratio, more preferably less than 10%, such as 1%, 3%, or 5%, related to the matrix material.

The hole transporting layer is generally used for injecting and transporting holes efficiently, and aromatic or heterocyclic amine compounds are preferably used.

Specific examples for compounds for the hole transporting layer are represented by the general formula (H),

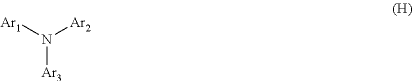

wherein
Ar₁ to Ar₃ each independently represents substituted or unsubstituted aryl group having 5 to 50 carbon atoms or substituted or unsubstituted heterocyclic group having 5 to 50 cyclic atoms, preferably phenyl group, biphenyl group, terphenyl group, naphthyl group, phenanthryl group, triphenylenyl group, fluorenyl group, spirobifluorenyl group, indenofluorenyl group, carbazolyl group, dibenzofuranyl group, dibenzothiophenyl group, carbazole substituted aryl group, dibenzofuran substituted aryl group or dibenzothiophene substituted aryl group; two or more substituents selected among Ar¹ to Ar³ may be bonded to each other to form a ring structure, such as a carbazole ring structure, or a acridane ring structure.

Preferably, at least one of Ar₁ to Ar₃ have additional one aryl or heterocyclic amine substituent, more preferably Ar₁ has an additional aryl amino substituent, at the case of that it is preferable that Ar₁ represents substituted or unsubstituted biphenylene group, substituted or unsubstituted fluorenylene group. Specific examples for the hole transport material are

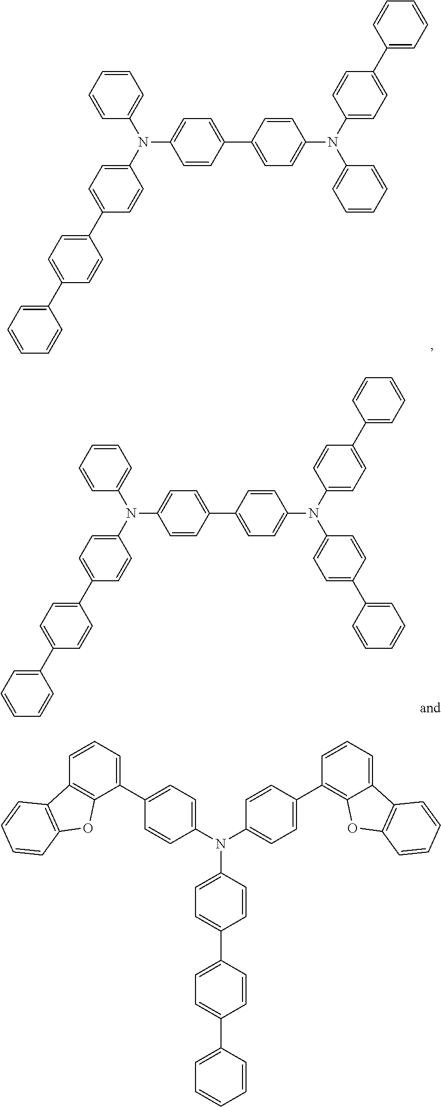 [SMILES: c1ccc(-c2ccc(-c3ccc(N(c4ccccc4)c4ccc(-c5ccc(N(c6ccccc6)c6ccc(-c7ccccc7)cc6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

and the like.

A second hole transporting layer is preferably inserted between the first hole transporting layer and the emitting layer to enhance device performance by blocking excess electrons or excitons.

Specific examples for second hole transporting layer are the same as for the first hole transporting layer. It is preferred that second hole transporting layer has higher triplet energy to block triplet excitons, especially for phosphorescent devices, such as bicarbazole compounds, biphenyl-amine compounds, triphenylenyl amine compounds, fluorenyl amine compounds, carbazole substituted arylamine compounds, dibenzofuran substituted arylamine compounds, and dibenzothiophene substituted arylamine compounds.

### (Emitting Layer)

The emitting layer is a layer containing a substance having a high emitting property (emitter material or dopant material). As the dopant material, various materials can be used. For example, a fluorescent emitting compound (fluorescent dopant), a phosphorescent emitting compound (phosphorescent dopant) or the like can be used. A fluorescent emitting compound is a compound capable of emitting light from the singlet excited state, and an emitting layer containing a fluorescent emitting compound is called a fluorescent emitting layer. Further, a phosphorescent emitting compound is a compound capable of emitting light from the triplet excited state, and an emitting layer containing a phosphorescent emitting compound is called a phosphorescent emitting layer.

Preferably, the emitting layer in the organic EL device of the present application comprises a compound of formula (I) as a dopant material.

The emitting layer preferably comprises at least one dopant material and at least one host material that allows it to emit light efficiently. In some literatures, a dopant material is called a guest material, an emitter or an emitting material. In some literatures, a host material is called a matrix material.

A single emitting layer may comprise plural dopant materials and plural host materials. Further, plural emitting layers may be present.

In the present specification, a host material combined with the fluorescent dopant is referred to as a “fluorescent host” and a host material combined with the phosphorescent dopant is referred to as the “phosphorescent host”. Note that the fluorescent host and the phosphorescent host are not classified only by the molecular structure. The phosphorescent host is a material for forming a phosphorescent emitting layer containing a phosphorescent dopant, but does not mean that it cannot be used as a material for forming a fluorescent emitting layer. The same can be applied to the fluorescent host.

In one embodiment, it is preferred that the emitting layer comprises the compound represented by formula (I) according to the present invention (hereinafter, these compounds may be referred to as the “compound (I)”). More preferably, it is contained as a dopant material. Further, it is preferred that the compound (I) be contained in the emitting layer as a fluorescent dopant. Even further, it is preferred that the compound (I) be contained in the emitting layer as a blue fluorescent dopant.

In one embodiment, no specific restrictions are imposed on the content of the compound (1) as the dopant material in the emitting layer. In respect of sufficient emission and concentration quenching, the content is preferably 0.5 to 70 mass %, more preferably 0.8 to 30 mass %, further preferably 1 to 30 mass %, still further preferably 1 to 20 mass %, and particularly preferably 1 to mass %, further particularly preferably 1 to 5 mass %, even further particularly preferably 2 to 4 mass %, related to the mass of the emitting layer.

### (Fluorescent Dopant)

As a fluorescent dopant other than the compound (1), a fused polycyclic aromatic compound, a styrylamine compound, a fused ring amine compound, a boron-containing compound, a pyrrole compound, an indole compound, a carbazole compound can be given, for example. Among these, a fused ring amine compound, a boron-containing compound, carbazole compound is preferable.

As the fused ring amine compound, a diaminopyrene compound, a diaminochrysene compound, a diaminoanthracene compound, a diaminofluorene compound, a diaminofluorene compound with which one or more benzofuro skeletons are fused, or the like can be given.

As the boron-containing compound, a pyrromethene compound, a triphenylborane compound or the like can be given.

As a blue fluorescent dopant, pyrene compounds, styrylamine compounds, chrysene compounds, fluoranthene compounds, fluorene compounds, diamine compounds, triarylamine compounds and the like can be given, for example. Specifically, N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenyamine (abbreviation: YGAPA), 4-(10-phenyl-9-anthryl)-4′-(9-phenyl-9H-carbazole-3-yl)triphenylamine (abbreviation: PCBAPA) or the like can be given.

As a green fluorescent dopant, an aromatic amine compound or the like can be given, for example. Specifically, N-(9,10-diphenyl-2-anthryl)-N,9-diphenyl-9H-carbazole-3-amine (abbreviation: 2PCAPA), N-[9,10-bis(1,1′-biphenyl-2-yl)-2-anthryl]-N,9-diphenyl-9H-carbazole-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), N-[9,10-bis(1,1′-biphenyl-2-yl)]-N-[4-(9H-carbazole-9-yl)phenyl]-N-phenylanthracene-2-amine (abbreviation: 2YGABPhA), N,N,9-triphenylanthracene-9-amine (abbreviation: DPhAPhA) or the like can be given, for example.

As a red fluorescent dopant, a tetracene compound, a diamine compound or the like can be given. Specifically, N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD) or the like can be given.

### (Phosphorescent Dopant)

As a phosphorescent dopant, a phosphorescent emitting heavy metal complex and a phosphorescent emitting rare earth metal complex can be given.

As the heavy metal complex, an iridium complex, an osmium complex, a platinum complex or the like can be given. The heavy metal complex is for example an ortho-metalated complex of a metal selected from iridium, osmium and platinum.

Examples of rare earth metal complexes include terbium complexes, europium complexes and the like. Specifically, tris(acetylacetonate)(monophenanthroline)terbium(III) (abbreviation: Tb(acac)₃(Phen)), tris(1,3-diphenyl-1,3-propandionate)(monophenanthroline)europium(II) (abbreviation: Eu(DBM)₃(Phen)), tris[1-(2-thenoyl)-3,3,3-trifluoroacetonate](monophenanthroli-ne)europium(II) (abbreviation: Eu(TTA)₃(Phen)) or the like can be given. These rare earth metal complexes are preferable as phosphorescent dopants since rare earth metal ions emit light due to electronic transition between different multiplicity.

As a blue phosphorescent dopant, an iridium complex, an osmium complex, a platinum complex, or the like can be given, for example. Specifically, bis[2-(4′,6′-difluorophenyl)pyridinate-N,C2′]iridium(III) tetrakis(1-pyrazolyl)borate (abbreviation: Flr6), bis[2-(4′,6′-difluorophenyl) pyri-dinato-N,C2′]iridium(II) picolinate (abbreviation: Ir(CF₃ppy)₂(pic)), bis[2-(4′,6′-difluorophenyl)pyridinato-N,C2′]iridium(II) acetylacetonate (abbreviation: Flracac) or the like can be given.

As a green phosphorescent dopant, an iridium complex or the like can be given, for example. Specifically, tris(2-phenylpyridinato-N,C2′) iridium(III) (abbreviation: Ir(ppy)₃), bis(1,2-diphenyl-1H-benzimidazolato)iridium(III) acetylacetonate (abbreviation: Ir(pbi)₂(acac)), bis(benzo[h]quinolinato)iridium(III) acetylacetonate (abbreviation: Ir(bzq)₂(acac)) or the like can be given.

As a red phosphorescent dopant, an iridium complex, a platinum complex, a terbium complex, a europium complex or the like can be given. Specifically, bis[2-(2′-benzo[4,5-a]thienyl)pyridinato-N,C3′]iridium(II) acetylacetonate (abbreviation: Ir(btp)₂(acac)), bis(1-phenylisoquinolinato-N,C2′)iridium(III) acetylacetonate (abbreviation: Ir(piq)₂(acac)), (acetylacetonato)bis[2,3-bis(4-fluorophenyl)quinoxalinato]iridium(II) (abbreviation: Ir(Fdpq)₂(acac)), 2,3,7,8,12,13,17,18-octaethyl-21H,23H-porphyrin platinum(II) (abbreviation PtOEP) or the like can be given.

As mentioned above, the emitting layer preferably comprises at least one compound (1) as a dopant.

### (Host Material)

As host material, metal complexes such as aluminum complexes, beryllium complexes and zinc complexes; heterocyclic compounds such as indole compounds, pyridine compounds, pyrimidine compounds, triazine compounds, quinoline compounds, isoquinoline compounds, quinazoline compounds, dibenzofuran compounds, dibenzothiophene compounds, oxadiazole compounds, benzimidazole compounds, phenanthroline compounds; fused polyaromatic hydrocarbon (PAH) compounds such as a naphthalene compound, a triphenylene compound, a carbazole compound, an anthracene compound, a phenanthrene compound, a pyrene compound, a chrysene compound, a naphthacene compound, a fluoranthene compound; and aromatic amine compound such as triarylamine compounds and fused polycyclic aromatic amine compounds can be given, for example. Plural types of host materials can be used in combination.

As a fluorescent host, a compound having a higher singlet energy level than a fluorescent dopant is preferable. For example, a heterocyclic compound, a fused aromatic compound or the like can be given. As a fused aromatic compound, an anthracene compound, a pyrene compound, a chrysene compound, a naphthacene compound or the like are preferable. An anthracene compound is preferentially used as blue fluorescent host.

In the case that compound (1) is employed as at least one dopant material, preferred host materials are substituted or unsubstituted polyaromatic hydrocarbon (PAH) compounds, substituted or unsubstituted polyheteroaromatic compounds, substituted or unsubstituted anthracene compounds, or substituted or unsubstituted pyrene compounds, preferably substituted or unsubstituted anthracene compounds or substituted or unsubstituted pyrene compounds, more preferably substituted or unsubstituted anthracene compounds, most preferably anthracene compounds represented by formula (10), as mentioned above.

As a phosphorescent host, a compound having a higher triplet energy level as compared with a phosphorescent dopant is preferable. For example, a metal complex, a heterocyclic compound, a fused aromatic compound or the like can be given. Among these, an indole compound, a carbazole compound, a pyridine compound, a pyrimidine compound, a triazine compound, a quinolone compound, an isoquinoline compound, a quinazoline compound, a dibenzofuran compound, a dibenzothiophene compound, a naphthalene compound, a triphenylene compound, a phenanthrene compound, a fluoranthene compound or the like can be given.

### (Electron-Transporting Layer)/(Electron-Injecting Layer)

The electron-transporting layer is an organic layer that is formed between the emitting layer and the cathode and has a function of transporting electrons from the cathode to the emitting layer. When the electron-transporting layer is formed of plural layers, an organic layer or an inorganic layer that is nearer to the cathode is often defined as the electron injecting layer (see for example layer 8 in FIG. 1, wherein an electron injecting layer 8 and an electron transporting layer 7 form an electron injecting and transporting unit 11). The electron injecting layer has a function of injecting electrons from the cathode efficiently to the organic layer unit. Preferred electron injection materials are alkali metal, alkali metal compounds, alkali metal complexes, the alkaline earth metal complexes and the rare earth metal complexes.

According to one embodiment, it is preferred that the electron-transporting layer further comprises one or more layer(s) like a second electron-transporting layer, an electron injection layer to enhance efficiency and lifetime of the device, a hole blocking layer, an exciton blocking layer or a triplet blocking layer.

According to one embodiment, it is preferred that an electron-donating dopant be contained in the interfacial region between the cathode and the emitting unit. Due to such a configuration, the organic EL device can have an increased luminance or a long life. Here, the electron-donating dopant means one having a metal with a work function of 3.8 eV or less. As specific examples thereof, at least one selected from an alkali metal, an alkali metal complex, an alkali metal compound, an alkaline earth metal, an alkaline earth metal complex, an alkaline earth metal compound, a rare earth metal, a rare earth metal complex and a rare earth metal compound or the like can be mentioned.

As the alkali metal, Li (work function: 2.9 eV), Na (work function: 2.36 eV), K (work function: 2.28 eV), Rb (work function: 2.16 eV), Cs (work function: 1.95 eV) and the like can be given. One having a work function of 2.9 eV or less is particularly preferable. Among them, K, Rb and Cs are preferable. Rb or Cs is further preferable. Cs is most preferable. As the alkaline earth metal, Ca (work function: 2.9 eV), Sr (work function: 2.0 eV to 2.5 eV), Ba (work function: 2.52 eV) and the like can be given. One having a work function of 2.9 eV or less is particularly preferable. As the rare-earth metal, Sc, Y, Ce, Tb, Yb and the like can be given. One having a work function of 2.9 eV or less is particularly preferable.

Examples of the alkali metal compound include an alkali oxide such as Li₂O, Cs₂O or K₂O, and an alkali halide such as LiF, NaF, CsF and KF. Among them, LiF, Li₂O and NaF are preferable.

Examples of the alkaline earth metal compound include BaO, SrO, CaO, and mixtures thereof such as BaₓSr₁₋ₓO (0<x<1) and BaₓCa₁₋ₓO (0<x<1). Among them, BaO, SrO and CaO are preferable. Examples of the rare earth metal compound include YbF₃, ScF₃, ScO₃, Y₂O₃, Ce₂O₃, GdF₃ and TbF₃. Among these, YbF₃, ScF₃ and TbF₃ are preferable.

The alkali metal complexes, the alkaline earth metal complexes and the rare earth metal complexes are not particularly limited as long as they contain, as a metal ion, at least one of alkali metal ions, alkaline earth metal ions, and rare earth metal ions. Meanwhile, preferred examples of the ligand include, but are not limited to, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzimidazole, hydroxybenzotriazole, hydroxyfluborane, bipyridyl, phenanthroline, phthalocyanine, porphyrin, cyclopentadiene, β-diketones, and azomethines.

Regarding the addition form of the electron-donating dopant, it is preferred that the electron-donating dopant be formed in a shape of a layer or an island in the interfacial region. A preferred method for the formation is a method in which an organic compound (a light emitting material or an electron-injecting material) for forming the interfacial region is deposited simultaneously with deposition of the electron-donating dopant by a resistant heating deposition method, thereby dispersing the electron-donating dopant in the organic compound.

In a case where the electron-donating dopant is formed into the shape of a layer, the light-emitting material or electron-injecting material which serves as an organic layer in the interface is formed into the shape of a layer. After that, a reductive dopant is solely deposited by the resistant heating deposition method to form a layer preferably having a thickness of from 0.1 nm to 15 nm. In a case where the electron-donating dopant is formed into the shape of an island, the emitting material or the electron-injecting material which serves as an organic layer in the interface is formed into the shape of an island. After that, the electron-donating dopant is solely deposited by the resistant heating deposition method to form an island preferably having a thickness of from 0.05 nm to 1 nm. As the electron-transporting material used in the electron-transporting layer other than a compound of the formula (I), an aromatic heterocyclic compound having one or more hetero atoms in the molecule may preferably be used. In particular, a nitro-gen-containing heterocyclic compound is preferable.

According to one embodiment, it is preferable that the electron-transporting layer comprises a nitrogen-containing heterocyclic metal chelate.

According to the other embodiment, it is preferable that the electron-transporting layer comprises a substituted or unsubstituted nitrogen containing heterocyclic compound. Specific examples of preferred heterocyclic compounds for the electron-transporting layer are, 6-membered azine compounds; such as pyridine compounds, pyrimidine compounds, triazine compounds, pyrazine compounds, preferably pyrimidine compounds or triazine compounds; 6-membered fused azine compounds, such as quinolone compounds, isoquinoline compounds, quinoxaline compounds, quinazoline compounds, phenanthroline compounds, benzoquinoline compounds, benzoisoquinoline compounds, dibenzoquinoxaline compounds, preferably quinolone compounds, isoquinoline compounds, phenanthroline compounds; 5-membered heterocyclic compounds, such as imidazole compounds, oxazole compounds, oxadiazole compounds, triazole compounds, thiazole compounds, thiadiazole compounds; fused imidazole compounds, such as benzimidazole compounds, imidazopyridine compounds, naphthoimidazole compounds, benzimidazophenanthridine compounds, benzimidzobenzimidazole compounds, preferably benzimidazole compounds, imidazopyridine compounds or benzimidazophenanthridine compounds.

According to another embodiment, it is preferable the electron-transporting layer comprises a phosphine oxide compound represented as Arₚ₁Arₚ₂Arₚ₃P═O.

Arₚ₁ to Arₚ₃ are the substituents of phosphor atom and each independently represent substituted or unsubstituted above mentioned aryl group or substituted or unsubstituted above mentioned heterocyclic group.

According to another embodiment, it is preferable that the electron-transporting layer comprises aromatic hydrocarbon compounds. Specific examples of preferred aromatic hydrocarbon compounds for the electron-transporting layer are, oligo-phenylene compounds, naphthalene compounds, fluorene compounds, fluoranthenyl group, anthracene compounds, phenanthrene compounds, pyrene compounds, triphenylene compounds, benzanthracene compounds, chrysene compounds, benzphenanthrene compounds, naphthacene compounds, and benzochrysene compounds, preferably anthracene compounds, pyrene compounds and fluoranthene compounds.

### (Cathode)

For the cathode, a metal, an alloy, an electrically conductive compound, and a mixture thereof, each having a small work function (specifically, a work function of 3.8 eV or less) are preferably used. Specific examples of a material for the cathode include an alkali metal such as lithium and cesium; an alkaline earth metal such as magnesium, calcium, and strontium; aluminum, an alloy containing these metals (for example, magnesium-silver, aluminum-lithium); a rare earth metal such as europium and ytterbium; and an alloy containing a rare earth metal.

The cathode is usually formed by a vacuum vapor deposition or a sputtering method. Further, in the case of using a silver paste or the like, a coating method, an inkjet method, or the like can be employed.

Moreover, various electrically conductive materials such as silver, ITO, graphene, indium oxide-tin oxide containing silicon or silicon oxide, selected independently from the work function, can be used to form a cathode. These electrically conductive materials are made into films using a sputtering method, an inkjet method, a spin coating method, or the like.

### (Insulating Layer)

In the organic EL device, pixel defects based on leakage or a short circuit are easily generated since an electric field is applied to a thin film. In order to prevent this, it is preferred to insert an insulating thin layer between a pair of electrodes. Examples of materials used in the insulating layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide. A mixture thereof may be used in the insulating layer, and a laminate of a plurality of layers that include these materials can be also used for the insulating layer.

### (Spacing Layer)

A spacing layer is a layer provided between a fluorescent emitting layer and a phosphorescent emitting layer when a fluorescent emitting layer and a phosphorescent emitting layer are stacked in order to prevent diffusion of excitons generated in the phosphorescent emitting layer to the fluorescent emitting layer or in order to adjust the carrier balance. Further, the spacing layer can be provided between the plural phosphorescent emitting layers.

Since the spacing layer is provided between the emitting layers, the material used for the spacing layer is preferably a material having both electron-transporting capability and hole-transporting capability. In order to prevent diffusion of the triplet energy in adjacent phosphorescent emitting layers, it is preferred that the spacing layer have a triplet energy of 2.6 eV or more. As the material used for the spacing layer, the same materials as those used in the above-mentioned hole-transporting layer can be given.

### (Electron-Blocking Layer, Hole-Blocking Layer, Exciton-Blocking Layer)

An electron-blocking layer, a hole-blocking layer, an exciton (triplet)-blocking layer, and the like may be provided in adjacent to the emitting layer.

The electron-blocking layer has a function of preventing leakage of electrons from the emitting layer to the hole-transporting layer. The hole-blocking layer has a function of preventing leakage of holes from the emitting layer to the electron-transporting layer. In order to improve hole blocking capability, a material having a deep HOMO level is preferably used. The exciton-blocking layer has a function of preventing diffusion of excitons generated in the emitting layer to the adjacent layers and confining the excitons within the emitting layer. In order to improve triplet block capability, a material having a high triplet level is preferably used.

### (Method for Forming a Layer)

The method for forming each layer of the organic EL device of the invention is not particularly limited unless otherwise specified. A known film-forming method such as a dry film-forming method, a wet film-forming method or the like can be used. Specific examples of the dry film-forming method include a vacuum deposition method, a sputtering method, a plasma method, an ion plating method, and the like. Specific examples of the wet film-forming method include various coating methods such as a spin coating method, a dipping method, a flow coating method, an inkjet method, and the like.

### (Film Thickness)

The film thickness of each layer of the organic EL device of the invention is not particularly limited unless otherwise specified. If the film thickness is too small, defects such as pinholes are likely to occur to make it difficult to obtain a sufficient luminance. If the film thickness is too large, a high driving voltage is required to be applied, leading to a lowering in efficiency. In this respect, the film thickness is preferably 0.1 nm to 10 μm, and more preferably 5 nm to 0.2 μm.

### (Electronic Apparatus (Electronic Equipment))

The present invention further relates to an electronic equipment (electronic apparatus) comprising the organic electroluminescence device according to the present application. Examples of the electronic apparatus include display parts such as an organic EL panel module; display devices of television sets, mobile phones, smart phones, and personal computer, and the like; and emitting devices of a lighting device and a vehicle lighting device.

### EXAMPLES

Next, the invention will be explained in more detail in accordance with the following synthesis examples, examples, and comparative examples, which should not be construed as limiting the scope of the invention.

The percentages and ratios mentioned in the examples below—unless stated otherwise—are % by weight and weight ratios.

### I SYNTHESIS EXAMPLES

All experiments are carried out in protective gas atmosphere.

### Compound 1

### Step 1-1

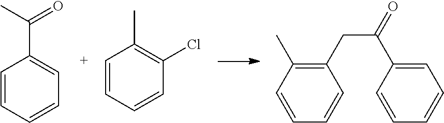

The product was prepared according to Org. Lett. 2002, 4, 4053.

To 24.0 g (0.250 mol) sodium t-butoxide in 200 ml water free THF, 12.0 g (0.100 mol) acetophenone were added under argon at 25° C. 12.6 g (0.100 mmol) o-chlorotoluene were added. The reaction mixture was degassed with argon. 287 mg (0.50 mmol) (SIPr)Pd(allyl)Cl (CAS: 478980-01-7) were added and the reaction mixture was degassed with argon. The reaction mixture was stirred at 25° C. under argon for 2 h and then for 1.5 h at 60° C.

The reaction mixture was poured on water. The organic phase was extracted with dichloromethane. The organic phase was dried with magnesium sulfate and the solvent was removed in vacuum. The product was used without purification for the next step.

Yield 21.0 g (100%)

### Step 1-2

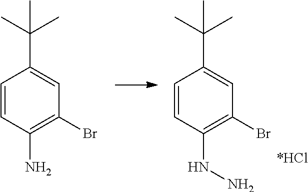

To a solution of 22.8 g (0.100 mol) 2-bromo-t-butyl-aniline in 225 ml HCl (36%) a solution of 6.90 g (0.100 mol) sodium nitrite in 39 ml water was slowly added at −10° C. The reaction mixture was stirred at −10° C. for 15 min. 56.9 g (0.300 mol) tin(II) chloride in 48 ml HCl (36%) was slowly added at −10° C.

The reaction mixture was stirred at −10° C. for 15 min. The product was filtered off and was washed with a sat. NaCl solution. The product was washed with c-hexane. The product was dried at 40° C. in vacuum. Yield 39.5 g content 36%. The product was used without purification for the next reaction.

### Step 1-3

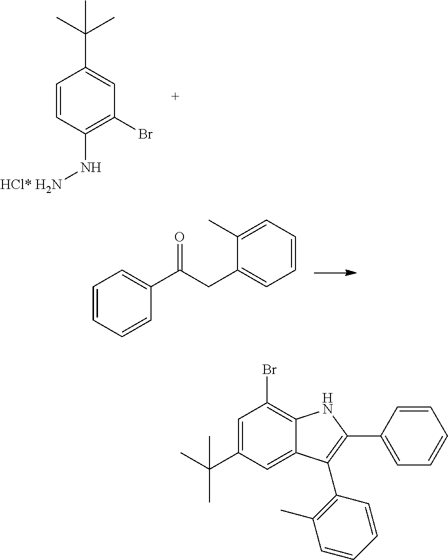

To 2.10 g (10.0 mmol) of the product of step 1 and 9.27 g (12.0 mmol, content 36%) of the product of step 2 in 25 ml ethanol, 1.07 g (20.0 mmol) sulfuric acid (96%) were added. The reaction mixture was refluxed under nitrogen for 3 h.

The reaction mixture was poured on a 10% sodium hydroxide solution in water. The water phase was extracted with dichloromethane. The organic phase was dried with magnesium sulfate and the solvent was removed in vacuum. Column chromatography on silica gel with heptane/toluene gave the product. Yield 3.15 g (76%).

¹H NMR (300 MHz, CD₂Cl₂) δ: 8.49 (s, 1H), 7.50 (s, 1H), 7.32 (m, 10H), 2.07 (s, 3H), 1.36 (s, 9H).

### Step 1-4

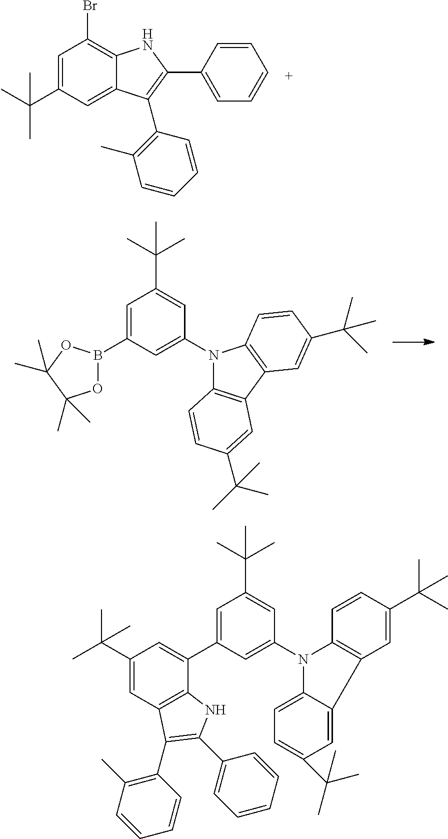

2.00 g (4.78 mmol) of the product of step 3, 2.75 g (5.11 mmol) of the product of step 8 and 3.04 g (14.3 mmol) tri potassium phosphate, in 40 ml toluene, 20 ml dioxane and 15 ml water were degassed with argon. 157 mg (0.382 mmol) SPhos and 43 mg (190 mmol) palladium (II) acetate are added and the reaction mixture is degassed with argon.

The reaction mixture was refluxed for 1 h under argon.

The solids were filtered off and washed with heptane. The organic phase was separated and was dried with magnesium sulfate. The solvent was removed in vacuum. Column chromatography on silica gel with heptane and then heptane/ethyl acetate 95/5 gave the product. Yield 3.50 g, (97%).

¹H NMR (300 MHz, DMSO-d₆) δ: 11.1 (s, 1H), 8.32 (s, 2H), 7.47 (m, 18H), 2.00 (s, 3H), 1.49 (s, 9H), 1.43 (s, 18H), 1.31 (s, 9H).

### Step 1-5

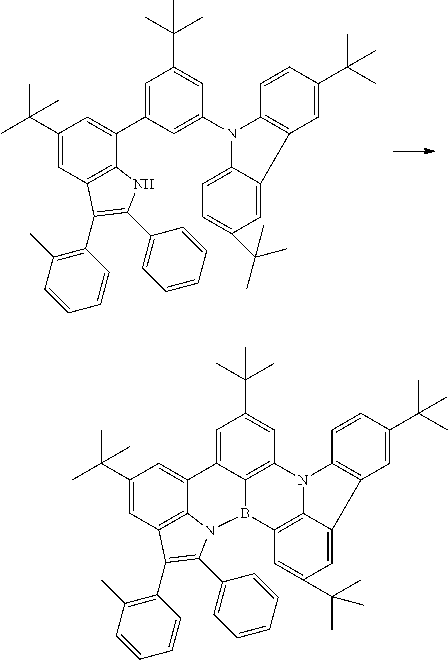

To 2.50 g (3.34 mmol) of the product of step 4 and 1.73 g (13.4 mmol)N-ethyl-N-isopropylpropan-2-amine in 35 ml water free o-dichlorobenzene 1.67 g (6.67 mmol) tribromoborane was added slowly during stirring and under argon. The reaction mixture was stirred for 96 h at 190° C. under argon.

The product was poured on methanol and the product was filtered off. Yield 1.42 g (56%).

¹H NMR (300 MHz, DMSO-d₆) δ: 8.51 (m, 5H), 8.38 (d, 1H), 7.78 (dd, 1H), 7.23 (m, 11H), 1.83 (s, 3H), 1.63 (s, 9H), 1.48 (s, 9H), 1.47 (s, 9H), 1.07 (s, 9H).

### Step 1-6

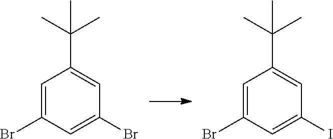

To a solution of 50.0 g (171 mmol) 1,3-dibromo-5-(tert-butyl)benzene in 700 ml water free THE 69.2 ml n-butyl lithium (2.5 M in hexane) was added slowly at −78° C. under argon. The reaction mixture was stirred for 30 min at −78° C. under argon. 47.8 g (188 mmol) diiodine in 100 ml THE were slowly added. The reaction mixture was warmed to −15° C. and 400 ml of a 10% solution sodium sulfite solution in water were added. Heptane was added and the organic phase was separated. The organic phase was dried with sodium sulfate and the solvent was removed in vacuum.

Yield 55.3 g; 81%

The product was used without purification for the next step.

### Step 1-7

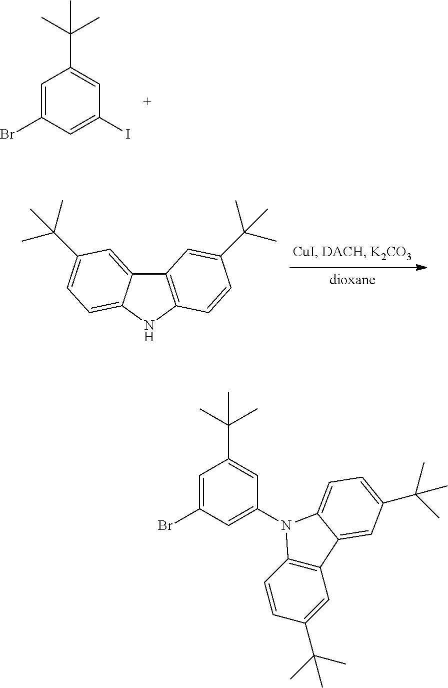 [SMILES: CC(C)(C)c1cc(Br)cc(I)c1 ; CC(C)(C)c1ccc2[nH]c3ccc(C(C)(C)C)cc3c2c1 ; CC(C)(C)c1cc(Br)cc(-n2c3ccc(C(C)(C)C)cc3c3cc(C(C)(C)C)ccc32)c1]

To a solution of 1-bromo-3-(tert-butyl)-5-iodobenzene (20 g, 59.0 mmol) in dioxane (230 ml) was added tripotassium phosphate (37.6 g, 177 mmol), 3,6-di-tert-butyl-9H-carbazole (13.19 g, 47.2 mmol), copper(I) iodide (1.124 g, 5.90 mmol) and 1,2-diaminocyclohexane (2.173 ml, 17.70 mmol). The flask was fitted with a thermometer and reflux condenser and the reaction was heated at 95° C. for 6 h. The reaction was cooled to room temperature, then toluene (200 mL) was added and the suspension filtered over celite directly into a separation funnel. The organic layer was washed with a 10% solution of 3-amino-2-propanol until the blue color disappeared. The organic layer was further washed with brine (20 mL), dried with sodium sulfate, filtered and concentrated. The crude was purified via flash chromatography in 100% heptanes to give 19.81 g white solid (86% yield). The molecular mass of the product was confirmed by LC-MS [M+H] 490.4.

### Step 1-8

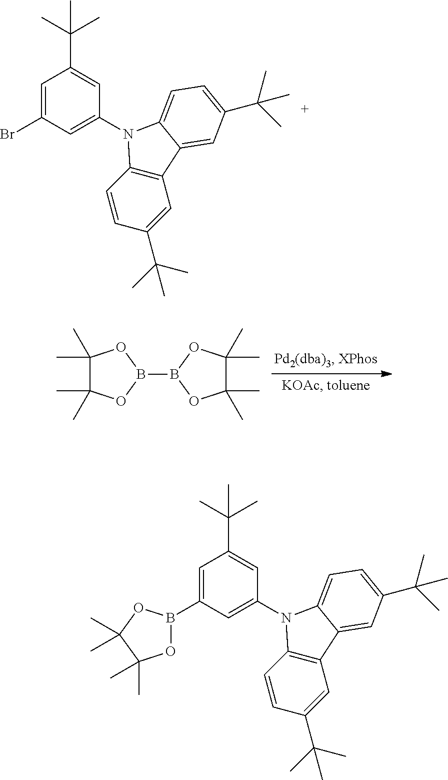

To a solution of 9-(3-bromo-5-(tert-butyl)phenyl)-3,6-di-tert-butyl-9H-carbazole (7.87 g, 16.04 mmol) in toluene (80 mL) was added 4,4,4′,4′,5,5,5′,5′-octamethyl-2,2′-bi(1,3,2-dioxaborolane) (6.93 g, 27.3 mmol), potassium acetate (3.15 g, 32.1 mmol), XPhos (0.765 g, 1.604 mmol) and Pd₂(dba)₃ (0.367 g, 0.401 mmol). The reaction was heated to 110° C. and stirred for 8 h. The reaction was cooled to room temperature, then toluene (100 mL) and water (75 mL) were added.

The layers were separated and the organic layer was further washed with brine (20 mL), dried with sodium sulfate, filtered and concentrated. The crude was dissolved in a mixture of dichloromethane:acetonitrile (1:2), then the dichloromethane was removed under reduced pressure, leading to the formation of a slurry in acetonitrile. The solid was filtered, giving 7.34 g white solid (85% yield) which was used as is for the next step. The molecular mass of the product was confirmed by LC-MS [M+H] 538.7.

In the following, the preparation of bromo benzimidazoles, which may be used as an alternative for the bromo indoles obtained in step 3 described above in the preparation of the compounds of formula (I) is shown:

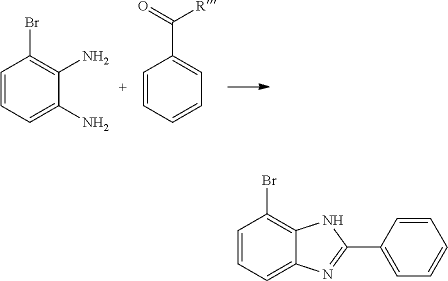

R″′ is H or OCH₃

Bromo benzimidazols can be prepared as described in Chemical Communications (2013), 49(39), 4304-4306, Journal of Medicinal Chemistry (2014), 57(17), 7355-7366, WO2015171628 A1, WO2020/217229, or Tetrahedron Letters (2014), 55(35), 4853-4855.

### Compound 2

### Step 2-1

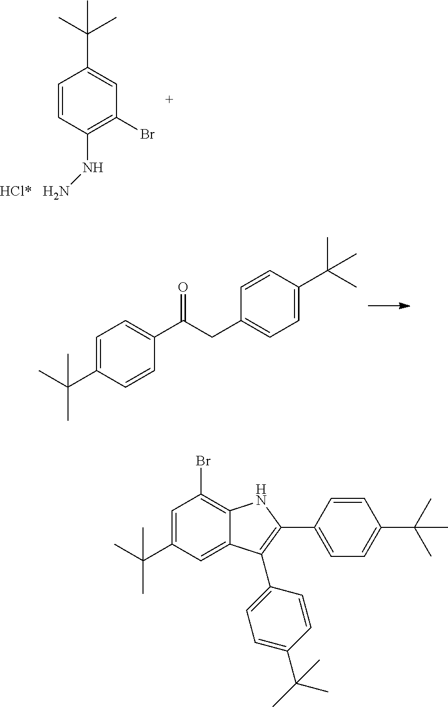

To 5.00 g (16.2 mmol) 1,2-bis(4-(tert-butyl)phenyl)ethan-1-one and 32.0 g (19.5 mmol, content 17%) of the product of step 2 in 25 ml ethanol, 3.18 g (32.4 mmol) sulfuric acid (96%) were added. The reaction mixture was refluxed under nitrogen for 1.5 h.

The reaction mixture was poured on a 10% sodium hydroxide solution in water. The water phase was extracted with dichloromethane. The organic phase was dried with magnesium sulfate and the solvent was removed in vacuum. Column chromatography on silica gel with heptane/toluene 95/5 gave the product. Yield 4.72 g (52%).

¹H NMR (300 MHz, DMSO-d₆) δ: 11.3 (s, 1H), 7.38 (m, 10H), 1.33 (s, 9H), 1.31 (s, 9H), 1.30 (s, 9H).

### Step 2-2

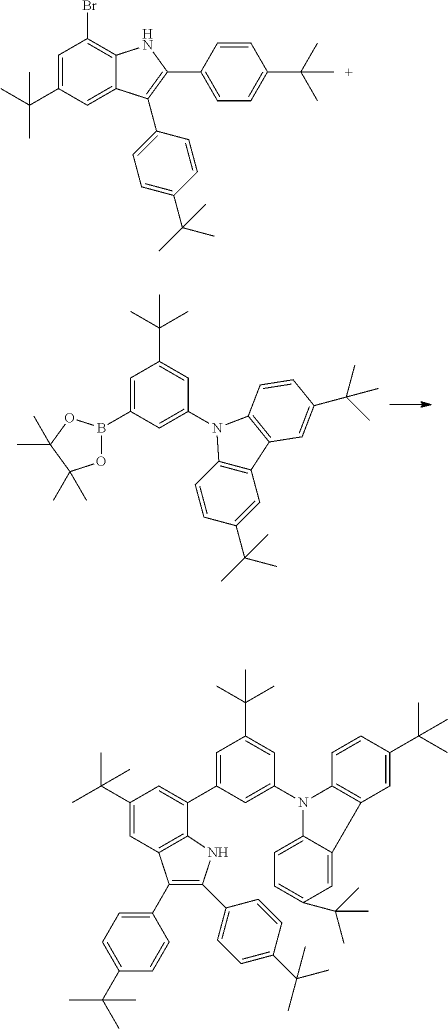

4.70 g (9.10 mmol) of the product of step 2-1, 5.14 g (9.55 mmol) of the product of step 8 and 5.79 g (27.3 mmol) tri potassium phosphate, in 60 ml toluene, 40 ml dioxane and 30 ml water were degassed with argon. 299 mg (0.728 mmol) SPhos and 82 mg (360 mmol) palladium (II) acetate were added and the reaction mixture is degassed with argon.

The reaction mixture was refluxed for 1 h under argon.

The solids were filtered of and washed with heptane. The organic phase was separated and was dried with sodium sulfate. The solvent was removed in vacuum. Column chromatography on silica gel with heptane/ethyl acetate 99/1 gave the product. Second column chromatography on silica gel with heptane gave the product. Yield 3.50 g, (45%).

¹H NMR (300 MHz, CD₂Cl₂) δ: 8.43 (s, 1H), 8.20 (s, 2H), 7.77 (m, 4H), 7.57 (s, 4H), 7.43 (m, 9H), 1.55 (s, 9H), 1.53 (s, 18H), 1.49 (s, 9H), 1.45 (s, 9H), 1.37 (s, 9H).

### Step 2-3

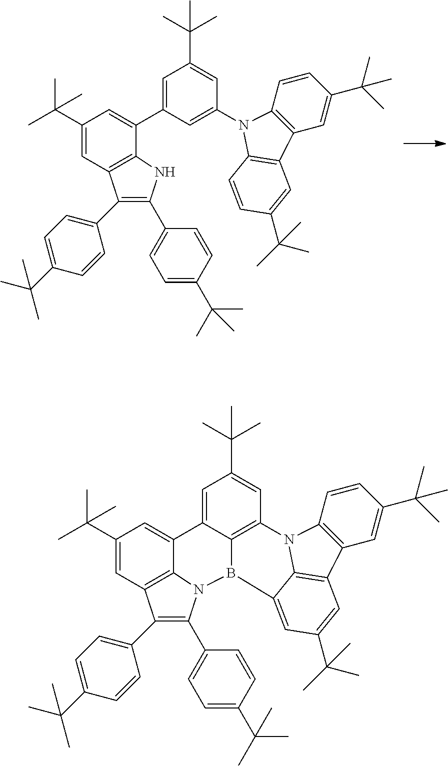

To 2.90 g (3.42 mmol) of the product of step 2-2 and 1.77 g (13.7 mmol)N-ethyl-N-isopropylpro-pan-2-amine in 39 ml water free o-dichlorobenzene 1.71 g (6.85 mmol) tribromoborane was added slowly during stirring and under argon. The reaction mixture was stirred for 4 d at 190° C. under argon.

The product was poured on methanol and the product was filtered of. The product was dissolved in dichloromethane and 50 ml heptane was added. The dichloromethane was slowly distilled of.

The product was filtered of. Yield: 1.40 g (48%) ¹H NMR (300 MHz, CD₂Cl₂) δ: 8.15-8.60 (m, 6H), 7.73-7.86 (m, 2H), 7.12-7.55 (m, 9H), 1.71 (s, 9H), 1.61 (s, 9H), 1.59 (s, 9H), 1.46 (s, 9H), 1.32 (s, 9H), 1.14 (s, 9H).

### Synthesis Compound 3

### Step 3-1

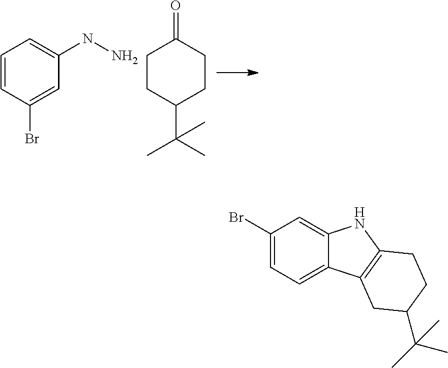

To 28.0 g (125 mmol) (3-bromophenyl)hydrazine hydrochloride in 270 acetic acid 19.4 g (125 mmol) 4-(tert-butyl)cyclohexan-1-one were added. The reaction mixture was stirred at 85° C. under nitrogen for 5 h.

The reaction mixture was poured on water. The water phase was extracted with toluene and the organic phase was washed with sodium hydrogen carbonate solution in water. The organic phase was dried with magnesium sulfate and the solvent was removed in vacuum. Yield 38.4 g The product was used directly for the next reaction step.

### Step 3-2

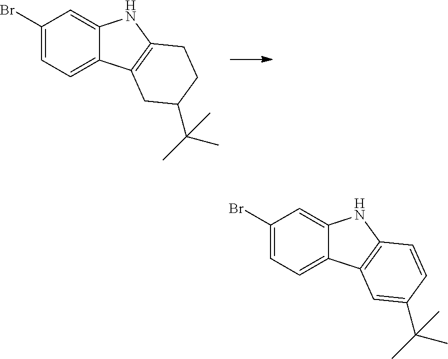 [SMILES: CC(C)(C)C1CCc2[nH]c3cc(Br)ccc3c2C1 ; CC(C)(C)c1ccc2[nH]c3cc(Br)ccc3c2c1]

To 38.1 g (124 mmol) of the product of step 3-1 in 250 ml toluene 56.5 g (249 mmol) DDQ were added during 10 min. The reaction mixture was stirred for 1 h at 25° C.

The reaction mixture was filtered and the organic phase was washed with a 10% solution of sodium hydroxide in water. The organic phase was dried with magnesium sulfate.

The formed isomers were separated by column chromatography on silica gel with heptane/ethyl acetate 95/5. Yield 8.47 g, (22.5%).

¹H NMR (300 MHz, DMSO-d₆) δ: 11.2 (s, 1H), 8.12 (s, 1H), 8.10 (s, 1H), 7.63 (d, 1H), 7.51 (dd, 1H), 7.43 (dd, 1H), 7.26 (dd, 1H), 1.39 (s, 9H).

### Step 3-3

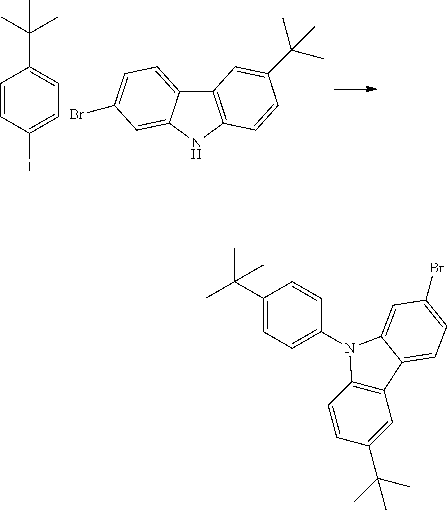

To 14.7 g (48.6 g) 2-bromo-6-(tert-butyl)-9H-carbazole in 150 ml dioxane, 13.9 g (53.5 mmol) 1-(tert-butyl)-4-iodobenzene, 31.0 g (146 mmol) tri potassium phosphate, 1.85 g (9.73 mmol) cop-per(I) iodide and 2.22 g (19.5 mmol) 1,2-diaminocyclohexane were added. The reaction mixture was stirred at 95° C. under nitrogen for 1 h.

The solids were filtered of and washed with heptane. The organic phase was washed with water and brine. The organic phase was dried with sodium sulfate and the solvent was removed in vacuum. Column chromatography on silica gel with heptane 100% gave the product. Yield 14.5 g, (69%).

¹H NMR (300 MHz, CDCl₃) δ: 8.13 (s, 1H), 8.02 (d, 1H), 7.63 (m, 2H), 7.51 (m, 4H), 7.37 (m, 2H), 1.48 (s, 9H), 1.46 (s, 9H).

### Step 3-4

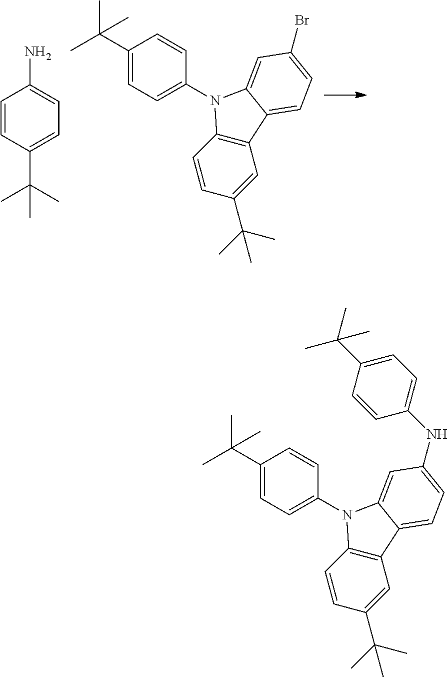

To 14.6 g (33.7 mmol) of the product of step 3-3 in 120 ml toluene, 5.63 g (37.7 mmol) 4-(tert-butyl)aniline and 7.13 g (74.1 mmol) sodium tert-butoxide were added. The reaction mixture was degassed with argon. 0.309 g (0.337 mmol) Pd₂(dba)₃ and 430 mg (0.674 mmol) BINAP were added. The reaction mixture was degassed with argon. The reaction mixture was stirred at 80° C. for 4 h.

The reaction mixture was filtered on Hyflo with toluene. The organic phase was washed with brine and dried with magnesium sulfate. The solvent was removed in vacuum. Column chromatography on silica gel with heptane/ethyl acetate 98/2 gave the product. Yield 15.7 g, (93%).

¹H NMR (300 MHz, DMSO-d₆) δ: 8.20 (s, 1H), 8.04 (m, 2H), 7.66 (d, 2H), 7.52 (d, 2H), 7.35 (d, 1H), 7.24 (m, 3H), 7.01 (m, 4H), 1.40 (s, 9H), 1.38 (s, 9H), 1.26 (s, 9H).

### Step 3-5

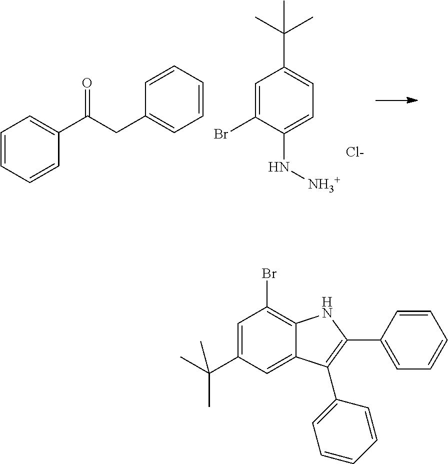 [SMILES: O=C(Cc1ccccc1)c1ccccc1 ; CC(C)(C)c1ccc(N[NH3+])c(Br)c1 ; [Cl-] ; CC(C)(C)c1cc(Br)c2[nH]c(-c3ccccc3)c(-c3ccccc3)c2c1]

To 10.0 g (51.0 mmol) 1,2-phenylethan-1-one and 101 g (61.1 mmol, content 17%) of the product of step 2 (compound1) in 25 ml ethanol, 8.75 g (89.0 mmol) sulfuric acid (96%) were added. The reaction mixture was refluxed under nitrogen for 30 min.

The reaction mixture was filtered on Hyflo with ethanol and the ethanol was removed. 50 ml sodium hydroxide solution 4M un water was added and the water phase was extracted with dichloromethane. The organic phase was dried with magnesium sulfate and the solvent was removed in vacuum. Column chromatography on silica gel with heptane/toluene 95/5 gave the product. Yield 13.5 g (65%).

¹H NMR (300 MHz, DMSO-d₆) δ: 11.5 (s, 1H), 7.38 (m, 12H), 1.31 (s, 9H).

### Step 3-6

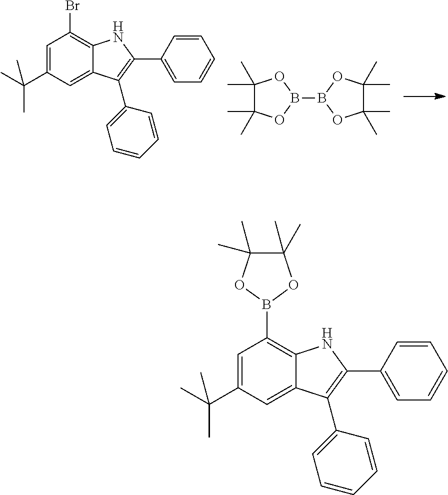

To 12.0 g (29.7 mmol) 7-bromo-5-(tert-butyl)-2,3-diphenyl-1H-indole in 120 ml toluene, 13.6 g (53.4 mmol) 4,4,4′, 4′, 5,5,5′, 5′-octamethyl-2,2′-bi(1,3,2-dioxaborolane) and 7.28 g (74.2 mmol) potassium acetate were added. The reaction mixture was degassed with argon. 408 mg (0.445 mmol) Pd₂(dba)₃ and 849 mg (1.78 mmol) 2-dicyclohexylphosphino-2′,4′,6′-triisopropylbiphenyl (x-Phos) were added. The reaction mixture was degassed with argon. The reaction mixture was stirred at 105° C. for 4 h under argon.

The reaction mixture was filtered and the solids were washed with toluene. The reaction mixture was washed with a 1% solution of sodium cyanide in water, 2 times with water and with brine.

The organic phase was dried with magnesium sulfate and filtered with toluene on silica gel. The solvent was removed in vacuum. To the product 50 ml acetonitrile was added and the mixture was stirred at 75° C. for 5 min. The product was filtered of and was washed with acetonitrile. Yield 8.60 g (64%)

¹H NMR (300 MHz, DMSO-d₆) δ: 9.78 (s, 1H), 7.43 (m, 12H), 1.40 (s, 12H), 1.33 (s, 9H).

### Step 3-7

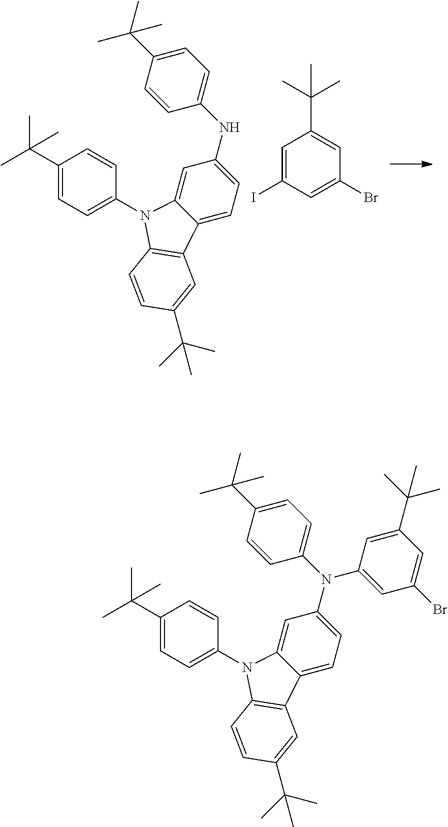

To 11.0 g (21.9 mmol) of the product of step 3-4 in 120 ml toluene, 9.27 g (21.9 mmol) 1-bromo-3-(tert-butyl)-5-iodobenzene and 4.63 g (48.1 mmol) sodium tert-butoxide were added. The reaction mixture was degassed with argon. 200 mg (0.219 mmol) Pd₂(dba)₃ and 506 mg (0.875 mmol) xantphos were added. The reaction mixture was degassed with argon. The reaction mixture was stirred at 100° C. for 1 h under argon.

The reaction mixture was filtered and the solids were washed with toluene. The organic phase was washed with brine and dried with sodium sulfate. The solvent was distilled of. Column chromatography on silica gel with heptane/toluene 98/2 gave the product. The product was crystalized from methanol. Yield 9.28 g (61%).

¹H NMR (300 MHz, CD₂Cl₂) δ: 8.08 (m, 2H), 7.24 (m, 15H), 1.52 (s, 9H), 1.42 (s, 9H), 1.28 (s, 9H), 1.24 (s, 9H).

### Step 3-8

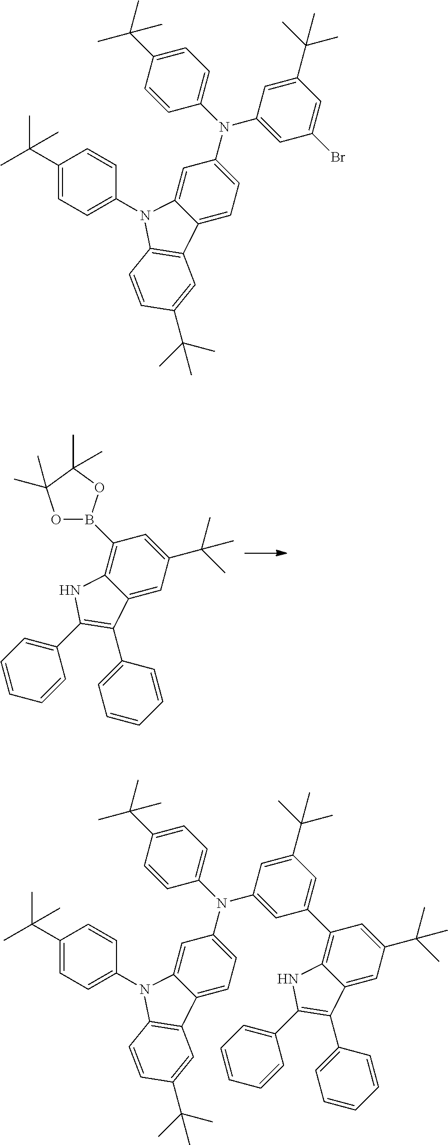

To 9.25 g (13.0 mmol) of the product of step 3-7 in 80 ml toluene, 40 ml dioxane, 30 ml water, 6.16 g (13.0 mmol) of the product of step 3-6 and 6.99 g (32.4 mmol) tripotassium phosphate were added. The reaction mixture was degassed with argon. 213 mg (0.518 mmol) SPhos and 58 mg (0.259 mmol) palladium (II) acetate were added. The reaction mixture was degassed with argon. The reaction mixture was stirred for 3 h under reflux and under argon.

The reaction mixture was filtered and the solids were washed with heptane. The organic phase was washed with water and dried with sodium sulfate. The solvent was distilled of. Column chromatography on silica gel with heptane 100% gave the product. The product was crystalized from methanol. Yield 10.8 g (86%).

¹H NMR (300 MHz, CD₂Cl₂) δ: 8.29 (s, 1H), 8.05 (m, 2H), 7.67 (s, 1H), 7.41 (m, 26H), 1.52 (s, 9H), 1.45 (s, 9H), 1.40 (s, 9H), 1.37 (s, 9H), 1.27 (s, 9H).

### Step 3-9

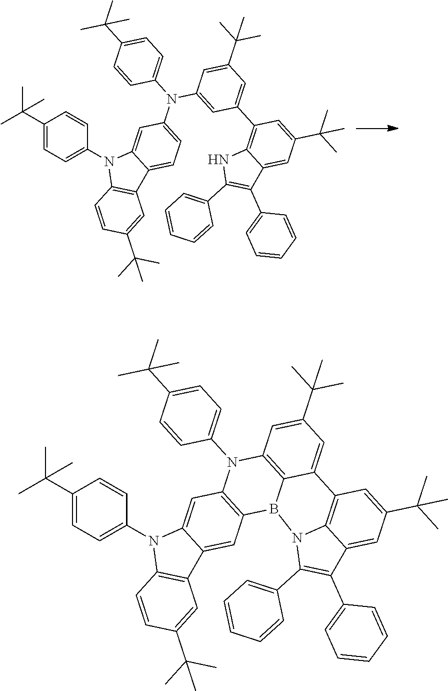

To 7.00 g (7.30 mmol) of the product of step 3-8 and 3.78 g (29.2 mmol)N-ethyl-N-isopropylpro-pan-2-amine in 69 ml water free o-dichlorobenzene 3.66 g (14.6 mmol) tribromoborane was added slowly during stirring and under argon. The reaction mixture was stirred for 7 d at 190° C. under argon.

The reaction mixture was filtered and methanol was added. The precipitated product was filtered of and was washed with methanol. The product was several times crystalized from dichloromethane and n-hexane. Yield: 6.38 g (90%)

¹H NMR (300 MHz, CD₂Cl₂) δ: 8.37 (m, 1H), 8.03 (m, 1H), 7.67 (s, 1H), 7.74 (m, 3H), 7.61 (m, 3H), 7.37 (m, 18H), 7.13 (m, 1H), 1.57 (s, 9H), 1.48 (s, 9H), 1.46 (s, 9H), 1.39 (s, 9H), 1.36 (s, 9H).

### Synthesis Compound 4

### Step 4-1

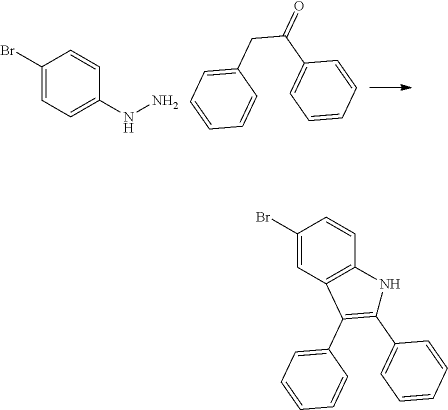

To 10.8 g (55.0 mmol) desoxybenzoin and 12.9 g (57.8 mmol) 4-bromophenylhydrazine hydrochloride in 100 ml ethanol, 10.6 g (110.0 mmol) sulfuric acid (96%) were added. The reaction mixture was stirred at 95° C. under nitrogen for 1 h.

The reaction mixture poured on water and neutralized with a sodium hydrogen carbonate solution in water. The solids were filtered of and were washed with water. The product was dissolved in dichloromethane. The organic phase was dried with magnesium sulfate. The solution of the product was filtered on silica gel with dichloromethane. The solvents were distilled of. Yield 16.4 g (85%).

¹H NMR (300 MHz, DMSO-d₆) δ: 11.8 (s, 1H), 7.55 (d, 1H), 7.37 (m, 12H).

### Step 4-2

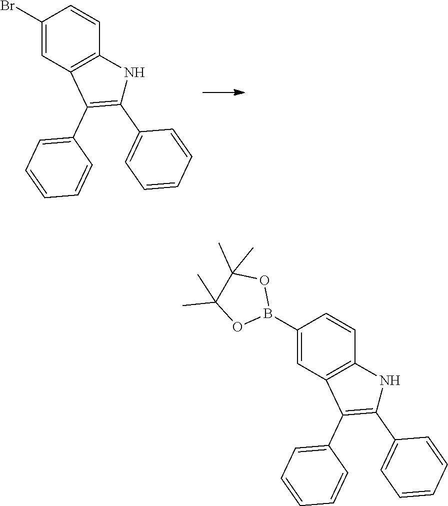 [SMILES: Brc1ccc2[nH]c(-c3ccccc3)c(-c3ccccc3)c2c1 ; CC1(C)OB(c2ccc3[nH]c(-c4ccccc4)c(-c4ccccc4)c3c2)OC1(C)C]

To 7.21 g (20.7 mmol) 5-bromo-2,3-diphenyl-1H-indole in 120 ml dioxane, 9.46 g (37.3 mmol) 4,4,4′,4′,5,5,5′,5′-octamethyl-2,2′-bi(1,3,2-dioxaborolane) and 5.08 g (51.8 mmol) potassium acetate were added. The reaction mixture was degassed with argon. 284 mg (0.311 mmol) Pd₂(dba)₃ and 296 mg (0.621 mmol) 2-dicyclohexylphosphino-2′,4′,6′-triisopropylbiphenyl (x-Phos) were added. The reaction mixture was degassed with argon. The reaction mixture was stirred at 90° C. for 1 h under argon.

The reaction mixture was filtered and the solids were washed with dioxane. The solvent was removed in vacuum. The product was dissolved in 20 ml dioxane and 100 m methanol was added. The product was filtered of. Yield 6.00 g (73%).

¹H NMR (300 MHz, DMSO-d₆) δ: 11.7 (s, 1H), 7.82 (d, 1H), 7.39 (m, 12H), 1.29 (s, 12H).

### Step 4-3

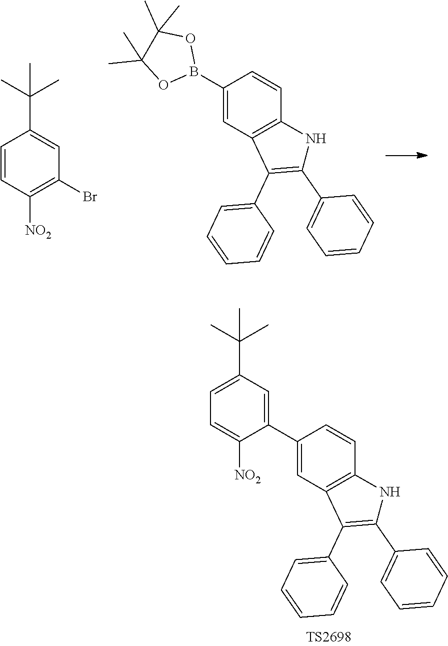

To 6.23 g (15.8 mmol) of the product of step 4-2 in 60 ml toluene, 30 ml dioxane, 20 ml water, 4.07 g (15.8 mmol) 2-bromo-4-(tert-butyl)-1-nitrobenzene and 5.45 g (39.4 mmol) potassium carbonate were added. The reaction mixture was degassed with argon. 259 mg (0.630 mmol) SPhos and 71 mg (0.315 mmol) palladium (II) acetate were added. The reaction mixture was degassed with argon. The reaction mixture was stirred for 2.5 h at 100° C. and under argon.

The solids were filtered of. The organic phase was washed with water and brine. The organic phase was dried with magnesium sulfate. The solvent was distilled of. Column chromatography on silica gel with heptane/ethyl acetate 95/5 gave the product. Yield 5.88 g (79%).

¹H NMR (300 MHz, DMSO-d₆) δ: 11.8 (s, 1H), 7.85 (d, 1H), 7.45 (m, 14H), 7.15 (dd, 1H), 1.34 (s, 9H).

### Step 4-4

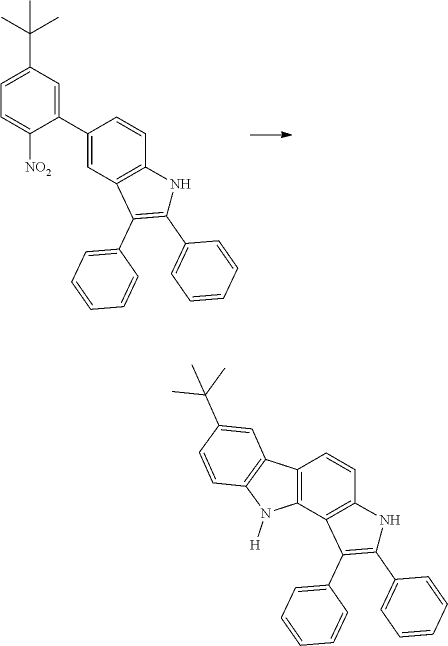 [SMILES: CC(C)(C)c1ccc([N+](=O)[O-])c(-c2ccc3[nH]c(-c4ccccc4)c(-c4ccccc4)c3c2)c1 ; CC(C)(C)c1ccc2[nH]c3c(ccc4[nH]c(-c5ccccc5)c(-c5ccccc5)c43)c2c1]

To 5.88 g (13.2 mmol) of the product of step 4-3 (without solvent), 20.7 g (79.0 mmol) tri-phenylphosphine were added. The reaction mixture was stirred at 200° C. for 1.5 h under nitrogen. Column chromatography on silica gel with heptane/toluene 90/10 gave the product. Yield 3.32 g (61%).

¹H NMR (300 MHz, DMSO-d₆) δ: 11.8 (s, 1H), 9.37 (s, 1H), 8.01 (s, 1H), 7.90 (d, 1H), 7.40 (m, 13H), 1.40 (s, 9H).

### Step 4-5

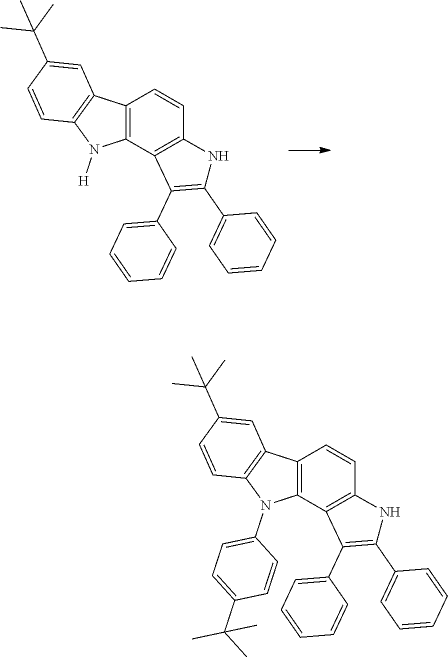 [SMILES: CC(C)(C)c1ccc2[nH]c3c(ccc4[nH]c(-c5ccccc5)c(-c5ccccc5)c43)c2c1 ; CC(C)(C)c1ccc(-n2c3ccc(C(C)(C)C)cc3c3ccc4[nH]c(-c5ccccc5)c(-c5ccccc5)c4c32)cc1]

To 2.90 g (7.00 mmol) of the product of step 4-4 in 30 ml xylene, 1.79 g (8.39 mmol) 1-bromo-4-(tert-butyl)benzene and 1.68 g (17.5 mmol) sodium tert-butoxide ware added. The reaction mixture was degassed with argon. 256 mg (0.280 mmol) Pd₂(dba)₃ and 325 mg (1.12 mmol) tri-tert-butylphosphonium tetrafluoroborate were added. The reaction mixture was degassed with argon.

The reaction mixture was stirred for 1 h at 135° C. and under argon.

The reaction mixture was filtered on silica gel with toluene. Column chromatography on silica gel with heptane/ethyl acetate 95/5 gave the product. Yield 3.65 g (90%).

¹H NMR (300 MHz, DMSO-d₆) δ: 9.59 (s, 1H), 8.03 (s, 1H), 7.94 (d, 1H), 7.30 (m, 16H), 6.97 (d, 1H), 1.40 (s, 9H), 1.31 (s, 9H).

### Step 4-6

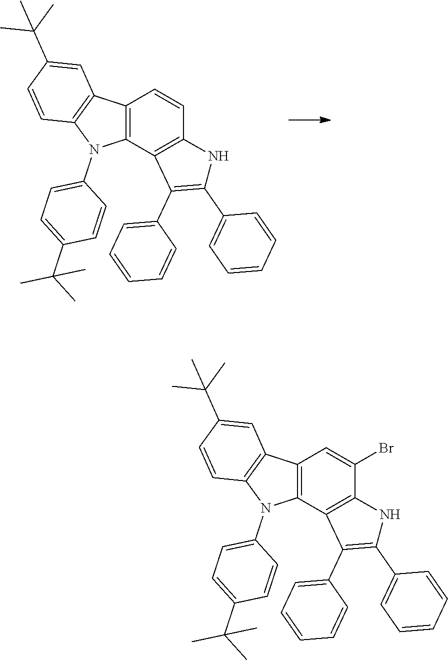 [SMILES: CC(C)(C)c1ccc(-n2c3ccc(C(C)(C)C)cc3c3ccc4[nH]c(-c5ccccc5)c(-c5ccccc5)c4c32)cc1 ; CC(C)(C)c1ccc(-n2c3ccc(C(C)(C)C)cc3c3cc(Br)c4[nH]c(-c5ccccc5)c(-c5ccccc5)c4c32)cc1]

To 3.65 g (6.28 mmol) of the product of step 4-5 in 35 ml dichloromethane, 894 mg (5.02 mmol) N-bromosuccinimide were added at 0° C. under nitrogen. The reaction mixture was stirred 1 h at 0° C. and then 1 h at 25° C. under nitrogen.

The reaction mixture was filtered and the solvent was removed in vacuum. Column chromatography on silica gel with heptane/toluene 95/5 and then heptane/toluene 75/25 gave the product.

Yield 2.92 g (65%).

¹H NMR (300 MHz, DMSO-d₆) δ: 9.58 (s, 1H), 8.23 (s, 1H), 8.12 (s, 1H), 7.37 (m, 11H), 7.11 (m, 5H), 1.39 (s, 9H), 1.25 (s, 9H).

### Step 4-7

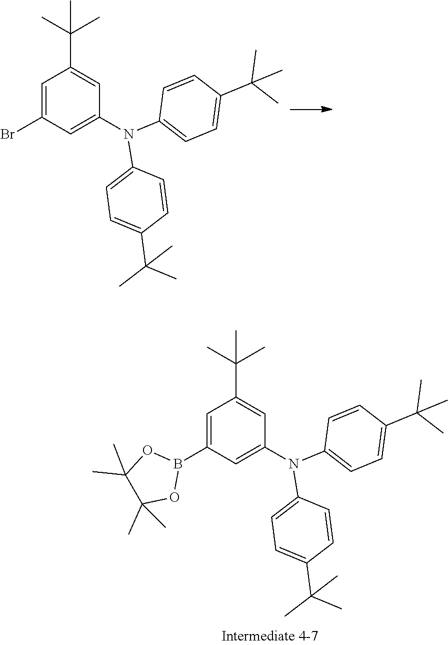

The synthesis of the intermediate 4-7 was described in B2020-002 (Intermediate 22-2).

### Step 4-8

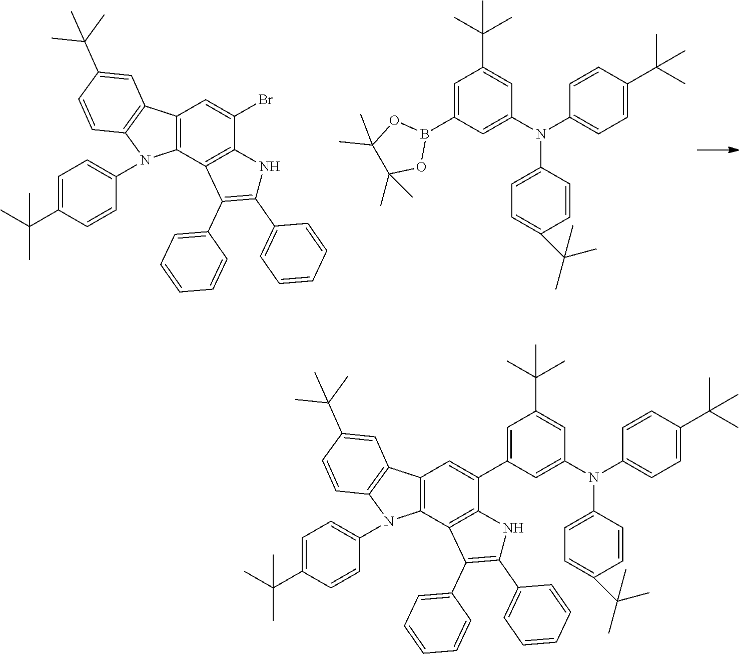 [SMILES: CC(C)(C)c1ccc(-n2c3ccc(C(C)(C)C)cc3c3cc(Br)c4[nH]c(-c5ccccc5)c(-c5ccccc5)c4c32)cc1 ; CC(C)(C)c1ccc(N(c2ccc(C(C)(C)C)cc2)c2cc(B3OC(C)(C)C(C)(C)O3)cc(C(C)(C)C)c2)cc1 ; CC(C)(C)c1ccc(N(c2ccc(C(C)(C)C)cc2)c2cc(-c3cc4c5cc(C(C)(C)C)ccc5n(-c5ccc(C(C)(C)C)cc5)c4c4c(-c5ccccc5)c(-c5ccccc5)[nH]c34)cc(C(C)(C)C)c2)cc1]

To 2.90 g (3.94 mmol) of the product of step 4-6 in 25 ml toluene, 15 ml dioxane, 10 ml water, 2.60 g (4.53 mmol) of the product of step 4-7 and 2.51 g (11.8 mmol) tripotassium phosphate were added. The reaction mixture was degassed with argon. 129 mg (0.315 mmol) SPhos and 35 mg (0.158 mmol) palladium (II) acetate were added. The reaction mixture was degassed with argon. The reaction mixture was stirred for 6 h at 85° C. and under argon.

Heptane was added and the water phase was separated. The organic phase was washed with a 1% sodium cyanide solution in water and dried with sodium sulfate. The solvent was distilled of. Column chromatography on silica gel with heptane 100% and then heptane/toluene 80/20 gave the product. Yield 2.38 g (90%).

¹H NMR (300 MHz, C₂D₂Cl₄) δ: 7.18 (m, 30H), 1.48 (s, 9H), 1.38 (s, 18H), 1.28 (s, 9H), 1.11 (s, 9H).

### Step 4-9

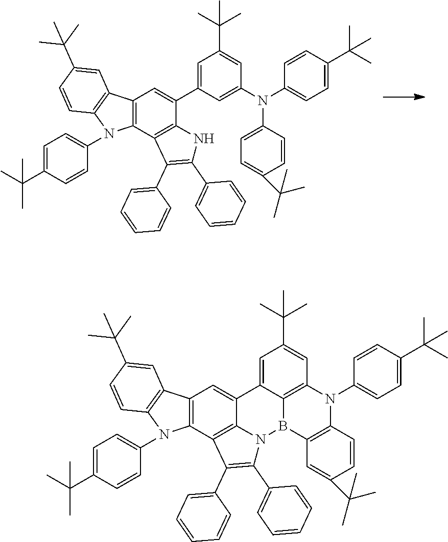

To 1.35 g (1.41 mmol) of the product of step 4-8 and 728 mg (5.63 mmol)N-ethyl-N-isopropylpro-pan-2-amine in 13 ml water free o-dichlorobenzene, 706 mg (2.82 mmol) tribromoborane was added slowly during stirring and under argon. The reaction mixture was stirred for 7 d at 190° C. under argon.

The reaction mixture was poured on 500 ml methanol and 50 ml water. The precipitated product was filtered of and was washed with methanol. Column chromatography on silica gel with heptane 100% and then heptane/toluene 80/20 gave the product. Yield 5 mg (0.4%).

MS (ESI) m/z=966 (M+1)

### Comparative Compound 1

### Intermediate C-1.2

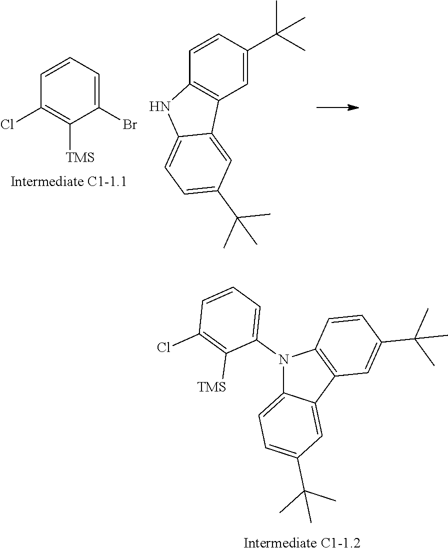

5.00 g (18.97 mmol) of Intermediate C1-1.1, 5.83 g (2.86 mmol) of 3,6-di-tert-butyl-9H-carbazole and 7.29 g (76.00 mmol) of sodium tert-butoxide were added to 150 ml of xylenes. The suspension was degassed using 3 freeze-pump-thaw cycles, and 347 mg (2 mol %) of tris(dibenzylideneacetone)dipalladium(0) and 329 mg (3 mol %) of Xantphos (4,5-bis(diphenylphosphino)-9,9-dimethylxanthene) were added to the reaction mixture. After two additional freeze-pump-thaw cycles, the reaction mixture was heated to 120° C. for 15 hours. An additional 347 mg (2 mol %) of tris(dibenzylideneacetone)dipalladium(0) and 329 mg (3 mol %) of Xantphos were added to the reaction mixture, and the reaction was further heated for a total of 50 hours. The reaction was then cooled to room temperature, extracted with toluene, and the organic extracts were dried over anhydrous MgSO₄ and filtered over a small pad of silica. The pad was washed with toluene, and the solvent of the filtrate was removed on the rotavap. The crude product was purified by silica-gel column chromatography using heptane to give 3.25 g (37% yield) of Intermediate 2-1 as a colorless foam.

¹H NMR (300 MHz, DMSO-d₆) δ 8.27 (d, J=1.5 Hz, 2H), 7.66 (dd, J=8.0, 1.3 Hz, 1H), 7.59 (t, J=7.8 Hz, 1H), 7.45 (dd, J=8.6, 1.9 Hz, 2H), 7.13 (dd, J=7.6, 1.3 Hz, 1H), 6.89 (d, J=8.5 Hz, 2H), 1.41 (s, 18H), 0.14 (s, 9H).

### Intermediate C1-2

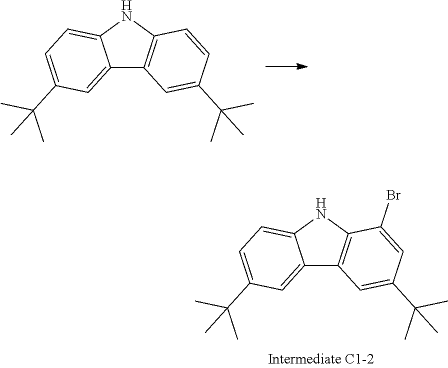 [SMILES: CC(C)(C)c1ccc2[nH]c3ccc(C(C)(C)C)cc3c2c1 ; CC(C)(C)c1ccc2[nH]c3c(Br)cc(C(C)(C)C)cc3c2c1]

5.00 g (17.89 mmol) of 3,6-di-tert-butyl-9H-carbazole were dissolved in 50 ml of acetic acid, and to the white suspension were added 3.18 g (17.89 mmol) of N-bromosuccinimide in portions. After 4 hours, 200 ml of water were added, and the reaction further stirred for 30 minutes. The resulting precipitate was filtered, and the solid was washed with water, sat. NaHCO₃ solution, and water again. The crude product was purified by silica-gel column chromatography using a mixture of heptane and toluene (0-40% gradient), and subsequently purified again by silica-gel column chromatography using a mixture of cyclohexane and dichloromethane (0-3% gradient). Pure fractions were combined and the solvent removed on the rotavap to give 3.42 g (45% yield) of Intermediate C1-2 as a clear colorless oil.

¹H NMR (300 MHz, DMSO-d₆) a 11.10 (s, 1H), 8.20 (d, J=1.5 Hz, 1H), 8.18 (dd, J=1.4, 0.9 Hz, 1H), 7.57 (d, J=1.7 Hz, 1H), 7.50 (dd, J=8.6, 1.8 Hz, 1H), 7.45 (dd, J=8.7, 0.8 Hz, 1H), 1.40 (s, 18H).

### Intermediate C1-3

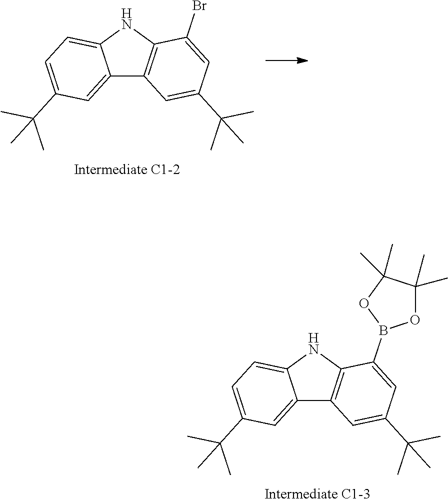 [SMILES: CC(C)(C)c1ccc2[nH]c3c(Br)cc(C(C)(C)C)cc3c2c1 ; CC(C)(C)c1ccc2[nH]c3c(B4OC(C)(C)C(C)(C)O4)cc(C(C)(C)C)cc3c2c1]

3.40 g (9.49 mmol) of Intermediate C1-2, 3.13 g (12.34 mmol) of bis(pinacolato)diboron and 3.73 g (39.20 mmol) of potassium acetate were suspended in 40 ml of anhydrous N,N-dimethylformamide. The suspension was degassed by evacuating the reaction vessel with high vacuum and backfilling with argon. The procedure was repeated 7 times, and 542 mg (7 mol %) of [1,1′-bis(di-phenylphosphino)ferrocene]dichloropalladium(II), complex with dichloromethane were added to the reaction mixture before repeating the evacuation-backfilling 2 times. The reaction mixture was then heated to 80° C. for 21 hours. After cooling to room temperature, the reaction was diluted with diethyl ether and washed with water, dried over MgSO₄ and filtered over a small pad of silica-gel. The pad was washed with 300 ml of 5:1 mixture of cyclohexane and diethyl ether.

The solvents were removed on the rotavap, and to the brown residue were added 30 ml of petroleum ether 60-80. The solution was then concentrated until a white powder precipitated. The solid was filtered and washed with cold petroleum ether to give 3.05 g (79% yield) of Intermediate C1-3 as a white powder.

¹H NMR (300 MHz, DMSO-d₆) δ 10.04 (s, 1H), 8.34 (d, J=2.0 Hz, 1H), 8.16 (d, J=1.9 Hz, 1H), 7.71 (d, J=2.1 Hz, 1H), 7.60 (d, J=8.6 Hz, 1H), 7.45 (dd, J=8.6, 2.0 Hz, 1H), 1.41 (s, 30H).

### Intermediate C1-4

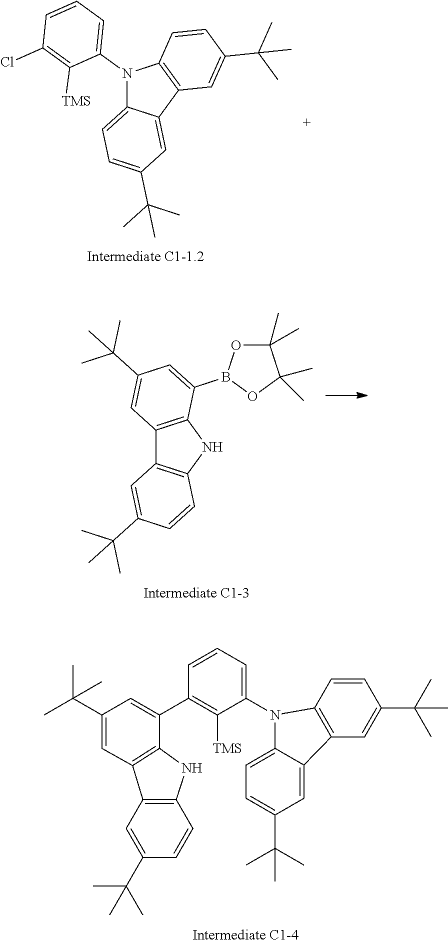

2.00 g (4.33 mmol) of Intermediate C1-1.2, 2.46 g (6.06 mmol) of Intermediate C1-3 and 3.67 g (17.3 mmol) of K₃PO₄ were suspended in a mixture of 50 ml of toluene, 25 ml of dioxane, and 15 ml of water. The suspension was degassed using 3 freeze-pump-thaw cycles, and 9.7 mg (1 mol %) of palladium(II) acetate and 107 mg (6 mol %) of SPhos were added to the reaction mixture. After two additional freeze-pump-thaw cycles, the reaction mixture was heated to 80° C. for hours, then an additional 0.35 g (0.86 mmol) of Intermediate 2-3, 9.7 mg (1 mol %) of palladium(II) acetate and 107 mg (6 mol %) of SPhos were added, and the reaction heated to 80° C. for a further 12 hours. The reaction was then cooled to room temperature and extracted with toluene, and the organic extracts were dried over anhydrous MgSO₄, and filtered over a small pad of silica. The pad was washed with toluene, and the solvent of the filtrate was removed on the rotavap. The crude product was purified by silica-gel column chromatography using a mixture of heptane and tetrahydrofuran (0-1% gradient), to give 2.80 g (92% yield) of Intermediate C1-4 as a white foam.

¹H NMR (300 MHz, DMSO-d₆) δ 10.70 (s, 1H), 8.27 (d, J=1.9 Hz, 2H), 8.22 (d, J=1.8 Hz, 1H), 8.20-8.17 (m, 1H), 7.70 (t, J=7.6 Hz, 1H), 7.56 (dd, J=7.5, 1.3 Hz, 1H), 7.54-7.47 (m, 2H), 7.46-7.41 (m, 2H), 7.33 (d, J=1.8 Hz, 1H), 7.24 (d, J=8.5 Hz, 1H), 7.20 (dd, J=7.8, 1.2 Hz, 1H), 7.12 (d, J=8.6 Hz, 1H), 1.47 (s, 9H), 1.45-1.43 (m, 18H), 1.42 (s, 9H), −0.72 (s, 9H).

### Comparative Compound 1

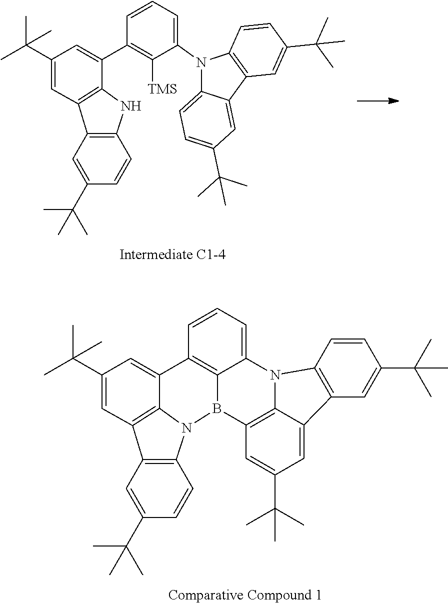

2.44 g (3.46 mmol) of Intermediate C1-4 were dissolved in 70 ml of 1,2-dichlorobenzene and the reaction vessel was purged with nitrogen. 2.42 ml (13.84 mmol) of N,N-diisopropylethylamine were added at room temperature, followed by the dropwise addition of 5.20 ml (5.20 mmol) of tribromoborane (1 M solution in heptane). The resulting clear pale orange solution was heated to 145° C. for 20 hours before cooling to room temperature. The reaction was quenched with the slow addition of 15 ml of methanol, and the resulting solution was poured into 200 ml of methanol. The yellow precipitate was stirred for 5 minutes then filtered, and washed with methanol and dried to give 1.11 g (50% yield) of Comparative Compound 1 as a yellow solid.

¹H NMR (300 MHz, THF-d₈) δ 9.00 (d, J=1.9 Hz, 1H), 8.65 (d, J=8.7 Hz, 1H), 8.58 (d, J=1.9 Hz, 1H), 8.54 (d, J=1.7 Hz, 1H), 8.52 (d, J=8.3 Hz, 1H), 8.46-8.35 (m, 3H), 8.35 (d, J=1.6 Hz, 1H), 8.31 (d, J=1.9 Hz, 1H), 7.95 (t, J=8.1 Hz, 1H), 7.70 (dd, J=8.9, 2.0 Hz, 1H), 7.62 (dd, J=8.7, 2.1 Hz, 1H), 1.61 (s, 18H), 1.54-1.50 (m, 18H).

### II Evaluation of Compounds

### 1 Device Application Data (Invented Compound as Emitter Dopant)

### Preparation and Evaluation of Organic EL Devices

The organic EL devices were prepared and evaluated as follows:

### Application Example 1

A glass substrate with 130 nm-thick indium-tin-oxide (ITO) transparent electrode (manufactured by Geomatec Co., Ltd.) used as an anode was first treated with N2 plasma for 100 sec. This treatment also improved the hole injection properties of the ITO. The cleaned substrate was mounted on a substrate holder and loaded into a vacuum chamber. Thereafter, the organic materials specified below were applied by vapor deposition to the ITO substrate at a rate of approximately 0.2-1 Å/sec at about 10⁻⁶-10⁻⁸ mbar. As a hole injection layer, 10 nm-thick mixture of Compound HT-1 and 3% by weight of compound HI were applied. Then 80 nm-thick of Compound HT-1 and 10 nm of Compound HT-2 were applied as hole transporting layer 1 and hole transporting layer 2, respectively. Subsequently, a mixture of 2% by weight of an emitter Compound 1 and 98% by weight of host Compound BH-1 were applied to form a 25 nm-thick fluorescence-emitting layer. On the emitting layer, 10 nm-thick Compound ET-1 was applied as electron transporting layer 1 and 15 nm of Compound ET-2 as electron transporting layer 2. Finally, 1 nm-thick LiF was deposited as an electron injection layer and 80 nm-thick Al was then deposited as a cathode to complete the device. The device was sealed with a glass lid and a getter in an inert nitrogen atmosphere with less than 1 ppm of water and oxygen.

To characterize the OLED, electroluminescence (EL) spectra were recorded at various currents and voltages. EL peak maximum and Full Width at Half Maximum (FWHM) were recorded at 10 mA/cm². In addition, the current-voltage characteristics were measured in combination with the luminance to determine luminous efficiency and external quantum efficiency (EQE). Driving voltage (Voltage) was given at a current density of 10 mA/cm². The device results are shown in Table 1.

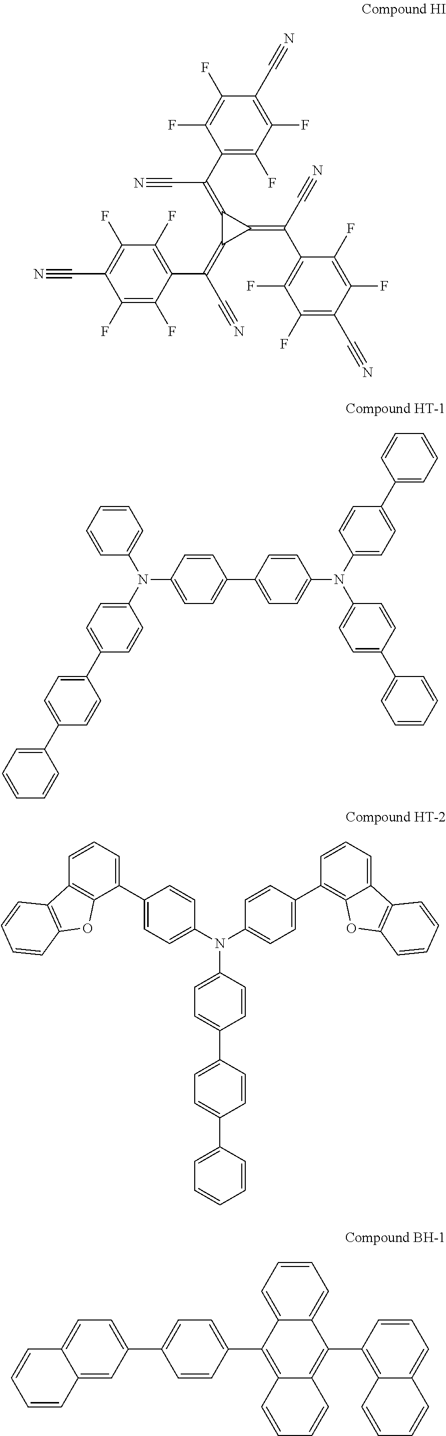

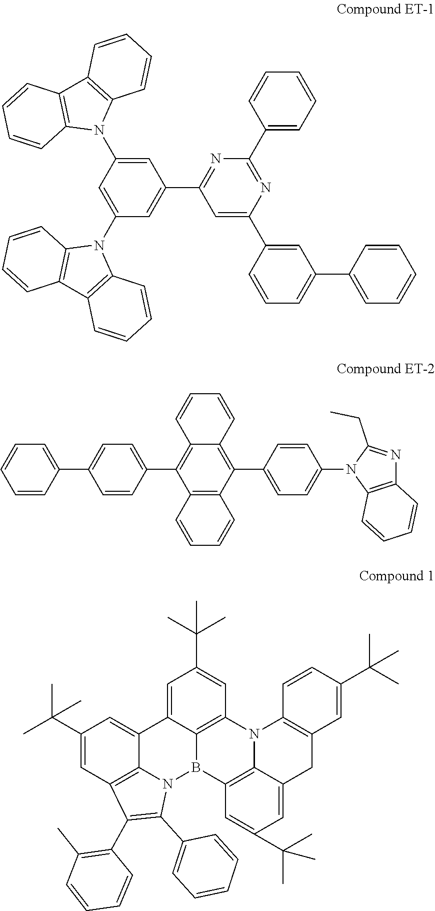 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; CCc1nc2ccccc2n1-c1ccc(-c2c3ccccc3c(-c3ccc(-c4ccccc4)cc3)c3ccccc23)cc1 ; Cc1ccccc1-c1c(-c2ccccc2)n2c3c(cc(C(C)(C)C)cc13)-c1cc(C(C)(C)C)cc3c1B2c1cc(C(C)(C)C)cc2c1N3c1ccc(C(C)(C)C)cc1C2]

### Comparative Application Example 1

Application Example 1 was repeated except for using the Comparative Compound 1 instead of the Compound 1. The device results are shown in Table 1.

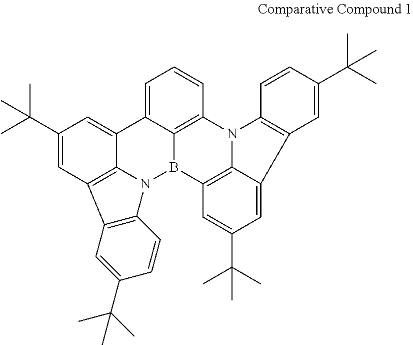 [SMILES: CC(C)(C)c1ccc2c(c1)c1cc(C(C)(C)C)cc3c1n2B1c2c-3cccc2-n2c3ccc(C(C)(C)C)cc3c3cc(C(C)(C)C)cc1c32]

TABLE 1

| Appl. Ex. | Voltage, V | EQE, % |
|---|---|---|
| Appl. Ex. 1 | 3.65 | 9.64 |
| Comp. Appl. Ex. 1 | 3.69 | 9.00 |

These results demonstrate that Compound 1 gives a better EQE than Comparative Compound 1 when used as blue fluorescent emitting material in OLED devices.

### Application Example 2

Application Example 1 was repeated except the emitter Compound 1 was replaced with Compound 2 in fluorescent emitting layer. The device results are shown in Table 2 and 3.

### Application Example 3

Application Example 1 was repeated except the emitter Compound 1 was replaced with Compound 3 in fluorescent emitting layer. The device results are shown in Table 3.

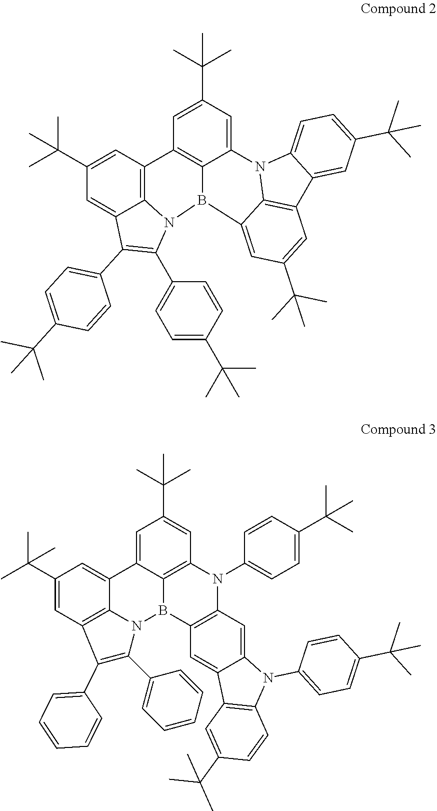

TABLE 2

| Appl. Ex. | Voltage, V | EQE, % |
|---|---|---|
| Appl. Ex. 2 | 3.66 | 9.62 |

These results demonstrate that Compound 2 gives better EQE than Comparative Compound 1 when used as blue fluorescent emitting material in OLED devices.

TABLE 3

| Appl. Ex. | Voltage, V | LT95, h |
|---|---|---|
| Appl. Ex. 2 | 3.66 | 153 |
| Appl. Ex. 3 | 3.69 | 130 |

These results demonstrate that Compounds 2 and 3 give longer LT95 than Comparative Compound 1 when used as blue fluorescent emitting material in OLED devices.

1: A heterocyclic compound represented by formula (I): 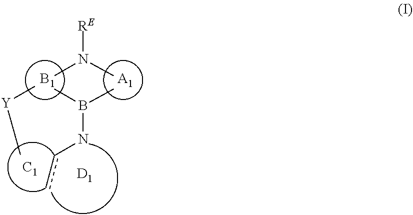
wherein ring A₁, ring B₁ and ring C₁ each independently represents a substituted or unsubstituted aromatic group having 6 to 60 ring carbon atoms, or a substituted or unsubstituted heteroaromatic group having 5 to 60 ring atoms;
ring D₁ represents a substituted or unsubstituted, monocyclic ring having 5 to 7 ring atoms, which may be fused with at least one unsubstituted or substituted non-aromatic group having 5 to 60 ring atoms;
ring C₁ and ring D₁ are fused together by a shared single or double bond;
ring A₁ and ring D₁ may additionally be connected via a direct bond, O, S, NR²³, SiR²⁴R²⁵ or CR²⁷R²⁸;
R^{E} represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an iminyl group R²³—C═N, an alkynyl group having from 2 to 20 carbon atoms which is unsubstituted or substituted; or
R^{E} or a substituent on R^{E} may be bonded to the ring A₁ and/or to the ring B₁ or to a substituent on the ring A₁ and/or the ring B₁ to form a ring structure which is unsubstituted or substituted,
Y represents a direct bond, O, S, NR²³, SiR²⁴R²⁵ or CR²⁷R²⁸;
in the case that Y is a direct bond, ring B₁ and C₁ may additionally be connected via O, S, NR²³, SiR²⁴R²⁵ or CR²⁷R²⁸;
R²³, R²⁴, R²⁵, R²⁷ and R²⁸ each independently represents an aryl group having from 6 to 60 ring carbon atoms which is unsubstituted or substituted; a heteroaryl group having from to 60 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted; and/or
R²³, R²⁴, R²⁵, R²⁷ and R²⁸ may be bonded to the ring B₁ and/or to the ring C₁ to form a ring structure which is unsubstituted or substituted; and/or
two residues R²⁴ and R²⁵ and/or two residues R²⁷ and R²⁸ together form a ring structure which is unsubstituted or substituted.

2: The heterocyclic compound according to claim 1, represented by the following formula (II): 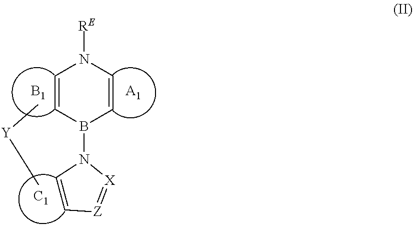
wherein X and Z each independently represents CR²⁹ or N; and
R²⁹ represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
one residue R²⁹ at the X position and one residue R²⁹ at the Z position together form an unsubstituted or substituted non-aromatic group having 5 to 60 ring atoms; and/or
R²⁹ at the X position and ring A₁ may be connected via a direct bond, O, S, NR²³, SiR²⁴R²⁵ or CR²⁷R²⁸; and/or
R²⁹ at the Z position may be bonded to the ring C₁ to form a ring structure which is unsubstituted or substituted;
wherein R²⁹ at the X position and R²⁹ at the Z position may be different or the same.

3: The heterocyclic compound according to claim 1, represented by the following formula (III): 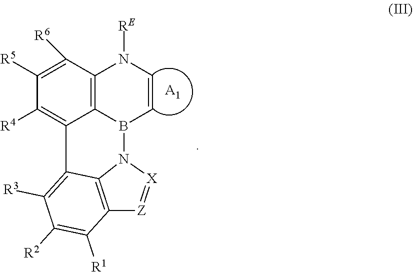
wherein R¹, R², R³, R⁴, R⁵ and R⁶ each independently represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
two adjacent residues R¹, R² and/or R³ and/or two adjacent residues R⁴, R⁵ and/or R⁶ together form a ring structure which is unsubstituted or substituted; and/or
R²⁹ at the Z position and R¹ may together form a ring structure which is unsubstituted or substituted; and/or
R⁶ is bonded to R^{E} or a substituent on R^{E} to form a ring structure which is unsubstituted or substituted;
R²⁰ and R²² each independently represents an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; or a cycloalkyl group having from 3 to 20 ring carbon atoms which is unsubstituted or substituted;
R²¹ represents an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; N(R²²)₂ or OR²⁰; and/or
two residues R²² and/or two residues R²¹ together form a ring structure which is unsubstituted or substituted; or
R²⁰, R²¹, and/or R²² together with an adjacent residue R¹, R², R³, R⁴, R⁵ and R⁶ forms a ring structure which is unsubstituted or substituted; and
R²⁴, R²⁵ and R²⁶ each independently represents an aryl group having from 6 to 60 ring carbon atoms which is unsubstituted or substituted; a heteroaryl group having from 5 to 60 ring atoms which is unsubstituted or substituted and which is linked via a carbon atom to N or Si; an alkyl group having from 1 to 20 carbon atoms which is unsubstituted or substituted; or a cycloalkyl group having from 3 to 20 ring carbon atoms which is unsubstituted or substituted and/or
two residues R²⁴ and R²⁵ together form a ring structure which is unsubstituted or substituted.

4: The heterocyclic compound according to claim 1, represented by the following formula (IV); 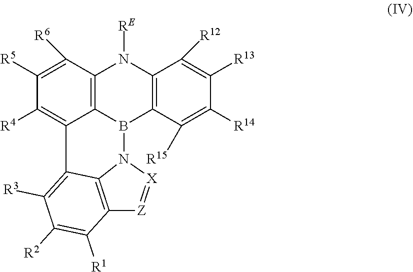
wherein R¹², R¹³, R¹⁴ and R¹⁵ each independently represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; or
two adjacent residues R¹², R¹³, R¹⁴ and/or R¹⁵ together form a ring structure which is unsubstituted or substituted, and/or
R¹² is bonded to R^{E} or a substituent on R^{E} to form a ring structure which is unsubstituted or substituted and/or
R²⁹ at the X position and R¹⁵ may be connected via a direct bond, O, S, NR²³, SiR²⁴R²⁵ or CR²⁷R²⁸.

5: The heterocyclic compound according to claim 1, represented by the following formula (I-1): 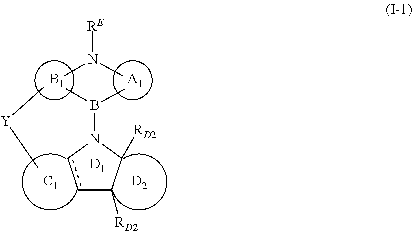
wherein the dotted line in the ring structure of D₁ is an optional double bond;
ring D₂ represents a substituted or unsubstituted aliphatic ring or a nonheteroaromatic monocyclic ring having 5 to 7 ring atoms, which may be fused with at least one unsubstituted or substituted non-aromatic group having 5 to 60 ring atoms; R_{D2} each independently represents an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; a cycloalkyl group having from 3 to 20 ring carbon atoms which is unsubstituted or substituted; an alkenyl group having from 2 to 20 carbon atoms which is unsubstituted or substituted; an alkynyl group having from 2 to 20 carbon atoms which is unsubstituted or substituted; or
two R_{D2} together form a ring structure which is unsubstituted or substituted.

6: The heterocyclic compound according to claim 1, wherein R^{E} is a group of the following formula (V): 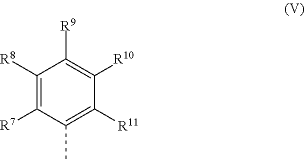
wherein R⁷, R⁸, R⁹, R¹⁰ and R¹¹ each independently represents hydrogen; an aryl group having from 6 to 60 ring carbon atoms which is unsubstituted or substituted; a heteroaryl group having from 5 to 60 ring atoms which is unsubstituted or substituted; an alkyl group having from 1 to 20 carbon atoms which is unsubstituted or substituted; an alkylhalide group having from 1 to 20 carbon atoms which is unsubstituted or substituted; a cycloalkyl group having from 3 to 20 ring carbon atoms which is unsubstituted or substituted; CN; N(R²²)₂; OR²⁰; SR²⁰; B(R²¹)₂; SiR²⁴R²⁵R²⁶ or halogen; and/or
two adjacent residues R⁷, R⁸, R⁹, R¹⁰ and/or R¹¹ together form a ring structure which is unsubstituted or substituted; and/or
R⁷ and/or R¹¹ are connected to the ring B₁ and/or to the ring A₁ or to a substituent on the ring A₁ and/or the ring B₁ to form a ring structure which is unsubstituted or substituted; and
the dotted line is a bonding site.

7: The heterocyclic compound according to claim 2, wherein R²⁹ represents an aryl group having from 6 to 60 ring carbon atoms which is unsubstituted or substituted; a heteroaryl group having from 5 to 60 ring atoms which is unsubstituted or substituted; or an alkyl group having from 1 to 20 carbon atoms which is unsubstituted or substituted.

8: The heterocyclic compound according to claim 2, wherein at least one of R²⁹ is not hydrogen.

9: A material for an organic electroluminescence device, comprising the heterocyclic compound of claim 1.

10: An organic electroluminescence device comprising the heterocyclic compound of claim 1.

11: The organic electroluminescence device according to claim 10, comprising a cathode, an anode and one or more organic thin film layers comprising an emitting layer disposed between the cathode and the anode, wherein at least one layer of the organic thin film layers comprises the heterocyclic compound.

12: The organic electroluminescence device according to claim 11, wherein the light emitting layer comprises the heterocyclic compound.

13: The organic electroluminescence device according to claim 12, wherein the light emitting layer comprises at least one host and at least one dopant, wherein the dopant comprises the heterocyclic compound.

14. The organic electroluminescence device according to claim 13, wherein the host comprises at least one substituted or unsubstituted fused aromatic hydrocarbon compound and/or at least one substituted or unsubstituted anthracene compound.

15: The organic electroluminescence device according to claim 14, wherein the anthracene compound is represented by the following formula (10): 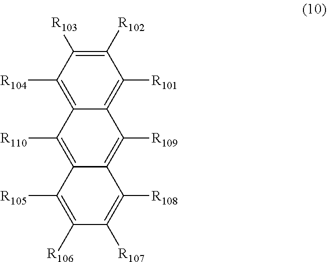
wherein one or more pairs of two or more adjacent R₁₀₁ to R₁₁₀ may form a substituted or unsubstituted, saturated or unsaturated ring;
R₁₀₁ to R₁₁₀ that do not form the substituted or unsubstituted, saturated or unsaturated ring are independently a hydrogen atom, a substituted or unsubstituted alkyl group including 1 to 50 carbon atoms, a substituted or unsubstituted haloalkyl group including 1 to 50 carbon atoms, a substituted or unsubstituted alkenyl group including 2 to 50 carbon atoms, a substituted or unsubstituted alkynyl group including 2 to 50 carbon atoms, a substituted or unsubstituted cycloalkyl group including 3 to 50 ring carbon atoms, a substituted or unsubstituted alkoxy group including 1 to 50 carbon atoms, a substituted or unsubstituted alkylene group including 1 to 50 carbon atoms, a substituted or unsubstituted aryloxy group including 6 to 50 ring carbon atoms, a substituted or unsubstituted arylthio group including 6 to 50 ring carbon atoms, a substituted or unsubstituted aralkyl group including 7 to 50 carbon atoms, —Si(R₁₂₁)(R₁₂₂)(R₁₂₃), —C(═O)R₁₂₄, —COOR₁₂₅, —N(R₁₂₆)(R₁₂₇), a halogen atom, a cyano group, a nitro group, a substituted or unsubstituted aryl group including 6 to 50 ring carbon atoms, a substituted or unsubstituted monovalent heterocyclic group including 5 to 50 ring atoms, or a group represented by the following formula (31);
R₁₂₁ to R₁₂₇ are independently a hydrogen atom, a substituted or unsubstituted alkyl group including 1 to 50 carbon atoms, a substituted or unsubstituted cycloalkyl group including 3 to 50 ring carbon atoms, a substituted or unsubstituted aryl group including 6 to 50 ring carbon atoms or a substituted or unsubstituted monovalent heterocyclic group including 5 to 50 ring atoms; when each of R₁₂₁ to R₁₂₇ is present in plural, each of the plural R₁₂₁ to R₁₂₇ may be the same or different; provided that at least one of R₁₀₁ to R₁₁₀ that do not form the substituted or unsubstituted, saturated or unsaturated ring is a group represented by the following formula (31); if two or more groups represented by the formula (31) are present, each of these groups may be the same or different;
-L₁₀₁-Ar₁₀₁ (31)
wherein in the formula (31), L₁₀₁ is a single bond, a substituted or unsubstituted arylene group including 6 to 30 ring carbon atoms or a substituted or unsubstituted divalent heterocyclic group including 5 to 30 ring atoms; Ar₁₀₁ is a substituted or unsubstituted aryl group including 6 to 50 ring carbon atoms or a substituted or unsubstituted monovalent heterocyclic group including 5 to 50 ring atoms.

16: An electronic equipment comprising the organic electroluminescence device according to claim 10.

17: A light emitting layer comprising at least one host and at least one dopant, wherein the dopant comprises the compound according to claim 1.

18. (canceled)
